(19) United States
(12) Patent Application Publication
(10) Pub. No.: US 2020/0357838 A1
(43) Pub. Date: Nov. 12, 2020

(54) LAMINATED LENS STRUCTURE, SOLID-STATE IMAGING ELEMENT, AND ELECTRONIC APPARATUS

(71) Applicant: SONY SEMICONDUCTOR SOLUTIONS CORPORATION, Kanagawa (JP)

(72) Inventors: Munekatsu FUKUYAMA, Tokyo (JP); Hirotaka YOSHIOKA, Kanagawa (JP); Kunihiko HIKICHI, Kanagawa (JP); Atsushi YAMAMOTO, Kanagawa (JP); Kaori TAKIMOTO, Kanagawa (JP); Minoru ISHIDA, Tokyo (JP)

(73) Assignee: SONY SEMICONDUCTOR SOLUTIONS CORPORATION, Kanagawa (JP)

(21) Appl. No.: 16/640,898

(22) PCT Filed: Aug. 17, 2018
(86) PCT No.: PCT/JP2018/030493

§ 371 Date: Feb. 21, 2020

(30) Foreign Application Priority Data
Aug. 31, 2017 (JP) 2017-167826

(51) Int. Cl. H01L 27/146; G02B 3/04; H04N 5/225

(52) U.S. Cl. CPC H01L 27/14627; B29D 11/00375; H04N 5/2254; G02B 3/04

(57) ABSTRACT

Provided is a laminated lens structure capable of corresponding various optical parameters. The laminated lens structure includes at least one or more sheets of first lens-attached substrates and at least one or more sheets of second lens-attached substrates as a lens-attached substrate including a lens resin portion that forms a lens, and a carrier substrate that carries the lens resin portion. The carrier substrate of the first lens-attached substrates is constituted by laminating a plurality of sheets of carrier configuration substrates in a thickness direction, and the carrier substrate of the second lens-attached substrates is constituted by one sheet of carrier configuration substrate. For example, the present technology is applicable to a camera module and the like.

### TECHNICAL FIELD

The present technology relates to a laminated lens structure, a solid-state imaging element, and an electronic apparatus, and particularly to, a laminated lens structure, a solid-state imaging element, and an electronic apparatus which can provide a laminated lens structure capable of corresponding to various optical parameters.

### CROSS REFERENCE TO RELATED APPLICATIONS

This application claims the benefit of Japanese Priority Patent Application JP 2017-167826 filed on Aug. 31, 2017, the entire contents of which are incorporated herein by reference.

### BACKGROUND ART

As an imaging lens that is suitable for an optical system of a complementary metal oxide semiconductor (CMOS) image sensor, PTL 1 discloses an optical system (lens group) for a camera which pursues satisfactory optical performance while having a simple lens configuration of a small number of lenses.

In addition, PTL 2 discloses a technology of providing a laminated lens structure in which a lens is formed on a substrate capable of being used in manufacturing of an electronic device such as a semiconductor device and a flat panel display device, and a plurality of sheets of the resultant lens-attached substrates are laminated.

### CITATION LIST

### Patent Literature

PTL 1: JP 2005-345919A
PTL 2: WO 2017/022190A

### SUMMARY OF INVENTION

### Technical Problem

For example, in a camera module embedded in a smart phone, high-quality image and high function are in progress, and a demand for variation expansion of parameters such as the thickness of a lens, a curvature of the lens, and a distance between adjacent two lenses, which have an effect on the performance of the optical system for a camera, has increased.

The present technology has been made in consideration of the above-described circumstances, and it is desired to provide a laminated lens structure capable of corresponding to various optical parameters.

### Solution to Problem

According to a first aspect of the present technology a laminated lens structure in accordance with independent claim 1 is provided. According to a second aspect of the present technology a solid-state imaging element according to independent claim 15 is provided. According to a third aspect of the present technology an electronic apparatus according to independent claim 16 is provided. Further aspects of the present technology are provided in the dependent claims, the drawings and in the following description.

Some embodiments pertain to a laminated lens structure comprising:

at least one sheet of a first type of lens-attached substrate and at least one sheet of a second type of lens-attached substrate, wherein each of the first type and the second type lens-attached substrate includes a lens resin portion that forms a lens, and a carrier substrate that carries the lens resin portion,

wherein the carrier substrate of the first type of lens-attached substrate is constituted by a plurality of sheets of carrier configuration substrates which are laminated in a thickness direction of the carrier substrate, and

the carrier substrate of the second type of lens-attached substrate is constituted by one sheet of carrier configuration substrate.

Hence, in some embodiments, the laminated lens structure comprises multiple sheets of the first type of lens-attached substrate and multiple sheets of the second type of lens-attached substrate. The sheets of the first and the second type of lens-attached substrate may be arranged in any order with respect to each other. Moreover, the laminated lens structure may additionally comprise one or more sheets of lens-attached substrate which are neither of the first nor of the second type of lens-attached substrate.

In some embodiments, the thickness of the carrier substrate of the first type of lens-attached substrate is larger than the thickness of the carrier substrate of the second type of lens-attached substrate.

In some embodiments, a sheet of the first type of lens-attached substrate is disposed on a side closest to a light incident surface.

In some embodiments, a sheet of the first type of lens-attached substrate is disposed on a side closest to an imaging unit.

In some embodiments, a sheet of the first type of lens-attached substrate is disposed on a side closest to a light and another sheet of the first type of lens-attached substrate is disposed on a side closest to an imaging unit. Hence, in such embodiments the laminated lens structure includes at least two sheets of the first type of lens-attached substrate.

In some embodiments, the laminated lens structure comprises at least two sheets of the first type of lens-attached substrate,

wherein the thickness of each of the plurality of sheets of carrier configuration substrates which constitute the carrier substrate of a predetermined sheet of the at least two sheets of the first type of lens-attached substrates is larger than the thickness of the carrier substrate of the at least one sheet of the second type of lens-attached substrate. In other words, at least one of the at least two sheets of the first type of lens-attached substrate is the predetermined sheet.

In some embodiments, the laminated lens structure comprises at least two sheets of the first type of lens-attached substrate,

wherein the thickness of each of the plurality of sheets of carrier configuration substrates which constitute the carrier substrate of a predetermined sheet of the at least two sheets of the first type of lens-attached substrates is smaller than the thickness of the carrier substrate of the at least one sheet of the second type of lens-attached substrate. In some embodiments, this applies to all sheets of the first and second type of lens-attached substrate, respectively.

In some embodiments, the thickness of the lens resin portion in a region, in which the lens resin portion and the carrier substrate of each of the at least one sheet of the first type of lens-attached substrate are in contact with each other, in a direction that is perpendicular to the at least one sheet of the first type of lens-attached substrate is larger than the thickness of the lens resin portion in a region, in which the lens resin portion and the carrier substrate of each of the at least one sheet of the second type of lens-attached substrate are in contact with each other, in a direction that is perpendicular to the at least one sheet of the second type of lens-attached substrate. In some embodiments, this applies to all sheets of the first and second type of lens-attached substrate, respectively.

In some embodiments, the thickness of a central portion of the lens resin portion of each of the at least one sheet of the first type of lens-attached substrate is larger than the thickness of the central portion of the lens resin portion of each of the at least one sheet of the second type of lens-attached substrates. In some embodiments, this applies to all sheets of the first and second type of lens-attached substrate, respectively.

In some embodiments, the thickness of the lens of each of the at least one sheet of the first type of lens-attached substrate is larger than the thickness of the lens of each of the at least one sheet of the second type of lens-attached substrate. In some embodiments, this applies to all sheets of the first and second type of lens-attached substrate, respectively.

In some embodiments, the at least one sheet of the second type of lens-attached substrate includes:

an extension structure in which a lower surface of the lens resin portion provided in the lens-attached substrate further extends to a lower side in comparison to a lower surface of the carrier substrate that carries the lens resin portion, and/or
an upper surface of the lens resin portion provided in the lens-attached substrate further extending to an upper side in comparison to an upper surface of the carrier substrate that carries the lens resin portion, and/or
the lens resin portion provided in the lens-attached substrate further extending in upper and lower directions in comparison to the thickness of the carrier substrate.

In some embodiments, the laminated lens structure further comprises at least one sheet of a third type of lens-attached substrate including one sheet of the second type of lens-attached substrate including the extension structure,

wherein the thickness of the lens of the at least one sheet of the third type of lens-attached substrate is larger than the thickness of the lens of any of the at least one sheet of the second type of lens-attached substrate having a thickness of the carrier substrate being equal to or larger than the thickness of the carrier substrate of the third type of lens-attached substrate.

In some embodiments, the laminated lens structure further comprises at least one sheet of a third type of lens-attached substrate including one sheet of the second type of lens-attached substrate including the extension structure, and a further sheet of the second type of lens-attached substrate which is adjacent to the sheet of the third type of lens-attached substrate, and in which a part of the lens resin portion of the sheet of the third type of lens-attached substrate is disposed, and wherein

the sum of the thickness of the lens resin portion that exists in a through-hole of the further sheet of the second type of lens-attached substrate is larger than the thickness of the lens resin portion of any of the other sheets of the second type of lens-attached substrates in which the thickness of the carrier substrate is equal to or less than the thickness of the carrier substrate of the further sheet of the second type of lens-attached substrate.

In some embodiments, the laminated lens structure further comprises a sheet of a third type of lens-attached substrate including one sheet of the second type of lens-attached substrate including the extension structure, wherein

a part of the lens resin portion of the sheet of the third type of lens-attached substrate is disposed in a through-hole of a sheet of the first type of lens-attached substrate that is adjacent to the sheet of the third lens-attached substrate, and

the thickness of the lens of the sheet of the third type of lens-attached substrate is larger than the thickness of the lens of the sheet of the second type of lens-attached substrate.

Some embodiments pertain to a solid-state imaging element, comprising a laminated lens structure as described herein; and

an imaging unit that photoelectrically converts incident light that is condensed by the lens.

Some embodiments pertain to an electronic apparatus, comprising:

a laminated lens structure as described herein;

an imaging unit that photoelectrically converts incident light that is condensed by the lens; and

a signal processing circuit that processes a signal that is output from the imaging unit.

Generally, the skilled person will appreciate that the embodiments disclosed herein can be combined with each other and such combinations of embodiments are directly and unambiguously derivable by the skilled person.

The laminated lens structure, the solid-state imaging element, and the electronic apparatus may be independent device, or a module embedded in another device.

### Advantageous Effects of Invention

According to the aspects of the present technology, it is possible to provide a laminated lens structure capable of corresponding to various optical parameters.

Furthermore, the effect described here is not limited, and may be any one effect described in the present disclosure.

### BRIEF DESCRIPTION OF DRAWINGS

FIG. 1A and FIG. 1B are views illustrating a first embodiment of a camera module to which the present technology is applied.

FIG. 2 is a cross-sectional view illustrating a first configuration example of a laminated lens structure.

FIG. 3 is a cross-sectional view illustrating the laminated lens structure and a diaphragm plate.

FIG. 4A to FIG. 4D are views illustrating a configuration of a lens resin portion.

FIG. 5A to FIG. 5D are views illustrating a configuration of the lens resin portion.

FIG. 6 is a view illustrating a method of manufacturing the laminated lens structure.

FIG. 7 is a view illustrating the method of manufacturing the laminated lens structure.

FIG. 8 is a view illustrating the method of manufacturing the laminated lens structure.

FIG. 9 is a view illustrating direct joining.

FIG. 10 is a cross-sectional view illustrating a detailed configuration of a lens-attached laminated substrate.

FIG. 11 shows a plan view and a cross-section view of the lens-attached laminated substrate.

FIG. 12 is a view illustrating a detailed configuration of a lens-attached single-layer substrate.

FIG. 13 is a view illustrating a detailed configuration of the lens-attached single-layer substrate.

FIG. 14 is a view illustrating a method of manufacturing the lens-attached single-layer substrate.

FIG. 15 is a view illustrating the method of manufacturing the lens-attached single-layer substrate.

FIG. 16A to FIG. 16G are views illustrating the method of manufacturing the lens-attached single-layer substrate.

FIG. 17 is a flowchart illustrating a process of manufacturing the lens-attached single-layer substrate.

FIG. 18 is a flowchart illustrating a process of manufacturing the lens-attached laminated substrate.

FIG. 19A to FIG. 19D are views illustrating a method of manufacturing the lens-attached laminated substrate.

FIG. 20A and FIG. 20B are views illustrating direct joining of a lens-attached substrate.

FIG. 21A and FIG. 21B are views illustrating direct joining of the lens-attached substrate.

FIG. 22A to FIG. 22F are views illustrating a first lamination method in which five sheets of lens-attached substrates are laminated in a substrate state.

FIG. 23A to FIG. 23F are views illustrating a second lamination method in which the five sheets of lens-attached substrates are laminated in a substrate state.

FIG. 24 is a cross-sectional view illustrating a second configuration example of the laminated lens structure.

FIG. 25 is a cross-sectional view illustrating a third configuration example of the laminated lens structure.

FIG. 26 is a cross-sectional view illustrating a fourth configuration example of the laminated lens structure.

FIG. 27A to FIG. 27C are cross-sectional views illustrating a fifth configuration example of the laminated lens structure.

FIG. 28A to FIG. 28H are views illustrating a shape of the lens resin portion of a protruding lens-attached substrate.

FIG. 29 is a cross-sectional view illustrating a sixth configuration example of the laminated lens structure.

FIG. 30 is a cross-sectional view illustrating a seventh configuration example of the laminated lens structure.

FIG. 31 is a cross-sectional view illustrating an eighth configuration example of the laminated lens structure.

FIG. 32 is a cross-sectional view illustrating a ninth configuration example of the laminated lens structure.

FIG. 33 is a cross-sectional view illustrating a tenth configuration example of the laminated lens structure.

FIG. 34 is a cross-sectional view illustrating an eleventh configuration example of the laminated lens structure.

FIG. 35 is a cross-sectional view illustrating a twelfth configuration example of the laminated lens structure.

FIG. 36 is a cross-sectional view illustrating a thirteenth configuration example of the laminated lens structure.

FIG. 37 is a cross-sectional view illustrating comparison between the thirteenth configuration example and the tenth configuration example of the laminated lens structure.

FIG. 38 is a view illustrating an example in which a through-hole having a rectangular planar shape is formed.

FIG. 39A to FIG. 39C are views illustrating an example of a cross-sectional shape of the through-hole.

FIG. 40A to FIG. 40F are views illustrating a method of forming the through-hole by using dry etching.

FIG. 41A and FIG. 41B are plan views of a carrier substrate in which a through-groove is formed in addition to the through-hole.

FIG. 42 is a view illustrating a method of manufacturing the lens-attached laminated substrate.

FIG. 43 is a flowchart illustrating a process of manufacturing the lens-attached laminated substrate.

FIG. 44A to FIG. 44C are views illustrating the process of manufacturing the lens-attached laminated substrate.

FIG. 45A to FIG. 45C are views illustrating a modification example of the lens-attached single-layer substrate.

FIG. 46A to FIG. 46C are views illustrating a modification example of the lens-attached laminated substrate.

FIG. 47 is a view illustrating a first modification example of the lens resin portion and the through-hole of the lens-attached single-layer substrate.

FIG. 48 is a view illustrating a second modification example of the lens resin portion and the through-hole of the lens-attached single-layer substrate.

FIG. 49 is a cross-sectional view illustrating another configuration example of the lens resin portion and the through-hole.

FIG. 50A to FIG. 50F are views illustrating a method of forming a through-hole having a stepped shape.

FIG. 51 is a view illustrating a third modification example of the lens resin portion and the through-hole of the lens-attached single-layer substrate.

FIG. 52 is a view illustrating a fourth modification example of the lens resin portion and the through-hole of the lens-attached single-layer substrate.

FIG. 53 is a view illustrating a first modification example of the lens resin portion and the through-hole of the lens-attached laminated substrate.

FIG. 54 is a view illustrating a second modification example of the lens resin portion and the through-hole of the lens-attached laminated substrate.

FIG. 55 is a view illustrating a third modification example of the lens resin portion and the through-hole of the lens-attached laminated substrate.

FIG. 56 is a view illustrating a fourth modification example of the lens resin portion and the through-hole of the lens-attached laminated substrate.

FIG. 57 is a view illustrating a fifth modification example of the lens resin portion and the through-hole of the lens-attached laminated substrate.

FIG. 58 is a view illustrating a sixth modification example of the lens resin portion and the through-hole of the lens-attached laminated substrate.

FIG. 59 is a cross-sectional view of a laminated lens structure that uses another modification example of the lens-attached laminated substrate.

FIG. 60A to FIG. 60D are views illustrating a first manufacturing method of the lens-attached substrate in FIG. 59.

FIG. 61A to FIG. 61C are views illustrating a second manufacturing method of the lens-attached substrate in FIG. 59.

FIG. 62A to FIG. 62E are views illustrating a method of forming a carrier configuration substrate illustrated in FIG. 61A.

FIG. 63A to FIG. 63D are views illustrating a third manufacturing method of the lens-attached substrate in FIG. 59.

FIG. 64A to FIG. 64C are cross-sectional views illustrating a modification example of a groove.

FIG. 65A to FIG. 65D are cross-sectional views illustrating a modification example of the groove.

FIG. 66A to FIG. 66E are views illustrating a shape of the groove in a plane direction.

FIG. 67A to FIG. 67C are views illustrating a shape of the groove in a plane direction.

FIG. 68 is a cross-sectional view illustrating a first modification example of the laminated lens structure.

FIG. 69 is a cross-sectional view illustrating a second modification example of the laminated lens structure.

FIG. 70 is a cross-sectional view illustrating a third modification example of the laminated lens structure.

FIG. 71 is a cross-sectional view illustrating a fourth modification example of the laminated lens structure.

FIG. 72 is a cross-sectional view illustrating a fifth modification example of the laminated lens structure.

FIG. 73 is a cross-sectional view illustrating a sixth modification example of the laminated lens structure.

FIG. 74 is a cross-sectional view illustrating a first modification example of a diaphragm plate.

FIG. 75 is a cross-sectional view illustrating a second modification example of a diaphragm plate.

FIG. 76 is a cross-sectional view illustrating a third modification example of a diaphragm plate.

FIG. 77A and FIG. 77B are views illustrating a second embodiment of the camera module to which the present technology is applied.

FIG. 78A and FIG. 78B are views illustrating a third embodiment of the camera module to which the present technology is applied.

FIG. 79A to FIG. 79C are views illustrating a planar shape of a suspension.

FIG. 80A and FIG. 80B are views illustrating a first modification example of the third embodiment of the camera module to which the present technology is applied.

FIG. 81A and FIG. 81B are views illustrating a second modification example of the third embodiment of the camera module to which the present technology is applied.

FIG. 82A to FIG. 82C are views illustrating a fourth embodiment of the camera module to which the present technology is applied.

FIG. 83A to FIG. 83C are views illustrating a fifth embodiment of the camera module to which the present technology is applied.

FIG. 84A and FIG. 84B are views illustrating a sixth embodiment of the camera module to which the present technology is applied.

FIG. 85A and FIG. 85B are views illustrating a seventh embodiment of the camera module to which the present technology is applied.

FIG. 86A and FIG. 86B are views illustrating an eighth embodiment of the camera module to which the present technology is applied.

FIG. 87A and FIG. 87B are views illustrating a ninth embodiment of the camera module to which the present technology is applied.

FIG. 88A and FIG. 88B are views illustrating a tenth embodiment of the camera module to which the present technology is applied.

FIG. 89A and FIG. 89B are views illustrating an eleventh embodiment of the camera module to which the present technology is applied.

FIG. 90A and FIG. 90B are views illustrating a twelfth embodiment of the camera module to which the present technology is applied.

FIG. 91 is a view illustrating a thirteenth embodiment of the camera module to which the present technology is applied.

FIG. 92 is a view illustrating a fourteenth embodiment of the camera module to which the present technology is applied.

FIG. 93A and FIG. 93B are views illustrating a fifteenth embodiment of the camera module to which the present technology is applied.

FIG. 94A and FIG. 94B are views illustrating a sixteenth embodiment of the camera module to which the present technology is applied.

FIG. 95A and FIG. 95B are views illustrating the sixteenth embodiment of the camera module to which the present technology is applied.

FIG. 96A and FIG. 96B are views illustrating the sixteenth embodiment of the camera module to which the present technology is applied.

FIG. 97A and FIG. 97B are views illustrating the sixteenth embodiment of the camera module to which the present technology is applied.

FIG. 98 is a view illustrating a seventeenth embodiment of the camera module to which the present technology is applied.

FIG. 99 is a view illustrating an eighteenth embodiment of the camera module to which the present technology is applied.

FIG. 100 is a view illustrating a nineteenth embodiment of the camera module to which the present technology is applied.

FIG. 101 is a view illustrating a twentieth embodiment of the camera module to which the present technology is applied.

FIG. 102A to FIG. 102H are views illustrating a twenty-first embodiment of the camera module to which the present technology is applied.

FIG. 103A to FIG. 103F are views illustrating a twenty-second embodiment of the camera module to which the present technology is applied.

FIG. 104A to FIG. 104F are views illustrating a twenty-third embodiment of the camera module to which the present technology is applied.

FIG. 105A to FIG. 105D are views illustrating a twenty-fourth embodiment of the camera module to which the present technology is applied.

FIG. 106A to FIG. 106D are views illustrating an example of a planar shape of the diaphragm plate that is provided in the camera module.

FIG. 107 is a view illustrating a configuration of an imaging unit of the camera module.

FIG. 108 is a view illustrating a first example of pixel arrangement in a light-receiving region of the camera module.

FIG. 109 is a view illustrating a second example of the pixel arrangement in the light-receiving region of the camera module.

FIG. 110 is a view illustrating a third example of the pixel arrangement in the light-receiving region of the camera module.

FIG. 111 is a view illustrating a fourth example of the pixel arrangement in the light-receiving region of the camera module.

FIG. 112 is a view illustrating a modification example of the pixel arrangement illustrated in FIG. 108.

FIG. 113 is a view illustrating a modification example of the pixel arrangement illustrated in FIG. 110.

FIG. 114 is a view illustrating a modification example of the pixel arrangement illustrated in FIG. 111.

FIG. 115A to FIG. 115D are views illustrating a fifth example of the pixel arrangement in the light-receiving region of the camera module.

FIG. 116A to FIG. 116D are views illustrating a sixth example of the pixel arrangement in the light-receiving region of the camera module.

FIG. 117 is a view illustrating a seventh example of the pixel arrangement in the light-receiving region of the camera module.

FIG. 118 is a view illustrating an eighth example of the pixel arrangement in the light-receiving region of the camera module.

FIG. 119 is a view illustrating a ninth example of the pixel arrangement in the light-receiving region of the camera module.

FIG. 120 is a view illustrating a tenth example of the pixel arrangement in the light-receiving region of the camera module.

FIG. 121A to FIG. 121D are views illustrating an eleventh example of the pixel arrangement in the light-receiving region of the camera module.

FIG. 122A to FIG. 122D are views illustrating a twenty-fifth embodiment of the camera module that uses the laminated lens structure to which the present technology is applied.

FIG. 123 is a view illustrating a structure of a light-receiving element according to the twenty-fifth embodiment.

FIG. 124 is a view illustrating the structure of the light-receiving element according to the twenty-fifth embodiment.

FIG. 125 is a view illustrating the structure of the light-receiving element according to the twenty-fifth embodiment.

FIG. 126A to FIG. 126C are views illustrating a twenty-sixth embodiment of the camera module that uses the laminated lens structure to which the present technology is applied.

FIG. 127 is a view illustrating a substrate configuration example of the light-receiving element according to the twenty-sixth embodiment.

FIG. 128 is a view illustrating a processing example of the light-receiving element according to the twenty-sixth embodiment.

FIG. 129A to FIG. 129C are views illustrating a twenty-seventh embodiment of the camera module that uses the laminated lens structure to which the present technology is applied.

FIG. 130 is a view illustrating a drive method of the light-receiving element according to the twenty-seventh embodiment.

FIG. 131 is a view illustrating a configuration example of the light-receiving element according to the twenty-seventh embodiment.

FIG. 132 is a cross-sectional view illustrating a first modification example of the imaging unit.

FIG. 133 is a cross-sectional view illustrating a second modification example of the imaging unit.

FIG. 134 is a block diagram illustrating a configuration example of an imaging apparatus as an electronic apparatus to which the present technology is applied.

FIG. 135 is a view illustrating a use example of the camera module.

FIG. 136 is a block diagram illustrating an example a schematic configuration of a body internal information acquisition system.

FIG. 137 is a view illustrating an example of a schematic configuration of an endoscopic surgery system.

FIG. 138 is a block diagram illustrating an example of a functional configuration of a camera head and a CCU.

FIG. 139 is a block diagram illustrating an example of a schematic configuration of a vehicle control system.

FIG. 140 is a view illustrating an example of an installation position of an out-of-vehicle information detection unit and an imaging unit.

### DESCRIPTION OF EMBODIMENTS

Hereinafter, embodiments for carrying out the present technology (hereinafter, referred to as “embodiment”) will be described. Furthermore, description will be made in the following order.

### 1. First Embodiment of Camera Module 1

### 2. First Configuration Example of Laminated Lens Structure 11

### 3. Method of Manufacturing Laminated Lens Structure 11

### 4. Description of Direct Joining

### 5. Detailed Configuration of Lens-Attached Laminated Substrate 41

### 6. Detailed Configuration of Lens-Attached Single-Layer Substrate 41

### 7. Method of Manufacturing Lens-Attached Single-Layer Substrate 41

### 8. Method of Manufacturing Lens-Attached Laminated Substrate 41

### 9. Direct Joining Between Lens-Attached Substrates

### 10. Second Configuration Example of Laminated Lens Structure 11

### 11. Third Configuration Example of Laminated Lens Structure 11

### 12. Fourth Configuration Example of Laminated Lens Structure 11

### 13. Fifth Configuration Example of Laminated Lens Structure 11

### 14. Sixth Configuration Example of Laminated Lens Structure 11

### 15. Seventh Configuration Example of Laminated Lens Structure 11

### 16. Eighth Configuration Example of Laminated Lens Structure 11

### 17. Ninth Configuration Example of Laminated Lens Structure 11

### 18. Tenth Configuration Example of Laminated Lens Structure 11

### 19. Eleventh Configuration Example of Laminated Lens Structure 11

### 20. Twelfth Configuration Example of Laminated Lens Structure 11

### 21. Thirteenth Configuration Example of Laminated Lens Structure 11

### 22. Another Method of Manufacturing Lens-Attached Single-Layer Substrate 41

### 23. Another Method of Manufacturing Lens-Attached Laminated Substrate 41

### 24. Modification Example of Lens-Attached Single-Layer Substrate 41

### 25. Modification Example of Lens-Attached Laminated Substrate 41

### 26. Modification Example of Lens Resin Portion 82 and Through-Hole 83 of Lens-Attached Single-Layer Substrate 41

### 27. Modification Example of Lens Resin Portion 82 and Through-Hole 83 of Lens-Attached Laminated Substrate 41

### 28. Another Modification Example of Lens-Attached Laminated Substrate 41

### 29. Modification Example of Laminated Lens Structure 11

### 30. Modification Example of Diaphragm Plate 51

### 31. Second Embodiment of Camera Module 1

### 32. Third Embodiment of Camera Module 1

### 33. Modification Example of Third Embodiment of Camera Module 1

### 34. Fourth Embodiment of Camera Module 1

### 35. Fifth Embodiment of Camera Module 1

### 36. Sixth Embodiment of Camera Module 1

### 37. Seventh Embodiment of Camera Module 1

### 38. Eighth Embodiment of Camera Module 1

### 39. Ninth Embodiment of Camera Module 1

### 40. Tenth Embodiment of Camera Module 1

### 41. Eleventh Embodiment of Camera Module 1

### 42. Twelfth Embodiment of Camera Module 1

### 43. Thirteenth Embodiment of Camera Module 1

### 44. Fourteenth Embodiment of Camera Module 1

### 45. Fifteenth Embodiment of Camera Module 1

### 46. Sixteenth Embodiment of Camera Module 1

### 47. Seventeenth Embodiment of Camera Module 1

### 48. Eighteenth Embodiment of Camera Module 1

### 49. Nineteenth Embodiment of Camera Module 1

### 50. Twentieth Embodiment of Camera Module 1

### 51. Twenty-First Embodiment of Camera Module 1

### 52. Twenty-second Embodiment of Camera Module 1

### 53. Twenty-Third Embodiment of Camera Module 1

### 54. Twenty-Fourth Embodiment of Camera Module 1

### 55. Description of Pixel Arrangement of Imaging Unit 12 and Structure and Usage of Diaphragm Plate

### 56. Twenty-Fifth Embodiment of Camera Module 1

### 57. Twenty-Sixth Embodiment of Camera Module 1

### 58. Twenty-Seventh Embodiment of Camera Module 1

### 59. First Modification Example of Imaging Unit 12

### 60. Second Modification Example of Imaging Unit 12

### 61. Application Example to Electronic Apparatus

### 62. Application Example to Body Internal Information Search System

### 63. Application Example to Endoscopic Surgery System

### 64. Application Example to Moving Body

<1. First Embodiment of Camera Module 1>

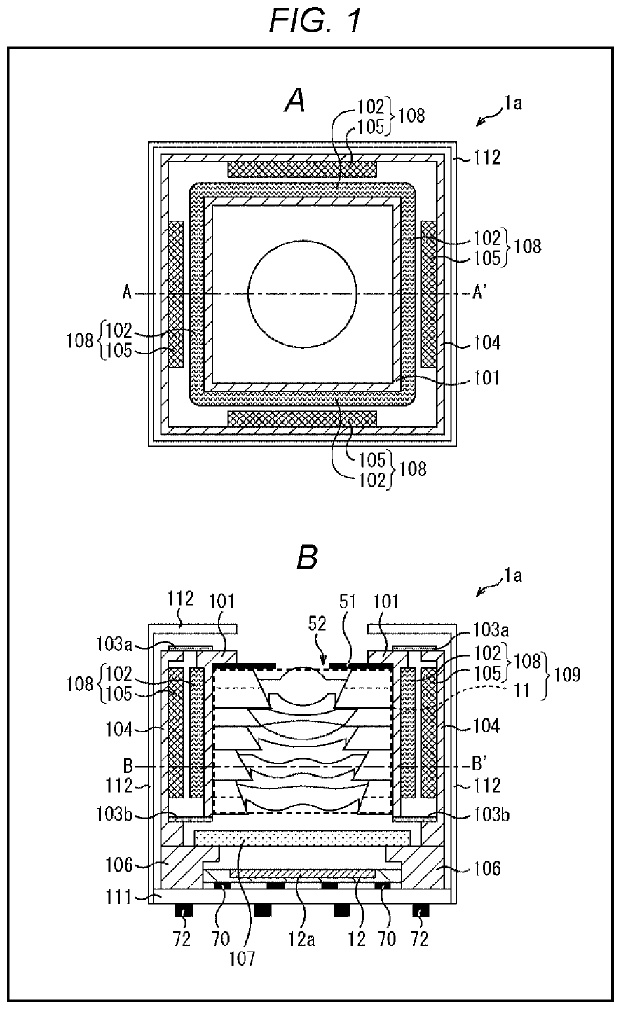

FIG. 1 is a view illustrating a first embodiment of a camera module to which the present technology is applied.

FIG. 1A is a plan view of a camera module 1a that is a first embodiment of a camera module 1, and FIG. 1B is a cross-sectional view of the camera module 1a.

FIG. 1A is a plan view taken along line B-B′ in the cross-sectional view in FIG. 1B, and FIG. 1B is a cross-sectional view taken along line A-A′ in the plan view in FIG. 1A.

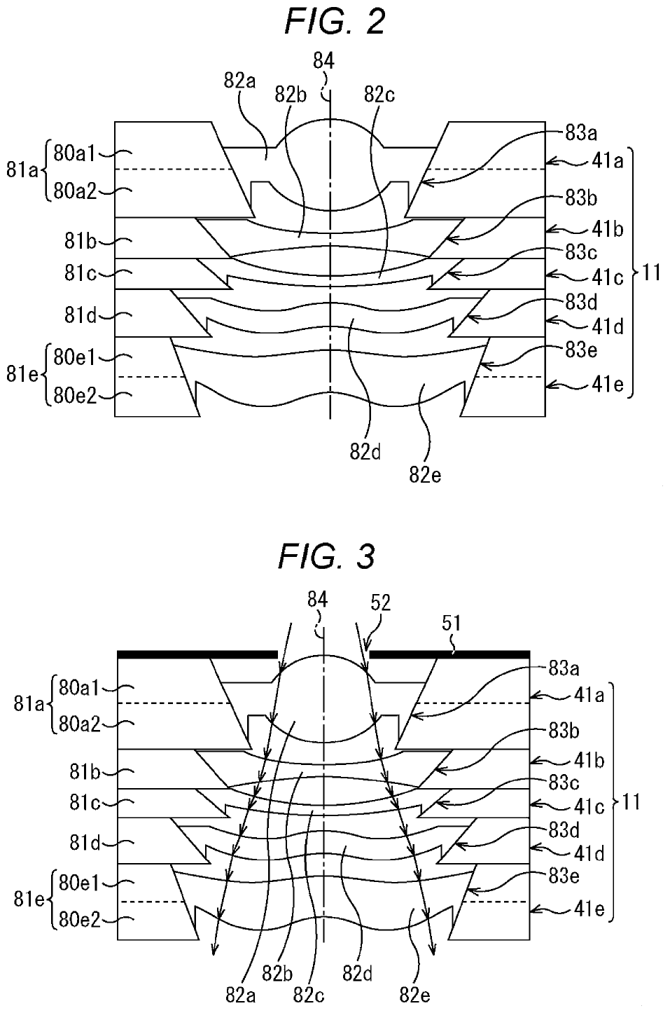

The camera module 1a includes a laminated lens structure 11 and an imaging unit 12. The laminated lens structure 11 is constructed by laminating a plurality of lenses, and condenses incident light to a light-receiving region 12a of the imaging unit 12. The imaging unit 12 is a semiconductor chip or a semiconductor die that includes a photoelectric conversion element and a transistor. The imaging unit 12 photoelectrically converts light incident to the light-receiving region 12a to generate an imaging signal (pixel signal) and outputs the imaging signal. In the light-receiving region 12a, a pixel array, in which pixels including a photoelectric conversion element such as a photodiode, a plurality of pixel transistors, and the like are two-dimensionally arranged in a matrix shape, is formed. A solid-state imaging element includes at least the laminated lens structure 11 and the imaging unit 12. A detailed structure of the laminated lens structure 11 will be described later with reference to FIG. 2.

The laminated lens structure 11 is accommodated in a lens barrel (lens holder) 101 in combination with a diaphragm plate 51. For example, the diaphragm plate 51 includes a layer that includes a material having a light-absorbing property or a light-shielding property. An opening 52 through which incident light passes through is formed in the diaphragm plate 51. The lens barrel 101 is formed by using a resin or a metallic material. The laminated lens structure 11 is bonded and fixed to an inner peripheral side of the lens barrel 101, and a coil 102 for auto focus (AF) is bonded and fixed to an outer periphery side.

As illustrated in FIG. 1B, the lens barrel 101 has a cross-sectional shape of an inverted L-shape that overhangs toward the inner periphery side on an upper surface that is farthest from the imaging unit 12. When bonding and fixing the laminated lens structure 11 to the lens barrel 101, the laminated lens structure 11 is positioned to come into contact with the overhang portion that overhangs toward an inner periphery side of the inverted L-shape in combination with the diaphragm plate 51, and is bonded and fixed to the lens barrel 101. The coil 102 for AF is wound around the periphery of the lens barrel 101 in a spiral shape, and is bonded and fixed to the outer periphery.

The lens barrel 101 is connected to a first fixing and supporting portion 104 that is disposed on an outer side of the lens barrel 101 by suspensions 103a and 103b, and can move in an optical axis direction integrally with the laminated lens structure 11 and the coil 102 for AF.

The first fixing and supporting portion 104 fixes the suspension 103a on an upper side thereof and fixes the suspension 103b on a lower side thereof. In addition a lower surface of the first fixing and supporting portion 104 is fixed to a second fixing and supporting portion 106. In the suspensions 103a and 103b, for example, one end of both ends is fixed to the lens barrel 101 by an adhesive and the like, and the other end is fixed to the first fixing and supporting portion 104 by an adhesive and the like.

The first fixing and supporting portion 104 has a rectangular cylindrical shape and a hollow inside. A magnet 105 for AF, which is a permanent magnet for AF, is fixed to a lateral wall of each of four surfaces on an inner peripheral side of the first fixing and supporting portion 104 at a position that faces the coil 102 for AF. The coil 102 for AF and the magnet 105 for AF constitute an electromagnetic type AF drive unit 108. When a current flows to the coil 102 for AF, the laminated lens structure 11 is moved in an optical axis direction and a distance between the laminated lens structure 11 and the imaging unit 12 is adjusted. An AF module 109, which adjusts a focal length of light condensed by the laminated lens structure 11, includes at least the laminated lens structure 11 and the AF drive unit 108.

The module substrate 111 fixes the second fixing and supporting portion 106 by an adhesive, and indirectly fixes the laminated lens structure 11 through the suspension 103b that is fixed to the second fixing and supporting portion 106, and the first fixing and supporting portion 104. In addition, the module substrate 111 also fixes a cover member 112 that covers an outer side of the first fixing and supporting portion 104 and the second fixing and supporting portion 106. The cover member 112 includes a conductive metal material and the like for a noise countermeasure.

The module substrate 111 is electrically connected to the imaging unit 12 by a connection terminal 70. The imaging unit 12 outputs an imaging signal that is generated to the module substrate 111 through the connection terminal 70, or receives power from the module substrate 111 through the connection terminal 70. The imaging signal that is output to the module substrate 111 from the imaging unit 12 is output from an external terminal 72 of the module substrate 111 to an external circuit substrate.

The second fixing and supporting portion 106 fixes an IR cutter filter 107 that is disposed between the laminated lens structure 11 and the imaging unit 12. The IR cutter filter 107 shields infrared light in incident light transmitted through the laminated lens structure 11, and allows light of wavelengths corresponding to R, G, and B to be transmitted therethrough. Furthermore, the IR cutter filter 107 may be disposed on the uppermost surface of the imaging unit 12.

An upper surface of the cover member 112 is opened in a circular shape or a rectangular shape so as not to shield light incident to the opening 52 of the diaphragm plate 51.

The camera module 1a having the above-described configuration exhibits an operation or effect capable of changing a distance between the laminated lens structure 11 and the imaging unit 12 by the AF drive unit 108 when the imaging unit 12 captures an image, and performing an auto focus operation.

In addition, in a case where the laminated lens structure 11 is not employed as a configuration of a laminated lens in which a plurality of sheets of lenses are laminated in the optical axis direction, a process of loading lens-attached substrates into the lens barrel sheet by sheet is necessary in a number corresponding to the number of lenses which are provided in the camera module.

In contrast, in the case of employing the laminated lens structure 11 as the configuration of the laminated lens in which a plurality of sheets of lenses are laminated in the optical axis direction, only after loading the laminated lens structure 11, in which a plurality of sheets of lens-attached substrates are integrated in the optical axis direction, into the lens barrel 101 once, assembly of the laminated lens and the lens barrel is terminated. Accordingly, in the camera module 1a, an operational effect in which assembly of a module is easy is exhibited.

<2. First Configuration Example of Laminated Lens Structure 11>

Next, a configuration of the laminated lens structure 11 illustrated in FIG. 1A and FIG. 1B will be described with reference to FIG. 2.

Furthermore, the laminated lens structure 11 illustrated in FIG. 2 shows a first configuration example of a plurality of laminated lens structures 11 which can be embedded in the camera module 1.

<2.1 Lens-Attached Substrate that Constitutes Laminated Lens Structure 11>

The laminated lens structure 11 illustrated in FIG. 2 according to a first configuration example includes five sheets of lens-attached substrates 41a to 41e which are laminated. In a case where the five sheets of lens-attached substrates 41a to 41e are not particularly distinguished, the substrates will be simply noted as a lens-attached substrate 41 in description. In addition, the five sheets of lens-attached substrates 41a to 41e, which are laminated, may be referred to as a lens-attached substrate 41a in a first layer or an uppermost layer, a lens-attached substrate 41b in a second layer, a lens-attached substrate 41c in a third layer, a lens-attached substrate 41d in a fourth layer, and a lens-attached substrate 41e in a fifth layer or a lowermost layer sequentially from the upper side.

Furthermore, in this embodiment, the laminated lens structure 11 includes the five sheets of lens-attached substrates 41a to 41e, but the number of sheets of the lens-attached substrates 41 laminated is not particularly limited as long as two or more sheets are laminated.

Each of the lens-attached substrates 41 which constitute the laminated lens structure 11 has a configuration in which a lens resin portion 82 is added to a carrier substrate 81. The carrier substrate 81 has a through-hole 83, and the lens resin portion 82 is formed on an inner side of the through-hole 83. Accordingly, the lens-attached substrate 41 includes the carrier substrate 81 and the lens resin portion 82. The lens resin portion 82 includes a region having a function as a lens, and a region that is connected to the carrier substrate 81. An optical axis 84 of the lens resin portion 82 of the laminated lens structure 11 is indicated by a one-dot chain line.

A cross-sectional shape of the through-hole 83 of the lens-attached substrates 41 which constitute the respective laminated lens structure 11 has a so-called downwardly narrowing shape in which an opening width decreases as it goes toward a lower side (side in which the imaging unit 12 is disposed).

Furthermore, in the case of being distinguished, as illustrated in FIG. 2, the carrier substrates 81, the lens resin portions 82, or the through-holes 83 of the lens-attached substrates 41a to 41e are noted as carrier substrates 81a to 81e, lens resin portions 82a to 82e, or through-holes 83a to 83e in correspondence with the lens-attached substrates 41a to 41e in description.

Among the five sheets of lens-attached substrates 41a to 41e, the lens-attached substrate 41a in the uppermost layer and the lens-attached substrate 41e in the lowermost layer have a structure in which the carrier substrate 81 is obtained by bonding a plurality of sheets of substrates (hereinafter, referred to as “carrier configuration substrate”) 80. This example employs a structure in which two sheets of the carrier configuration substrates 80 are bonded to each other, but a bonding structure of three or more sheets may be employed. (Such structures in which two or more sheets of the carrier configuration substrates are bonded, laminated and/or stacked to each other to form a lens-attached substrate are also referred to first type of lens-attached substrate.)

Specifically, the carrier substrate 81a is constituted by bonding carrier configuration substrates 80a1 and 80a2 to each other, and the carrier substrate 81e is constituted by bonding carrier configuration substrates 80e1 and 80e2 to each other. In FIG. 2, a broken line shown in the carrier substrates 81a and 81e of the lens-attached substrates 41a and 41e indicates a bonding surface of the two sheets of carrier configuration substrates 80.

In contrast, among the five sheets of lens-attached substrates 41a to 41e, the lens-attached substrates 41b to 41d include one sheet of the carrier substrate 81. That is, one sheet of the carrier substrate 81 is constituted by using one sheet of carrier configuration substrate 80. (Such structures in which one sheet of the carrier configuration substrate is used to form a lens-attached substrate are also referred to second type of lens-attached substrate.)

In the first configuration example of the laminated lens structure 11 illustrated in FIG. 2, the lens resin portion 82a formed on an inner side of the through-hole 83a in the lens-attached substrate 41a in the uppermost layer is formed to exist between an upper surface and a lower surface of the carrier substrate 81a. In other words, the lens resin portion 82a has a thickness and a shape in which the lens resin portion 82a does not protrude from the upper surface and the lower surface of the carrier substrate 81a. In the other four sheets of lens-attached substrates 41b to 41e, similarly, the thickness and the shape of the lens resin portions 82b to 82e are set to a thickness and a shape in which the lens resin portions 82b to 82e do not protrude from the upper surface and the lower surface of the carrier substrates 81b to 81e.

In the following description, the carrier substrate 81 having the bonding structure of a plurality of sheets of carrier configuration substrates 80 is referred to as “lamination-structure carrier substrate 81” or “laminated carrier substrate 81”, and the lens-attached substrate 41 including the laminated carrier substrate 81 is referred to as “lens-attached laminated substrate 41 (first lens-attached substrate)”.

On the other hand, the carrier substrate 81 which is constituted by one sheet of substrate and does not have the bonding structure as in the laminated carrier substrate 81 is referred to as “single-layer-structure carrier substrate 81” or “single-layer carrier substrate 81”, and the lens-attached substrate 41 including the single-layer carrier substrate 81 is referred to as “lens-attached single-layer substrate 41 (second lens-attached substrate)”. The lens-attached substrate 41 is a high-level concept including both of the lens-attached single-layer substrate 41 and the lens-attached laminated substrate 41. In addition, the carrier substrate 81 is a high-level concept including both of the single-layer carrier substrate 81 and the laminated carrier substrate 81.

<2.2. Light Propagation Direction in Laminated Lens Structure 11>

FIG. 3 is a cross-sectional view illustrating a propagation direction of light that is incident to the laminated lens structure 11 in a configuration including the laminated lens structure 11 and the diaphragm plate 51 as illustrated in FIG. 1A and FIG. 1B.

In the camera module 1a, after light incident to the camera module 1a is narrowed by the diaphragm plate 51, the light can spread at the inside of the laminated lens structure 11, and is incident to the imaging unit 12 (not illustrated in FIG. 3) that is disposed on a lower side of the laminated lens structure 11. That is, in an overview of the entirety of the laminated lens structure 11, light incident to the camera module 1a propagates in a downwardly spreading state from the opening 52 of the diaphragm plate 51 toward a lower side.

<2.3. Configuration of Lens Resin Portion 82>

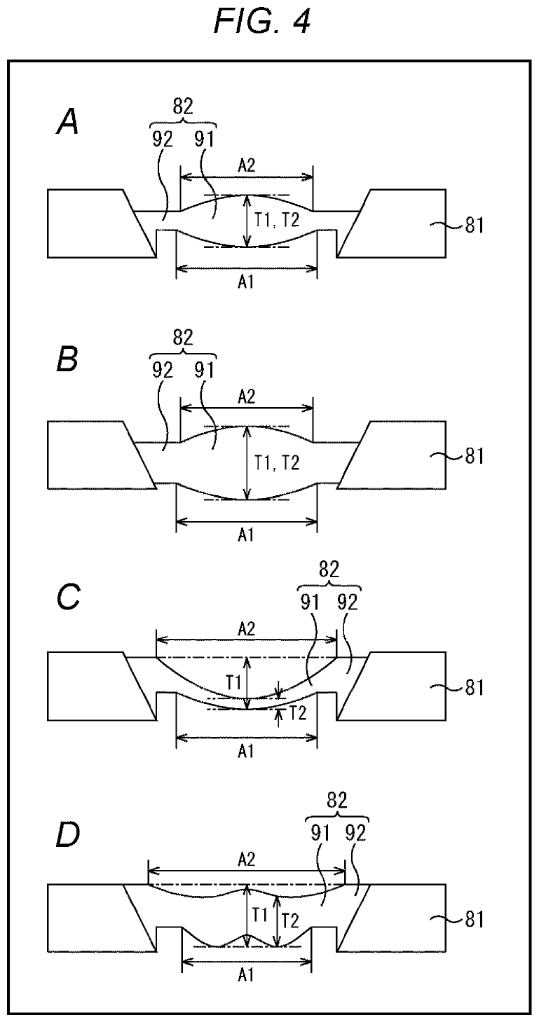

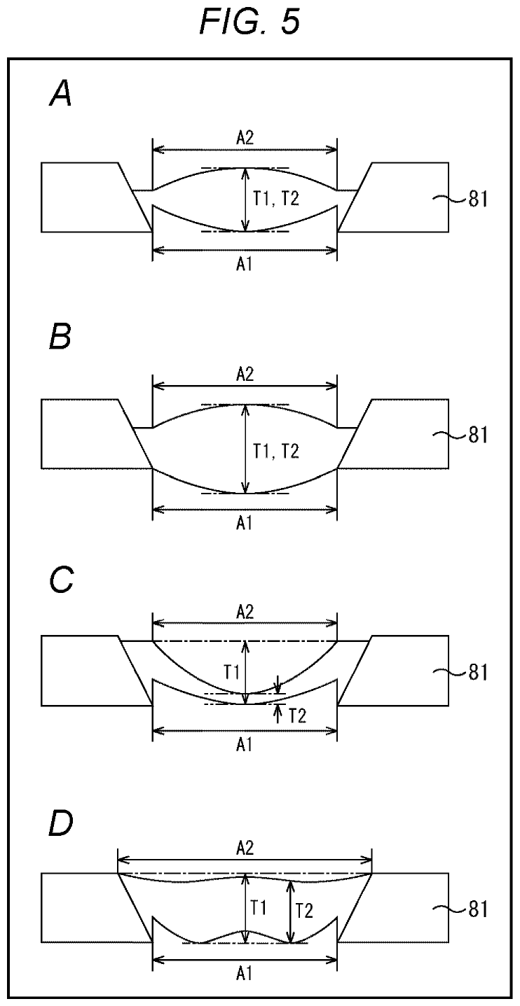

A configuration of the lens resin portion 82 will be described with reference to FIG. 4A to FIG. 5D.

FIG. 4A to FIG. 4D illustrate an example in which the lens resin portion 82 includes a lens portion 91 and a carrier portion 92.

The lens portion 91 is a portion having performance as a lens, in other words, “a portion that refracts light to focus or diverge the light”, or “a portion including a curved surface such as a convex surface, a concave surface, and an aspheric surface, or a portion in which a plurality of polygons used in a lens using a Fresnel lens or a diffraction lattice are continuously disposed”.

The carrier portion 92 is a portion that extends from the lens portion 91 to the carrier substrate 81 and carries the lens portion 91. The carrier portion 92 is disposed at an outer periphery of the lens portion 91. In the carrier portion 92, an upper surface or a lower surface of the lens resin portion 82 is formed in a flat surface (horizontally) instead of a curved surface in a horizontal direction.

FIG. 4A and FIG. 4B illustrate an example of the lens resin portion 82 in which an upper surface and a lower surface of the lens portion 91 are formed as a convex lens.

FIG. 4C illustrates an example of the lens resin portion 82 in which the upper surface and the lower surface of the lens portion 91 are respectively formed as a concave lens and a convex lens.

FIG. 4D illustrates an example of the lens resin portion 82 in which the upper surface and the lower surface of the lens portion 91 are formed as an aspheric lens.

In FIG. 4A to FIG. 4D, with regard to a shape of the lens resin portion 82, an upper surface side lens region A2, a lower surface side lens region A1, the thickness T1 of the lens portion 91, and the thickness T2 of the lens resin portion 82 are illustrated in the drawings.

The upper surface side lens region A2 of the lens portion 91 becomes an inner region of the carrier portion 92 that is horizontally formed on the upper surface side of the lens resin portion 82, and the lower surface side lens region A1 of the lens portion 91 becomes an inner region of the carrier portion 92 that is horizontally formed on the lower surface side of the lens resin portion 82.

Furthermore, a horizontally formed region may not exist on the upper surface or the lower surface of the lens resin portion 82 in accordance with the shape of the lens resin portion 82.

FIG. 5A to FIG. 5D illustrate an example of the shape of the lens resin portion 82 in which the horizontally formed region does not exist on any one of the upper surface or the lower surface of the lens resin portion 82.

FIG. 5A and FIG. 5B illustrate an example in which the horizontally formed region does not exist on the lower surface in the lens resin portion 82 in which the upper surface and the lower surface of the lens portion 91 are formed as a convex lens.

FIG. 5C illustrates an example in which the horizontally formed region does not exist on the lower surface in the lens resin portion 82 in which the upper surface and the lower surface of the lens portion 91 are respectively formed as a concave lens and a convex lens.

FIG. 5D illustrates an example in which the horizontally formed region does not exist on the upper surface in the lens resin portion 82 in which the upper surface and the lower surface of the lens portion 91 are formed as an aspheric lens.

In FIG. 4A to FIG. 5D, the thickness T1 of the lens portion 91 represents a thickness from the uppermost portion of the lens resin portion 82 in the upper surface side lens region A2 to the lowermost portion of the lens resin portion 82 in the lower surface side lens region A1 in the optical axis direction.

In addition, in FIG. 4A to FIG. 5D, the thickness T2 of the lens resin portion 82 represents the thickness of the lens resin portion 82 between the upper surface side lens region A2 and the lower surface side lens region A1 in the optical axis direction.

<2.4. Thickness of Carrier Substrate 81 and Lens Portion 91>

The laminated lens structure 11 illustrated in FIG. 2 includes one or more sheets of the lens-attached single-layer substrates 41 and one or more sheets of the lens-attached laminated substrates 41. The lens-attached single-layer substrates 41 include the single-layer-structure carrier substrate 81, and the lens-attached laminated substrates 41 include the lamination-structure carrier substrate 81. Among a plurality of sheets of the lens-attached substrates 41 which constitute the laminated lens structure 11, both of the lens-attached substrate 41a that is disposed on a side closest to the light incident plane, and the lens-attached substrate 41e that is disposed on a side closest to the imaging unit 12 are constituted by the lens-attached laminated substrate 41. When using the laminated carrier substrates 81a and 81e in the lens-attached substrates 41a and 41e, it is possible to make the thickness of the carrier substrates 81a and 81e, which are provided in the lens-attached laminated substrates 41a and 41e, larger than the thickness of the carrier substrates 81b to 81d which are provided in the lens-attached substrates 41b to 41d.

With regard to the thickness T1 of the lens portion 91, when using the lens-attached laminated substrates 41a and 41e, which respectively include the laminated carrier substrates 81a and 81d, as the lens-attached substrates 41a and 41e, it is possible to make the thickness T1 of the lens portion 91 provided in the lens-attached laminated substrates 41a and 41e larger than the thickness T1 of the lens portion 91 that is provided in the lens-attached single-layer substrates 41b to 41d.

In a region of the lens-attached substrate 41 in which the lens resin portion 82 and the carrier substrate 81 are in contact with each other, with regard to the thickness of the lens resin portion 82 in a direction perpendicular to a plane direction of the lens-attached substrate 41, it is possible to make a thickness relating to the lens-attached laminated substrates 41a and 41e larger than a thickness relating to the lens-attached single-layer substrates 41b to 41d.

With regard to the thickness of the lens resin portion 82 at the central portion (position of the optical axis 84) in a diameter direction of the lens resin portion 82, it is possible to make a thickness relating to the lens-attached laminated substrates 41a and 41e larger than a thickness relating to the lens-attached single-layer substrates 41b to 41d.

Here, typically, the thickness of a semiconductor substrate that is used in manufacturing of an electronic apparatus or an electronic device conforms to SEMI standards. For example, in the case of a silicon substrate having a diameter of 300 mm, the thickness is determined as 775±20 μm.

Accordingly, in the laminated lens structure 11 illustrated in FIG. 2, the thickness of the carrier substrate 81a of the lens-attached substrate 41a in the uppermost layer and the carrier substrate 81e of the lens-attached substrate 41e in the lowermost layer may be set to 775 μm or greater.

In addition, the thickness of the carrier substrates 81a and 81e which have a structure in which two sheets of the carrier configuration substrates 80 are bonded to each other becomes 1550 μm (775×2 μm) or less. In this case, in a region (lateral wall of the though-hole 83) of the lens-attached laminated substrate 41 in which the lens resin portion 82 and the carrier substrate 81 are in contact with each other, the thickness of the lens resin portion 82 in a direction (thickness direction) perpendicular to the lens-attached laminated substrate 41 also becomes 775 μm to 1550 μm. The thickness of the central portion (center in a diameter direction) of the lens resin portion 82 of the lens-attached laminated substrate 41 also becomes 775 μm to 1550 μm.

Furthermore, the carrier substrate 81 may be configured as a bonding structure of three or more carrier configuration substrates 80. For example, in a case where the carrier substrate 81 is configured as a bonding structure of three carrier configuration substrates 80, the thickness of the carrier substrate 81 becomes 2325 μm (775×3 μm) or less. In this case, in a region (lateral wall of the though-hole 83) of the lens-attached laminated substrate 41 in which the lens resin portion 82 and the carrier substrate 81 are in contact with each other, the thickness of the lens resin portion 82 in a direction (thickness direction) perpendicular to the lens-attached laminated substrate 41 also becomes 775 μm to 2325 μm. The thickness of the central portion (center in a diameter direction) of the lens resin portion 82 of the lens-attached laminated substrate 41 also becomes 775 μm to 2325 μm.

On the other hand, the thickness of the carrier substrates 81b to 81d of the lens-attached substrates 41b to 41d in layers other than the lowermost layer and the uppermost layer becomes less than 775 μm. It is preferable that the thickness becomes 50 μm or greater, more preferably 100 μm or greater, and still more preferably 200 μm or greater to secure constant mechanical strength.

In a region (lateral wall of the though-hole 83) of the lens-attached single-layer substrate 41 in which the lens resin portion 82 and the carrier substrate 81 are in contact with each other, the thickness of the lens resin portion 82 in a direction (thickness direction) perpendicular to the lens-attached single-layer substrate 41 also becomes 50 μm or greater, 100 μm or greater, or 200 μm or greater, and less than 775 μm. The thickness of the central portion (center in a diameter direction) of the lens resin portion 82 of the lens-attached single-layer substrate 41 also becomes 50 μm or greater, 100 μm or greater, or 200 μm or greater, and less than 775 μm.

With regard to a lens, as described above, in the first configuration example of the laminated lens structure 11 as illustrated in FIG. 2, the thickness and the shape of the lens resin portions 82a to 82e are set to a thickness and a shape in which the lens resin portions 82a to 82e do not protrude from the upper surface and the lower surface of the carrier substrates 81a to 81e. Accordingly, the thickness T1 of the lens portion 91 of the lens-attached laminated substrate 41 in which two sheets of the carrier configuration substrates 80 are bonded to each other becomes 775 μm to 1550 μm. The thickness T1 of the lens portion 91 of the lens-attached laminated substrate 41 in which three sheets of the carrier configuration substrates 80 are bonded to each other becomes 775 μm to 2325 μm.

The thickness T1 of the lens portion 91 of the lens-attached single-layer substrate 41 becomes 50 μm or greater, 100 μm or greater, or 200 μm or greater, and less than 775 μm.

As first means for obtaining the laminated carrier substrates 81a and 81e which are thicker than the single-layer carrier substrates 81b to 81d, a substrate that is thicker than at least one of the single-layer carrier substrates 81b to 81d is used as the carrier configuration substrates 80a1 and 80a2 which constitute the laminated carrier substrate 81a, and as the carrier configuration substrates 80e1 and 80e2 which constitute the laminated carrier substrate 81e. According to this, it is possible to obtain the laminated carrier substrates 81a and 81e which are thicker than the single-layer carrier substrates 81b to 81d.

As second means for obtaining the laminated carrier substrates 81a and 81e which are thicker than the single-layer carrier substrates 81b to 81d, a substrate that is thinner than the single-layer carrier substrates 81b to 81d is used as the carrier configuration substrates 80a1 and 80a2 which constitute the laminated carrier substrate 81a, and as the carrier configuration substrates 80e1 and 80e2 which constitute the laminated carrier substrate 81e. According to this, with regard to the thickness of the carrier substrate 81 after lamination, it is also possible to obtain the laminated carrier substrates 81a and 81e which are thicker than the single-layer carrier substrates 81b to 81d.

As third means for obtaining the laminated carrier substrates 81a and 81e which are thicker than the single-layer carrier substrates 81b to 81d, a substrate that is thicker than at least one of the single-layer carrier substrates 81b to 81d is used as at least one of the carrier configuration substrates 80a1 and 80a2 which constitute the laminated carrier substrate 81a, and the carrier configuration substrates 80e1 and 80e2 which constitute the laminated carrier substrate 81e, and a substrate having a thickness smaller than that of the single-layer carrier substrates 81b to 81d is used as the other carrier configuration substrates 80 which constitute the laminated carrier substrates 81a to 81e. According to this, with regard to the thickness of the carrier substrate 81 after lamination, it is possible to obtain the laminated carrier substrates 81a and 81e which are thicker than the single-layer carrier substrates 81b to 81d.

Furthermore, any one of the single-layer carrier substrate 81 and the laminated carrier substrate 81 may be subjected to substrate thinning processing as necessary as described later. Through the processing, any of the single-layer carrier substrate 81 and the laminated carrier substrate 81 may have an arbitrary thickness (desired thickness) in the above-described thickness range. In correspondence with this configuration, in the first configuration example of the laminated lens structure 11 as illustrated in FIG. 2, the thickness of the lens portion 91 can also have an arbitrary thickness (desired thickness) in the above-described thickness range.

<2.5. Operational Effect of Laminated Lens Structure 11>

Description will be given of the structure of the laminated lens structure 11 illustrated in FIG. 2 and an operational effect of the structure.

The laminated lens structure 11 has a structure in which among the five sheets of lens-attached substrates 41a to 41e, the thickness of the carrier substrate 81a of the lens-attached substrate 41a in the uppermost layer, and the thickness of the carrier substrate 81e of the lens-attached substrate 41e in the lowermost layer are larger than the thickness of the carrier substrates 81b to 81d of the other three sheets of lens-attached substrates 41b to 41d.

In addition, the lens-attached substrate 41a in the uppermost layer and the lens-attached substrate 41e in the lowermost layer are constituted by the lens-attached laminated substrate 41, and the other three sheets of lens-attached substrates 41b to 41d are constituted by the lens-attached single-layer substrate 41.

In other words, each of the carrier substrate 81a of the lens-attached substrate 41a in the uppermost layer and the carrier substrate 81e of the lens-attached substrate 41e in the lowermost layer has a lamination structure in which a plurality of sheets of the carrier configuration substrates 80 are bonded to each other, and the carrier substrates 81b to 81d of the other three sheets of lens-attached substrates 41b to 41d have a structure that does not have the bonding structure of the carrier configuration substrates 80 and is constituted by one sheet of substrate.

As described above, the laminated lens structure 11 including at least one sheet of laminated carrier substrate 81 can use a lens having a larger thickness in comparison to a laminated lens structure that does not include the laminated carrier substrate 81. With this configuration, in the laminated lens structure 11, a selection range relating to the thickness of a lens that can be manufactured becomes wide. In addition, the degree of freedom of design of a lens of the laminated lens structure 11 and the degree of freedom of design of a camera module that uses the laminated lens structure 11 are raised.

For example, in the case of a camera module that is used in a smart phone, a reduction in volume of the camera module and a configuration of the camera module capable of capturing a high-quality image while having a small volume are desired to be compatible with each other at a high level so as to accommodate the camera module in a small casing of an apparatus. Accordingly, a lens group used in the camera module for the above-described use typically has a configuration in which light is narrowed in a lens in the uppermost layer, the narrowed light spreads to a size of an imaging plane of an imaging element in a lens group in lower layers, and the light spread to the size of the imaging surface of the imaging element is incident to the imaging element after adjusting an incidence angle of the light in the lens closest to the imaging element so that the light is incident in a vertical direction as much as possible. As described above with reference to FIG. 3, the camera module 1a and the laminated lens structure 11 which are described in FIG. 1A to FIG. 3 have a similar configuration.

According to the lens group having the above-described configuration, in a lens closest to the imaging element, a distance between an upper surface (first surface) and a lower surface (second surface) of the lens is great to allow light to be incident to the imaging element in a vertical direction as much as possible. In other words, it is demanded to use a lens having a large thickness. Accordingly, when including the configuration of the laminated lens structure 11, it is possible to use a lens having a larger thickness in comparison to a laminated lens structure that does not include the configuration. As a result, it is possible to exhibit an operational effect capable of allowing light to be incident to the imaging element at an angle closer to a vertical direction.

In addition, in a lens group having a configuration as in the laminated lens structure 11, the amount of light that can be received by the lens group is greatly influenced by the shape of a lens in the uppermost layer. In the laminated lens structure 11, it is possible to use a lens having a larger thickness in comparison to a laminated lens structure that does not include the laminated carrier substrate 81. With this configuration, it is possible to use a lens having a relatively large radius of curvature, for example, in the lens in the uppermost layer, and thus it is possible to exhibit an operational effect capable of receiving a larger amount of light.

In addition, with regard to a lens in which a lens having a large thickness is not necessary, the single-layer carrier substrate 81 is used to reduce the thickness of the carrier substrate 81. According to this, it is possible to exhibit an operational effect capable of further reducing the height of the laminated lens structure 11 and the camera module 1 using the laminated lens structure 11 in comparison to a configuration that uses the laminated carrier substrate 81 in the entirety of lens provided in the laminated lens structure 11.

As described above, according to the laminated lens structure 11 of the present disclosure, it is possible to provide a laminated lens structure capable of corresponding to various optical parameters.

<3. Method of Manufacturing Laminated Lens Structure 11>

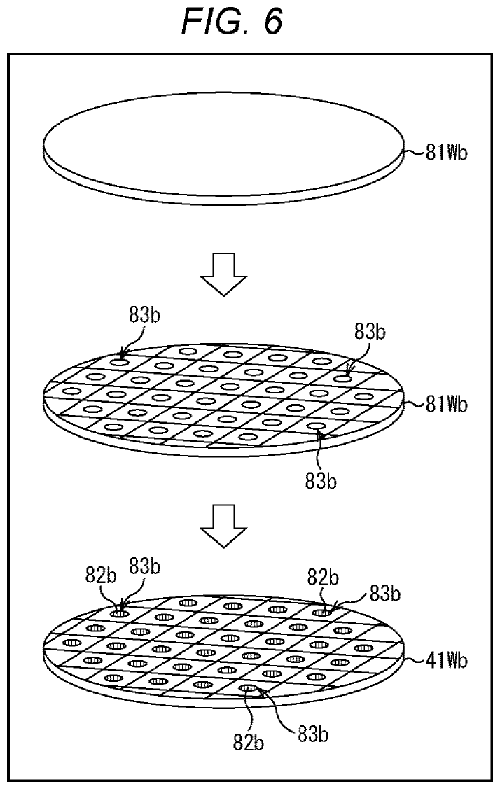

Next, a method of manufacturing the laminated lens structure 11 will be described with reference to FIG. 6 to FIG. 8.

The laminated lens structure 11 is manufactured as follows. After the lens-attached substrates 41a to 41e are manufactured in a substrate state (wafer state), the lens-attached substrates 41a to 41e are laminated, and the resultant laminated body is divided into individual chip units to obtain the laminated lens structure 11.

In this specification and the accompanying drawings, a substrate state (wafer state) before the lens-attached substrates 41a to 41e are divided into individual chip units is illustrated by attaching “W” to a symbol like lens-attached substrate 41Wa to 41We. This is also true of the carrier substrate 81 and the like.

First, description will be given of a method of manufacturing the lens-attached single-layer substrate 41, for example, the lens-attached substrate 41b in the laminated lens structure 11 including the five sheets of lens-attached substrates 41a to 41e with reference to FIG. 6.

First, as illustrated in FIG. 6, a carrier substrate 81Wb in a substrate state is prepared. The carrier substrate 81Wb in a substrate state is prepared after being adjusted to a desired thickness as necessary.

In addition, through-holes 83b are formed in the carrier substrate 81Wb in a substrate state in a chip region unit when being divided into individual pieces.

Then, a lens resin portion 82b is formed with respect to the carrier substrate 81Wb in a substrate state, in which the through-holes 83b are formed in a chip region unit, on an inner side of each of the through-holes 83b. Through this process, the lens-attached single-layer substrate 41Wb in a substrate state is completed.

Other lens-attached single-layer substrates 41Wc and 41Wd in a substrate state are manufactured in a similar manner.

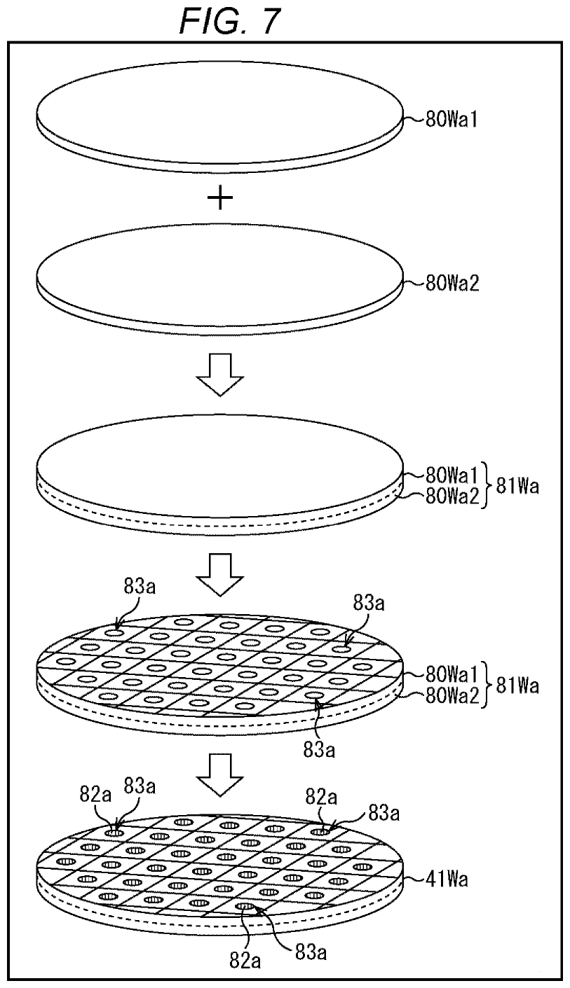

Next, description will be given of a method of manufacturing the lens-attached laminated substrate 41, for example, the lens-attached substrate 41a in the laminated lens structure 11 including the five sheets of lens-attached substrates 41a to 41e with reference to FIG. 7.

First, as illustrated in FIG. 7, a carrier configuration substrate 80Wa1 in a substrate state, and a carrier configuration substrate 80Wa2 in a substrate state are prepared. The carrier configuration substrates 80Wa1 and 80Wa2 in a substrate state are prepared after being adjusted to a desired thickness as necessary.

In addition, the carrier configuration substrate 80Wa1 in a substrate state and the carrier configuration substrate 80Wa2 in a substrate state are directly joined to each other to manufacture a carrier substrate 81Wa in a substrate state.

Next, through-holes 83a are formed in the carrier substrate 81Wa in a substrate state in a chip region unit when being divided into individual pieces.

Then, a lens resin portion 82a is formed with respect to the carrier substrate 81Wa in a substrate state, in which the through-holes 83a are formed in a chip region unit, on an inner side of each of the through-holes 83a. Through this process, the lens-attached laminated substrate 41Wa in a substrate state is completed.

Other lens-attached laminated substrates 41We in a substrate state are manufactured in a similar manner.

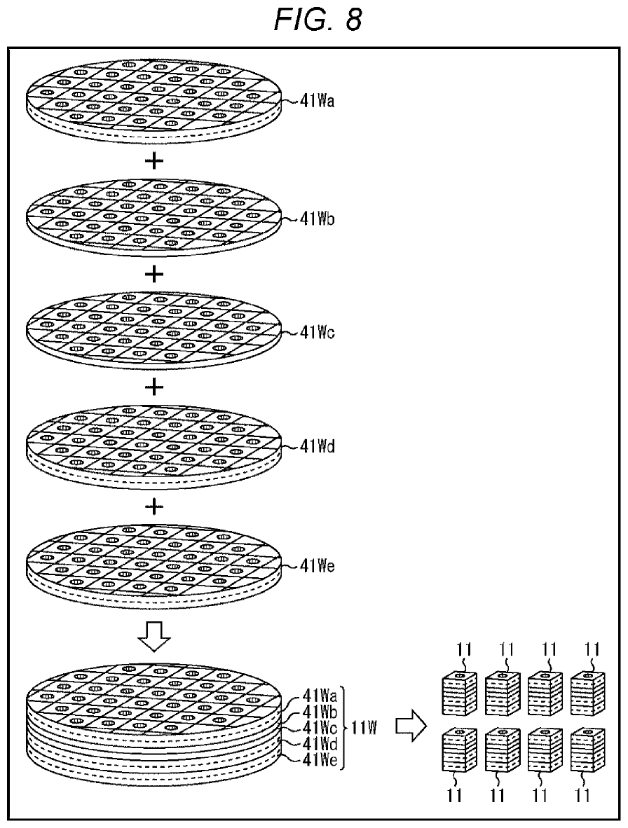

FIG. 8 is a view illustrating a method of manufacturing the laminated lens structure 11 by using the lens-attached single-layer substrates 41Wb to 41Wd in a substrate state, and the lens-attached laminated substrates 41Wa and 41We in a substrate state.

First, five sheets of the lens-attached substrates 41Wa to 41We manufactured by the manufacturing method described with reference to FIG. 6 and FIG. 7 are laminated in a state in which the lens-attached substrates 41W in a substrate state, which are in vertical contact with each other, are directly joined to each other. In addition, the five sheets of lens-attached substrates 41Wa to 41We in a substrate state, which are laminated, are divided into individual module units or individual chip units. Through this process, the laminated lens structure 11 in a unit embedded in the camera module 1 is completed.

<4. Description of Direct Joining>

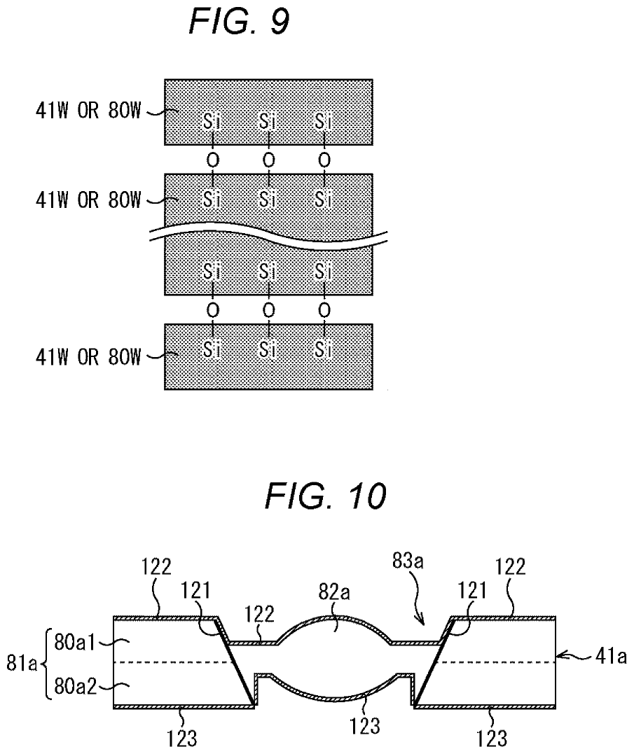

FIG. 9 is a view illustrating direct joining that is employed in bonding between two sheets of the lens-attached substrates 41W in a substrate state, and bonding between two sheets of the carrier configuration substrates 80W in a substrate state.

The two sheets of lens-attached substrates 41W which are laminated are directly joined to each other through covalent bond between a surface layer constituted by an oxide or a nitride formed on a substrate surface on one side, and a surface layer constituted by an oxide or a nitride formed on a substrate surface on the other side. As a specific example, as illustrated in FIG. 9, a silicon oxide film or a silicon nitride film as a surface layer is formed on a surface of each of the two sheets of lens-attached substrates 41W which are laminated. After a hydroxyl group is bonded to the silicon oxide film or the silicon nitride film, the two sheets of lens-attached substrates 41W are bonded to each other, and the resultant laminated body is dehydrated and condensed by raising a temperature. As a result, a silicon-oxygen covalent bond is formed between the surface layers of the two sheets of lens-attached substrates 41W. Accordingly, the two sheets of lens-attached substrates 41W are directly joined to each other. Furthermore, as a result of the condensation, elements included in the surface layers of the two sheets may directly form a covalent bond.

In this specification, the following fixing aspects are referred to as the direct joining. Specific examples of the fixing aspects include an aspect in which the two sheets of lens-attached substrate 41W are fixed through an inorganic layer that is disposed between the two sheets of lens-attached substrates 41W, an aspect in which the two sheets of lens-attached substrates 41W are fixed to each other by chemically bonding inorganic layers respectively disposed on surfaces of the two sheets of lens-attached substrates 41W, an aspect in which the two sheets of lens-attached substrates 41W are fixed to each other by forming a bond due to dehydration and condensation between inorganic layers which are respectively disposed on the surfaces of the two sheets of lens-attached substrates 41W, an aspect in which the two sheets of lens-attached substrates 41W are fixed to each other by forming a covalent bond through oxygen or a covalent bond between elements included in the inorganic layers between inorganic layers which are respectively disposed on the surfaces of the two sheets of lens-attached substrates 41W, and an aspect in which the two sheets of lens-attached substrates 41W are fixed to each other by forming a silicon-oxygen covalent bond or a silicon-silicon covalent bond between silicon oxide layers or silicon nitrides which are respectively disposed on the surfaces of the two sheets of lens-attached substrates 41W.

To perform the bonding and the dehydration and condensation through temperature rising, in this embodiment, substrates which are used in a manufacturing field of a semiconductor device or a flat display device are used. A lens is formed in a substrate state, and dehydration and condensation through temperature rising are performed in a substrate state. According to this, joining by a covalent bond in a substrate state is performed. The structure in which the inorganic layers formed on the surface of the two-sheets of lens-attached substrates 41W are joined by the covalent bond exhibits an operation or effect capable of suppressing deformation due to hardening shrinkage of a resin that occurs over the entirety of substrates in the case of joining the substrates with an adhesive resin, or deformation due to thermal expansion of the resin in actual use.

The same thing is also true of bonding between two sheets of the carrier configuration substrates 80W in a substrate state. In addition, the same thing is also true of bonding between two sheets of the lens-attached substrates 41 after division into individual pieces instead of bonding in the substrate state, and bonding between two sheets of the carrier configuration substrates 80.

<5. Detailed Configuration of Lens-Attached Laminated Substrate 41>

Next, a detailed configuration of the lens-attached laminated substrate 41 will be described.

FIG. 10 is a cross-sectional view illustrating a detailed configuration of the lens-attached laminated substrate 41a.

Furthermore, in FIG. 10, the lens-attached laminated substrate 41a in the uppermost layer between the lens-attached laminated substrates 41a and 41e is illustrated, but the other lens-attached laminated substrate 41e also has a similar configuration.

In the lens-attached laminated substrate 41a illustrated in FIG. 10, with respect to the through-hole 83a formed in the carrier substrate 81a, the lens resin portion 82a is formed to plug the through-hole 83a when seen from an upper surface. As described above with reference to FIG. 4A to FIG. 4D, the lens resin portion 82a includes the lens portion 91 (not illustrated in the drawing) located at the central portion, and the carrier portion 92 (not illustrated in the drawing) located at the peripheral portion.

A film 121 having a light absorbing property or a light shielding property is formed on a lateral wall that becomes the through-hole 83a of the lens-attached laminated substrate 41a to prevent ghost or flare caused by light reflection. The film 121 is referred to as a light-shielding film 121 for convenience.

An upper surface layer 122 including an oxide, a nitride, or other insulating materials is formed on upper surfaces of the carrier substrate 81a and the lens resin portion 82a, and a lower surface layer 123 including an oxide, a nitride, or other insulating materials is formed on lower surfaces of the carrier substrate 81a and the lens resin portion 82a.

As an example, the upper surface layer 122 constitutes an antireflection film in which a plurality of layers of low-refractive films and a plurality of layers of high-refractive films are alternately laminated. For example, the antireflection film can be constituted by laminating a total of four layers in a film configuration in which the low-refractive film and the high-refractive film are alternately laminated. For example, the low-refractive film is constituted by an oxide film such as SiOx (1≤x≤2), SiOC, and SiOF, and for example, the high-refractive film is constituted by a metal oxide film such as TiO, TaO, and Nb₂O₅.

Furthermore, for example, the configuration of the upper surface layer 122 may be designed by using optical simulation so as to obtain desired antireflection performance, and the material, the film thickness, the number of lamination of the low-refractive film and the high-refractive film, and the like are not particularly limited. In this embodiment, an outermost surface of the upper surface layer 122 is constituted by the low-refractive film, the film thickness thereof is set to, for example, 20 to 1000 nm, a density thereof is set to, for example, 2.2 to 2.5 g/cm³, and the degree of flatness thereof is set to, for example, root mean square surface roughness Rq (RMS) of 1 nm or less. In addition, although details will be described later, the upper surface layer 122 also becomes a joining film when being joined to another lens-attached substrate 41.

As an example, the upper surface layer 122 may be an antireflection film in which a plurality of layers of the high-refractive films and a plurality of layers the low-refractive films are alternately laminated, and an inorganic antireflection film is preferable. As another example, the upper surface layer 122 may be a single-layer film including an oxide, a nitride, or other insulating materials, and an inorganic film is preferable.

As an example, the lower surface layer 123 may be an antireflection film in which a plurality of the low-refractive films and a plurality of the high-refractive films are alternately laminated, and an inorganic antireflection film is preferable. As another example, the lower surface layer 123 may be a single-layer film including an oxide, a nitride, or other insulating materials, and an inorganic film is preferable.

Description will be given of a structure and a film forming method of the light-shielding film 121.

The light-shielding film 121 is a thin film including a material that absorbs light, has a light-shielding property, and a light reflection suppressing property. The film thickness of the light-shielding film 121 is arbitrarily selected, and may be set to, for example, approximately 1 μm. For example, the light-shielding film 121 includes a black material. The black material is an arbitrary material, and may be, for example, a pigment such as carbon black and titanium black. In addition, for example, the light-shielding film 121 may be a metal film that is constituted by a metal. The metal is arbitrarily selected, and may be, for example, tungsten (W) and chromium (Cr). In addition, the light-shielding film 121 may be a CVD film that is formed through chemical vapor deposition (CVD). For example, the light-shielding film 121 may be a CVD film that is formed by using a carbon nanotube and the like. In addition, the light-shielding film 121 may be obtained by laminating a plurality of materials.

A method of forming the light-shielding film 121 is arbitrarily selected. For example, in the case of using a black material such as a black pigment as a material of the light-shielding film 121, film formation may be performed by spin and spray applications, and the like. In addition, lithography such as for performing patterning and removal may be performed as necessary. In addition, the light-shielding film 121 may be formed by ink jet. In addition, for example, in the case of using a metal such as tungsten (W) and chromium (Cr) as a material of the light-shielding film 121, a film may be formed by physical vapor deposition (PVD) and a surface of the film may be polished. In addition, for example, in the case of using carbon nanotube or the like as a material of the light-shielding film 121, a film may be formed by CVD, and a surface of the film may be polished.

When the light-shielding film 121 is formed on the lateral wall of the through-hole 83a, it is possible to suppress light reflection or light transmission at the lateral wall, and it is possible to suppress occurrence of ghost or flare. That is, it is possible to suppress a reduction in an image quality due to the lens-attached laminated substrate 41a (laminated lens structure 11).

In addition, an adhesive auxiliary agent that improves contact property between the lateral wall and the lens resin portion 82a may be added to the light-shielding film 121. A material of the adhesive auxiliary agent is arbitrarily selected. For example, a material corresponding to a material (characteristics) of the lens resin portion 82a may be used. For example, in a case where the lens resin portion 82a includes a hydrophilic material (for example, a material having a lot of OH groups), a hydrophilic material may be used as the adhesive auxiliary agent that is added. In addition, for example, in a case where the lens resin portion 82a includes from a hydrophobic material, a hydrophobic material may be used as the adhesive auxiliary agent that is added. For example, a silane coupling agent may be used as the adhesive auxiliary agent.

In this manner, when the adhesive auxiliary agent is added to the material of the light-shielding film 121, a contact property between the lateral wall and the lens resin portion 82a can be improved. According to this configuration, maintenance stability of the lens resin portion 82a is improved, and thus it is possible to obtain sufficient stability even though a contact area between the lateral wall and the lens resin portion 82a is small.

Furthermore, as described above, as the material of the adhesive auxiliary agent, a material corresponding to the material of the lens resin portion 82a can be used, and thus it is possible to improve a contact property with respect to the lens resin portion 82a that includes various materials. Accordingly, it is possible to suppress limitation of choices of the material of the carrier substrate 81 due to the material of the lens resin portion 82a.

<Detailed Description of Lens Resin Portion>

Next, description will be given of a shape of the lens resin portion 82 with reference to the lens resin portion 82a of the lens-attached laminated substrate 41a as an example.

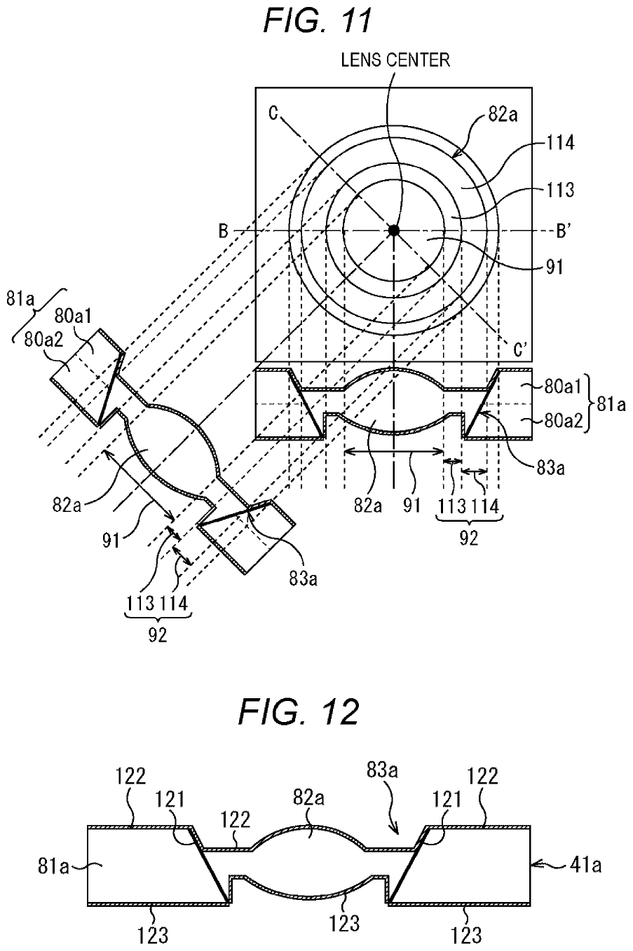

FIG. 11 shows a plan view and cross-sectional views of the carrier substrate 81a and the lens resin portion 82a which constitute the lens-attached laminated substrate 41a.

The cross-sectional views of the carrier substrate 81a and the lens resin portion 82a illustrated in FIG. 11 are cross-sectional views which are respectively taken along line B-B′ and line C-C′ in the plan view.

As described above, the lens resin portion 82a includes the lens portion 91 and the carrier portion 92. The carrier portion 92 is a portion that extends from the lens portion 91 to the carrier substrate 81a and carries the lens portion 91. The carrier portion 92 includes an arm portion 113 and a leg portion 114, and is located at the outer periphery of the lens portion 91.

The arm portion 113 is a portion that is disposed on an outer side of the lens portion 91 to be in contact with the lens portion 91, and outwardly extends from the lens portion 91 in a constant film thickness. The leg portion 114 is a portion other than the arm portion 113 in the carrier portion 92, and includes a portion that is in contact with the lateral wall of the through-hole 83a. In the leg portion 114, it is preferable that a resin film thickness is larger than that of the arm portion 113.

A planar shape of the through-hole 83a that is formed in the carrier substrate 81a is a circle, and a cross-sectional shape thereof is naturally the same regardless of a diameter direction. In a shape of the lens resin portion 82a which is determined by the shape of an upper mold and a lower mold when forming a lens, a cross-sectional shape is also formed to be the same regardless of a diameter direction.

<6. Detailed Configuration of Lens-Attached Single-Layer Substrate 41>

Next, a detailed configuration of the lens-attached single-layer substrate 41 will be described.

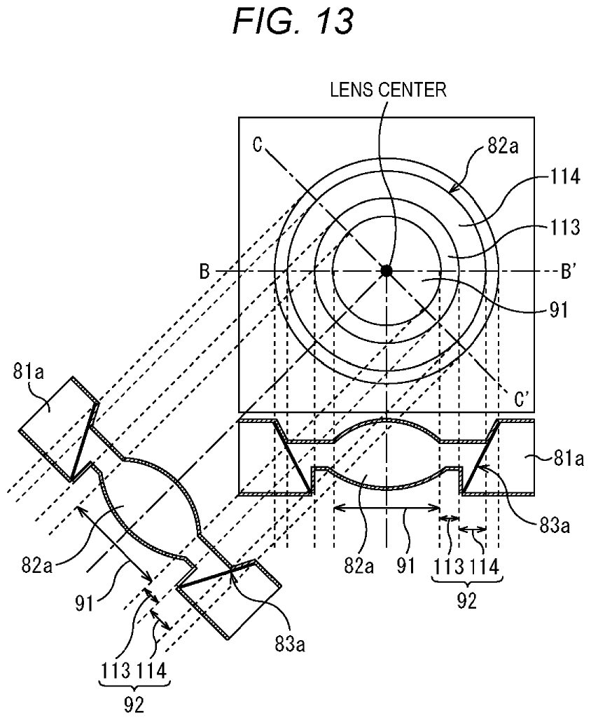

FIG. 12 and FIG. 13 illustrate an aspect in which the lens-attached laminated substrate 41a in FIG. 10 and FIG. 11 is changed to the lens-attached single-layer substrate 41a to explain the shape of the lens resin portion 82 in a unified manner.

As illustrated in FIG. 12 and FIG. 13, even in the lens-attached single-layer substrate 41a, the light-shielding film 121, the upper surface layer 122, and the lower surface layer 123 are formed in a similar manner. In addition, the lens resin portion 82a includes the lens portion 91 and the carrier portion 92, and the carrier portion 92 includes the arm portion 113 and the leg portion 114 and is located at the outer periphery of the lens portion 91.

<7. Method of Manufacturing Lens-Attached Single-Layer Substrate 41>

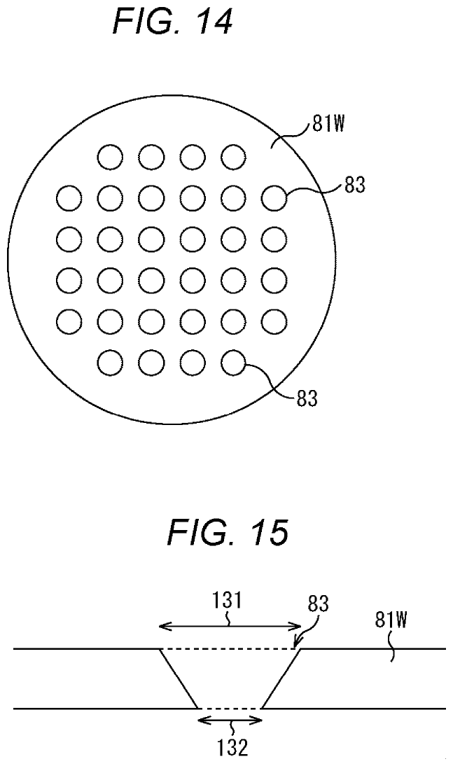

Next, a method of manufacturing the lens-attached single-layer substrate 41 will be described with reference to FIG. 14 to FIG. 17.

Furthermore, even in FIG. 14 to FIG. 17, description will be made by using an aspect in which the lens-attached laminated substrate 41a is changed to the lens-attached single-layer substrate 41a to explain the shape of the lens resin portion 82 in a unified manner.

First, a carrier substrate 81W in a substrate state in which a plurality of through-holes 83 are formed is prepared. As the carrier substrate 81W, for example, a silicon substrate that is used in a typical semiconductor device can be used. For example, a shape of the carrier substrate 81W is a circle as illustrated in FIG. 14, and a diameter thereof is set to, for example, 200 mm, 300 mm, and the like. The carrier substrate 81W may be, for example, a glass substrate, a resin substrate, or a metal substrate instead of the silicon substrate.

In addition, a planar shape of the through-holes 83 may be a circle as illustrated in FIG. 14.

As an opening width of the through-holes 83, for example, an opening width of approximately 100 μm to approximately 20 mm may be employed. In this case, for example, approximately 100 pieces to approximately 5,000,000 pieces may be disposed in the carrier substrate 81W.

As illustrated in FIG. 15, in the through-holes 83, a second opening width 132 in a second surface, which faces a first surface, of the carrier substrate 81W is smaller than a first opening width 131 in the first surface.

The through-holes 83 of the carrier substrate 81W can be formed by etching the carrier substrate 81W through wet etching. For example, the through-holes 83 can be formed through wet etching that uses chemicals capable of etching silicon into a desired shape without receiving a crystal orientation restriction disclosed in WO 2011/010739 A and the like. As the chemicals, for example, chemicals obtained by adding at least one of polyoxyethylene alkyl phenyl ether, polyoxyalkylene alkyl ether, and polyethylene glycol which are surfactants in a tetramethylammonium hydroxide (TMAH) aqueous solution, and chemicals obtained by adding isopropyl alcohol to a KOH aqueous solution, and the like can be employed.

When performing etching for forming the through-holes 83 with respect to the carrier substrate 81W including single crystal silicon in which a substrate surface orientation is (100) by using any one of the chemicals, in a case where a planar shape of an opening of an etching mask is a circle, the through-holes 83, in which a planar shape is a circle and the second opening width 132 is smaller than the first opening width 131, and which has an inclination of a constant angle, are formed. A three-dimensional shape of the through-holes 83 which are formed becomes a truncated cone or a shape similar thereto.

<Method of Manufacturing Lens-Attached Substrate>

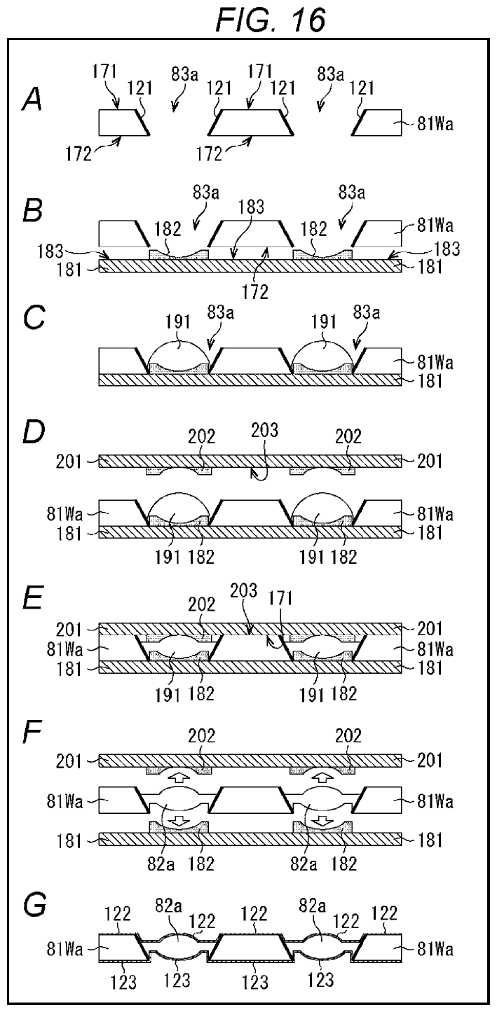

Next, a method of manufacturing the lens-attached substrate 41Wa in a substrate state will be described with reference to FIG. 16A to FIG. 16G.

First, as illustrated in FIG. 16A, the carrier substrate 81Wa in which a plurality of through-holes 83a are formed is prepared. The light-shielding film 121 is formed on a lateral wall of the through-holes 83a. In FIG. 16A to FIG. 16G, only two through-holes 83a are illustrated due to a restriction of a paper surface. However, as illustrated in FIG. 14, actually, the plurality of through-holes 83a are formed in a plane direction of the carrier substrate 81Wa. In addition, an alignment mark (not illustrated in the drawing) for alignment is formed in a region that is close to the outer periphery of the carrier substrate 81Wa.

A front side flat portion 171 on an upper side of the carrier substrate 81Wa and a rear side flat portion 172 on a lower side are formed as a flat surface that is flat to a certain extent capable of performing plasma joining to be performed in the subsequent process. The thickness of the carrier substrate 81Wa also functions as a spacer that determines a distance between lenses when being finally divided into individual pieces as the lens-attached substrate 41a and superimposed on another lens-attached substrate 41a.

As the carrier substrate 81Wa, it is preferable to use a low-thermal-expansion-coefficient base material having a thermal expansion coefficient of 10 ppm/° C. or less.

Next, as illustrated in FIG. 16B, the carrier substrate 81Wa is disposed on a lower mold 181 on which a plurality of concave optical transfer surfaces 182 are arranged at a constant interval. More specifically, the rear side flat portion 172 of the carrier substrate 81Wa and a flat surface 183 of the lower mold 181 are superimposed so that each of the concave optical transfer surfaces 182 is located on an inner side of each of the through-holes 83a of the carrier substrate 81Wa. The optical transfer surfaces 182 of the lower mold 181 are formed to correspond to the through-holes 83a of the carrier substrate 81Wa in one-to-one correspondence, and a position of the carrier substrate 81Wa and a position of the lower mold 181 in a plane direction are adjusted so that the centers of the optical transfer surface 182 and the through-hole 83a match each other in the optical axis direction. The lower mold 181 includes a hard mold member, and is constituted by, for example, a metal, silicon, quartz, or glass.

Next, as illustrated in FIG. 16C, an energy-curable resin 191 is filled (is added dropwise) in the through-hole 83a of the carrier substrate 81Wa and the lower mold 181 which are superimposed. The lens resin portion 82a is formed by using the energy-curable resin 191. Accordingly, it is preferable that the energy-curable resin 191 is subjected to a defoaming treatment in advance so as not to include air bubbles. As the defoaming treatment, a vacuum defoaming treatment, or a defoaming treatment by a centrifugal force is preferable. In addition, it is preferable that the vacuum defoaming treatment is performed after filling of the resin. When the defoaming treatment is performed, air bubbles are not involved, and thus molding of the lens resin portion 82a is possible.

Next, as illustrated in FIG. 16D, an upper mold 201 is disposed on the lower mold 181 and the carrier substrate 81Wa which are superimposed. A plurality of concave optical transfer surfaces 202 are arranged on the upper mold 201 at a constant interval. As in the disposition of the lower mold 181, the upper mold 201 is disposed after being positioned with accuracy so that the center of the through-hole 83a and the center of each of the optical transfer surfaces 202 match each other in the optical axis direction.

With regard to a height direction that is a vertical direction on the paper, the position of the upper mold 201 is fixed by a control device that controls an interval between the upper mold 201 and the lower mold 181 so that the interval between the upper mold 201 and the lower mold 181 becomes a predetermined distance. At this time, a space between the optical transfer surface 202 of the upper mold 201 and the optical transfer surface 182 of the lower mold 181 becomes equal to the thickness of the lens resin portion 82a which is calculated by optical design.

Alternatively, as illustrated in FIG. 16E, as in the disposition of the lower mold 181, a flat surface 203 of the upper mold 201 and the front side flat portion 171 of the carrier substrate 81Wa may be superimposed. In this case, a distance between the upper mold 201 and the lower mold 181 becomes a value that is the same as the thickness of the carrier substrate 81Wa, and alignment with high accuracy in the plane direction and the height direction becomes possible.

When the interval between the upper mold 201 and the lower mold 181 is controlled to be a distance that is set in advance, in the process illustrated in FIG. 16C, a filling amount of the energy-curable resin 191 that is added dropwise into the through-hole 83a of the carrier substrate 81Wa becomes an amount that is controlled so as not to overflow from a space surrounded by the through-hole 83a of the carrier substrate 81Wa, and the upper mold 201 and the lower mold 181 which are located on an upper side and a lower side of the through-hole 83a. According to this configuration, the material of the energy-curable resin 191 is not wasted, and thus it is possible to reduce the manufacturing cost.

Subsequently, in a state illustrated in FIG. 16E, a curing treatment of the energy-curable resin 191 is performed. For example, the energy-curable resin 191 is cured when being left as is for a predetermined time after application of heat or UV light as energy. During the curing, it is possible to suppress deformation due to shrinkage of the energy-curable resin 191 to the minimum by downwardly pushing the upper mold 201 or performing alignment.

A thermoplastic resin may be used instead of the energy-curable resin 191. In this case, in the state illustrated in FIG. 16E, when raising a temperature of the upper mold 201 and the lower mold 181, the energy-curable resin 191 is molded into a lens shape, and is cured through cooling-down.

Next, as illustrated in FIG. 16F, the control device that controls the position of the upper mold 201 and the lower mold 181 moves the upper mold 201 to an upward side, and moves the lower mold 181 to a downward side to release the upper mold 201 and the lower mold 181 from the carrier substrate 81Wa. When the upper mold 201 and the lower mold 181 are released from the carrier substrate 81Wa, the lens resin portion 82a is formed on an inner side of the through-hole 83a of the carrier substrate 81Wa.

Furthermore, the surfaces of the upper mold 201 and the lower mold 181, which come into contact with the carrier substrate 81Wa, may be coated with a release agent such as a fluorine-based release agent and a silicon-based release agent. In this configuration, it is possible to easily release the carrier substrate 81Wa from the upper mold 201 and the lower mold 181. In addition, with regard to a method of easily releasing the molds from the contact surface with the carrier substrate 81Wa, various kinds of coating with a fluorine-containing diamond like carbon (DLC) and the like may be performed.

Next, as illustrated in FIG. 16G, the upper surface layer 122 is formed on the front surface of the carrier substrate 81Wa and the lens resin portion 82a, and the lower surface layer 123 is formed on the rear surface of the carrier substrate 81Wa and the lens resin portion 82a. Before and after film formation of the upper surface layer 122 and the lower surface layer 123, chemical mechanical polishing (CMP) and the like may be performed as necessary to planarize the front side flat portion 171 and the rear side flat portion 172 of the carrier substrate 81Wa.

As described above, the energy-curable resin 191 is press-molded (imprinted) into the through-hole 83a formed in the carrier substrate 81Wa by using the upper mold 201 and the lower mold 181 to form the lens resin portion 82a, thereby manufacturing the lens-attached substrate 41a.

The shape of the optical transfer surface 182 and the optical transfer surface 202 is not limited to the above-described concave shape, and is appropriately determined in correspondence with the shape of the lens resin portion 82a. As described above with reference to FIG. 3, the lens shape of the lens-attached substrates 41a to 41e can take various shapes derived by optical system design, and may be, for example, a biconvex shape, a biconcave shape, a planoconvex shape, a planoconcave shape, a convex meniscus shape, a concave meniscus shape, a higher order aspheric shape, and the like.

In addition, the shape of the optical transfer surface 182 and the optical transfer surface 202 may be set to a shape in which a shape of a lens after being formed becomes a moth-eye structure.

According to the above-described manufacturing method, it is possible to cut off a fluctuation in a distance between the lens resin portions 82a in a plane direction due to curing shrinkage of the energy-curable resin 191 by interposition of the carrier substrate 81Wa, and thus it is possible to control the degree of inter-lens distance accuracy with high accuracy. In addition, there is an effect of reinforcing the energy-curable resin 191 having weak strength with the carrier substrate 81Wa having strong strength. According to this configuration, it is possible to provide a lens array substrate in which a plurality of lens with excellent handleability are arranged, and it is possible to attain an effect capable of suppressing bending of the lens array substrate.

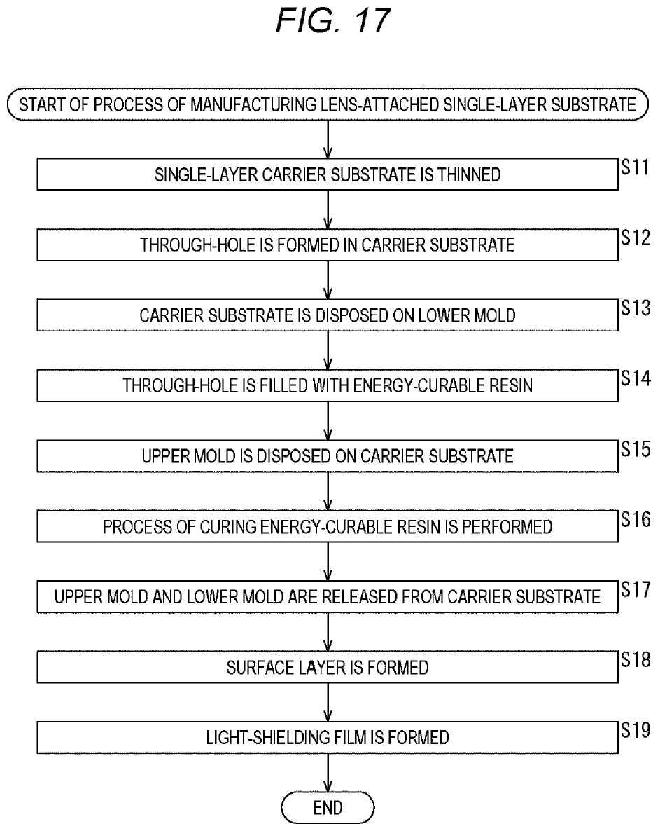

Next, a process of manufacturing the lens-attached single-layer substrate 41 will be described with reference to a flowchart in FIG. 17.

First, in step S11, the single-layer carrier substrate 81W is thinned in correspondence with the thickness of the carrier substrate 81W which is necessary. In a case where thinning is not necessary, this step can be omitted.

In step S12, the through-hole 83 is formed in the carrier substrate 81W (single-layer carrier substrate 81W).

In step S13, the carrier substrate 81W is disposed on the lower mold 181. In step S14, the through-hole 83 of the carrier substrate 81W is filled with the energy-curable resin 191.

In step S15, the upper mold 201 is disposed on the carrier substrate 81W. In step S16, a curing treatment of the energy-curable resin 191 is performed. In step S17, the upper mold 201 and the lower mold 181 are released from the carrier substrate 81W. Through the above-described processes, as illustrated in FIG. 16F, the lens resin portion 82 is formed in the through-hole 83 of the carrier substrate 81W.

In step S18, the upper surface layer 122 is formed on a light incident side surface of the carrier substrate 81W and the lens resin portion 82W, and the lower surface layer 123 is formed on a light emission side surface.

In step S19, in the case of manufacturing the lens-attached substrate 41W, which is laminated on the most light incident side, in the laminated lens structure 11, the light-shielding film 121 is formed on a light incident side surface of the carrier portion 92 of the lens resin portion 82W. In the case of manufacturing the lens-attached substrate 41W used as the other layers of the laminated lens structure 11, the above-described process can be omitted.

As described above, the lens-attached single-layer substrate 41 is completed.

<8. Method of Manufacturing Lens-Attached Laminated Substrate 41>

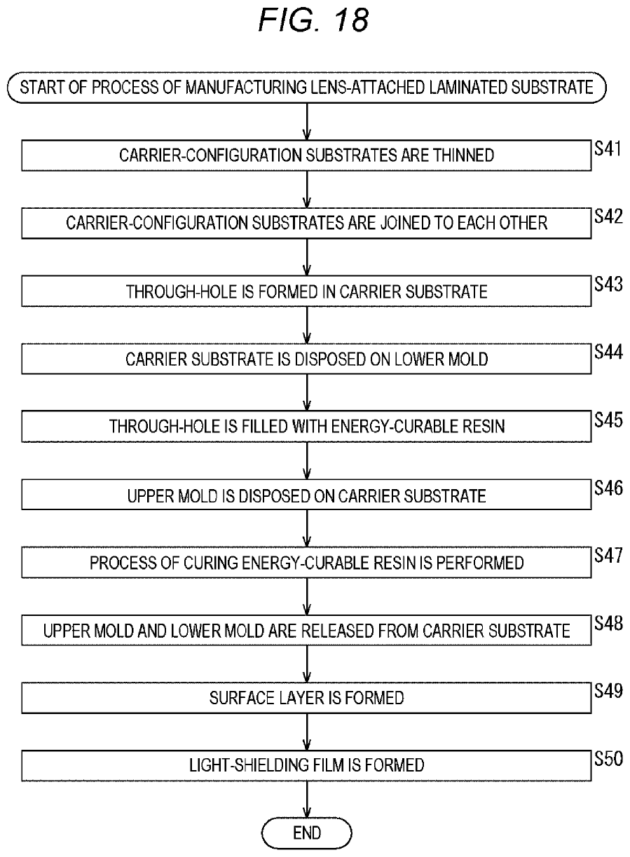

Next, a process of manufacturing the lens-attached laminated substrate 41 will be described with reference to a flowchart in FIG. 18.

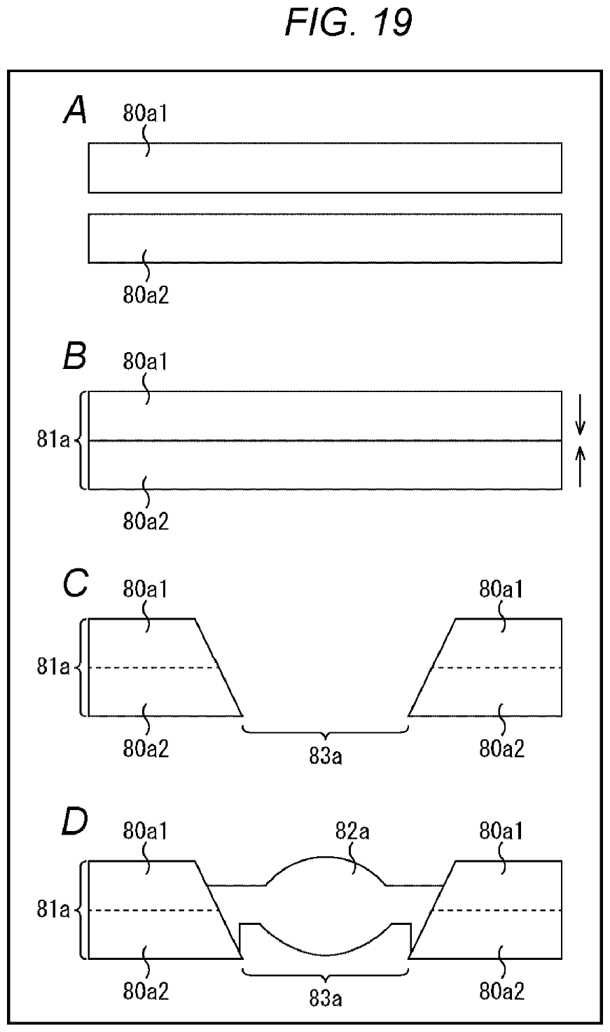

Furthermore, in description of FIG. 18, description will be made with reference to FIG. 19A to FIG. 19D as necessary. FIG. 19A to FIG. 19D are views illustrating a process of manufacturing the lens-attached laminated substrate 41 in an individual piece state, but the drawing is also true of the lens-attached laminated substrate 41W in a substrate state.

First, in step S41, a plurality of sheets of the carrier configuration substrates 80a which constitute the carrier substrate 81a (laminated carrier substrate 81a) are thinned into a desired thickness. With respect to the carrier configuration substrate 80a for which the thinning is not necessary, the step can be omitted.

In step S42, the plurality of sheets of carrier configuration substrates 80 are joined to each other. For example, as illustrated in FIG. 19A and FIG. 19B, two sheets of the carrier configuration substrates 80a1 and carrier configuration substrate 80a2 can be bonded to each other through direct joining. The resultant bonded substrate becomes the carrier substrate 81a (laminated carrier substrate 81a).

Furthermore, the process in step S41 and the process in step S42 may be substituted with each other. That is, the thinning process into a desired thickness may be performed after joining the plurality of sheets of carrier configuration substrates 80.

In step S43, as illustrated in FIG. 19C, the through-hole 83a is formed in the carrier substrate 81a.

In step S44, the carrier substrate 81a is disposed on the lower mold 181. In step S45, the through-hole 83a of the carrier substrate 81a is filled with the energy-curable resin 191.

In step S46, the upper mold 201 is disposed on the carrier substrate 81a. In step S47, a curing treatment of the energy-curable resin 191 is performed. In step S48, the upper mold 201 and the lower mold 181 are released from the carrier substrate 81a. Through the above-described process, as illustrated in FIG. 19D, the lens resin portion 82a is formed in the through-hole 83a of the carrier substrate 81a.

In step S49, the upper surface layer 122 is formed on the light incident side surface of the carrier substrate 81a and the lens resin portion 82a, and the lower surface layer 123 is formed on the light emission side surface.

In step S50, in the case of manufacturing the lens-attached substrate 41a, which is laminated on the most light incident side, in the laminated lens structure 11, the light-shielding film 121 is formed on a light incident side surface of the carrier portion 92 of the lens resin portion 82a. In the case of manufacturing the lens-attached substrate 41W used as the other layers of the laminated lens structure 11, the above-described process can be omitted.

Through the processes, the lens-attached laminated substrate 41 is completed.

<9. Direct Joining Between Lens-Attached Substrates>

Next, description will be given of direct joining between the lens-attached substrates 41W in a substrate state in which a plurality of the lens-attached substrates 41 are formed.

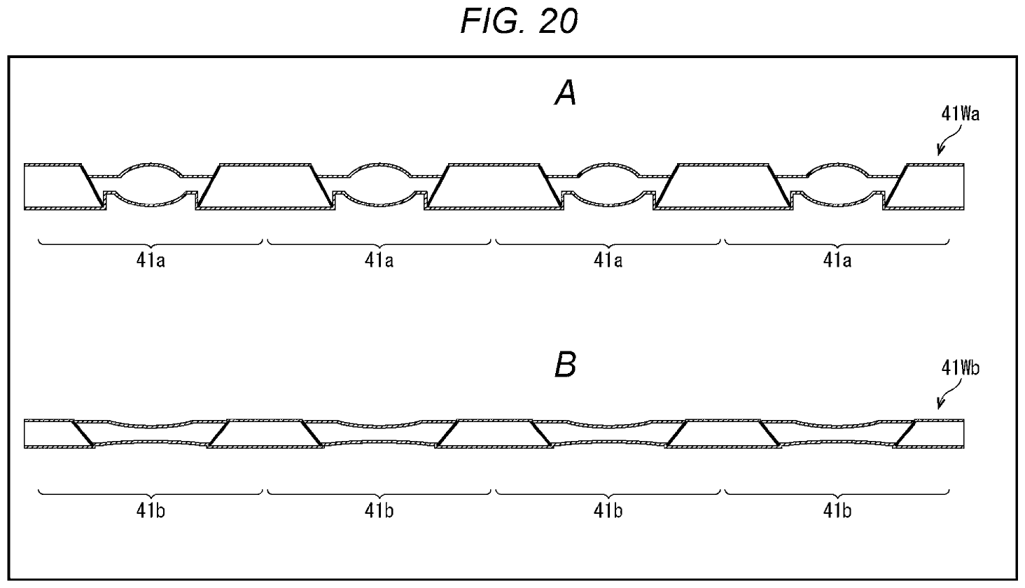

Specifically, description will be given of direct joining between the lens-attached substrate 41Wa in a substrate state in which a plurality of the lens-attached substrate 41a are formed as illustrated in FIG. 20A, and the lens-attached substrate 41Wb in a substrate state in which a plurality of the lens-attached substrate 41b are formed as illustrated in FIG. 20B.

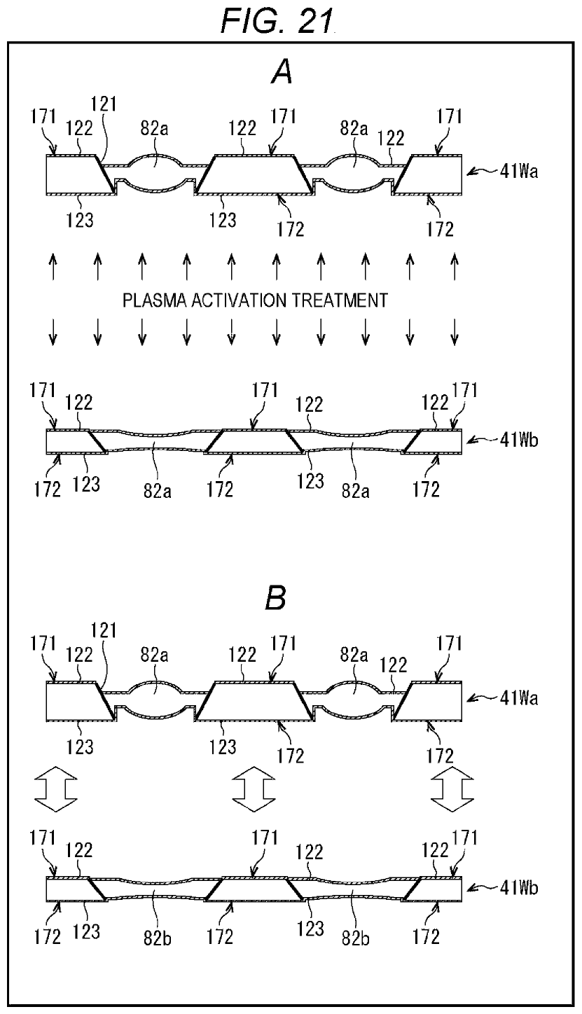

Furthermore, in the lens-attached substrate 41Wa in a substrate state in FIG. 20A to FIG. 21B, a broken line indicating a bonding surface of the carrier configuration substrate 80 is not illustrated in the drawings, but the lens-attached substrate 41Wa is the lens-attached laminated substrate 41Wa that uses the laminated carrier substrate 81 in which a plurality of sheets of the carrier configuration substrates 80 are bonded to each other.

FIG. 21A and FIG. 21B are views illustrating the direct joining between the lens-attached substrate 41Wa in a substrate state and the lens-attached substrate 41Wb in a substrate state.

Furthermore, in FIG. 21A and FIG. 21B, the same reference numerals as in the lens-attached substrate 41Wa will be given to portions of the lens-attached substrate 41Wb which correspond to respective portions of the lens-attached substrate 41Wa in description.

The upper surface layer 122 is formed on upper surfaces of the lens-attached substrate 41Wa and the lens-attached substrate 41Wb. The lower surface layer 123 is formed on lower surfaces of the lens-attached substrate 41Wa and the lens-attached substrate 41Wb. In addition, as illustrated in FIG. 21A, a plasma activation treatment is performed to joining surfaces of the lens-attached substrates 41Wa and 41Wb, that is, the entirety of the lower surface, which includes the rear side flat portion 172, of the lens-attached substrate 41Wa, and the entirety of the upper surface, which includes the front side flat portion 171, of the lens-attached substrate 41Wb. A gas that is used in the plasma activation treatment may be any gas such as O₂, N₂, He, Ar, and H₂ which are capable of performing the plasma treatment. However, it is preferable to use the same gas as a constituent element of the upper surface layer 122 and the lower surface layer 123 as the gas that is used in the plasma activation treatment, when considering that it is possible to suppress a change in film quality of the upper surface layer 122 and the lower surface layer 123.

In addition, as illustrated in FIG. 21B, the rear side flat portion 172 of the lens-attached substrate 41Wa in an activated surface state, and the front side flat portion 171 of the lens-attached substrate 41Wb in an activated surface state can be bonded to each other.

Through the bonding process between the lens-attached substrates, a hydrogen bond occurs between hydrogen in OH group on a surface of the lower surface layer 123 of the lens-attached substrate 41Wa, and hydrogen in OH group on a surface of the upper surface layer 122 of the lens-attached substrate 41Wb. Accordingly, the lens-attached substrate 41Wa and the lens-attached substrate 41Wb are fixed to each other. The bonding process between the lens-attached substrates can be performed under a condition of an atmospheric pressure.

An annealing treatment is performed with respect to the lens-attached substrate 41Wa and the lens-attached substrate 41Wb which are bonded to each other. According to this treatment, dehydration and condensation occur from a state in which a hydrogen bond is formed between the OH groups, and a covalent bond with oxygen interposed therein occurs between the lower surface layer 123 of the lens-attached substrate 41Wa and the upper surface layer 122 of the lens-attached substrate 41Wb. Alternatively, an element contained in the lower surface layer 123 of the lens-attached substrate 41Wa and an element contained in the upper surface layer 122 of the lens-attached substrate 41Wb form a covalent bond. Two sheets of the lens-attached substrates 41W are strongly fixed to each other due to the bond. In this manner, an aspect, in which a covalent bond is formed between the lower surface layer 123 of the lens-attached substrate 41W that is disposed on an upper side, and the upper surface layer 122 of the lens-attached substrate 41W that is disposed on a lower side, and two sheets of the lens-attached substrates 41W are fixed to each other due to the covalent bond, is referred to as the direct joining in this specification. For example, in a method in which a plurality of sheets of lens-attached substrates are fixed by a resin over the entirety of a substrate surface, there is a concern on curing shrinkage and thermal expansion, and lens deformation due to the curing shrinkage and the thermal expansion. In contrast, in the direct joining of the present technology, when fixing the plurality of sheets of lens-attached substrates 41W, a resin is not used. Accordingly, there is an operation or an effect capable of fixing the plurality of sheets of lens-attached substrates 41W without causing the curing shrinkage and the thermal expansion due to the resin.

The above-described annealing treatment can be performed under a condition of an atmospheric pressure. The annealing treatment can be performed at 100° C. or higher, 150° C. or higher, or 200° C. or higher so as to perform dehydration and condensation. On the other hand, the annealing treatment can be performed at 400° C. or lower, 350° C. or lower, or 300° C. or lower from the viewpoint of protecting the energy-curable resin 191 that forms the lens resin portion 82 from heat, and the viewpoint of suppressing degassing from the energy-curable resin 191.

In a case where the bonding between the lens-attached substrates 41W or the direct joining between the lens-attached substrates 41W is performed under a condition other than the atmospheric pressure, when the lens-attached substrate 41Wa and the lens-attached substrate 41Wb which are joined to each other are returned to an environment of the atmospheric pressure, a pressure difference occurs between the space between the lens resin portion 82 and the lens resin portion 82 which are joined to each other, and the outside of the lens resin portion 82. Due to the pressure difference, there is a concern that a pressure increases in the lens resin portion 82, and the lens resin portion 82 is deformed.

When performing the bonding between the lens-attached substrates 41W or the direct joining between the lens-attached substrates 41W under the condition of the atmospheric pressure, it is possible to exhibit an operation or an effect capable of avoiding deformation of the lens resin portion 82 which may occur in the case of performing the joining under a condition other than the atmospheric pressure.

When the substrates which are subjected to the plasma activation treatment are directly bonded to each other, in other words, when the substrates are plasma-joined to each other, for example, it is possible to suppress fluidity and thermal expansion which occur in the case of using a resin as an adhesive. Accordingly, it is possible to improve positional accuracy when joining the lens-attached substrate 41Wa and the lens-attached substrate 41Wb.

As described above, the upper surface layer 122 or the lower surface layer 123 is formed on the rear side flat portion 172 of the lens-attached substrate 41Wa and the front side flat portion 171 of the lens-attached substrate 41Wb. A dangling bond is likely to be formed on the upper surface layer 122 and the lower surface layer 123 due to the plasma activation treatment that is previously performed. That is, the lower surface layer 123 that is formed on the rear side flat portion 172 of the lens-attached substrate 41Wa and the upper surface layer 122 that is formed on the front side flat portion 171 of the lens-attached substrate 41Wb also play a role of increasing joining strength.

In addition, in a case where the upper surface layer 122 or the lower surface layer 123 is constituted by an oxide film, it is not susceptible to an influence of film-quality variation due to plasma (O₂). Accordingly, with respect to the lens resin portion 82, an effect of suppressing corrosion due to plasma is exhibited.

As described above, after being subjected to the surface activation treatment with plasma, the lens-attached substrate 41Wa in a substrate state in which the plurality of lens-attached substrates 41a are formed and the lens-attached substrate 41Wb in a substrate state in which the plurality of lens-attached substrates 41b are formed are directly joined to each other, in other words, are joined to each other by using plasma joining.

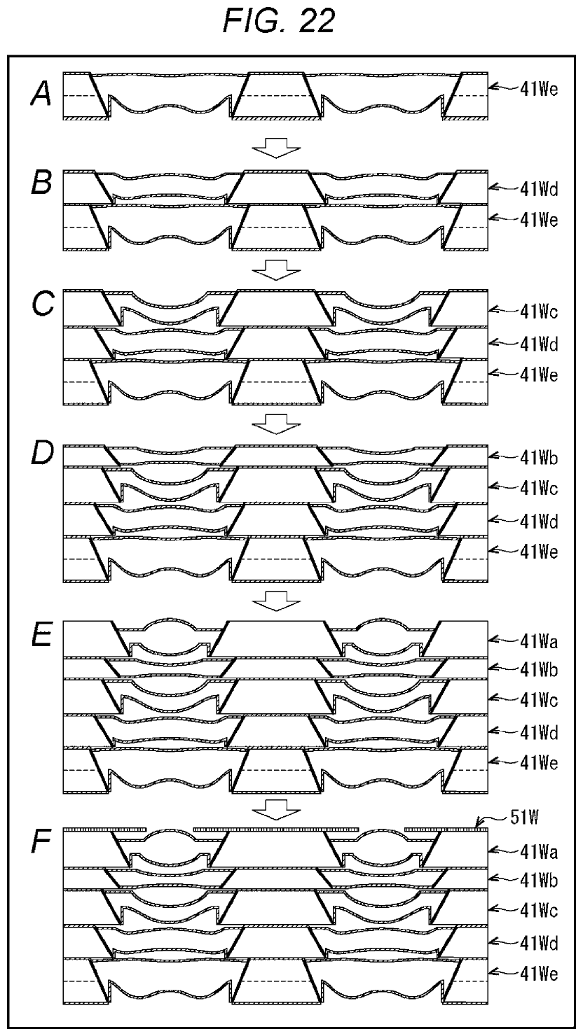

FIG. 22A to FIG. 22F illustrate a first lamination method in which five sheets of the lens-attached substrates 41a to 41e corresponding to the laminated lens structure 11 in FIG. 2 are laminated in a substrate state by using the method of joining the lens-attached substrates 41W in a substrate state as described above with reference to FIG. 21A and FIG. 21B.

First, as illustrated in FIG. 22A, the lens-attached substrate 41We in a substrate state, which is located in the lowermost layer in the laminated lens structure 11, is prepared.

Next, as illustrated in FIG. 22B, the lens-attached substrate 41Wd in a substrate state, which is located in a second layer from the lower side in the laminated lens structure 11, is joined onto the lens-attached substrate 41We in a substrate state.

Next, as illustrated in FIG. 22C, the lens-attached substrate 41Wc in a substrate state, which is located in a third layer from the lower side in the laminated lens structure 11, is joined onto the lens-attached substrate 41Wd in a substrate state.

Next, as illustrated in FIG. 22D, the lens-attached substrate 41Wb in a substrate state, which is located in a fourth layer from the lower side in the laminated lens structure 11, is joined onto the lens-attached substrate 41Wc in a substrate state.

Next, as illustrated in FIG. 22E, the lens-attached substrate 41Wa in a substrate state, which is located in a fifth layer from the lower side in the laminated lens structure 11, is joined onto the lens-attached substrate 41Wb in a substrate state.

Finally, as illustrated in FIG. 22F, a diaphragm plate 51W, which is located in an upper layer of the lens-attached substrate 41a in the laminated lens structure 11, is joined onto the lens-attached substrate 41Wa in a substrate state.

As described above, the five sheets of lens-attached substrates 41Wa to 41We in a substrate state are sequentially laminated from the lens-attached substrate 41W in a lower layer in the laminated lens structure 11 to the lens-attached substrate 41W in an upper layer sheet by sheet, and thus the laminated lens structure 11W in a substrate state is obtained.

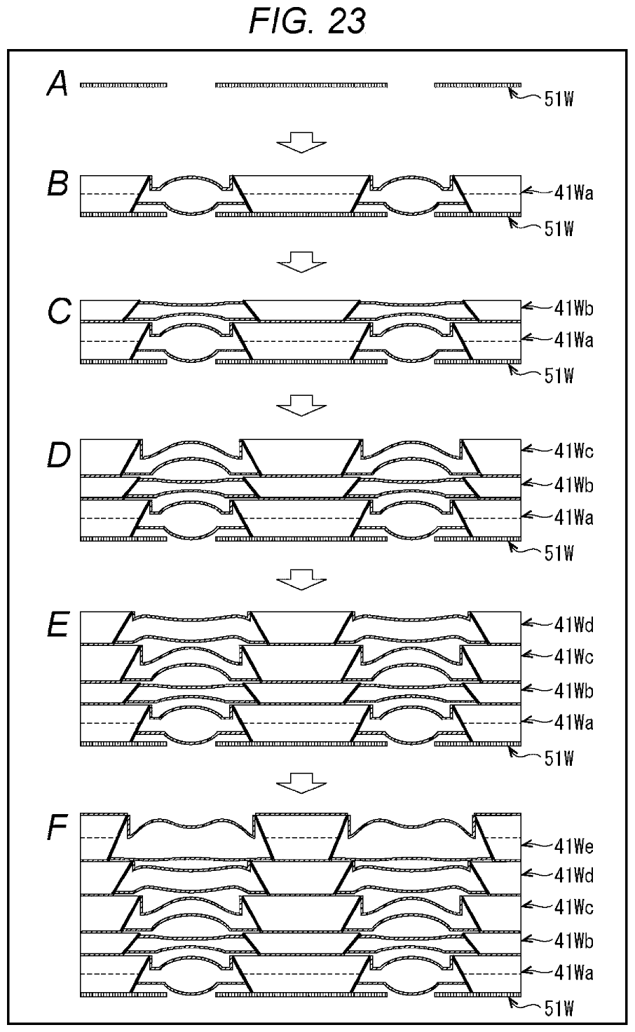

FIG. 23A to FIG. 23F illustrate a second lamination method in which five sheets of the lens-attached substrates 41a to 41e corresponding to the laminated lens structure 11 in FIG. 2 are laminated in a substrate state by using the method of joining the lens-attached substrates 41W in a substrate state as described above with reference to FIG. 21A and FIG. 21B.

First, as illustrated in FIG. 23A, the diaphragm plate 51W, which is located in an upper layer of the lens-attached substrate 41a in the laminated lens structure 11, is prepared.

Next, as illustrated in FIG. 23B, the lens-attached substrate 41Wa in a substrate state, which is located in the uppermost layer in the laminated lens structure 11, is vertically inverted, and is joined onto the diaphragm plate 51W.

Next, as illustrated in FIG. 23C, the lens-attached substrate 41Wb in a substrate state, which is located in a second layer from an upper side in the laminated lens structure 11, is vertically inverted, and is joined onto the lens-attached substrate 41Wa in a substrate state.

Next, as illustrated in FIG. 23D, the lens-attached substrate 41Wc in a substrate state, which is located in a third layer from the upper side in the laminated lens structure 11, is vertically inverted, and is joined onto the lens-attached substrate 41Wb in a substrate state.

Next, as illustrated in FIG. 23E, the lens-attached substrate 41Wd in a substrate state, which is located in a fourth layer from the upper side in the laminated lens structure 11, is vertically inverted, and is joined onto the lens-attached substrate 41Wc in a substrate state.

Next, as illustrated in FIG. 23F, the lens-attached substrate 41We in a substrate state, which is located in a fifth layer from the upper side in the laminated lens structure 11, is vertically inverted, and is joined onto the lens-attached substrate 41Wd in a substrate state.

As described above, the five sheets of lens-attached substrates 41Wa to 41We in a substrate state are sequentially laminated from the lens-attached substrate 41W in an upper layer in the laminated lens structure 11 to the lens-attached substrate 41W in a lower layer sheet by sheet, and thus the laminated lens structure 11W in a substrate state is obtained.

The five sheets of lens-attached substrates 41Wa to 41We in a substrate state which are laminated by the lamination method as described above with reference to FIG. 22A to FIG. 22F or FIG. 23A to FIG. 23F are divided into individual module units or chip units by using a blade, a laser, or the like, and thus the laminated lens structure 11 in which the five sheets of lens-attached substrates 41a to 41e are laminated is obtained.

<10. Second Configuration Example of Laminated Lens Structure 11>

Next, description will be given of another configuration example of the laminated lens structure 11 that can be embedded in the camera module 1.

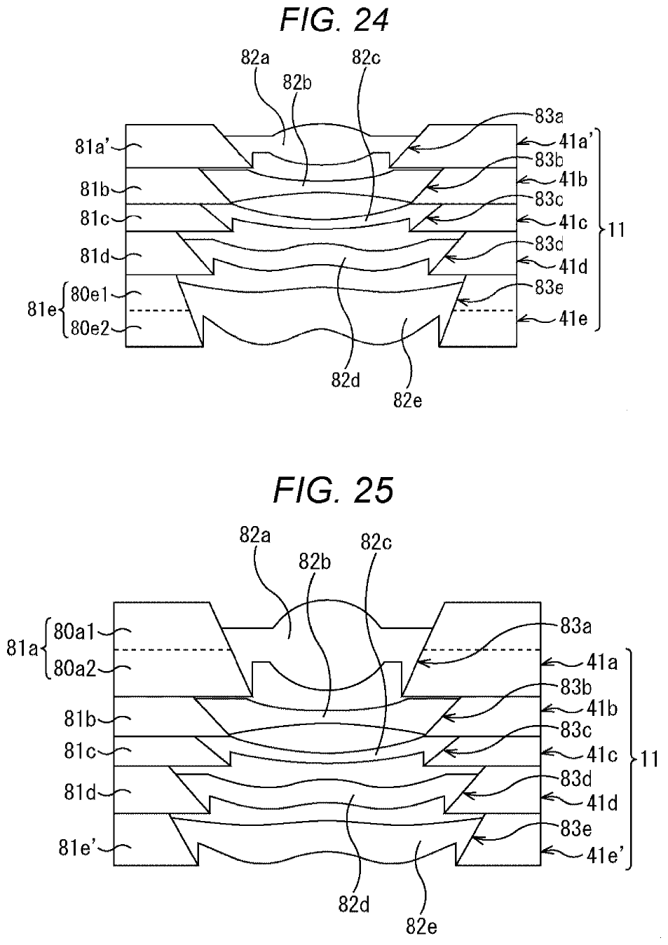

FIG. 24 is a cross-sectional view illustrating a second configuration example of the laminated lens structure 11.

In the second configuration example, a portion different from the first configuration example is illustrated, for example, by adding a dash (′) to a reference numeral as in a relationship between the lens-attached laminated substrate 41a and a lens-attached laminated substrate 41a′. This is also true of the following third configuration example or later.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In contrast, in the laminated lens structure 11 relating to the second configuration example in FIG. 24, among five sheets of lens-attached substrates 41a′ to 41e which are laminated, only the lens-attached substrate 41e located in the lowermost layer is constituted by the lens-attached laminated substrate 41 that uses the laminated carrier substrate 81, and the other four sheets of lens-attached substrates 41a′ to 41d are constituted by the lens-attached single-layer substrate 41 that uses the single-layer carrier substrate 81.

In other words, the lens-attached laminated substrate 41a, which uses the laminated carrier substrate 81a, in the uppermost layer according to the first configuration example is changed to the lens-attached single-layer substrate 41a′ that uses a single-layer carrier substrate 81a′ in the second configuration example.

The other structures of the second configuration example are similar to the laminated lens structure 11 according to the first configuration example.

As described above, with regard to the lens-attached substrate 41e in the lowermost layer, the laminated lens structure 11 relating to the second configuration example and the camera module 1 that uses the laminated lens structure 11 include a similar structure as in the first configuration example. Accordingly, an operational effect similar to the operational effect, which is exhibited by the lens-attached substrate 41e in the lowermost layer according to the first configuration example, is also exhibited in the second configuration example.

<11. Third Configuration Example of Laminated Lens Structure 11>

FIG. 25 is a cross-sectional view illustrating a third configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In contrast, in the laminated lens structure 11 relating to the third configuration example in FIG. 25, among five sheets of lens-attached substrates 41a to 41e′ which are laminated, only the lens-attached substrate 41a located in the uppermost layer is constituted by the lens-attached laminated substrate 41 that uses the laminated carrier substrate 81, and the other four sheets of lens-attached substrates 41b to 41e′ are constituted by the lens-attached single-layer substrate 41 that uses the single-layer carrier substrate 81.

In other words, the lens-attached laminated substrate 41e, which uses the laminated carrier substrate 81e, in the lowermost layer according to the first configuration example is changed to the lens-attached single-layer substrate 41e′ that uses a single-layer carrier substrate 81e′ in the third configuration example.

The other structures of the third configuration example are similar to the laminated lens structure 11 according to the first configuration example.

As described above, with regard to the lens-attached substrate 41a in the uppermost layer, the laminated lens structure 11 relating to the third configuration example and the camera module 1 that uses the laminated lens structure 11 include a similar structure as in the first configuration example. Accordingly, an operational effect similar to the operational effect, which is exhibited by the lens-attached substrate 41a in the uppermost layer according to the first configuration example, is also exhibited in the third configuration example.

<12. Fourth Configuration Example of Laminated Lens Structure 11>

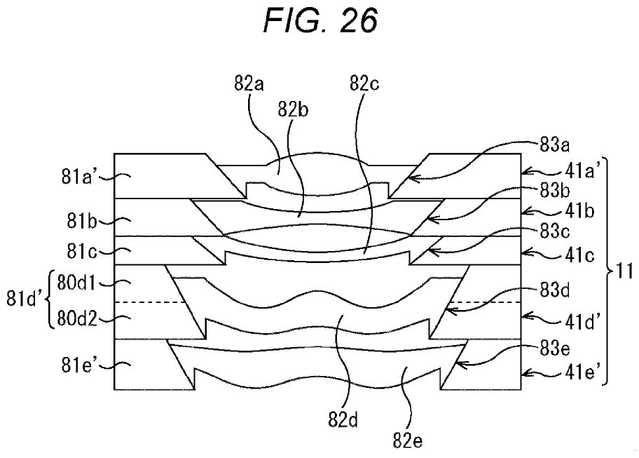

FIG. 26 is a cross-sectional view illustrating a fourth configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In contrast, in the laminated lens structure 11 relating to the fourth configuration example in FIG. 26, among five sheets of lens-attached substrates 41a′ to 41e′ which are laminated, only the lens-attached substrate 41d′ in the fourth layer as one intermediate layer is constituted by the lens-attached laminated substrate 41 that uses the laminated carrier substrate 81, and the other four sheets of lens-attached substrates 41a′ to 41c, and 41e′ are constituted by the lens-attached single-layer substrate 41 that uses the single-layer carrier substrate 81.

In other words, the lens-attached laminated substrate 41a, which uses the laminated carrier substrate 81a, in the uppermost layer and the lens-attached laminated substrate 41e, which uses the laminated carrier substrate 81e, in the lowermost layer according to the first configuration example are changed to the lens-attached single-layer substrate 41a′ that uses a single-layer carrier substrate 81a′ and the lens-attached single-layer substrate 41e′ that uses a single-layer carrier substrate 81e′ in the third configuration example.

In addition, the lens-attached single-layer substrate 41d, which uses the single-layer carrier substrate 81d, in the fourth layer according to the first configuration example is changed to the lens-attached laminated substrate 41d′ that uses a laminated carrier substrate 81d′ in the fourth configuration example. The laminated carrier substrate 81d′ is constituted by bonding two sheets of carrier configuration substrates 80d1 and 80d2.

The other structures of the fourth configuration example are similar to the laminated lens structure 11 according to the first configuration example.

The laminated lens structure 11 relating to the fourth configuration example and the camera module 1 that uses the laminated lens structure 11 include the lens-attached laminated substrate 41d′ that uses the laminated carrier substrate 81d′, and exhibits an operational effect capable of using a lens that is thicker in comparison to the laminated lens structure 11 that does not include the laminated carrier substrate 81 and the lens-attached laminated substrate 41 and the camera module 1 that uses the laminated lens structure 11.

In addition, in the laminated lens structure 11 relating to the fourth configuration example, and the camera module 1 that uses the laminated lens structure 11, with regard to a lens that is not necessary to be thick, the thickness of the carrier substrate 81 is set to be thin by using the single-layer carrier substrate 81. Accordingly, it is possible to exhibit an operational effect capable of further lowering the height of the laminated lens structure 11 and the camera module 1 that uses the laminated lens structure 11 in comparison to the laminated lens structure 11 that uses the laminated carrier substrate 81 in the entirety of the lens-attached substrates 41, and the camera module 1 that uses the laminated lens structure 11.

As described above, according to the laminated lens structure 11 relating to the fourth configuration example, it is possible to provide a laminated lens structure capable of corresponding to various optical parameters.

<13. Fifth Configuration Example of Laminated Lens Structure 11>

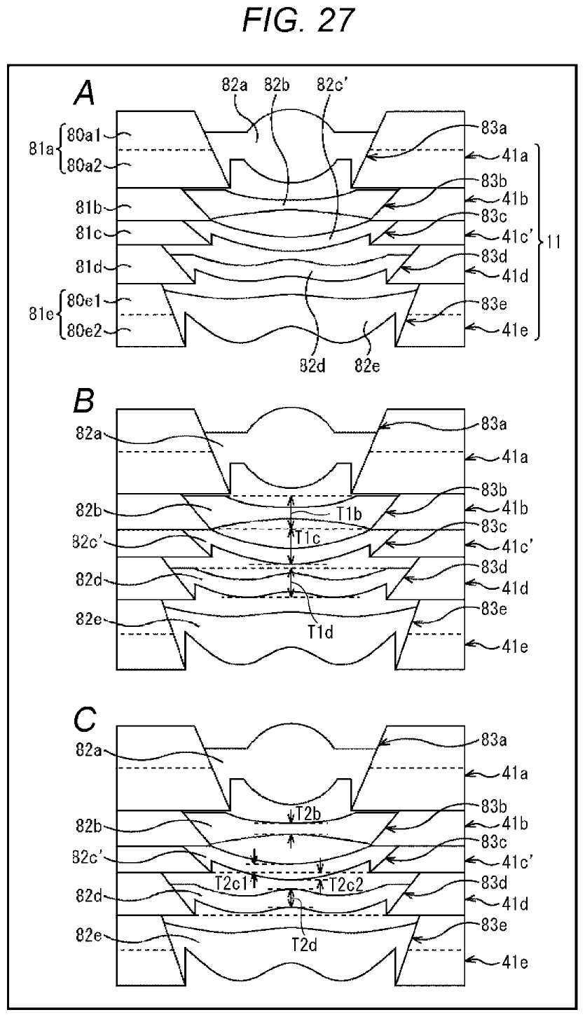

FIG. 27A is a cross-sectional view illustrating a fifth configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In addition, in the lens-attached substrates 41a to 41e, the thickness and the shape of the lens resin portions 82a to 82e are set to a thickness and a shape in which the lens resin portions 82a to 82e do not protrude from the upper surface and the lower surface of the corresponding carrier substrates 81a to 81e.

In contrast, in the laminated lens structure 11 relating to the fifth configuration example in FIG. 27A, among the five sheets of lens-attached substrates 41a to 41e which are laminated, the thickness and the shape of a lens resin portion 82c′ of a lens-attached substrate 41c′ in a third layer as one intermediate layer are set to a thickness and a shape in which the lens resin portion 82c′ protrudes from the lower surface of the corresponding carrier substrate 81c.

In other words, the lens resin portion 82c′ extends from an inner side of the lower surface of the carrier substrate 81c toward an outer side of the lower surface. As described above, a lens in which the lower surface of the lens resin portion 82c′ provided in the lens-attached substrate 41c′ further extends to a lower side in comparison to the lower surface of the carrier substrate 81c that carries the lens resin portion 82c′ is referred to as a protruding lens. In addition, the lens-attached substrate 41 including the protruding lens is referred to as a protruding lens-attached substrate 41.

Furthermore, the protruding lens represents a lens that includes any one extension structure among the following (a), (b), and (c). (Lens-attached substrates including one sheet of the second type of lens-attached substrate and including an extension structure are also referred to as third type of lens-attached substrate.)

(a) A lens in which the lower surface of the lens resin portion 82c′ provided in the lens-attached substrate 41c′ further extends to a lower side in comparison to the lower surface of the carrier substrate 81c that carries the lens resin portion 82c′.

(b) A lens in which the upper surface of the lens resin portion 82c′ provided in the lens-attached substrate 41c′ further extends to an upper side in comparison to the upper surface of the carrier substrate 81c that carries the lens resin portion 82c′.

(C) A lens in which the lens resin portion 82c′ provided in the lens-attached substrate 41c′ further extends in upper and lower directions in comparison to the thickness of the carrier substrate 81c.

The laminated lens structure 11 relating to the fifth configuration example has a structure in which a part of the lens resin portion 82c′ that protrudes from the protruding lens-attached substrate 41c′ is disposed in the through-hole 83 of the lens-attached substrate 41d that is disposed adjacently to the protruding lens-attached substrate 41c′, and the lens-attached substrate 41d that is adjacently disposed has a structure constituted by the lens-attached single-layer substrate 41 that uses the single-layer carrier substrate 81.

The laminated lens structure 11 relating to the fifth configuration example has a first characteristic in that among the five sheets of lens-attached substrates 41a to 41e which are laminated, the lens-attached substrate 41c′ as one intermediate layer is the protruding lens-attached substrate 41 that includes the protruding lens.

The laminated lens structure 11 relating to the fifth configuration example has a second characteristic in that the laminated lens structure 11 includes the protruding lens-attached substrate 41 (the former) and an additional lens-attached substrate 41 (the latter) that is disposed on a lower side of the protruding lens-attached substrate 41 to be adjacent thereto, and the lens resin portion 82 of the protruding lens provided in the former extends from the inside of the through-hole 83 of the former, and also exists in the through-hole 83 of the latter.

Hereinafter, in the structure including one sheet of the protruding lens-attached substrate 41 and another one sheet of the lens-attached substrate 41, a structure in which a part of the lens resin portion 82 provided in the protruding lens-attached substrate 41 on an upper side exists in the through-hole 83 provided in the lens-attached substrate 41 on a lower side is referred to as a structure in which the protruding lens on an upper side is received by the lens-attached substrate 41 on a lower side, or a structure in which the protruding lens-attached substrate 41 on an upper side is received by the lens-attached substrate 41 on a lower side.

The thickness T1 of the lens portion 91 of the lens resin portion 82c′ of the protruding lens-attached substrate 41c′ can be set to be larger than the thickness T1 of the lens portion 91 of the lens resin portion 82 of the other lens-attached single-layer substrate 41 using the single-layer carrier substrate 81 that does not include a protruding lens. Furthermore, definition of the thickness T1 of the lens portion 91 is the same as described above with reference to FIG. 4A to FIG. 5D.

Specifically, as illustrated in FIG. 27B, the thickness T1c of the lens portion 91 of the lens resin portion 82c′ of the protruding lens-attached substrate 41c′ can be set to be larger than any one or both of the thickness T1b and the thickness T1d of the lens portions 91 of the lens resin portions 82b and 82d of other lens-attached single-layer substrates 41b and 41d which use the single-layer carrier substrate 81 that does not include the protruding lens.

The laminated lens structure 11 relating to the fifth configuration example includes the above-described structure, and thus the sum of the thickness T2 of the lens resin portion 82 that exists in the through-hole 83 of the lens-attached substrate 41d in which a part of the lens resin portion 82c′ that protrudes from the protruding lens-attached substrate 41c′ is disposed can be larger than the thickness T2 of the lens resin portion 82 that exists in the through-hole 83 of another lens-attached single-layer substrate 41.

Detailed description will be given with reference to FIG. 27C. A part of the lens resin portion 82c′ that protrudes from the protruding lens-attached substrate 41c′, and the lens resin portion 82d provided in the lens-attached substrate 41d exist in the through-hole 83d of the lens-attached substrate 41d that becomes the protruding lens receiving side. In this structure, the thickness of the lens resin portion 82d that exists in the through-hole 83d becomes the sum (T2c2+T2d) of the thickness T2c2 of the lens resin portion 82c′ protruding from the lower surface of the protruding lens-attached substrate 41c′ and the thickness T2d of the lens resin portion 82d. The thickness of the lens resin portion 82d that exists in the through-hole 83d as defined above can be larger than any one or both of the thickness T2b and T2c1 of the lens resin portions 82 which exist in the through-holes 83 of other lens-attached single-layer substrates 41b and 41c.

The other structures of the fifth configuration example are similar to the laminated lens structure 11 according to the first configuration example.

As the shape of the lens resin portion 82c′ of the protruding lens-attached substrate 41, which is employed in the laminated lens structure 11 relating to the fifth configuration example, various shapes other than the shape illustrated in FIG. 27A to FIG. 27C can be employed.

According to the laminated lens structure 11 relating to the fifth configuration example, and the camera module 1 that uses the laminated lens structure 11, both of the protruding lens-attached substrate 41 and the lens-attached substrate 41 that receives the protruding lens-attached substrate 41 are provided. Accordingly, it is possible to exhibit an operational effect capable of using a thicker lens in the laminated lens structure 11 with the same height and the camera module 1 with the same height in comparison to the laminated lens structure 11 (for example, the laminated lens structure 11 relating to the first configuration example) that does not include the above-described structure and the camera module 1 that uses the laminated lens structure 11.

Typically, as a diameter of a lens is enlarged, it is necessary to make the thickness of the lens be larger. According to the laminated lens structure 11 relating to the fifth configuration example and the camera module 1 that uses the laminated lens structure 11, it is possible to use a thicker lens in the laminated lens structure 11 with the same height and the camera module 1 with the same height in comparison to the laminated lens structure 11 that does not include the above-described structure and the camera module 1 that uses the laminated lens structure 11. Accordingly, it is possible to exhibit an operational effect capable of using a lens having a larger diameter.

Alternatively, the laminated lens structure 11 relating to the fifth configuration example and the camera module 1 that uses the laminated lens structure 11 exhibit an operational effect capable of disposing a lens, which is provided in the camera module 1, at a distance closer to a lens that is adjacent to the lens on a lower side in comparison to the laminated lens structure 11 that does not include the above-described structure and the camera module 1 that uses the laminated lens structure 11. For example, as described in FIG. 2 of PTL 1 that is presented as the citation list. It is possible to exhibit an operational effect capable of realizing a lens arrangement in which a lens that is greatly curved on a convexity is closed to an adjacent lens even in the laminated lens structure 11 in which the lens resin portion 82 is formed in the through-hole 83 formed in the carrier substrate 81.

As described above, according to the laminated lens structure 11 according to the present disclosure, it is possible to provide a laminated lens structure capable of corresponding to various optical parameters.

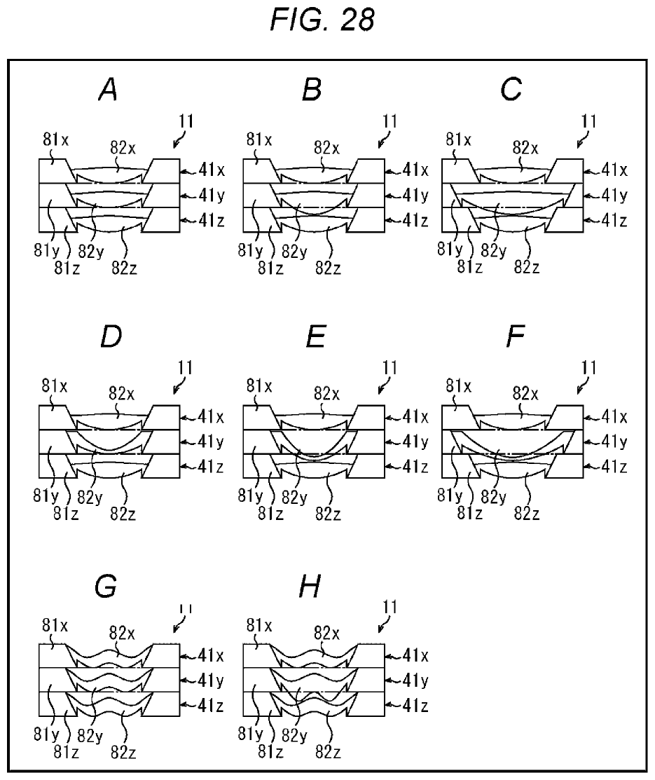

Description will be given of the shape of the lens resin portion 82c′ of the protruding lens-attached substrate 41 and an operational effect that is exhibited due to the shape with reference to FIG. 28A to FIG. 28H.

Furthermore, in FIG. 28A to FIG. 28H, description will be made by using a laminated lens structure 11 having a laminated structure of three sheets of lens-attached substrates 41x to 41z for simple comparison.

Laminated lens structures 11 at an upper stage in FIG. 28A to FIG. 28H (FIG. 28A to FIG. 28C) have a structure in which the lens-attached substrate 41y as an intermediate layer includes a lens resin portion 82y of which both surfaces have a convex surface shape.

Among the three laminated lens structures 11 at the upper stage in FIG. 28A to FIG. 28H, the laminated lens structure 11, which is disposed on a left side, in FIG. 28A is an example of the lens-attached substrate 41 in which the lens-attached substrate 41y as an intermediate layer does not include a protruding lens. The laminated lens structures 11, which are disposed at the center and on a right side, in FIG. 28B and FIG. 28C indicate an example in which the lens-attached substrate 41y as an intermediate layer in FIG. 28A is changed to the protruding lens-attached substrate 41.

Laminated lens structures 11 at an intermediate stage in FIG. 28A to FIG. 28H (FIG. 28D to FIG. 28F) have a structure in which the lens-attached substrate 41y as an intermediate layer includes a lens resin portion 82y of which one surface has a convex surface shape and the other surface has a concave surface shape.

Among the three laminated lens structures 11 at the intermediate stage in FIG. 28A to FIG. 28H, the laminated lens structure 11, which is disposed on a left side, in FIG. 28D is an example of the lens-attached substrate 41 in which the lens-attached substrate 41y as an intermediate layer does not include a protruding lens. The laminated lens structures 11, which are disposed at the center and on a right side, in FIG. 28E and FIG. 28F indicate an example in which the lens-attached substrate 41y as an intermediate layer in FIG. 28D is changed to the protruding lens-attached substrate 41.

Laminated lens structures 11 at a lower stage in FIG. 28A to FIG. 28H (FIG. 28G and FIG. 28H) have a structure in which the intermediate lens-attached substrate 41y includes an aspheric lens resin portion 82y.

In the two laminated lens structures 11 at the lower stage in FIG. 28A to FIG. 28H, the laminated lens structure 11, which is disposed on a left side, in FIG. 28G is an example of the lens-attached substrate 41 in which the lens-attached substrate 41y as an intermediate layer does not include a protruding lens. The laminated lens structure 11, which is disposed at the center, in FIG. 28H is an example in which the lens-attached substrate 41y as an intermediate layer in FIG. 28G is changed to the protruding lens-attached substrate 41.

As can be seen from comparison between the lens resin portions 82y illustrated in FIG. 28A and FIG. 28B, between the lens resin portions 82y illustrated in FIG. 28D and FIG. 28E, or between the lens resin portions 82y in FIG. 28G and FIG. 28H, in the laminated lens structure 11 that uses the protruding lens-attached substrate 41 in at least one sheet among a plurality of sheets of the lens-attached substrates 41, it is possible to enlarge the thickness T1 of the lens portion 91 (FIG. 4A to FIG. 4D, FIG. 5A to FIG. 5D), it is possible to enlarge the thickness T2 of the lens resin portion 82 (FIG. 4A to FIG. 4D, FIG. 5A to FIG. 5D), or it is possible to enlarge a curvature of the lens portion 91 in comparison to a case where the protruding lens-attached substrate 41 is not used.

In addition, as can be seen from comparison between the lens resin portions 82y illustrated in FIG. 28A and FIG. 28C, or between the lens resin portions 82y illustrated in FIG. 28D and FIG. 28F, in the laminated lens structure 11 that uses protruding lens-attached substrate 41 in at least one sheet among a plurality of sheets of the lens-attached substrates 41, it is possible to enlarge a radius of curvature of the lens portion 91 without changing the thickness of the carrier substrate 81y provided in the lens-attached substrate 41 and the curvature of the lens portion 91 in comparison to a case where the protruding lens-attached substrate 41 is not used.

In addition, it is possible to reduce a lens interval between the lens-attached substrates 41 adjacent to each other, and thus it is possible to reduce the size of the camera module 1 in a height direction.

In addition, as can be seen from comparison between the laminated lens structures 11 in FIG. 28D and FIG. 28E, when reducing an interval between the lens resin portions 82 adjacent to each other, it is possible to exhibit a primary operational effect capable of enlarging the curvature of the lens portion 91. In addition, a lens with a large curvature can be used. Accordingly, it is possible to exhibit a secondary operational effect in which a possibility capable of reducing the size of, for example, the camera module 1 in a height direction increases.

<14. Sixth Configuration Example of Laminated lens Structure 11>

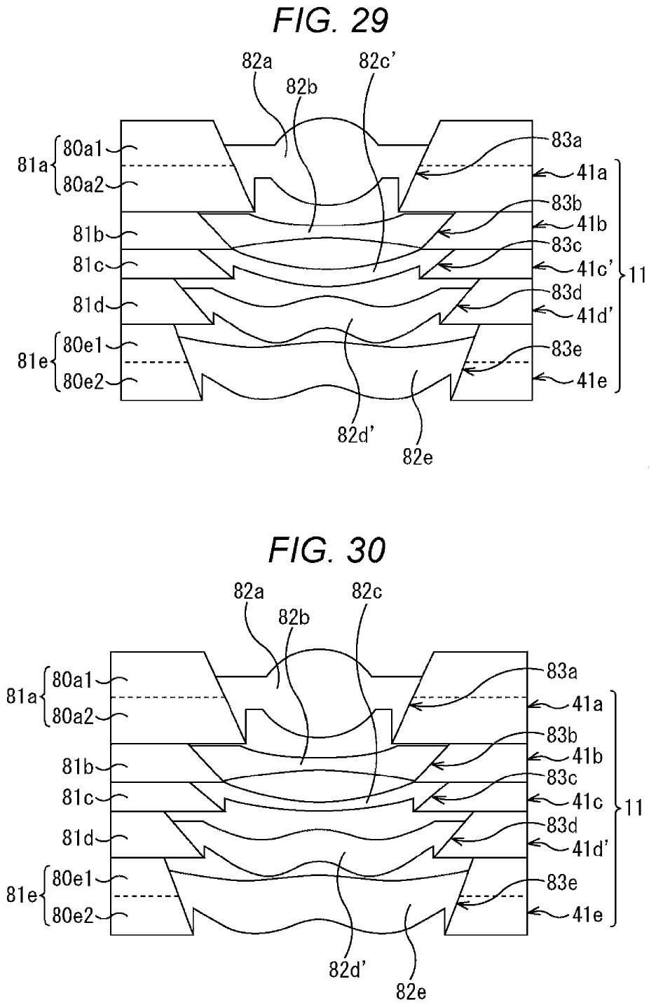

FIG. 29 is a cross-sectional view illustrating a sixth configuration example of the laminated lens structure 11.

In the laminated lens structure 11 relating to the first configuration example illustrated in FIG. 2, each of the five sheets of lens-attached substrates 41a to 41e which are laminated is constituted by the lens-attached substrate 41 that does not include a protruding lens.

In contrast, in the laminated lens structure 11 relating to the sixth configuration example in FIG. 29, among the five sheets of lens-attached substrates 41a to 41e which are laminated, two sheets of lens-attached substrates 41c′ and 41d′ as intermediate layers are constituted by a protruding lens-attached substrate 41. More specifically, the lens-attached substrate 41c′ includes a lens resin portion 82c′ that is a protruding lens in the single-layer carrier substrate 81c. The lens-attached substrate 41d′ includes a lens resin portion 82d′ that is a protruding lens in the single-layer carrier substrate 81d. In addition, a part of the lens resin portion 82c′, which protrudes from the protruding lens-attached substrate 41c′, is disposed in the through-hole 83d of the lens-attached laminated substrate 41d that is disposed adjacently to the protruding lens-attached substrate 41c′.

The other structures of the sixth configuration example are similar to the laminated lens structure 11 relating to the first configuration example.

Accordingly, the laminated lens structure 11 in FIG. 29 has a structure in which the protruding lens-attached substrate 41c′ including the protruding lens in the single-layer carrier substrate 81c is received by the protruding lens-attached substrate 41d′ including the protruding lens in the single-layer carrier substrate 81d.

With regard to a structure in which the lens resin portion 82c′, which protrudes from the protruding lens-attached substrate 41c′, disposed on an upper side is received by the lens-attached substrate 41d′ that is disposed on a lower side, in FIG. 27A to FIG. 27C relating to the fifth configuration example, a structure in which the lens resin portion 82c′ protruding from the protruding lens-attached substrate 41c′ is received by the lens-attached single-layer substrate 41d is exemplified. In contrast, in the sixth configuration example illustrated in FIG. 29, the lens resin portion 82c′ protruding from the protruding lens-attached substrate 41c′ is received by the protruding lens-attached single-layer substrate 41d′.

As in the sixth configuration example, when the lens-attached substrate 41d′ that becomes a protruding lens receiving side includes the protruding lens, it is possible to dispose a lens provided in the lens-attached substrate 41d′ on a further downward side in comparison to the laminated lens structure 11 that does not include this structure, for example, the laminated lens structure 11 relating to the fifth configuration example. When the lens provided in the lens-attached substrate 41d′ that becomes the protruding lens receiving side can be disposed on a further downward side, the lens resin portion 82c′ provided in the lens-attached substrate 41c′ on a protruding side, which is disposed on an upper side, can further greatly protrude. In other words, the thickness T1 of the lens portion 91 of the lens resin portion 82c′, which is provided in the lens-attached substrate 41c′ on the protruding side, can be further enlarged.

As described above, the laminated lens structure 11 relating to the sixth configuration example and the camera module 1 that uses the laminated lens structure 11 include the protruding lens as in the fifth configuration example, and the lens-attached substrate 41d′ that becomes the protruding lens receiving side also includes the protruding lens. Accordingly, it is possible to further exhibit the operational effect that is exhibited in the laminated lens structure 11 relating to the fifth configuration example and the camera module 1 that uses the laminated lens structure 11.

Furthermore, in the sixth configuration example illustrated in FIG. 29, when comparing a case where an upper surface shape (surface shape on the protruding lens-attached substrate 41c′ side) of the lens, which is provided in the lens-attached substrate 41d′ that becomes the protruding lens receiving side, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the sixth configuration example and the camera module 1 that uses the laminated lens structure 11 is further enhanced in a case where the upper surface shape (surface shape on the protruding lens-attached substrate 41c′ side) of the lens, which is provided in the lens-attached substrate 41d′ that becomes the protruding lens receiving side, is a concave lens or an aspheric lens in comparison to a case where the upper surface shape is a convex lens.

<15. Seventh Configuration Example of Laminated Lens Structure 11>

FIG. 30 is a cross-sectional view illustrating a seventh configuration example of the laminated lens structure 11.

In the laminated lens structure 11 relating to the first configuration example illustrated in FIG. 2, each of the five sheets of lens-attached substrates 41a to 41e which are laminated is constituted by the lens-attached substrate 41 that does not include a protruding lens.

In contrast, in the laminated lens structure 11 relating to the seventh configuration example in FIG. 30, among the five sheets of lens-attached substrates 41a to 41e which are laminated, a lens-attached substrate 41d′ in a fourth layer is constituted by a protruding lens-attached substrate 41. In addition, a part of a lens resin portion 82d′, which protrudes from the protruding lens-attached substrate 41d′, is disposed in the through-hole 83e of the lens-attached laminated substrate 41e in the lowermost layer which is disposed adjacently to the protruding lens-attached substrate 41d′.

The other structures of the seventh configuration example are similar to the laminated lens structure 11 relating to the first configuration example.

Accordingly, the laminated lens structure 11 in FIG. 30 has a structure in which the protruding lens-attached substrate 41d′ in the fourth layer, which includes the protruding lens in the single-layer carrier substrate 81d, is received by the lens-attached substrate 41e in the lowermost layer which uses the laminated carrier substrate 81e.

A configuration, in which the thickness T1 of the lens portion 91 of the lens resin portion 82d′ of the protruding lens-attached substrate 41d′ is larger than the thickness T1 of the lens portion 91 of the lens resin portion 82 of other lens-attached single-layer substrates 41b and 41c using the single-layer carrier substrate 81 that does not include a protruding lens, is similar to FIG. 27A to FIG. 27C.

As described with reference to FIG. 3 as the operational effect exhibited by the laminated lens structure 11 of the first configuration example, among the plurality of sheets of lens-attached substrates 41 provided in the laminated lens structure 11, it is preferable that the lens-attached substrate 41e in the lowermost layer includes the carrier substrate 81 having a larger thickness. When the lens-attached substrate 41e in the lowermost layer includes the carrier substrate 81 having a larger thickness, the depth of the through-hole 83 formed therein becomes also deeper.

With regard to a structure in which the lens resin portion 82 protruding from the protruding lens-attached substrate 41 that is disposed on an upper side is received by the lens-attached substrate 41 that is disposed on a lower side, when comparing the seventh configuration example in FIG. 30 in which the lens-attached substrate 41 that becomes a lens receiving side is the lens-attached substrate 41e in the lowermost layer, and the fifth configuration example in FIG. 27A to FIG. 27C in which the lens receiving side is the lens-attached substrate 41 in a layer other than the lowermost layer (specifically, the lens-attached substrate 41c′ in a third layer), in the seventh configuration example in which a protruding lens receiving substrate is the lens-attached substrate 41e in the lowermost layer which includes a deep through-hole 83, it is possible to exhibit an operational effect capable of further enlarging the size of the lens resin portion 82 that protrudes from the protruding lens-attached substrate 41 disposed on an upper side in comparison to the fifth configuration example in which the protruding lens receiving substrate is the lens-attached substrate 41 including a shallow through-hole 83 in a layer other than the lowermost layer.

As described above, the laminated lens structure 11 relating to the seventh configuration example and the camera module 1 that uses the laminated lens structure 11 include the protruding lens as in the fifth configuration example, and the protruding lens is received by the lens-attached substrate 41e in the lowermost layer. Accordingly, it is possible to further enhance the operational effect exhibited by the laminated lens structure 11 relating to the fifth configuration example and the camera module 1 that uses the laminated lens structure 11.

Furthermore, in the seventh configuration example illustrated in FIG. 30, when comparing a case where an upper surface shape (surface shape on the protruding lens-attached substrate 41d′ side) of the lens, which is provided in the lens-attached substrate 41e in the lowermost layer, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the seventh configuration example and the camera module 1 that uses the laminated lens structure 11 is further enhanced in a case where the upper surface shape (surface shape on the protruding lens-attached substrate 41d′ side) of the lens, which is provided in the lens-attached substrate 41e in the lowermost layer, is a concave lens or an aspheric lens in comparison to a case where the upper surface shape is a convex lens.

<16. Eighth Configuration Example of Laminated Lens Structure 11>

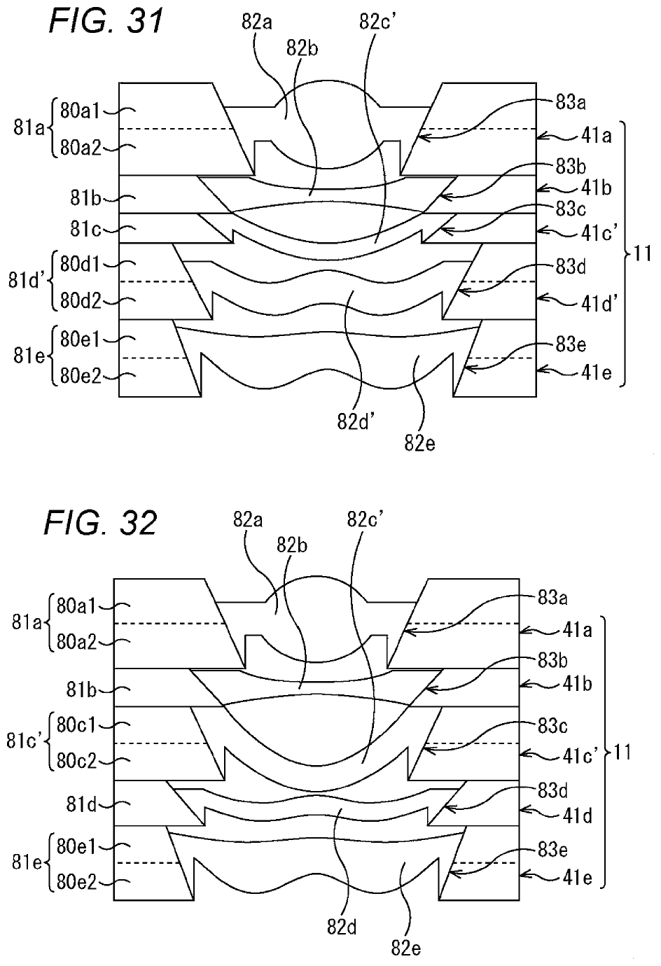

FIG. 31 is a cross-sectional view illustrating an eighth configuration example of the laminated lens structure 11.

In the laminated lens structure 11 relating to the first configuration example illustrated in FIG. 2, among five sheets of the lens-attached substrates 41a to 41e which are laminated, the lens-attached substrate 41a in the uppermost layer, and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the eighth configuration example in FIG. 31, among the five sheets of lens-attached substrates 41a to 41e which are laminated, a lens-attached substrate 41c′ in a third layer is constituted by a protruding lens-attached substrate 41. That is, a part of a lens resin portion 82c′ of the lens-attached substrate 41c′ is disposed in the through-hole 83d of a lens-attached laminated substrate 41d′ that is disposed adjacently to the lens-attached substrate 41c′. In addition, the lens-attached substrate 41d′ in a fourth layer is constituted by the lens-attached laminated substrate 41 that uses a laminated carrier substrate 81d′.

The other structures of the eighth configuration example are similar to the laminated lens structure 11 relating to the first configuration example.

Accordingly, the laminated lens structure 11 in FIG. 31 has a structure in which the protruding lens-attached substrate 41c′ in a third layer which includes a protruding lens in the single-layer carrier substrate 81c is received by the lens-attached substrate 41d′ in a fourth layer which uses the laminated carrier substrate 81d′.

As described with reference to FIG. 2 as the first configuration example, in the laminated lens structure 11, with regard to the thickness of the carrier substrate 81, the laminated carrier substrate 81 provided in the lens-attached laminated substrate 41 can have a thickness larger than that of the single-layer carrier substrate 81 provided in the lens-attached single-layer substrate 41. In addition, the depth of the through-hole 83 provided in the carrier substrate 81 can be made to be deeper.

With regard to a structure in which the lens resin portion 82 protruding from the protruding lens-attached substrate 41 that is disposed on an upper side is received by the lens-attached substrate 41 that is disposed on a lower side, when comparing the eighth configuration example in which the lens-attached substrate 41 that becomes a lens receiving side is the lens-attached laminated substrate 41 (41c′) in FIG. 31, and the fifth configuration example in which the lens receiving side is the lens-attached single-layer substrate 41 (41c′) in FIG. 27A to FIG. 27C, in the eighth configuration example in which the protruding lens receiving substrate is the lens-attached laminated substrate 41 including a deep through-hole 83, it is possible to exhibit an operational effect capable of further enlarging the size of the lens resin portion 82 that protrudes from the protruding lens-attached substrate 41 disposed on an upper side in comparison to the fifth configuration example in which the protruding lens receiving substrate is the lens-attached single-layer substrate 41 including a shallow through-hole 83.

As described above, the laminated lens structure 11 relating to the eighth configuration example and the camera module 1 that uses the laminated lens structure 11 include the protruding lens as in the fifth configuration example, and the protruding lens is received by the lens-attached laminated substrate 41. Accordingly, it is possible to further enhance the operational effect exhibited by the laminated lens structure 11 relating to the fifth configuration example and the camera module 1 that uses the laminated lens structure 11.

Furthermore, in the eighth configuration example illustrated in FIG. 31, when comparing a case where an upper surface shape (surface shape on the protruding lens-attached substrate 41c′ side) of the lens, which is provided in the lens-attached substrate 41d′ that becomes a lens receiving side, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the eighth configuration example and the camera module 1 that uses the laminated lens structure 11 is further enhanced in a case where the upper surface shape (surface shape on the protruding lens-attached substrate 41c′ side) of the lens, which is provided in the lens-attached laminated substrate 41d′ that becomes a lens receiving side, is a concave lens or an aspheric lens in comparison to a case where the upper surface shape is a convex lens.

<17. Ninth Configuration Example of Laminated Lens Structure 11>

FIG. 32 is a cross-sectional view illustrating a ninth configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the ninth configuration example in FIG. 32, among the five sheets of lens-attached substrates 41a to 41e which are laminated, a lens-attached substrate 41c′ in a third layer is constituted by a protruding lens-attached substrate 41 and a lens-attached laminated substrate 41 that uses a laminated carrier substrate 81c′. In addition, a part of a lens resin portion 82c′ that protrudes from the protruding lens-attached laminated substrate 41c′ is disposed in the through-hole 83d of the lens-attached laminated substrate 41d that is disposed adjacently to the protruding lens-attached laminated substrate 41c′. The laminated carrier substrate 81c′ is constituted by bonding two sheets of carrier configuration substrates 80c1 and 80c2.

The other structures of the ninth configuration example are similar to the laminated lens structure 11 relating to the first configuration example.

Accordingly, the laminated lens structure 11 in FIG. 32 has a structure in which the protruding lens-attached substrate 41c′ in a third layer, which includes a protruding lens in the laminated carrier substrate 81c′, is received by the lens-attached substrate 41d in a fourth layer which uses the single-layer carrier substrate 81d that does not include a protruding lens.

As described with reference to FIG. 2 as the first configuration example, in the laminated lens structure 11, with regard to the thickness of the carrier substrate 81, the laminated carrier substrate 81 provided in the lens-attached laminated substrate 41 can have a thickness larger than that of the single-layer carrier substrate 81 provided in the lens-attached single-layer substrate 41.

With regard to a structure in which the lens resin portion 82 protruding from the protruding lens-attached substrate 41 that is disposed on an upper side is received by the lens-attached substrate 41 that is disposed on a lower side, when comparing the ninth configuration example in which the lens-attached substrate 41 that becomes a lens protruding side is the lens-attached laminated substrate 41 (41c′) in FIG. 32, and the fifth configuration example in which the lens protruding side is the lens-attached single-layer substrate 41 (41c′) in FIG. 27A to FIG. 27C, in the ninth configuration example in which the lens-attached substrate 41 that becomes the lens protruding side includes the laminated carrier substrate 81, it is possible to exhibit an operational effect capable of making the thickness T1 of the lens portion 91 provided in the protruding lens-attached substrate 41 be larger in comparison to the fifth configuration example in which the lens-attached substrate 41 includes the single-layer carrier substrate 81 having a smaller thickness.

As described above, the laminated lens structure 11 relating to the ninth configuration example and the camera module 1 that uses the laminated lens structure 11 include the protruding lens as in the fifth configuration example, and the lens-attached substrate 41 that becomes a lens protruding side includes the laminated carrier substrate 81. Accordingly, it is possible to further enhance the operational effect exhibited by the laminated lens structure 11 relating to the fifth configuration example and the camera module 1 that uses the laminated lens structure 11.

Furthermore, in the ninth configuration example illustrated in FIG. 32, when comparing a case where an upper surface shape (surface shape on the protruding lens-attached substrate 41c′ side) of the lens, which is provided in the lens-attached substrate 41d that becomes a lens receiving side, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the ninth configuration example and the camera module 1 that uses the laminated lens structure 11 is further enhanced in a case where the upper surface shape (surface shape on the protruding lens-attached substrate 41c′ side) of the lens, which is provided in the lens-attached laminated substrate 41d that becomes a lens receiving side, is a concave lens or an aspheric lens in comparison to a case where the upper surface shape is a convex lens.

<18. Tenth Configuration Example of Laminated Lens Structure 11>

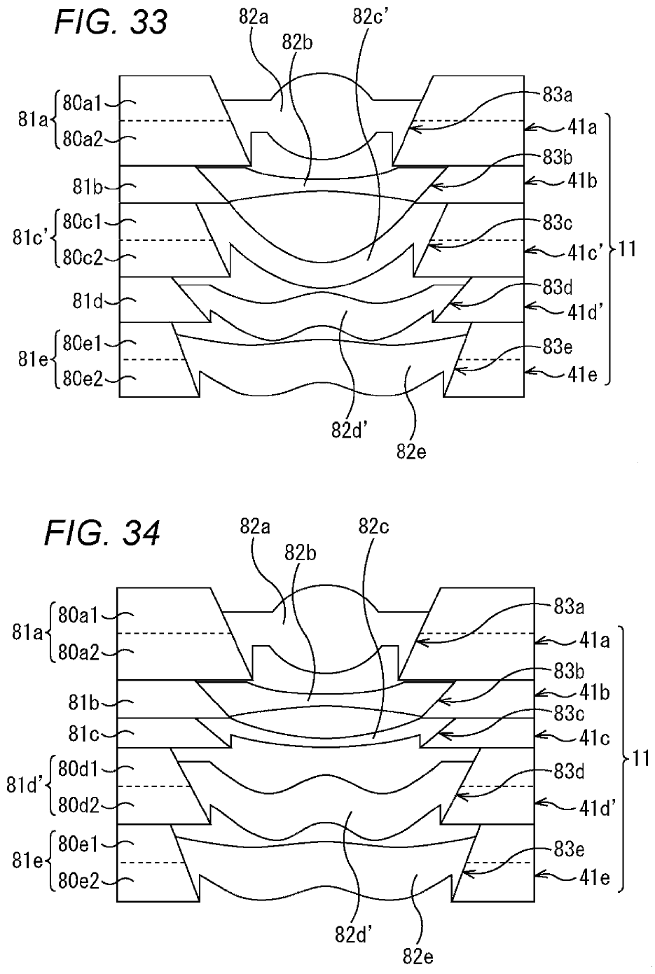

FIG. 33 is a cross-sectional view illustrating a tenth configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the tenth configuration example in FIG. 33, among the five sheets of lens-attached substrates 41a to 41e which are laminated, a lens-attached substrate 41c′ in a third layer is constituted by a protruding lens-attached substrate 41 and a lens-attached laminated substrate 41 that uses a laminated carrier substrate 81c′. In addition, a lens-attached substrate 41d′ in a fourth layer is constituted by a protruding lens-attached substrate 41 that uses a protruding lens. In addition, a part of a lens resin portion 82c′ that protrudes from the protruding lens-attached substrate 41c′ is disposed in the through-hole 83d of the lens-attached laminated substrate 41d′ that is disposed adjacently to the protruding lens-attached substrate 41c′.

The other structures of the tenth configuration example are similar to the laminated lens structure 11 relating to the first configuration example.

Accordingly, the laminated lens structure 11 in FIG. 33 has a structure in which the protruding lens-attached substrate 41c′ in a third layer, which includes a protruding lens in the laminated carrier substrate 81c′, is received by the protruding lens-attached substrate 41d′ in a fourth layer which uses the single-layer carrier substrate 81d.

With regard to a structure in which the lens resin portion 82c′ that protrudes from the protruding lens-attached substrate 41c′ that is disposed on an upper side is received by the lens-attached substrate 41d′ that is disposed on a lower side, in FIG. 32 relating to the ninth configuration example, a structure, in which the lens resin portion 82c′ protruding from the protruding lens-attached substrate 41c′ is received by the lens-attached single-layer substrate 41d, is exemplified. In contrast, the tenth configuration example illustrated in FIG. 33 has a structure in which the lens resin portion 82c′ protruding from the protruding lens-attached substrate 41c′ is received by the protruding lens-attached single-layer substrate 41d′.

As in the tenth configuration example, when the lens-attached substrate 41d′ that becomes a protruding lens receiving side also includes a protruding lens, it is possible to dispose a lens provided in the lens-attached substrate 41d′ on a further downward side in comparison to the laminated lens structure 11 that does not include this structure, for example, in comparison to the laminated lens structure 11 relating to the ninth configuration example. When the lens provided in the lens-attached substrate 41d′ that becomes the protruding lens receiving side can be disposed on a further downward side, the lens resin portion 82c′ provided in the lens-attached substrate 41c′ on a protruding side, which is disposed on an upper side, can further greatly protrude. In other words, the thickness T1 of the lens portion 91 of the lens resin portion 82c′, which is provided in the lens-attached substrate 41c′ on the protruding side, can be further enlarged.

As described above, the laminated lens structure 11 relating to the tenth configuration example and the camera module 1 that uses the laminated lens structure 11 include the protruding lens and the laminated carrier substrate 81 as in the ninth configuration example, and the lens-attached substrate 41d′ that becomes the protruding lens receiving side also includes the protruding lens. Accordingly, it is possible to further exhibit the operational effect that is exhibited in the laminated lens structure 11 relating to the ninth configuration example and the camera module 1 that uses the laminated lens structure 11.

Furthermore, in the tenth configuration example illustrated in FIG. 33, when comparing a case where an upper surface shape (surface shape on the protruding lens-attached substrate 41c′ side) of the lens, which is provided in the lens-attached substrate 41d′ that becomes a protruding lens receiving side, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the tenth configuration example and the camera module 1 that uses the laminated lens structure 11 is further enhanced in a case where the upper surface shape (surface shape on the protruding lens-attached substrate 41c′ side) of the lens, which is provided in the lens-attached substrate 41d′ that becomes a protruding lens receiving side, is a concave lens or an aspheric lens in comparison to a case where the upper surface shape is a convex lens.

<19. Eleventh Configuration Example of Laminated Lens Structure 11>

FIG. 34 is a cross-sectional view illustrating an eleventh configuration example of the laminated lens structure 11.

In the laminated lens structure 11 relating to the first configuration example illustrated in FIG. 2, among the five sheets of lens-attached substrates 41a to 41e which are laminated, the lens-attached substrate 41a in the uppermost layer and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the eleventh configuration example in FIG. 34, among the five sheets of lens-attached substrates 41a to 41e which are laminated, a lens-attached substrate 41d′ in a fourth layer is constituted by the protruding lens-attached substrate 41 and the lens-attached laminated substrate 41d that uses a laminated carrier substrate 81d′. In addition, a part of a lens resin portion 82d′ that protrudes from the protruding lens-attached substrate 41d′ is disposed in the through-hole 83e of the lens-attached laminated substrate 41e that is disposed adjacently to the protruding lens-attached substrate 41d′ in the lowermost layer.

The other structures of the eleventh configuration example are similar to the laminated lens structure 11 relating to the first configuration example.

Accordingly, the laminated lens structure 11 in FIG. 34 has a structure in which the protruding lens-attached substrate 41d′, in the fourth layer which includes a protruding lens in the laminated carrier substrate 81d′, is received by the lens-attached substrate 41e in the lowermost layer which uses the laminated carrier substrate 81e.

As described with reference to FIG. 3 as the operational effect exhibited by the laminated lens structure 11 of the first configuration example, among the plurality of sheets of lens-attached substrates 41 provided in the laminated lens structure 11, it is preferable that the lens-attached substrate 41e in the lowermost layer includes the carrier substrate 81 having a larger thickness. When the lens-attached substrate 41e in the lowermost layer includes the carrier substrate 81 having a larger thickness, the depth of the through-hole 83 formed therein becomes also deeper.

With regard to a structure in which the lens resin portion 82 protruding from the protruding lens-attached substrate 41 that is disposed on an upper side is received by the lens-attached substrate 41 that is disposed on a lower side, when comparing the eleventh configuration example in FIG. 34 in which the lens-attached substrate 41 that becomes a lens receiving side is the lens-attached substrate 41e in the lowermost layer, and the ninth configuration example in FIG. 32 in which the lens receiving side is the lens-attached substrate 41 (41d) in a layer other than the lowermost layer, in the eleventh configuration example in which a protruding lens receiving substrate is the lens-attached substrate 41e in the lowermost layer which includes a deep through-hole 83, it is possible to exhibit an operational effect capable of further enlarging the size of the lens resin portion 82 that protrudes from the protruding lens-attached substrate 41 disposed on an upper side in comparison to the ninth configuration example in which the protruding lens receiving substrate is the lens-attached substrate 41 including a shallow through-hole 83 in a layer other than the lowermost layer.

As described above, the laminated lens structure 11 relating to the eleventh configuration example and the camera module 1 that uses the laminated lens structure 11 include the protruding lens and the laminated carrier substrate 81 as in the ninth configuration example, and the protruding lens is received by the lens-attached substrate 41e in the lowermost layer. Accordingly, it is possible to further enhance the operational effect exhibited by the laminated lens structure 11 relating to the ninth configuration example and the camera module 1 that uses the laminated lens structure 11.

Furthermore, in the eleventh configuration example illustrated in FIG. 34, when comparing a case where an upper surface shape (surface shape on the protruding lens-attached substrate 41d′ side) of the lens, which is provided in the lens-attached substrate 41e in the lowermost layer, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the eleventh configuration example and the camera module 1 that uses the laminated lens structure 11 is further enhanced in a case where the upper surface shape (surface shape on the protruding lens-attached substrate 41d′ side) of the lens, which is provided in the lens-attached substrate 41e in the lowermost layer, is a concave lens or an aspheric lens in comparison to a case where the upper surface shape is a convex lens.

<20. Twelfth Configuration Example of Laminated Lens Structure 11>

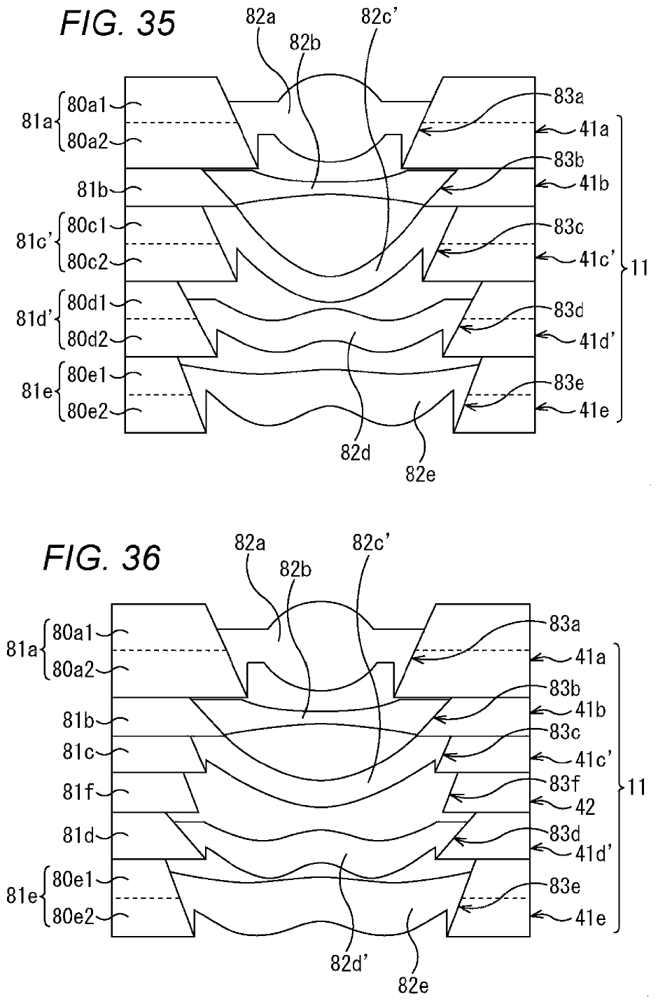

FIG. 35 is a cross-sectional view illustrating a twelfth configuration example of the laminated lens structure 11.

In the laminated lens structure 11 relating to the first configuration example illustrated in FIG. 2, among five sheets of the lens-attached substrates 41a to 41e which are laminated, the lens-attached substrate 41a in the uppermost layer, and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the twelfth configuration example in FIG. 35, among the five sheets of lens-attached substrates 41a to 41e which are laminated, a lens-attached substrate 41c′ in a third layer is constituted by a protruding lens-attached substrate 41 and a lens-attached laminated substrate 41 that uses a laminated carrier substrate 81c′. In addition, a lens-attached substrate 41d′ in a fourth layer is constituted by a lens-attached laminated substrate 41 that uses a laminated carrier substrate 81d′. In addition, a part of a lens resin portion 82c′ that protrudes from the protruding lens-attached substrate 41c′ is disposed in the through-hole 83d of the lens-attached laminated substrate 41d′ that is disposed adjacently to the protruding lens-attached substrate 41c′.

The other structures of the twelfth configuration example are similar to the laminated lens structure 11 relating to the first configuration example.

Accordingly, the laminated lens structure 11 in FIG. 35 has a structure in which the protruding lens-attached substrate 41c′ in a third layer, which includes a protruding lens in the laminated carrier substrate 81c′, is received by the lens-attached laminated substrate 41d′ in a fourth layer which uses the laminated carrier substrate 81d′.

As described with reference to FIG. 2 as the first configuration example, in the laminated lens structure 11, with regard to the thickness of the carrier substrate 81, the laminated carrier substrate 81 provided in the lens-attached laminated substrate 41 can have a thickness larger than that of the single-layer carrier substrate 81 provided in the lens-attached single-layer substrate 41. In addition, the depth of the through-hole 83 provided in the carrier substrate 81 can be made to be deeper.

With regard to a structure in which the lens resin portion 82 protruding from the protruding lens-attached substrate 41 that is disposed on an upper side is received by the lens-attached substrate 41 that is disposed on a lower side, when comparing the twelfth configuration example in FIG. 35 in which the lens-attached substrate 41 that becomes a lens receiving side is the lens-attached laminated substrate 41d′, and the ninth configuration example in FIG. 32 in which the lens receiving side is the lens-attached single-layer substrate 41d, in the twelfth configuration example in which the protruding lens receiving substrate is the lens-attached laminated substrate 41 that includes a deep through-hole 83, it is possible to exhibit an operational effect capable of further enlarging the size of the lens resin portion 82 that protrudes from the protruding lens-attached substrate 41 disposed on an upper side in comparison to the ninth configuration example in which the protruding lens receiving substrate is the lens-attached single-layer substrate 41 that includes a shallow through-hole 83.

As described above, the laminated lens structure 11 relating to the twelfth configuration example and the camera module 1 that uses the laminated lens structure 11 include the protruding lens and the laminated carrier substrate 81 as in the ninth configuration example, and the protruding lens is received by the lens-attached laminated substrate 41. Accordingly, it is possible to further enhance the operational effect exhibited by the laminated lens structure 11 relating to the ninth configuration example and the camera module 1 that uses the laminated lens structure 11.

Furthermore, in the twelfth configuration example illustrated in FIG. 35, when comparing a case where an upper surface shape (surface shape on the protruding lens-attached substrate 41c′ side) of the lens, which is provided in the lens-attached laminated substrate 41d that becomes a lens receiving side, is a convex lens, and a case where the upper surface shape is a concave lens or an aspheric lens, in the latter case, it is possible to downwardly dispose an upper end of the lens.

Accordingly, the operational effect exhibited by the laminated lens structure 11 relating to the twelfth configuration example and the camera module 1 that uses the laminated lens structure 11 is further enhanced in a case where the upper surface shape (surface shape on the protruding lens-attached substrate 41c′ side) of the lens, which is provided in the lens-attached laminated substrate 41d that becomes a lens receiving side, is a concave lens or an aspheric lens in comparison to a case where the upper surface shape is a convex lens.

<21. Thirteenth Configuration Example of Laminated Lens Structure 11>

FIG. 36 is a cross-sectional view illustrating a thirteenth configuration example of the laminated lens structure 11.

In the laminated lens structure 11 relating to the first configuration example illustrated in FIG. 2, among five sheets of the lens-attached substrates 41a to 41e which are laminated, the lens-attached substrate 41a in the uppermost layer, and the lens-attached substrate 41e in the lowermost layer are constituted by the lens-attached laminated substrate 41 that uses the laminated carrier substrate 81.

In addition, in the laminated lens structure 11 relating to the first configuration example, each of the five sheets of lens-attached substrates 41a to 41e which are laminated is constituted by the lens-attached substrate 41 that does not include a protruding lens.

In contrast, in the laminated lens structure 11 relating to the thirteenth configuration example in FIG. 36, among the five sheets of lens-attached substrates 41a to 41e which are laminated, a lens-attached substrate 41c′ in a third layer is constituted by the protruding lens-attached substrate 41. In addition, a spacer substrate 42 is inserted between the lens-attached substrate 41c′ in the third layer and a lens-attached substrate 41d′ in a fourth layer. Here, the spacer substrate 42 has a structure in which a through-hole 83f is formed in a carrier substrate 81f as in the lens-attached substrate 41, but the lens resin portion 82 is not disposed on an inner side of the through-hole 83f. In the example in FIG. 36, the carrier substrate 81f of the spacer substrate 42 is the single-layer-structure carrier substrate 81, but may be the lamination-structure carrier substrate 81. In addition, the lens-attached substrate 41d′ in the fourth layer is constituted by the protruding lens-attached substrate 41 that uses a protruding lens.

The other structures of the thirteenth configuration example are similar to the laminated lens structure 11 according to the first configuration example.

Accordingly, the laminated lens structure 11 in FIG. 36 has a structure in which the protruding lens-attached substrate 41c′ in the third layer, which includes the protruding lens in the single-layer carrier substrate 81c, is received by the spacer substrate 42 that does not include the lens resin portion 82.

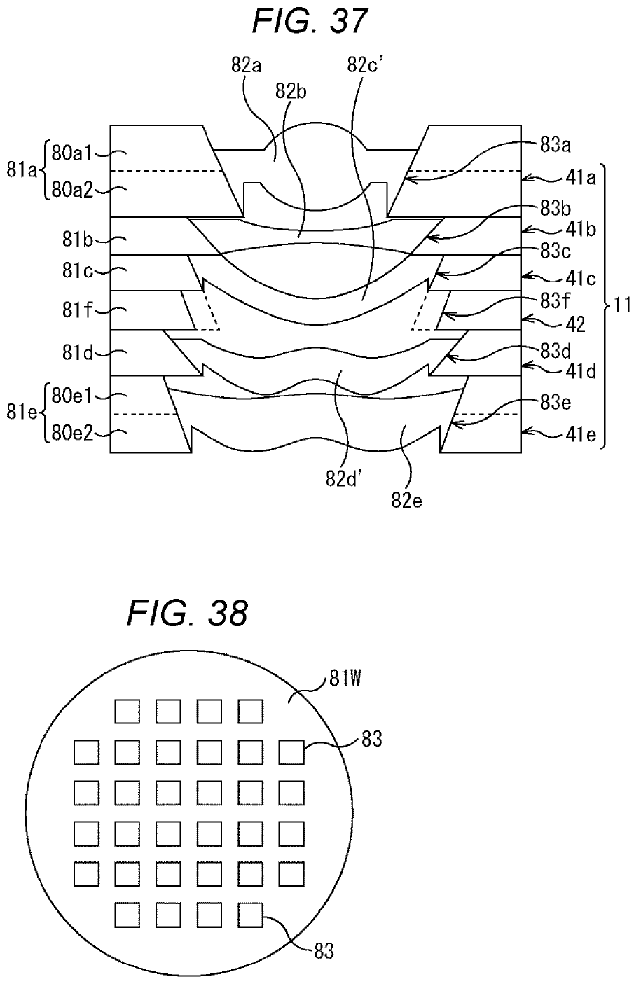

FIG. 37 is a cross-sectional view illustrating comparison between the thirteenth configuration example in FIG. 36 and the tenth configuration example illustrated in FIG. 33.

The thirteenth configuration example in FIG. 36 and the tenth configuration example in FIG. 33 include the lens resin portion 82c having the same shape in the protruding lens-attached substrate 41c′ in the third layer.

However, the carrier substrate 81c′ of the protruding lens-attached substrate 41c′ in the third layer in the tenth configuration example illustrated in FIG. 33 is the laminated carrier substrate 81c′. On the other hand, the carrier substrate 81c of the protruding lens-attached substrate 41c′ in the third layer in the thirteenth configuration example illustrated in FIG. 36 is the single-layer carrier substrate 81c, and has the same thickness as that of the laminated carrier substrate 81c′ in the tenth configuration example illustrated in FIG. 33 due to the spacer substrate 42.

In FIG. 37, a portion different from the shape of the carrier substrate 81c of the protruding lens-attached substrate 41c′ in the third layer in the tenth configuration example illustrated in FIG. 33 is indicated by a broken line on an inner side of the spacer substrate 42.

An upper surface side diameter of the through-hole 83c formed in the carrier substrate 81c of the protruding lens-attached substrate 41c′ in the third layer is the same as in the tenth configuration example in FIG. 33 and the thirteenth configuration example in FIG. 36.

On the other hand, when comparing a lower surface side diameter of the through-hole 83f of the spacer substrate 42 and a lower surface side diameter, which is indicated by a broken line, of the through-hole 83c of the carrier substrate 81c in the tenth configuration example in FIG. 33, the diameter of the through-hole 83f of the spacer substrate 42 is greater. In this manner, when using the spacer substrate 42, it is possible to further enlarge an open-hole diameter that becomes an incident light path in comparison to the case of using the carrier substrate 81 having the same thickness.

With this configuration, according to the laminated lens structure 11 relating to the thirteenth configuration example in FIG. 36, in a configuration in which light is narrowed by the lens resin portion 82a in the uppermost layer, and the light spreads toward the light-receiving region 12a of the imaging unit 12 by a lens group on a lower layer of the lens resin portion 82a and is incident to the imaging unit 12, it is possible to exhibit an operation effect capable of reducing a phenomenon in which the light spread by the lens resin portion 82a comes into contact with the carrier substrate 81c and thus an optical path is narrowed.

The laminated lens structure 11 relating to the thirteenth configuration example in FIG. 36 includes the protruding lens-attached substrate 41c′ and the spacer substrate 42 that is joined to a lower surface of the protruding lens-attached substrate 41c′, and has a structure in which a lateral wall of the through-hole 83c is downwardly extended while maintaining an angle made by a lateral wall of the through-hole 83c of the protruding lens-attached substrate 41c′ and a lower surface of the protruding lens-attached substrate 41c′, and on a surface in which the extended lateral wall of the through-hole 83c intersects an extended surface of the lower surface of the spacer substrate 42, an open-hole diameter of the through-hole 83f of the spacer substrate 42 in a lower surface is greater than an open-hole diameter formed by the extended lateral wall of the through-hole 83c.

Furthermore, an open-hole diameter of the through-hole 83f, through which light passes, of the spacer substrate 42 in an upper surface may be greater than the open-hole diameter of the through-hole 83c of the protruding lens-attached substrate 41c′ in the lower surface.

In addition, the open-hole diameter of the through-hole 83f of the spacer substrate 42 in the lower surface may be greater than an open-hole diameter of the through-hole 83c of the protruding lens-attached substrate 41c′ in an upper surface.

In addition, the open-hole diameter of the through-hole 83f of the spacer substrate 42 in the upper surface may be greater than the open-hole diameter of the through-hole 83c of the protruding lens-attached substrate 41c′ in the upper surface.

<22. Other Methods of Manufacturing Lens-Attached Single-Layer Substrate 41>

Next, other methods of manufacturing the lens-attached single-layer substrate 41 will be described.

The planar shape of the through-hole 83 of the lens-attached single-layer substrate 41 can be set to a circle as described above with reference to FIG. 14. In addition to this, the planar shape may be a polygon such as a quadrangle as illustrated in FIG. 38.

FIG. 38 illustrates an example in which the through-hole 83 of which a planar shape is quadrangle is formed in the carrier substrate 81W in a substrate state.

When a planar shape of an opening of an etching mask is set to a quadrangle by using the wet etching method described in FIG. 15, a through-hole 83, of which a planar shape is a quadrangle, in which the second opening width 132 is smaller than the first opening width 131, and a three-dimensional shape is a truncated pyramid or a shape similar thereto, is obtained. An angle of a lateral wall of the through-hole 83 becomes approximately 45° with respect to a substrate plane.

The size of the through-hole 83 in a plane direction of the carrier substrate 81W is referred to as an opening width. The opening width represents a length of one side in a case where the planar shape of the through-hole 83 is a quadrangle, and a diameter in a case where the planar shape of the through-hole 83 is a circle unless otherwise stated.

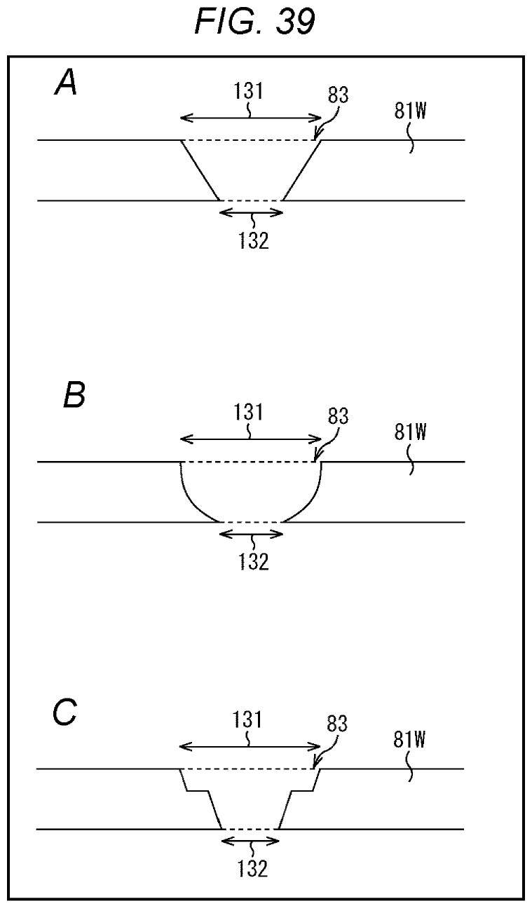

The through-hole 83 has a three-dimensional shape in which the second opening width 132 in a lower surface is smaller than the first opening width 131 in the upper surface as described in FIG. 15, but may be a truncated cone shape or a truncated polygonal pyramid shape as illustrated in FIG. 39A. A cross-sectional shape of the lateral wall of the through-hole 83 may be a straight line as illustrated in FIG. 39A, or a curved line as illustrated in FIG. 39B. Alternatively, a step difference may exist as illustrated in FIG. 39C.

In the through-hole 83 having a shape in which the second opening width 132 is smaller than the first opening width 131, when forming the lens resin portion 82 by supplying a resin into the through-hole 83, and by pressing the resin from a first surface and a second surface by mold members opposite to each other to form the lens resin portion 82, the resin that becomes the lens resin portion 82 receives a force from the two mold members opposite to each other, and is pressed to the lateral wall of the through-hole 83. Accordingly, an operation, in which adhesive strength between the resin that becomes the lens resin portion 82 and a carrier substrate is raised, can be exhibited.

Furthermore, as another embodiment of the through-hole 83, a shape in which the first opening width 131 and the second opening width 132 are the same as each other, that is, a shape in which a cross-sectional shape of the lateral wall of the through-hole 83 is vertical may be employed.

<Method of Forming Through-Hole by Using Dry Etching>

In addition, in etching for forming the through-hole 83, dry etching may be used instead of the above-described wet etching.

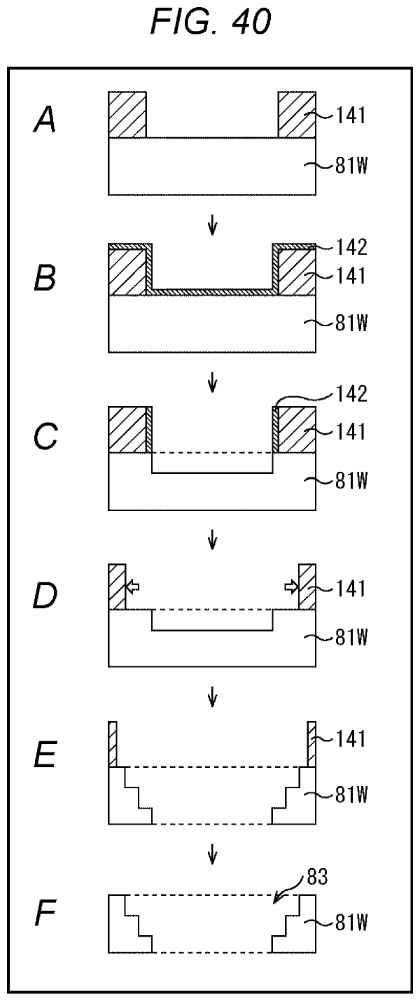

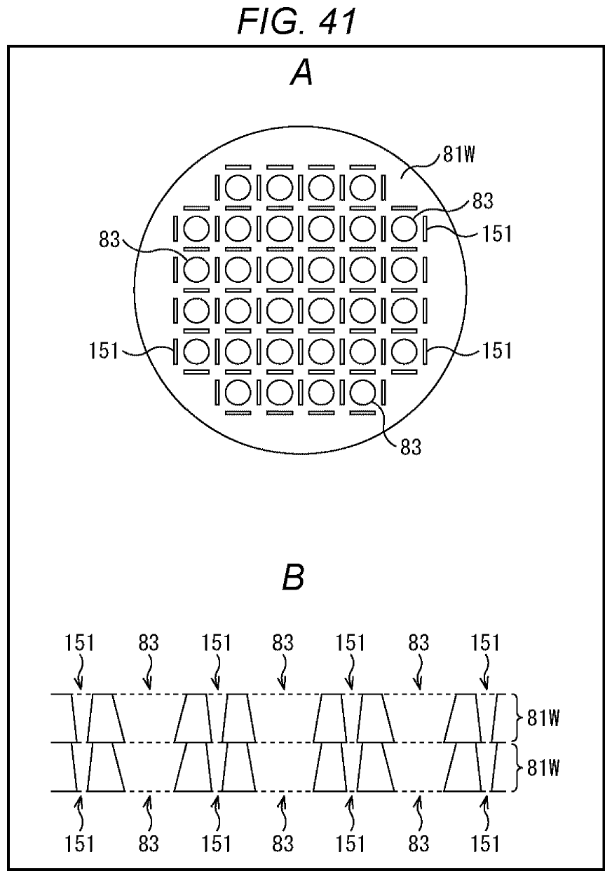

A method of forming the through-hole 83 by using dry etching will be described with reference to FIG. 40A to FIG. 40F.

As illustrated in FIG. 40A, an etching mask 141 is formed on one surface of the carrier substrate 81W. The etching mask 141 has a mask pattern in which a portion set to form the through-hole 83 is opened.

Next, as illustrated in FIG. 40B, a protective film 142 that protects a lateral wall of the etching mask 141 is formed, and as illustrated in FIG. 40C, the carrier substrate 81W is etched to a predetermined depth by dry etching. Through a dry etching process, the protective film 142 on a surface of the carrier substrate 81W and a surface of the etching mask 141 is removed, but the protective film 142 on a lateral surface of the etching mask 141 remains and thus the lateral surface of the etching mask 141 is protected. After etching, as illustrated in FIG. 40D, the protective film 142 on the lateral wall is removed, and the etching mask 141 is retreated in a direction in which a pattern size of an opening pattern is enlarged.

In addition, the protective film forming process, the dry etching process, and the etching mask retreating process in FIG. 40B to FIG. 40D are repetitively performed a plurality of times. Accordingly, as illustrated in FIG. 40E, the carrier substrate 81W is etched into a stair shape (concavo-convex shape) having a periodic step difference.

Finally, when the etching mask 141 is removed, as illustrated in FIG. 40F, the through-hole 83 having a stair-shaped lateral wall is formed in the carrier substrate 81W. The width (width of one step) of the stair shape of the through-hole 83 in a plane direction is set to, for example, approximately 400 nm to 1 μm.

In the case of forming the through-hole 83 by using dry etching as described above, the protective film forming process, the dry etching process, and the etching mask retreating process are repetitively performed.

The lateral wall of the through-hole 83 has the periodic stair shape (concavo-convex shape), and thus it is possible to suppress reflection of incident light. In addition, in a case where the lateral wall of the through-hole 83 is a concavo-convex shape having an arbitrary size, a void (cavity) may occur in an adhesive layer between a lens formed in the through-hole 83 and the lateral wall, and adhesiveness with the lens may deteriorate due to the void. However, according to the above-described forming method, the lateral wall of the through-hole 83 has a periodic concavo-convex shape, and thus adhesiveness is improved. As a result, it is possible to suppress a variation of optical characteristics due to lens positional deviation.

As an example of materials which are used in the respective processes, for example, the carrier substrate 81W may be set to single crystal silicon, the etching mask 141 may be set to a photoresist, the protective film 142 may be set to fluorocarbon polymer that is formed by using a gas plasma of C₄F₈, CHF₃, and the like, the etching treatment may be set to plasma etching that uses an F-containing gas such as SF₆/O₂ and C₄F₈/SF₆, and the mask retreating process may be set to O₂-containing plasma etching such as an O₂ gas and a CF₄/O₂.

Alternatively, the carrier substrate 81W may be set to single crystal silicon, the etching mask 141 may be set to SiO₂, the etching may be set to Cl₂-containing plasma, the protective film 142 may be set to an oxide film obtained by oxidizing an etching target material by using an O₂ plasma, the etching treatment may be set to plasma etching that uses a Cl₂-containing gas, the mask retreating process may be set to plasma etching that uses an F-containing gas such as CF₄/O₂.

As described above, a plurality of the through-holes 83 can be simultaneously formed in the carrier substrate 81W through the wet etching or the dry etching. However, as illustrated in FIG. 41A, a through-groove 151 may be formed in the carrier substrate 81W in a region in which the through-hole 83 is not formed.

FIG. 41A is a plan view of the carrier substrate 81W in which the through-groove 151 is formed in addition to the through-hole 83.

For example, as illustrated in FIG. 41A, the through-groove 151 is disposed at a part between through-holes 83 in a column direction and a row direction except for the plurality of through-holes 83 arranged in a matrix shape.

In addition, the through-groove 151 in the carrier substrate 81W can be disposed at the same position between the respective lens-attached substrates 41 which constitute the laminated lens structure 11. In this case, in a state in which a plurality of sheets of the carrier substrates 81W are laminated as the laminated lens structure 11, similarly to a cross-sectional view in FIG. 41B, a plurality of the through-grooves 151 of the plurality of sheets of carrier substrates 81W penetrate through the plurality of sheets of carrier substrates 81W.

For example, in a case where a stress that deforms the lens-attached substrate 41 is applied from the outside of the lens-attached substrate 41, the through-groove 151 of the carrier substrate 81W as a part of the lens-attached substrate 41 can exhibit an operation or an effect of mitigating deformation of the lens-attached substrate 41 due to the stress.

Alternatively, for example, in a case where a stress that deforms the lens-attached substrate 41 occurs from the inside of the lens-attached substrate 41, the through-groove 151 can exhibit an operation or an effect of mitigating deformation of the lens-attached substrate 41 due to the stress.

<23. Other Methods of Manufacturing Lens-Attached Laminated Substrate 41>

Next, other methods of manufacturing the lens-attached laminated substrate 41 will be described.

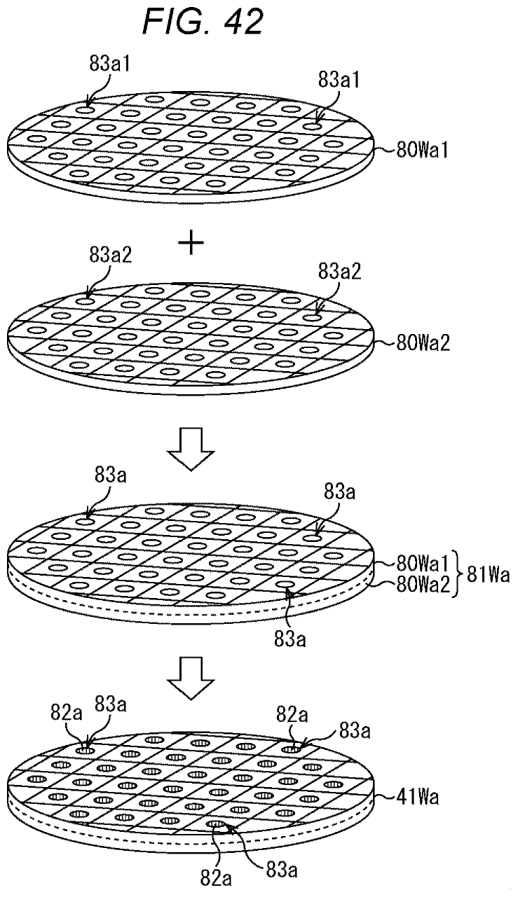

Next, description will be given of a method of manufacturing the lens-attached laminated substrate 41, for example, the lens-attached laminated substrate 41a with reference to FIG. 42.

First, as illustrated in FIG. 42, a carrier configuration substrate 80Wa1 in a substrate state in which a plurality of through-holes 83a1 are formed, and a carrier configuration substrate 80Wa2 in a substrate state in which a plurality of through-holes 83a2 are formed are prepared. The carrier configuration substrates 80Wa1 and 80Wa2 in a substrate state are prepared after being adjusted to a desired thickness as necessary.

In addition, the carrier configuration substrate 80Wa1 in a substrate state and the carrier configuration substrate 80Wa2 in a substrate state are directly joined to each other to manufacture a carrier substrate 81Wa in a substrate state in which the through-holes 83a are formed.

The lens resin portion 82a is formed on an inner side the through-holes 83a with respect to the carrier substrate 81Wa in a substrate state in which the through-holes 83a are formed. Through the processes, the lens-attached laminated substrate 41Wa in a substrate state is completed.

Other lens-attached laminated substrates 41We in a substrate state are manufactured in a similar manner.

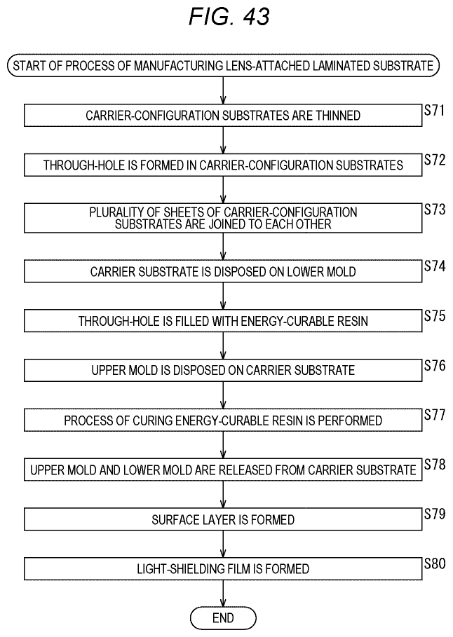

Description will be given of a process of manufacturing the lens-attached laminated substrate 41 according to the manufacturing method described in FIG. 42 with reference to a flowchart in FIG. 43.

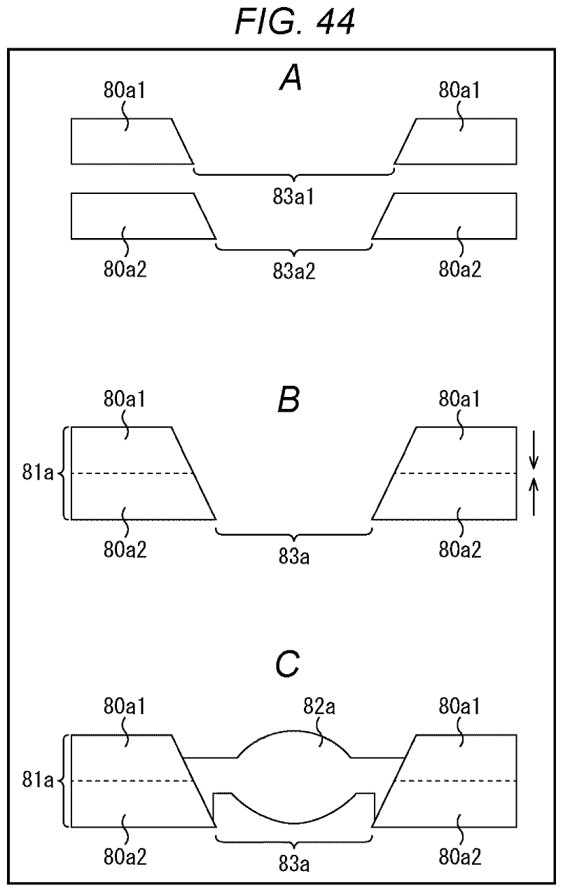

Furthermore, in description of FIG. 43, description will be made with reference to FIG. 44A to FIG. 44C as necessary. FIG. 44A to FIG. 44C are views illustrating a process of manufacturing the lens-attached laminated substrate 41 in an individual piece state, but the drawing is also true of the lens-attached laminated substrate 41W in a substrate state.

First, in step S71, a plurality of sheets of the carrier configuration substrates 80a which constitute the carrier substrate 81a (laminated carrier substrate 81a) are thinned into a desired thickness. In a case where the thinning is not necessary, the step can be omitted.

In step S72, as illustrated in FIG. 44A, the through-hole 83a is formed in each of the plurality of sheets of carrier configuration substrates 80a. In FIG. 44A, a through hole 83a1 is formed in a carrier configuration substrate 80a1, and a through-hole 83a2 is formed in a carrier configuration substrate 80a2.

In step S73, the plurality of sheets of carrier configuration substrates 80 are joined to each other. For example, as illustrated in FIG. 44B, the carrier configuration substrate 80a1 in which the through-hole 83a1 is formed and the carrier configuration substrate 80a2 in which the through-hole 83a2 is formed can be bonded to each other through direct joining. The resultant bonded substrate becomes the carrier substrate 81a (laminated carrier substrate 81a).

The processes in step S74 to step S80 are similar to the processes in step S44 to step S50 in FIG. 18, and thus description thereof will be omitted. Through the processes, as illustrated in FIG. 44C, the lens resin portion 82a is formed in the through-hole 83a of the carrier substrate 81a.

Through the above-described processes, the lens-attached laminated substrate 41 is completed.

<24. Modification Example of Lens-Attached Single-Layer Substrate 41>

Next, a modification example of the lens-attached single-layer substrate 41 will be described.

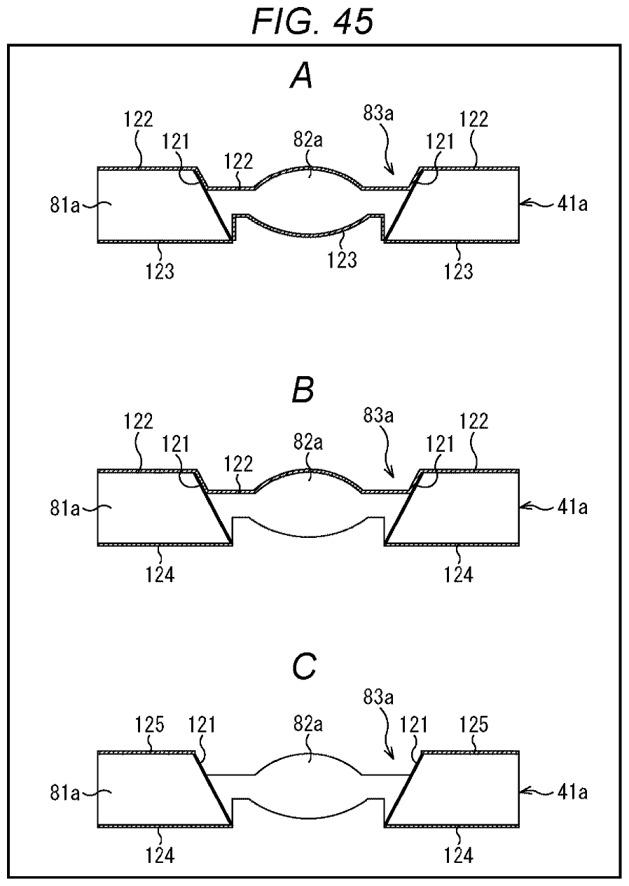

FIG. 45A is a cross-sectional view illustrating a configuration example of the lens-attached single-layer substrate 41a illustrated in FIG. 12, and FIG. 45B and FIG. 45C are cross-sectional views illustrating modification examples of the lens-attached single-layer substrate 41a in FIG. 12.

Accordingly, with regard to the lens-attached single-layer substrate 41a in FIG. 45B and FIG. 45C, description will be given of only a portion different from the lens-attached single-layer substrate 41a illustrated in FIG. 45A.

In the lens-attached single-layer substrate 41a illustrated in FIG. 45B, a film, which is formed on the lower surface of the carrier substrate 81a and the lens resin portion 82a, is different from that of the lens-attached single-layer substrate 41a illustrated in FIG. 45A.

In the lens-attached single-layer substrate 41a in FIG. 45B, a lower surface layer 124 including an oxide, a nitride, or other insulating materials is formed on the lower surface of the carrier substrate 81a. On the other hand, the lower surface layer 124 is not formed on the lower surface of the lens resin portion 82a. The lower surface layer 124 may include the same material as that of the upper surface layer 122 or a material different from that of the upper surface layer 122.

For example, this structure can be formed by a manufacturing method in which the lower surface layer 124 is formed on the lower surface of the carrier substrate 81a before forming the lens resin portion 82a, and then the lens resin portion 82a is formed. Alternatively, the structure can be formed by depositing a film, which constitutes the lower surface layer 124, on the lower surface of the carrier substrate 81a, for example, by PVD in a state in which a mask is formed on the lens resin portion 82a and the mask is not formed on the carrier substrate 81a after forming the lens resin portion 82a.

In the lens-attached single-layer substrate 41a in FIG. 45C, an upper surface layer 125 including an oxide, a nitride, or other insulating materials is formed on an upper surface of the carrier substrate 81a. On the other hand, the upper surface layer 125 is not formed on an upper surface of the lens resin portion 82a.

Similarly, even on a lower surface of the lens-attached single-layer substrate 41a, the lower surface layer 124 including an oxide, a nitride, or other insulating materials is formed on the lower surface of the carrier substrate 81a. On the other hand, the lower surface layer 124 is not formed on the lower surface of the lens resin portion 82a.

For example, this structure can be formed by a manufacturing method in which the upper surface layer 125 and the lower surface layer 124 are formed on the carrier substrate 81a before forming the lens resin portion 82a, and then the lens resin portion 82a is formed. Alternatively, the structure can be formed by depositing films, which constitute the upper surface layer 125 and the lower surface layer 124, on the surfaces of the carrier substrate 81a, for example, by PVD in a state in which a mask is formed on the lens resin portion 82a and the mask is not formed on the carrier substrate 81a after forming the lens resin portion 82a. The lower surface layer 124 and the upper surface layer 125 can include the same material or materials different from each other.

The lens-attached single-layer substrate 41a can be configured as described above.

<25. Modification Example of Lens-Attached Laminated Substrate 41>

Next, a modification example of the lens-attached laminated substrate 41 will be described.

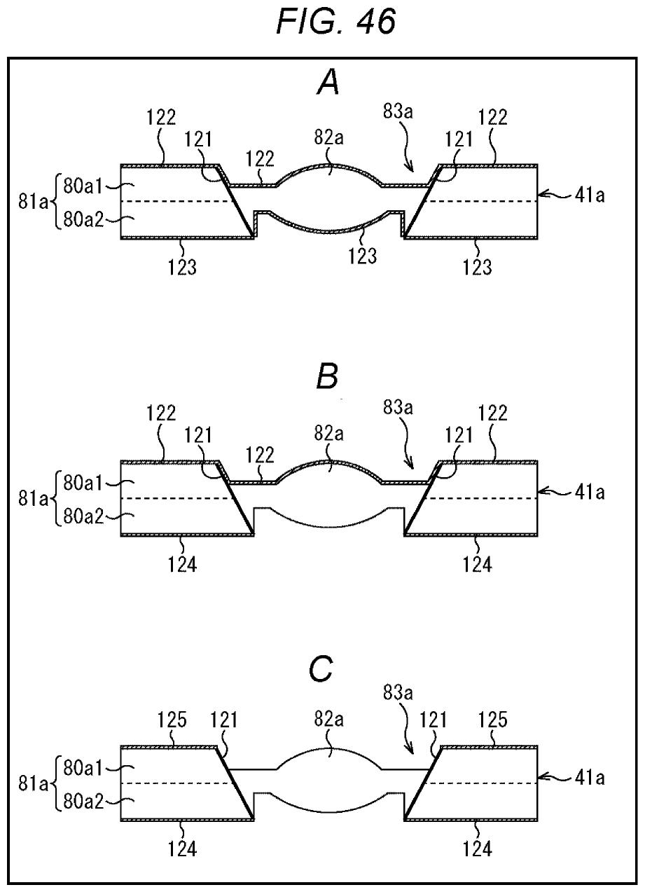

FIG. 46A is a cross-sectional-view illustrating a configuration example of the lens-attached laminated substrate 41a illustrated in FIG. 10, and FIG. 46B and FIG. 46C are cross-sectional views illustrating a modification example of the lens-attached laminated substrate 41a in FIG. 10.

Accordingly, with regard to the lens-attached laminated substrate 41a in FIG. 46B and FIG. 46C, description will be given of only a portion different from the lens-attached laminated substrate 41a illustrated in FIG. 46A.

Lens-attached laminated substrates 41a in FIG. 46B and FIG. 46C and the lens-attached single-layer substrates 41a in FIG. 45B and FIG. 45C are different from each other only in that the carrier substrate 81 is the single-layer-structure carrier substrate 81 or the lamination-structure carrier substrate 81, and the configuration of the lower surface layer 124 and the upper surface layer 125 is similar in each case.

<26. Modification Example of Lens Resin Portion 82 and Through-Hole 83 of Lens-Attached Single-Layer Substrate 41>

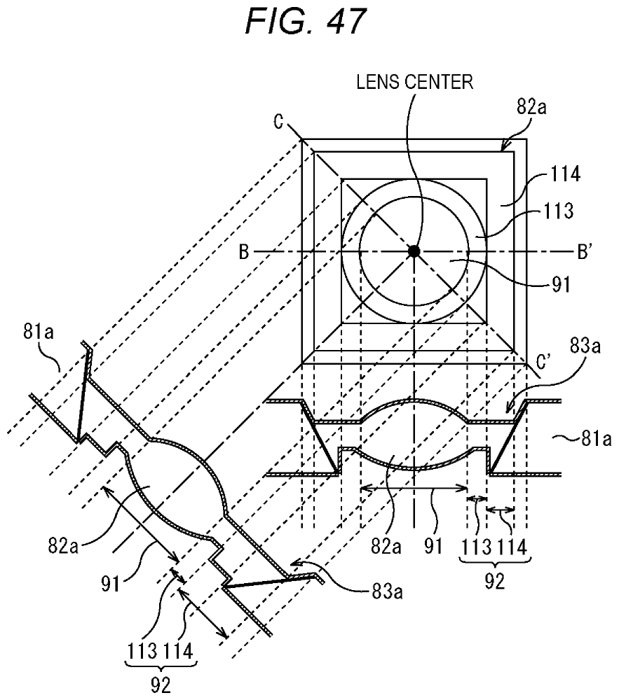

Next, a modification example of the lens resin portion 82 and the through-hole 83 of the lens-attached single-layer substrate 41 will be described with reference to FIG. 47 to FIG. 52.

Furthermore, as in the description in FIG. 12 and FIG. 13, in FIG. 47 to FIG. 52, description will be made by substituting the lens-attached laminated substrate 41a with the lens-attached single-layer substrate 41a.

As described with reference to FIG. 38, a planar shape of the through-hole 83 may be a polygon such as a quadrangle.

FIG. 47 shows a plan view and cross-sectional views of the carrier substrate 81a and the lens resin portion 82a of the lens-attached single-layer substrate 41a in a case where the planar shape of the through-hole 83 is a quadrangle.

The cross-sectional views of the lens-attached single-layer substrate 41a in FIG. 47 are cross-sectional views which are respectively taken along line B-B′ and line C-C′ in the plan view.

As can be seen from comparison between the cross-sectional view taken along line B-B′ and the cross-sectional view taken along line C-C′, in a case where the through-hole 83a has a quadrangular shape, a distance from the center of the through-hole 83a to an upper outer edge of the through-hole 83a, and a distance from the center of the through-hole 83a to a lower outer edge of the through-hole 83a are different between a side direction and a diagonal direction of the through-hole 83a having a quadrangular shape, and are longer on the diagonal direction side. Accordingly, in a case where a planar shape of the through-hole 83a is a quadrangle, when the lens portion 91 is set to a circular shape, it is necessary to set a distance from the outer periphery of the lens portion 91 to the lateral wall of the through-hole 83a, in other words, a length of the carrier portion 92 to be different between the side direction and the diagonal direction of a quadrangle.

Here, the lens resin portion 82a illustrated in FIG. 47 has the following structure.

(1) A length of the arm portion 113 disposed at the outer periphery of the lens portion 91 is the same between the side direction and the diagonal direction of the quadrangle.

(2) In the leg portion 114 that is disposed on an outer side of the arm portion 113 and extends to the lateral wall of the through-hole 83a, a length of the leg portion 114 in the diagonal direction of the quadrangle is set to be longer than a length of the leg portion 114 in the side direction of the quadrangle.

As illustrated in FIG. 47, the leg portion 114 is not in direct contact with the lens portion 91, and the arm portion 113 is in direct contact with the lens portion 91.

In the lens resin portion 82a in FIG. 47, when the length and the thickness of the arm portion 113, which is in direct contact with the lens portion 91, are set to be constant over the entirety of the outer periphery of the lens portion 91, it is possible to exhibit an operation or an effect capable of supporting the entirety of the lens portion 91 with a constant force without a deviation.

In addition, since the entirety of the lens portion 91 is supported with a constant force without a deviation, for example, in a case where a stress is applied from the carrier substrate 81a that surrounds the through-hole 83a over the entirety of the outer periphery of the through-hole 83a, the stress is transferred to the entirety of the lens portion 91 without a deviation. Accordingly, it is possible to exhibit an operation or an effect capable of suppressing the stress from being transferred to a specific portion of the lens portion 91 with a deviation.

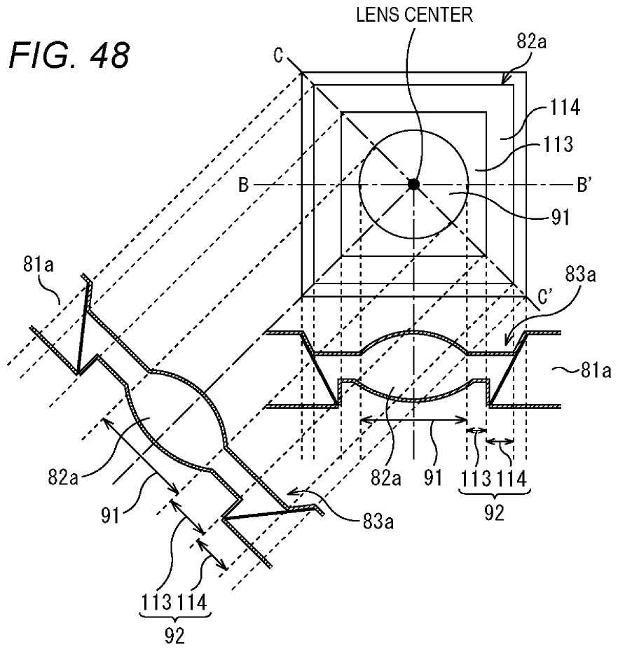

FIG. 48 shows a plan view and cross-sectional views of the carrier substrate 81a and the lens resin portion 82a of the lens-attached single-layer substrate 41a which illustrate another example of the through-hole 83 of which a planar shape is a quadrangle.

The cross-sectional views of the lens-attached single-layer substrate 41a in FIG. 48 are cross-sectional views which are respectively taken along line B-B′ and line C-C′ in the plan view.

Even in FIG. 48, a distance from the center of the through-hole 83a to an upper outer edge of the through-hole 83a, and a distance from the center of the through-hole 83a to a lower outer edge of the through-hole 83a are different between a side direction and a diagonal direction of the through-hole 83a having a quadrangular shape similarly to FIG. 47, and are longer on the diagonal direction side. Accordingly, in a case where a planar shape of the through-hole 83a is a quadrangle, when the lens portion 91 is set to a circular shape, it is necessary to set a distance from the outer periphery of the lens portion 91 to the lateral wall of the through-hole 83a, in other words, a length of the carrier portion 92 to be different between the side direction and the diagonal direction of a rectangle.

Here, the lens resin portion 82a illustrated in FIG. 48 has the following structure.

(1) A length of the leg portion 114 disposed at the outer periphery of the lens portion 91 is constant along four sides of a quadrangular shape of the through-hole 83a.

(2) To realize the structure in (1), with regard to the length of the arm portion 113, a length of the arm portion in the diagonal direction of the quadrangle is set to be longer than a length of the arm portion in the side direction.

As illustrated in FIG. 48, with regard to the film thickness of a resin, the film thickness of the leg portion 114 is larger than the film thickness of the arm portion 113. Accordingly, with regard to a volume of the lens-attached single-layer substrate 41a per unit area in a plane direction, the volume of the leg portion 114 is greater than the volume of the arm portion 113.

In the example of FIG. 48, the volume of the leg portion 114 is set to be small as much as possible, and is set to be constant along four sides of the rectangular shape of the through-hole 83a. Accordingly, for example, in a case where deformation such as swelling of the resin occurs, it is possible to exhibit an operation or an effect capable of suppressing a volume variation due to the deformation as much as possible, and is capable of suppressing a deviation of the volume variation over the entirety of the outer periphery of the lens portion 91.

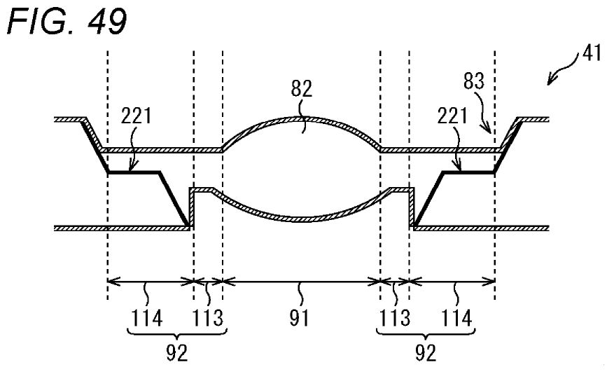

FIG. 49 is a cross-sectional view illustrating another configuration example of the lens resin portion 82 and the through-hole 83 of the lens-attached single-layer substrate 41.

The lens resin portion 82 and the through-hole 83, which are illustrated in FIG. 49, have the following structure.

(1) The lateral wall of the through-hole 83 has a stepped shape including a stepped portion 221.

(2) The leg portion 114 of the carrier portion 92 of the lens resin portion 82 is disposed on an upward side of the lateral wall of the through-hole 83, and extends in a plane direction of the lens-attached single-layer substrate 41 also on an upper side of the stepped portion 221 provided in the through-hole 83.

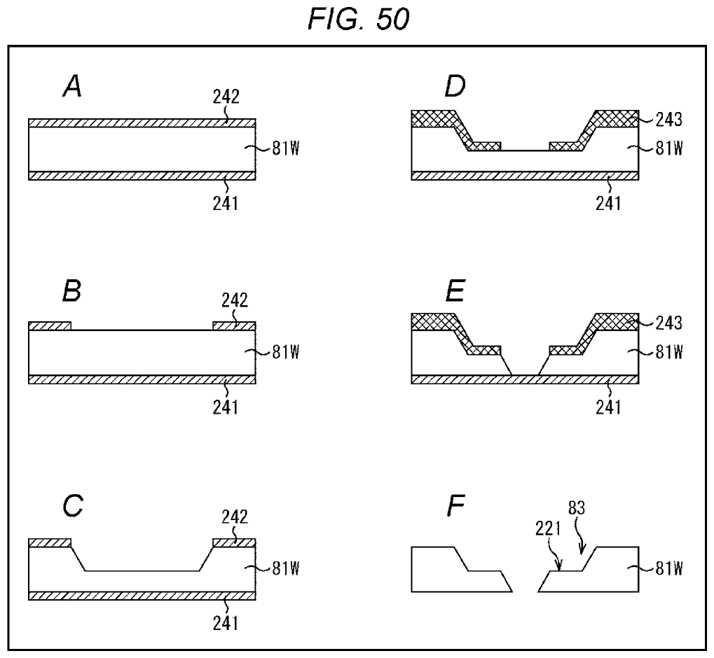

A method of forming the through-hole 83 having the stepped shape illustrated in FIG. 49 will be described with reference to FIG. 50A to FIG. 50F.

First, as illustrated in FIG. 50A, an etching stop film 241 having resistance with respect to wet etching when opening a through-hole is formed on one surface of the carrier substrate 81W. For example, the etching stop film 241 can be set to a silicon nitride film.

Next, a hard mask 242 having resistance with respect to wet etching when opening the through-hole is formed on the other surface of the carrier substrate 81W. For example, the hard mask 242 also can be set to a silicon nitride film.

Next, as illustrated in FIG. 50B, a predetermined region of the hard mask 242 is opened by first etching. In the first etching, a portion of the through-hole 83, which becomes an upper end of the stepped portion 221, is etched. Accordingly, the opening of the hard mask 242 for the first etching becomes a region corresponding to an opening in an upper substrate surface of the lens-attached single-layer substrate 41 illustrated in FIG. 49.

Next, as illustrated in FIG. 50C, the carrier substrate 81W is etched to a predetermined depth along the opening of the hard mask 242 through wet etching.

Next, as illustrated in FIG. 50D, a hard mask 243 is formed again on the surface of the carrier substrate 81W after being etched, and the hard mask 243 is opened in correspondence with a portion of the through-hole 83 which becomes a lower side of the stepped portion 221. For example, as the second hard mask 243, it is also possible to employ a silicon nitride film.

Next, as illustrated in FIG. 50E, the carrier substrate 81W is etched along the opening of the hard mask 243 by wet etching until reaching the etching stop film 241.

Finally, as illustrated in FIG. 50F, the hard mask 243 on the upper surface of the carrier substrate 81W and the etching stop film 241 on the lower surface thereof are removed.

As described above, etching of the carrier substrate 81W for forming the through-hole through wet etching is divided into two times, and thus the through-hole 83 having a stepped shape illustrated in FIG. 49 is obtained.

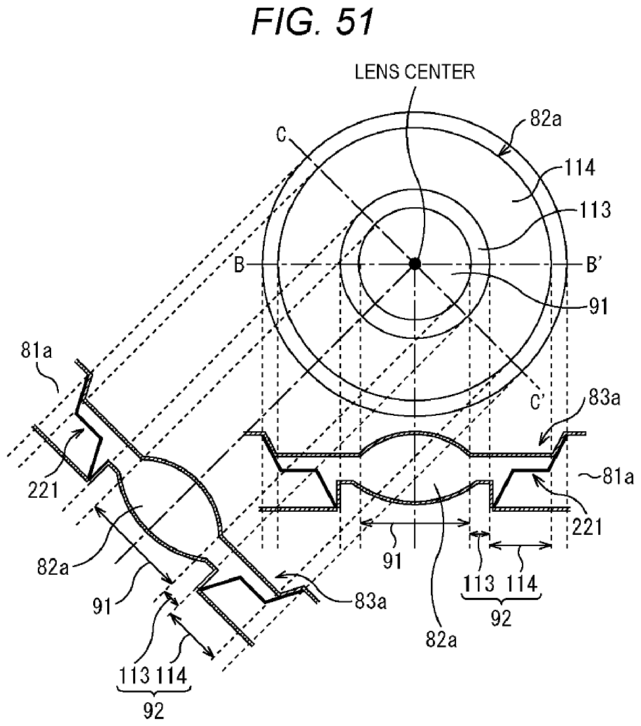

FIG. 51 shows a plan view and cross-sectional views of the carrier substrate 81a and the lens resin portion 82a of the lens-attached single-layer substrate 41a in a case where the through-hole 83a includes a stepped portion 221 and a planar shape of the through-hole 83a is a circle.

The cross-sectional views of the lens-attached single-layer substrate 41a in FIG. 51 are cross-sectional views which are respectively taken along line B-B′ and line C-C′ in the plan view.

In a case where the planar shape of the through-hole 83a is a circle, a cross-sectional shape of the through-hole 83a is the same regardless of a diameter direction. In addition to this, a cross-sectional shape of an outer edge, the arm portion 113, and the leg portion 114 of the lens resin portion 82a is formed to be the same regardless of the diameter direction.

The through-hole 83a having a stepped shape in FIG. 51 exhibits an operation or an effect capable of further enlarging a contact area between the leg portion 114 of the carrier portion 92 of the lens resin portion 82 and the lateral wall of the through-hole 83a in comparison to the through-hole 83a that does not include the stepped portion 221 at the inside of the through-hole 83a as illustrated in FIG. 13. In addition, according to this, it is possible to exhibit an operation or an effect capable of increasing adhesive strength between the lens resin portion 82 and the lateral wall of the through-hole 83a, in other words, adhesive strength between the lens resin portion 82a and the carrier substrate 81W.

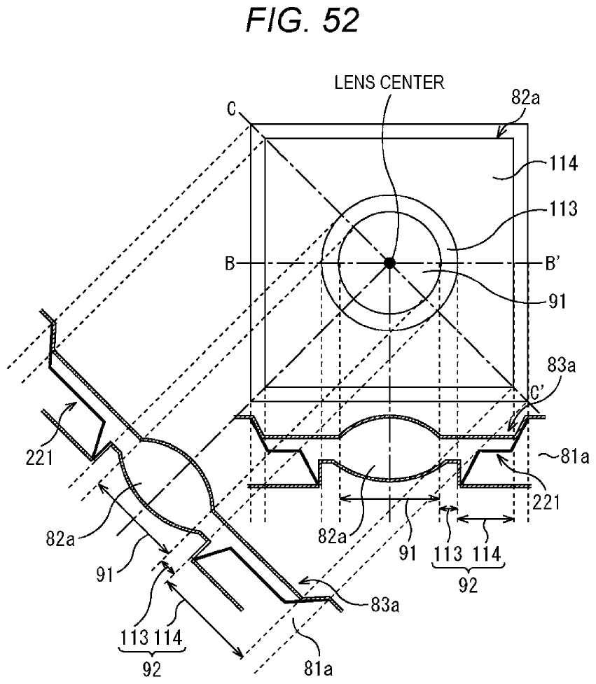

FIG. 52 shows a plan view and cross-sectional views of the carrier substrate 81a and the lens resin portion 82a of the lens-attached single-layer substrate 41a in a case where the through-hole 83a includes a stepped portion 221 and a planar shape of the through-hole 83a is a quadrangle.

The cross-sectional views of the lens-attached single-layer substrate 41a in FIG. 52 are cross-sectional views which are respectively taken along line B-B′ and line C-C′ in the plan view.

The lens resin portion 82 and the through-hole 83 illustrated in FIG. 52 have the following structure.

(1) A length of the arm portion 113 disposed at the outer periphery of the lens portion 91 is the same between a side direction and a diagonal direction of the quadrangle.

(2) In the leg portion 114 that is disposed on an outer side of the arm portion 113 and extends to the lateral wall of the through-hole 83a, a length of the leg portion 114 in the diagonal direction of the quadrangle is longer than a length of the leg portion 114 in the side direction of the quadrangle.

As illustrated in FIG. 52, the leg portion 114 is not in direct contact with the lens portion 91, and the arm portion 113 is in direct contact with the lens portion 91.

As in the lens resin portion 82a illustrated in FIG. 47, in the lens resin portion 82a in FIG. 52, when the length and the thickness of the arm portion 113, which is in direct contact with the lens portion 91, are set to be constant over the entirety of the outer periphery of the lens portion 91, it is possible to exhibit an operation or an effect capable of supporting the entirety of the lens portion 91 with a constant force without a deviation.

In addition, since the entirety of the lens portion 91 is supported with a constant force without a deviation, for example, in a case where a stress is applied from the carrier substrate 81a that surrounds the through-hole 83a over the entirety of the outer periphery of the through-hole 83a, the stress is transferred to the entirety of the lens portion 91 without a deviation. Accordingly, it is possible to exhibit an operation or an effect capable of suppressing the stress from being transferred to a specific portion of the lens portion 91 with a deviation.

In addition, the structure of the through-hole 83a in FIG. 52 exhibits an operation or an effect capable of further enlarging a contact area between the leg portion 114 of the carrier portion 92 of the lens resin portion 82a and the lateral wall of the through-hole 83a in comparison to the through-hole 83a that does not include the stepped portion 221 at the inside of the through-hole 83a as illustrated in FIG. 47 and the like. According to this structure, it is possible to exhibit an operation or an effect capable of increasing adhesive strength between the lens resin portion 82a and the lateral wall of the through-hole 83a, in other words, adhesive strength between the lens resin portion 82a and the carrier substrate 81a.

<27. Modification Example of Lens Resin Portion 82 and Through-Hole 83 of Lens-Attached Laminated Substrate 41>

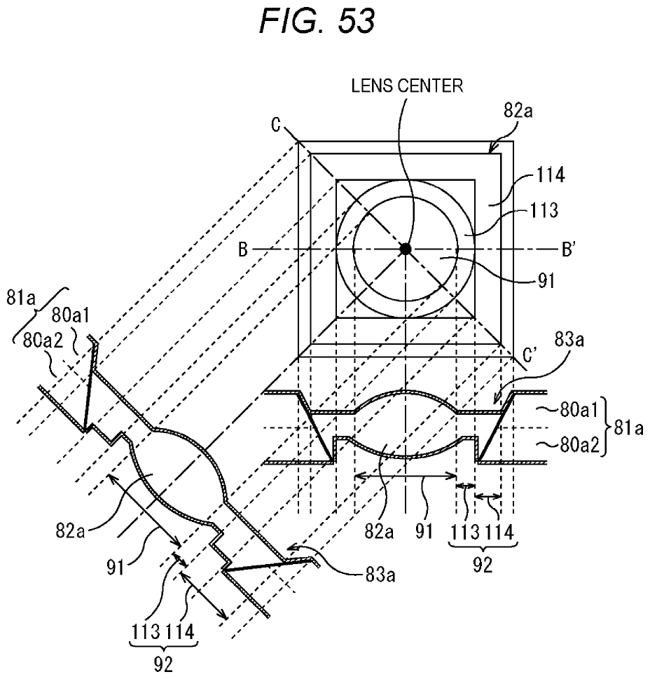

Next, description will be given of a modification example of the lens resin portion 82 and the through-hole 83 of the lens-attached laminated substrate 41 with reference to FIG. 53 to FIG. 58.

Furthermore, in FIG. 53 to FIG. 58, a modification example of the lens resin portion 82 and the through-hole 83 of the lens-attached laminated substrate 41a in comparison to the lens-attached single-layer substrate 41a described with reference to FIG. 47 to FIG. 52.

FIG. 53 shows a plan view and cross-sectional views of the carrier substrate 81a and the lens resin portion 82a of the lens-attached laminated substrate 41a in a case where the planar shape of the through-hole 83 is a quadrangle as in the lens-attached single-layer substrate 41a described with reference to FIG. 47.

The lens-attached laminated substrate 41a in FIG. 53 is similar to the lens-attached single-layer substrate 41a described with reference to FIG. 47 except the carrier substrate 81a is constituted by bonding two sheets of the carrier configuration substrates 80a1 and 80a2 to each other.

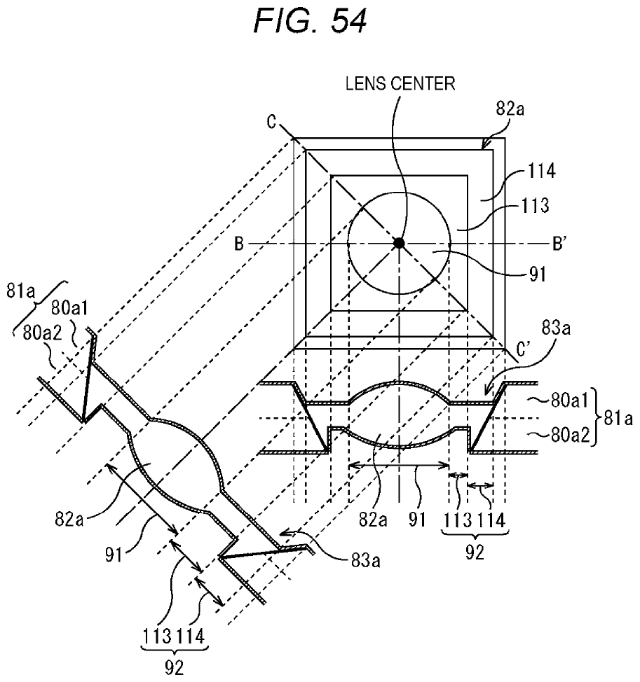

FIG. 54 shows a plan view and cross-sectional views of the carrier substrate 81a and the lens resin portion 82a of the lens-attached laminated substrate 41a in a case where the planar shape of the through-hole 83 is a quadrangle as in the lens-attached single-layer substrate 41a described with reference to FIG. 48.

The lens-attached laminated substrate 41a in FIG. 54 is similar to the lens-attached single-layer substrate 41a described with reference to FIG. 48 except the carrier substrate 81a is constituted by bonding two sheets of the carrier configuration substrates 80a1 and 80a2 to each other.

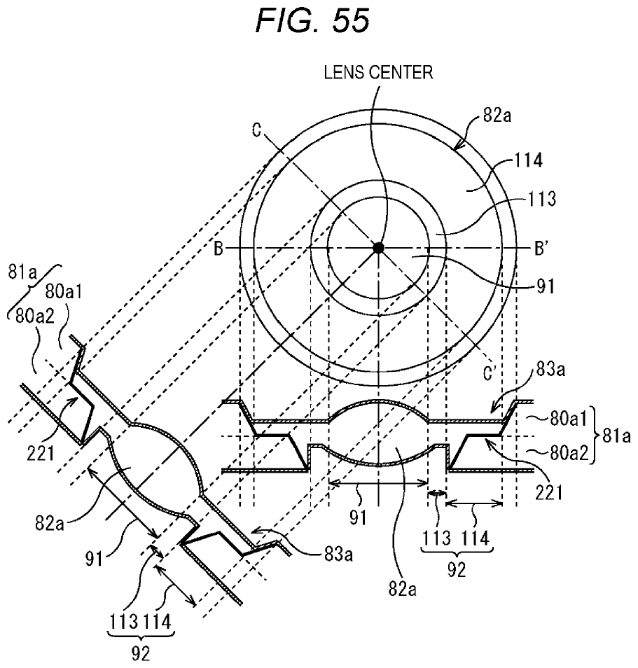

FIG. 55 shows a plan view and cross-sectional views of the carrier substrate 81a and the lens resin portion 82a of the lens-attached laminated substrate 41a in a case where the through-hole 83a includes the stepped portion 221, and the planar shape of the through-hole 83 is a circle as in the lens-attached single-layer substrate 41a described with reference to FIG. 51.

The lens-attached laminated substrate 41a in FIG. 55 is similar to the lens-attached single-layer substrate 41a described with reference to FIG. 51 except the carrier substrate 81a is constituted by bonding two sheets of the carrier configuration substrates 80a1 and 80a2 to each other.

In the carrier substrate 81a, a bonding surface of the two sheets of carrier configuration substrates 80a1 and 80a2 is the same as the surface of the stepped portion 221 of the through-hole 83a.

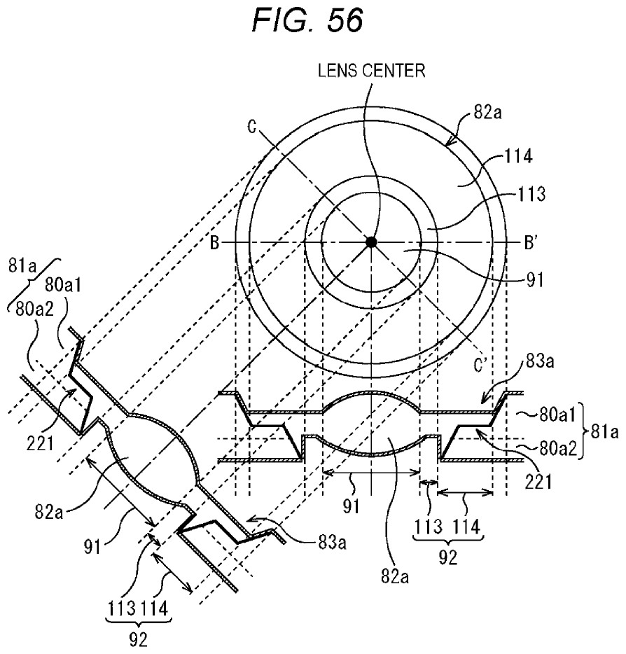

FIG. 56 shows a plan view and cross-sectional views of the carrier substrate 81a and the lens resin portion 82a of the lens-attached laminated substrate 41a in a case where the through-hole 83a includes the stepped portion 221, and the planar shape of the through-hole 83 is a circle as in the lens-attached single-layer substrate 41a described with reference to FIG. 51.

The lens-attached laminated substrate 41a in FIG. 56 is similar to the lens-attached single-layer substrate 41a described with reference to FIG. 51 except the carrier substrate 81a is constituted by bonding two sheets of the carrier configuration substrates 80a1 and 80a2 to each other.

In the carrier substrate 81a, a bonding surface of the two sheets of carrier configuration substrates 80a1 and 80a2 is different from the surface of the stepped portion 221 of the through-hole 83a.

Accordingly, a difference between the lens-attached laminated substrate 41a in FIG. 55 and the lens-attached laminated substrate 41a in FIG. 56 is a position of the bonding surface of the two sheets of the carrier configuration substrates 80a1 and 80a2 in a thickness direction.

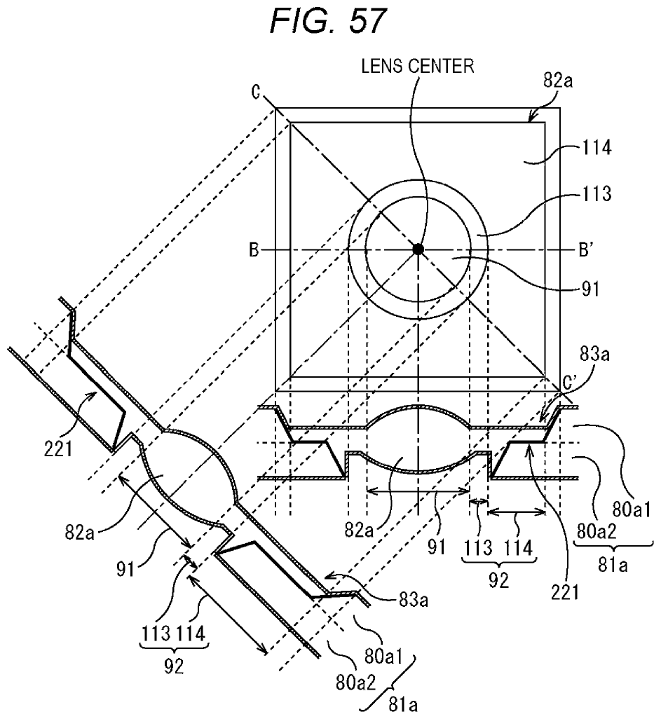

FIG. 57 shows a plan view and cross-sectional views of the carrier substrate 81a and the lens resin portion 82a of the lens-attached laminated substrate 41a in a case where the through-hole 83a includes the stepped portion 221, and the planar shape of the through-hole 83 is a quadrangle as in the lens-attached single-layer substrate 41a described with reference to FIG. 52.

The lens-attached laminated substrate 41a in FIG. 57 is similar to the lens-attached single-layer substrate 41a described with reference to FIG. 52 except the carrier substrate 81a is constituted by bonding two sheets of the carrier configuration substrates 80a1 and 80a2 to each other.

In the carrier substrate 81a, a bonding surface of the two sheets of carrier configuration substrates 80a1 and 80a2 is the same as the surface of the stepped portion 221 of the through-hole 83a.

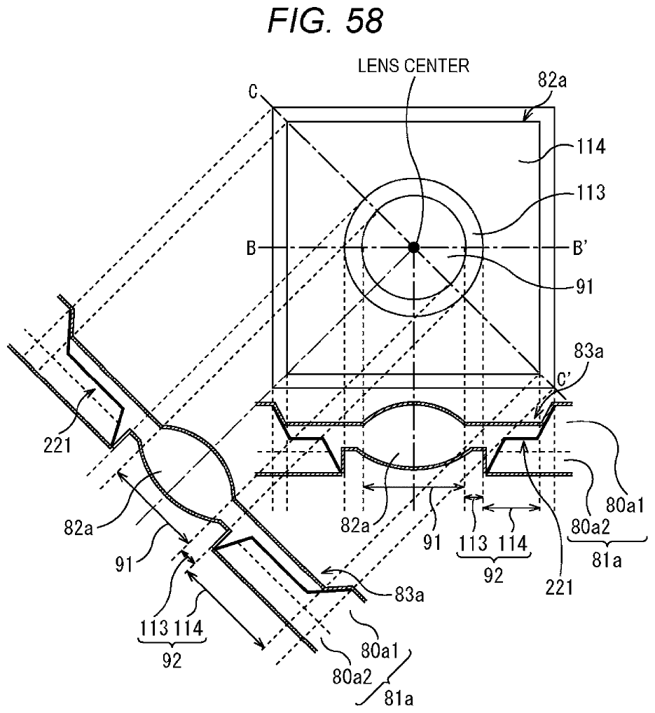

FIG. 58 shows a plan view and cross-sectional views of the carrier substrate 81a and the lens resin portion 82a of the lens-attached laminated substrate 41a in a case where the through-hole 83a includes the stepped portion 221, and the planar shape of the through-hole 83 is a quadrangle as in the lens-attached single-layer substrate 41a described with reference to FIG. 52.

The lens-attached laminated substrate 41a in FIG. 58 is similar to the lens-attached single-layer substrate 41a described with reference to FIG. 52 except the carrier substrate 81a is constituted by bonding two sheets of the carrier configuration substrates 80a1 and 80a2 to each other.

In the carrier substrate 81a, a bonding surface of the two sheets of carrier configuration substrates 80a1 and 80a2 is different from the surface of the stepped portion 221 of the through-hole 83a.

Accordingly, a difference between the lens-attached laminated substrate 41a in FIG. 57 and the lens-attached laminated substrate 41a in FIG. 58 is a position of the bonding surface of the two sheets of the carrier configuration substrates 80a1 and 80a2 in a thickness direction.

As described above, in the lens-attached substrate 41 used in the laminated lens structure 11, even in any of the lens-attached single-layer substrate 41 and the lens-attached laminated substrate 41, various shapes can be employed as the shape of the lens resin portion 82 and the through-hole 83.

<28. Another Modification Example of Lens-Attached Laminated Substrate 41>

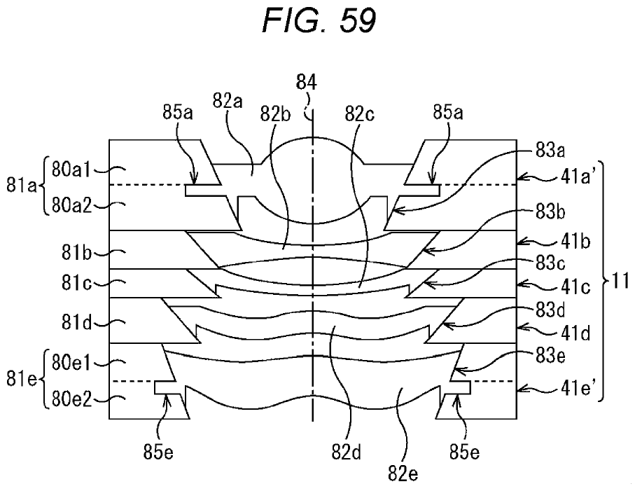

Next, description will be given of another modification example of the lens-attached laminated substrate 41 with reference to FIG. 59 to FIG. 67C.

FIG. 59 is a cross-sectional view of the laminated lens structure 11 that uses another modification example of the lens-attached laminated substrate 41.

In FIG. 59, as in the second configuration example to the thirteenth configuration example, a portion different from the first configuration example is illustrated by adding a dash (′) to a reference numeral.

The laminated lens structure 11 in FIG. 59 is different from the laminated lens structure 11 relating to the first configuration example illustrated in FIG. 2 in a lens-attached substrate 41a′ in the uppermost layer and a lens-attached substrate 41e′ in the lowermost layer.

More specifically, in the lens-attached substrate 41a′ in the uppermost layer, a groove 85a is additionally added to the lateral wall of the through-hole 83a in comparison to the lens-attached substrate 41a in the uppermost layer relating to the first configuration example. The lens resin portion 82a is embedded in the groove 85a.

With regard to the lens-attached substrate 41e′ in the lowermost layer, similarly, a groove 85e is additionally added to the lateral wall of the through-hole 83e in comparison to the lens-attached substrate 41a in the uppermost layer relating to the first configuration example. The lens resin portion 82e is embedded in the groove 85e.

As described with reference to FIG. 16A to FIG. 16G, the lens resin portion 82 is formed as follows. The energy-curable resin 191 is added dropwise onto the lower mold 181, a gap between the upper mold 201 and the lower mold 181 is controlled in order for the energy-curable resin 191 that is added dropwise to be interposed therebetween, and the energy-curable resin 191 is cured. At this time, controllability or optimization of the dropping amount of the energy-curable resin 191 becomes important. That is, when the dropping amount is less, a depression and the like occur in the lens portion 91, and thus desired optical characteristics are not obtained. In addition, in a case where the dropping amount is much, there is a concern that the energy-curable resin 191 overflows from a space between the upper mold 201 and the lower mold 181, and thus a substrate joining surface is contaminated. In addition, when curing the energy-curable resin 191, a resin volume is reduced (shrunk).

Here, as in the lens-attached substrate 41a′ in FIG. 59, when the groove 85a into which an excessive energy-curable resin 191 is retreated is formed, even though excessive filling with the energy-curable resin 191 occurs, it is possible to accommodate the excessive energy-curable resin 191 in the groove 85a, and it is possible to prevent the energy-curable resin 191 from overflowing from the space between the upper mold 201 and the lower mold 181. In addition, when the energy-curable resin 191 is cured and shrunk, the energy-curable resin 191 accommodated in the groove 85a is returned and supplied to the central portion of the through-hole 83, and thus a void does not occur between the upper mold 201 and the lower mold 181. That is, when the groove 85a is provided, it is possible to permit a variation of the dropping amount.

In addition, the energy-curable resin 191 that is cured in the groove 85a functions as a locking mechanism that fixes movement of the lens resin portion 82a in a vertical direction (optical axis direction). Accordingly, in the lens-attached substrate 41a′, retention strength of the carrier substrate 81a with the lateral wall of the through-hole 83a is improved. Particularly, as the volume of the lens resin portion 82 of the lens-attached substrate 41, which uses the lamination-structure carrier substrate 81, is larger, the necessity for securement of strength with the lateral wall of the through-hole 83 further increases.

Furthermore, in the example in FIG. 59, the groove 85 (85a and 85e) is formed in an upper surface of a carrier configuration substrate 80 on a lower side (on a side close to the imaging unit 12) between two sheets of the carrier configuration substrates 80 which constitute the lamination-structure carrier substrate 81, but the groove 85 may be formed in a lower surface of a carrier configuration substrate 80 on an upper side (on a side distant from the imaging unit 12).

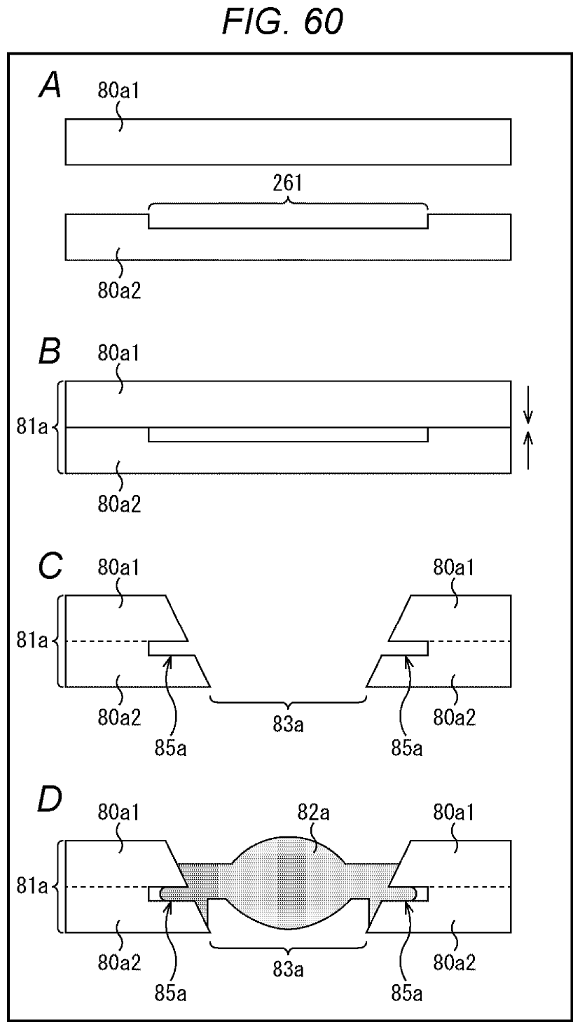

Description will be given of a first method of manufacturing the lens-attached substrate 41a′ in FIG. 59 with reference to FIG. 60A to FIG. 60D.

As illustrated in FIG. 60A, two sheets of carrier configuration substrates 80a1 and carrier configuration substrates 80a2 are prepared. Each of the carrier configuration substrates 80a is thinned to a desired thickness as necessary. In addition, in the carrier configuration substrate 80a2 that becomes a lower side in the carrier substrate 81a after bonding, a concave portion 261, which is obtained by reducing a substrate thickness by a predetermined thickness, is formed in a region that is symmetric to an optical axis (not illustrated in the drawing). The concave portion 261 can be formed by the above-described wet etching or dry etching.

Next, as illustrated in FIG. 60B, the carrier configuration substrate 80a1 and the carrier configuration substrate 80a2 in which the concave portion 261 is formed can be bonded to each other through direct joining. The resultant bonded substrate becomes the carrier substrate 81a.

Next, as illustrated in FIG. 60C, the through-hole 83a is formed in the carrier substrate 81a. Here, a diameter of the through-hole 83a at the bonding surface, which is indicated by a broken line, between the carrier configuration substrates 80a1 and 80a2 is smaller than a planar region of the concave portion 261, and a left portion of the concave portion 261 after the through-hole 83a is formed becomes the groove 85a.

Finally, as illustrated in FIG. 60D, the lens resin portion 82a is formed in the through-hole 83a of the carrier substrate 81a. A method of forming the lens resin portion 82a is similar to the method described with reference to FIG. 16A to FIG. 16G. The energy-curable resin 191 that is supplied (added dropwise) for filling (FIG. 16A to FIG. 16G) is cured in a state in which the energy-curable resin 191 also enters the groove 85a.

Furthermore, it is not necessary for the energy-curable resin 191 to enter the entirety of the inside of the groove 85a, and as in a gray region in FIG. 60D, a space (air gap) may be formed in a portion that is farthest from the lateral wall of the through-hole 83a. Whether or not the space is formed at a part of the inside of the groove 85a depends on the dropping amount of the energy-curable resin 191 that is added dropwise, shrinkage during curing, and the like.

As described above, the lens-attached substrate 41a′ including the groove 85a can be formed. Furthermore, in the case of forming the groove 85a in the carrier configuration substrate 80a1 on an upper side between the two sheets of carrier configuration substrates 80, in the process illustrated in FIG. 60A, the concave portion 261 may be formed in a lower surface of the carrier configuration substrate 80a1 on the upper side.

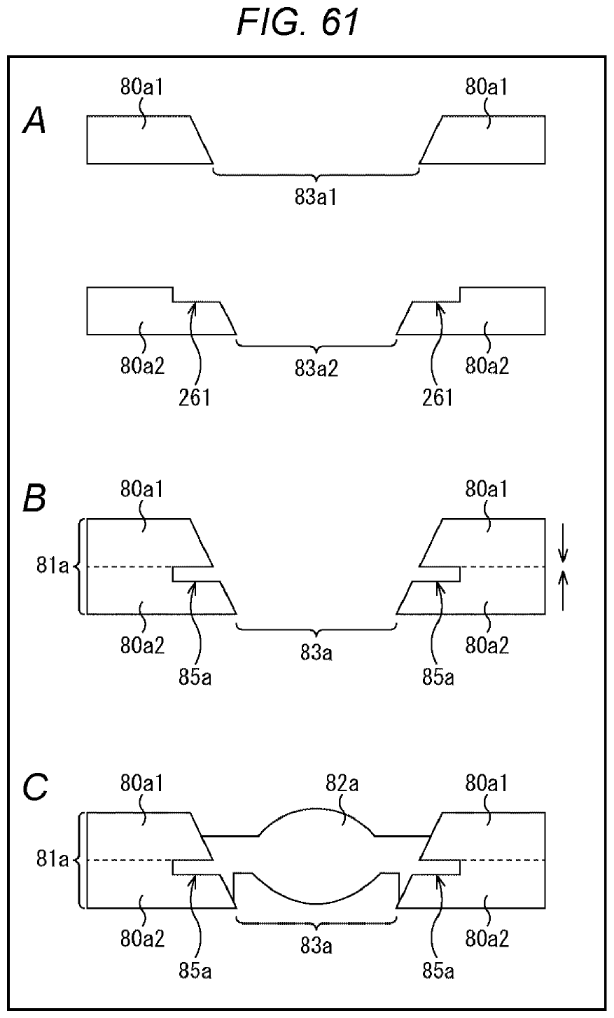

Next, description will be given of a second method of manufacturing the lens-attached substrate 41a′ in FIG. 59 with reference to FIG. 61A to FIG. 61C.

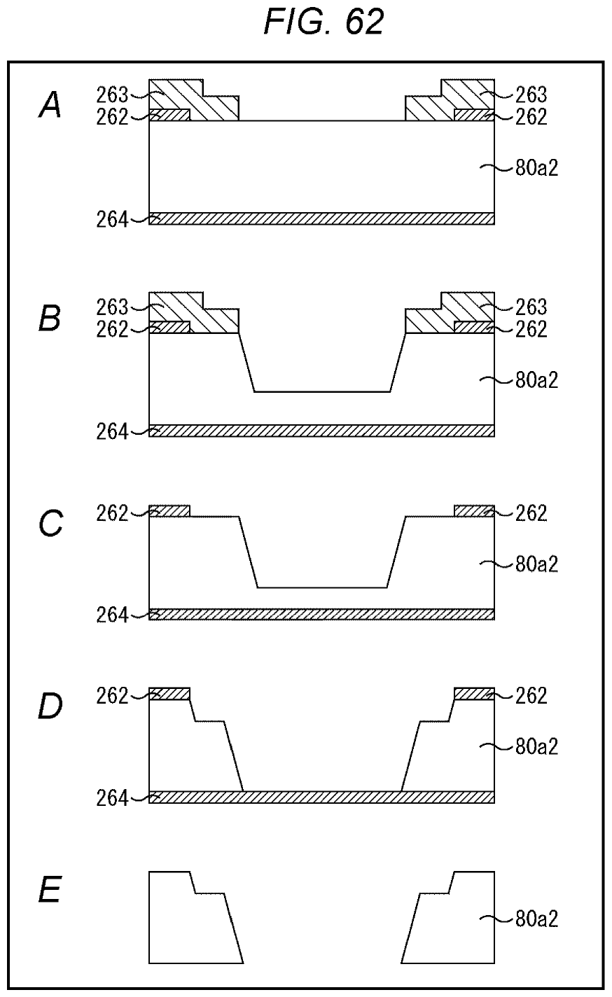

As illustrated in FIG. 61A, two sheets of carrier configuration substrate 80a1 and carrier configuration substrate 80a2 are prepared. A through-hole 83a1 is formed in the carrier configuration substrate 80a1, and a through-hole 83a2 is formed in the carrier configuration substrate 80a2. In addition, the concave portion 261, which becomes the groove 85a, is formed already in the carrier configuration substrate 80a2 that becomes a lower side in the carrier substrate 81a after bonding. Each of the carrier configuration substrates 80a is thinned to a desired thickness as necessary. A method of forming the carrier configuration substrate 80a2 including the through-hole 83a2 and the concave portion 261 will be described later with reference to FIG. 62A to FIG. 62E.

Next, as illustrated in FIG. 61B, the carrier configuration substrate 80a1 in which the through-hole 83a1 is formed, and the carrier configuration substrate 80a2 in which the through-hole 83a2 and the concave portion 261 are formed are bonded to each other through direct joining. The resultant bonded substrate becomes the carrier substrate 81a, and the through-holes 83a1 and 83a2 in the bonded state form one through-hole 83a. In addition, through the bonding, it enters a state in which an upward side of the concave portion 261 is covered with the carrier configuration substrate 80a1, and thus the groove 85a is formed.

Finally, as illustrated in FIG. 61C, the lens resin portion 82a is formed in the through-hole 83a of the carrier substrate 81a. A method of forming the lens resin portion 82a is similar to the method described with reference to FIG. 16A to FIG. 16G. The energy-curable resin 191 supplied for filling (FIG. 16A to FIG. 16G) is cured in a state in which the energy-curable resin 191 also enters the groove 85a. Furthermore, it is not necessary for the energy-curable resin 191 to enter the entirety of the inside of the groove 85a as in the first manufacturing method.

As described above, the lens-attached substrate 41a′ including the groove 85a can be formed. Furthermore, in the case of forming the groove 85a in the carrier configuration substrate 80a1 on an upper side between the two sheets of carrier configuration substrates 80, in the process illustrated in FIG. 61A, the concave portion 261 may be formed in a lower surface of the carrier configuration substrate 80a1 on the upper side.

Description will be given of a method of forming the carrier configuration substrate 80a2 in which the through-hole 83a1 and the concave portion 261 are formed as illustrated in FIG. 61A with reference to FIG. 62A to FIG. 62E.

First, as illustrated in FIG. 62A, an etching stop film 264 having resistance with respect to wet etching when opening a through-hole is formed on one surface (lower surface) of the carrier configuration substrate 80a2. For example, the etching stop film 264 can be set to a silicon nitride film.

Next, a first hard mask 262 and a second hard mask 263 which have resistance with respect to wet etching when opening the through-hole are formed on the other surface of the carrier configuration substrate 80a2 in conformity to a planar shape of the through-hole 83a2. For example, the first hard mask 262 and the second hard mask 263 also can be set to a silicon nitride film. The first hard mask 262 and the second hard mask 263 are different in an etching rate.

Next, as illustrated in FIG. 62B, the carrier configuration substrate 80a2 is etched by wet etching to a predetermined depth along an opening of the second hard mask 263.

Next, after the second hard mask 263 is removed as illustrated in FIG. 62C, as illustrated in FIG. 62D, the carrier configuration substrate 80a2 is etched along an opening of the first hard mask 262 through second wet etching until reaching the etching stop film 264.

Finally, as illustrated in FIG. 62E, the first hard mask 262 on the upper surface of the carrier configuration substrate 80a2 and the etching stop film 264 on the lower surface thereof are removed.

As described above, the first hard mask 262 and the second hard mask 263 are formed, and etching of the carrier configuration substrate 80a2 is divided into two times, and thus the carrier configuration substrate 80a2 illustrated in FIG. 61A is obtained.

Furthermore, the carrier configuration substrate 80a2 illustrated in FIG. 61A can be formed by using the method of forming the through-hole 83 having the stepped shape as described with reference to FIG. 50A to FIG. 50F.

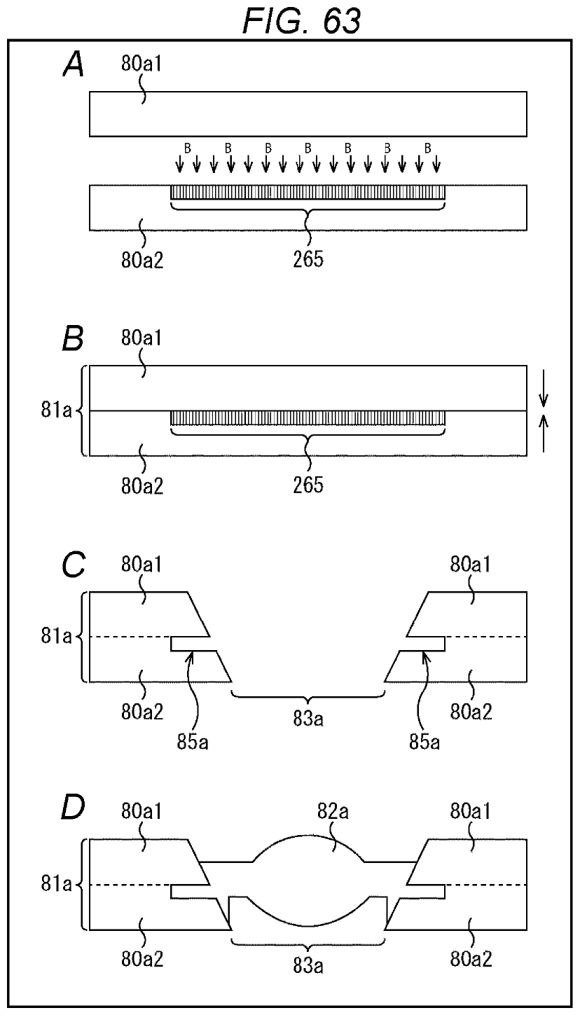

Next, description will be given of a third method of manufacturing the lens-attached substrate 41a′ in FIG. 59 with reference to FIG. 63A to FIG. 63D.

As illustrated in FIG. 63A, two sheets of carrier configuration substrate 80a1 and carrier configuration substrate 80a2 are prepared. In the carrier configuration substrate 80a2, a diffusion region 265, which is implanted with P-type ions such as boron and is annealed, is formed in a similar region as in the concave portion 261 in FIG. 60A to FIG. 60D.

Next, as illustrated in FIG. 63B, the carrier configuration substrate 80a1 and the carrier configuration substrate 80a2 in which the diffusion region 265 is formed can be bonded to each other through direct joining. The resultant bonded substrate becomes the carrier substrate 81a.

Next, as illustrated in FIG. 63C, the through-hole 83a is formed in the carrier substrate 81a through wet etching. At this time, an etching rate of the diffusion region 265, which is implanted with the P-type ions and is annealed, is high, and thus the groove 85a is formed simultaneously with the through-hole 83a.

Finally, as illustrated in FIG. 63D, the lens resin portion 82a is formed in the through-hole 83a of the carrier substrate 81a. A method of forming the lens resin portion 82a is similar to the method described with reference to FIG. 16A to FIG. 16G. Furthermore, it is not necessary for the energy-curable resin 191 to enter the entirety of the inside of the groove 85a as in the first manufacturing method.

As described above, the lens-attached substrate 41a′ including the groove 85a can be formed. Furthermore, in the case of forming the groove 85a in the carrier configuration substrate 80a1 on an upper side between the two sheets of carrier configuration substrates 80, in the process illustrated in FIG. 63A, the diffusion region 265 may be formed in a lower surface of the carrier configuration substrate 80a1 on the upper side.

Furthermore, it is possible to form the lens-attached substrate 41a′ by a method other than the above-described first to third manufacturing methods. For example, the through-hole 83a may be formed after bonding the two sheets of carrier configuration substrate 80a1 and carrier configuration substrate 80a2, and then the groove 85a may be formed. When forming the groove 85a after bonding, it is possible to employ a dry process of performing dry etching in a state in which a part of the lateral wall of the through-hole 83a is masked, laser processing, cutting processing, and the like.

The method of forming the groove 85a by the dry process, the laser processing, the cutting processing, and the like is also applicable to the case of forming the groove 85a in the single-layer-structure carrier substrate 81.

(Modification Example of Groove 85a)

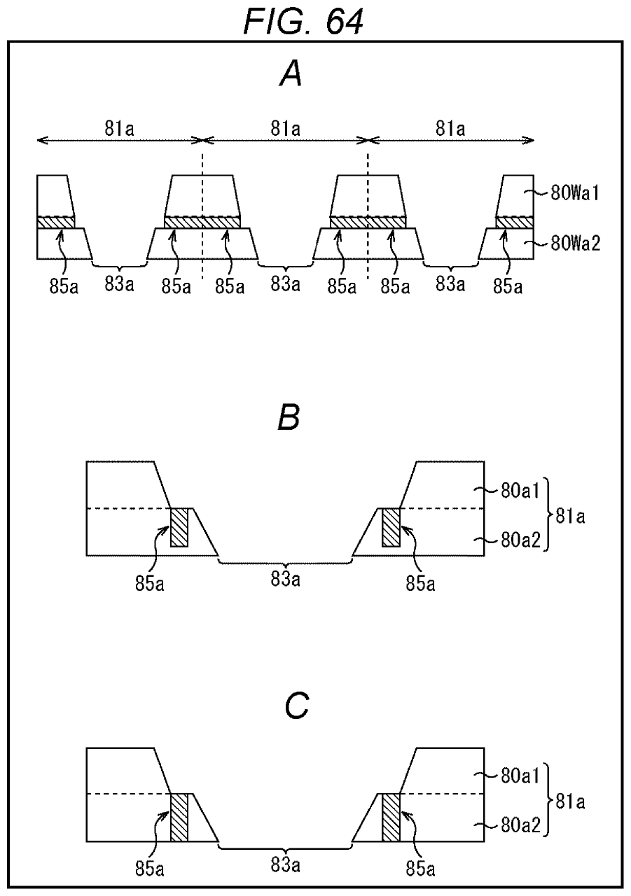

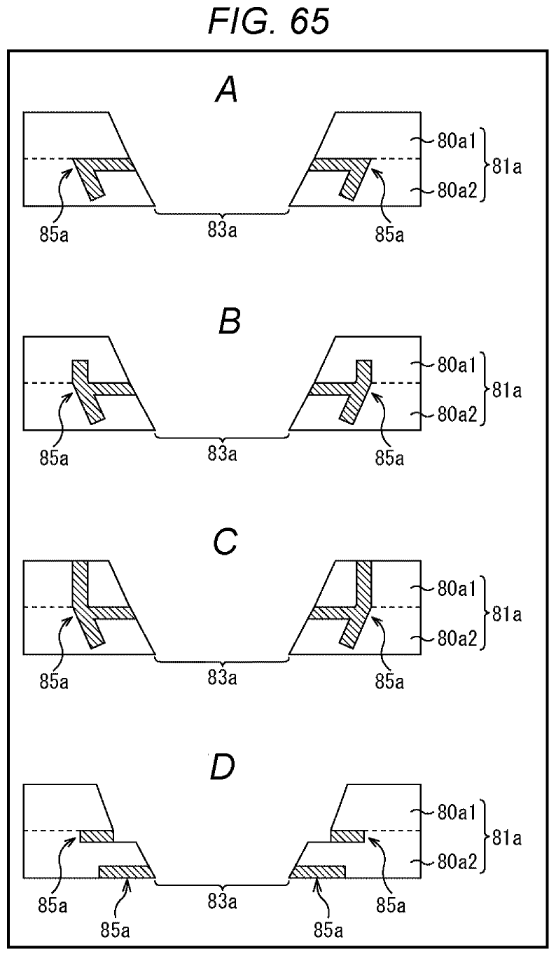

A modification example of the groove 85a will be described with reference to FIG. 64A to FIG. 64C and FIG. 65A to FIG. 65D.

As illustrated in FIG. 64A, in a substrate state, the groove 85a may have a penetration structure in a lateral direction (horizontal direction) to penetrate through an adjacent carrier substrate 81a.

As illustrated in FIG. 64B, the groove 85a may have a structure that is formed in a vertical direction (substrate depth direction).

As illustrated in FIG. 64C, the groove 85a may have a structure that penetrates through the carrier configuration substrate 80a2 in the vertical direction (substrate depth direction).

In addition, the groove 85a may be formed in an inclination direction having a predetermined angle without limitation to the horizontal direction or the vertical direction. In addition, the groove 85a may have the penetration structure or may not have the penetration structure.

In addition, as illustrated in FIG. 65A to FIG. 65C, the groove 85a may have a structure including two directions of the lateral direction (horizontal direction) and the vertical direction (substrate depth direction). Fixing strength of the lens resin portion 82a to the carrier substrate 81a is improved in combination of the lateral direction and the vertical direction.

FIG. 65A illustrates an example of the groove 85a in which the lateral direction and a downward direction are combined.

FIG. 65B illustrates an example of the groove 85a in which the lateral direction, an upward direction, and the downward direction are combined.

FIG. 65C illustrates an example of the groove 85a in which the lateral direction, the upward direction, and the downward direction are combined, and the groove 85a upwardly penetrates through the carrier configuration substrate 80a1. When the groove 85a penetrates through the carrier configuration substrate 80a1, it is possible to secure an air escape path when the groove 85a is filled with the energy-curable resin 191. Although not illustrated in the drawing, in contrast, the groove 85a may have a structure in which the lateral direction, the upward direction, and the downward direction are combined, and the groove 85a downwardly penetrates through the carrier configuration substrate 80a2.

FIG. 65D illustrates an example in which the groove 85a is formed in both of an upper surface and a lower surface of the carrier configuration substrate 80a2. When the groove 85a is provided in the upper surface and the lower surface, a contact area between the carrier configuration substrate 80a1 and the lens resin portion 82a increases, and thus fixing strength is improved.

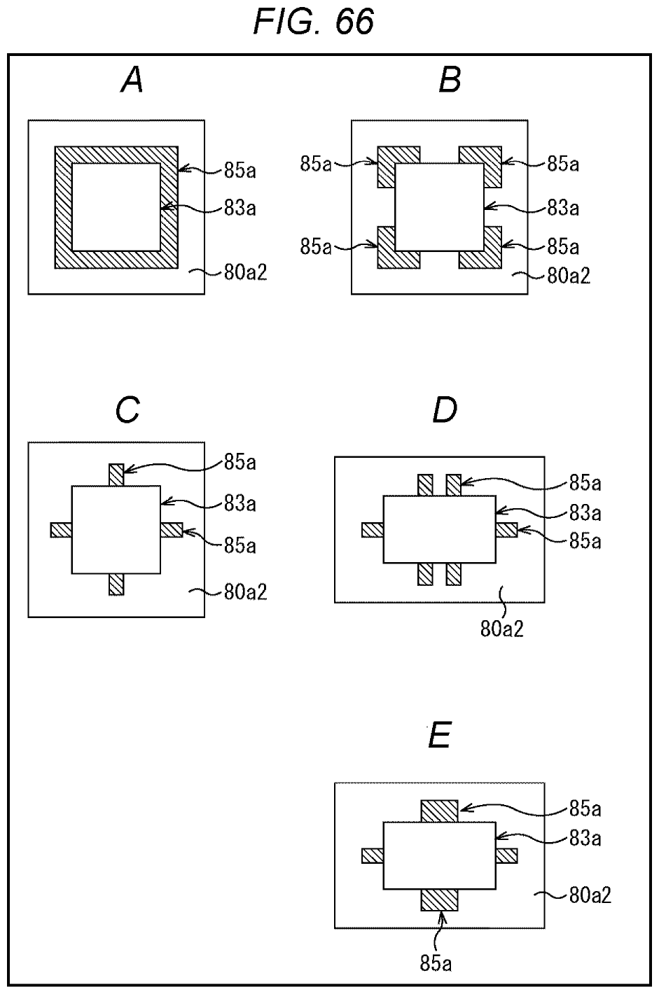

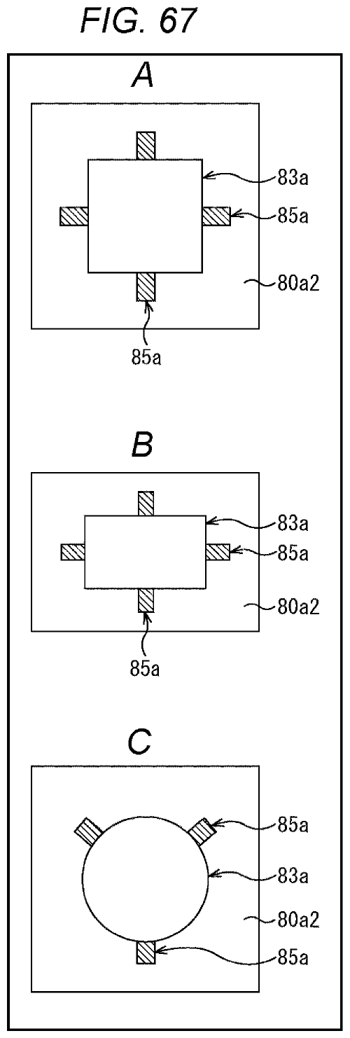

Next, description will be given of a shape of the groove 85a in a plane direction with reference to FIG. 66A to FIG. 66E and FIG. 67A to FIG. 67C.

FIG. 66A to FIG. 66E and FIG. 67A to FIG. 67C are plan views of the bonding surface of the carrier configuration substrates 80a1 and 80a2, and a hashed region represents a planar region of the groove 85a.

FIG. 66A illustrates an example in which the groove 85a is formed at the whole periphery (periphery) of a quadrangular through-hole 83a.

FIG. 66B illustrates an example in which the groove 85a is formed at four corners of the quadrangular through-hole 83a.

FIG. 66C illustrates an example in which the groove 85a is formed at the central portions of respective sides of a square through-hole 83a.

FIG. 66D and FIG. 66E illustrate an example in which the groove 85a is formed at the central portions of respective sides of a rectangular through-hole 83a, and a groove volume at a long side is set to be greater than a groove volume at a short side.

FIG. 66D illustrates an example in which the number of the grooves 85a having the same shape is set to be different between a short side and a long side of a quadrangular through-hole 83a so that the groove volume at the long side becomes greater than the groove volume at the short side.

FIG. 66E illustrates an example in which the shape (volume) of the groove 85a is set to be different between a short side and a long side of the quadrangular through-hole 83a so that the groove volume at the long side becomes greater than the groove volume at the short side.

Typically, the energy-curable resin 191 is added dropwise from the center of the through-hole 83a. In a case where the through-hole 83a has a quadrangular shape, first, the energy-curable resin 191 reaches the central portion of respective short sides between which a distance is short. Accordingly, as illustrated in FIG. 66C to FIG. 66E, when the groove 85a is formed at the central portion of respective sides, it is possible to prevent the resin from overflowing.

FIG. 67A to FIG. 67C illustrate an example of the groove 85a corresponding to a difference in the shape of the through-hole 83a.

Even though the planar shape of the through-hole 83a is any of a cubic shape as in FIG. 67A, a rectangular shape as in FIG. 67B, and a circular shape as in FIG. 67C, formation of the groove 85a is possible. Furthermore, the shape and arrangement of the groove 85a are not limited to the example in FIG. 67A to FIG. 67C, and an arbitrary shape and an arbitrary arrangement can be employed regardless of the shape of the through-hole 83a.

As described above, when the groove 85, into which the energy-curable resin 191 that is a material of the lens resin portion 82 enters, is formed in the lateral wall of the through-hole 83 of the lens-attached substrate 41, it is easy to control the dropping amount of the energy-curable resin 191, and it is easy to form the lens-attached substrate 41. In addition, after the energy-curable resin 191 is cured, retention strength of the lens resin portion 82 with the carrier substrate 81 enhanced, and thus reliability is improved.

Furthermore, as described above, the groove 85 is easily formed in a case where the carrier substrate 81 is constituted by the lamination-structure carrier substrate 81. However, even in the single-layer-structure carrier substrate 81, it is possible to form the groove 85 by using a dry process, laser processing, cutting processing, and the like. Accordingly, the groove 85 is also applicable to the lens-attached substrate 41 that uses the single-layer carrier substrate 81 without limitation to the lens-attached substrate 41 that uses the laminated carrier substrate 81.

<29. Modification Example of Laminated Lens Structure 11>

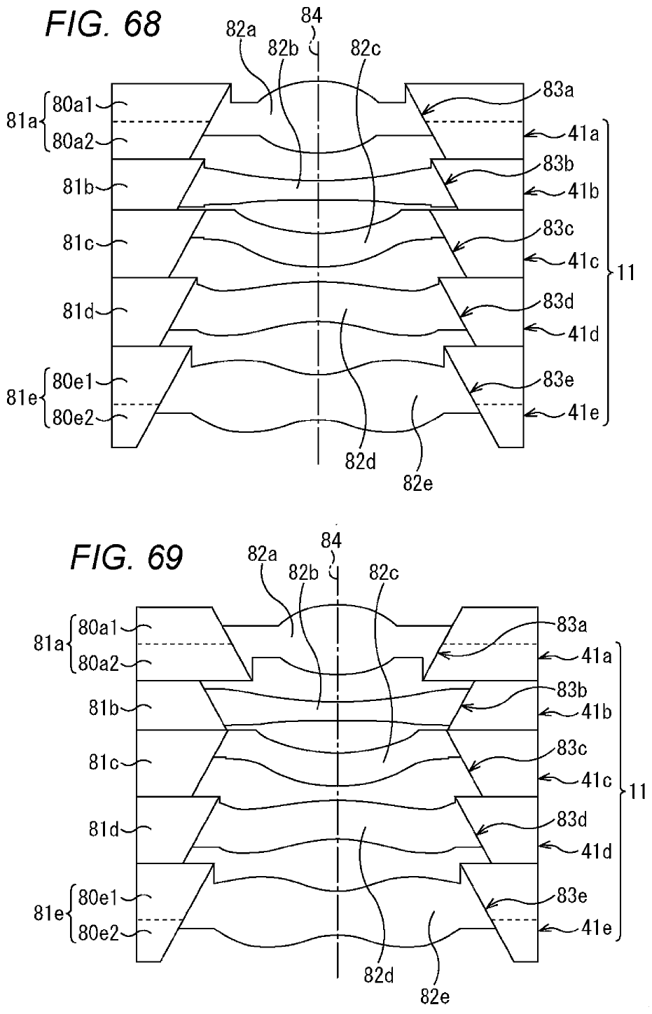

Next, modification examples of the laminated lens structure 11 will be described with reference to FIG. 68 to FIG. 73.

FIG. 68 is a cross-sectional view illustrating a first modification example of the laminated lens structure 11.

In respective modification examples in FIG. 68 to FIG. 73, description will be made with focus given to a portion different from the laminated lens structure 11 relating to the first configuration example illustrated in FIG. 2, and description of the same portions will be omitted.

In the laminated lens structure 11 relating to the first configuration example illustrated in FIG. 2, a cross-sectional shape of the through-hole 83 of the respective lens-attached substrates 41 which constitute the laminated lens structure 11 has a so-called downwardly narrowing shape in which an opening width decreases as it goes toward a lower side (side in which the imaging unit 12 is disposed).

In contrast, in the first modification example of the laminated lens structure 11 in FIG. 68, a cross-sectional shape of the through-hole 83 of the respective lens-attached substrates 41 which constitute the laminated lens structure 11 has a so-called downwardly spreading shape in which an opening width increases as it goes toward a lower side. In addition, a shape of a connection portion between the lens resin portion 82 and the through-hole 83 is different in correspondence with the cross-sectional shape of the through-hole 83.

As illustrated in FIG. 3, the laminated lens structure 11 of the camera module 1 has a structure in which incident light propagates in a downwardly spreading state from the opening 52 of the diaphragm plate 51 toward a lower side. In the downwardly spreading shape in which the opening width of the through-hole 83 increases as it goes toward a lower side, for example, the carrier substrate 81 is less likely to obstruct an optical path in comparison to the downwardly narrowing shape in which the opening width of the through-hole 83 decreases as it goes toward a lower side. According to this configuration, an operation in which the degree of freedom of lens design is high is exhibited.

In addition, with regard to a cross-sectional area of the lens resin portion 82 including the carrier portion 92 in a substrate plane direction, in the case of the downwardly narrowing shape in which the opening width of the through-hole 83 decreases as it goes toward a lower side, in a lower surface of the lens resin portion 82, the cross-sectional area becomes a specific size in order for light beams incident to the lens resin portion 82 to be transmitted therethrough, and the cross-sectional area increases as it goes toward an upper surface from the lower surface of the lens resin portion 82.

In contrast, in the case of the downwardly spreading shape in which the opening width of the through-hole 83 increases as it goes toward a lower side, the cross-sectional area in the lower surface of the lens resin portion 82 becomes approximately the same as in the downwardly narrowing shape, but the cross-sectional area decreases as it goes toward an upper surface from the lower surface of the lens resin portion 82.

Accordingly, in the structure in which the opening width of the through-hole 83 increases as it goes toward a lower side, it is possible to exhibit an operation or an effect capable of reducing the size of the lens resin portion 82 including the carrier portion 92. In addition, according to the structure, it is possible to exhibit an operation or an effect capable of reducing difficulty in lens formation in a case where the above-described lens is large.

FIG. 69 is a cross-sectional view illustrating a second modification example of the laminated lens structure 11.

Even in the second modification example of the laminated lens structure 11 in FIG. 69, the cross-sectional shape of the through-hole 83 of the respective lens-attached substrates 41 which constitute the laminated lens structure 11, and a shape of a connection portion between the lens resin portion 82 and the through-hole 83 are different from the first configuration example in FIG. 2.

The laminated lens structure 11 in FIG. 69 includes a lens-attached substrate 41 in which the cross-sectional shape of the through-hole 83 is set to a so-called downwardly narrowing shape in which the opening width decreases as it goes toward a lower side, and a lens-attached substrate 41 in which the cross-sectional shape of the through-hole 83 is set to a so-called downwardly spreading shape in which the opening width increases as it goes toward a lower side.

The lens-attached substrate 41 in which the through-hole 83 having a so-called downwardly narrowing shape in which the opening width decreases as it goes toward a lower side exhibits an operation or an effect in which incident light that comes into contact with the lateral wall of the through-hole 83 is reflected toward an upward direction, that is, a so-called incident side direction, and thus occurrence of stray light or noise light is suppressed.

Here, in the laminated lens structure 11 in FIG. 69, among a plurality of sheets of the lens-attached substrates 41 which constitute the laminated lens structure 11, particularly, in a plurality of sheets on an upper side (incident side), the lens-attached substrate 41, in which the cross-sectional shape of the through-hole 83 has a so-called downwardly narrowing shape in which the opening width decreases as it goes toward a lower side, is used.

In the lens-attached substrate 41 in which the cross-sectional shape of the through-hole 83 has a so-called downwardly spreading shape in which an opening width increases as it goes toward a lower side, the carrier substrate 81 provided in the lens-attached substrate 41 is less likely to obstruct an optical path, and thus it is possible to exhibit an operation or an effect capable of enhancing the degree of freedom of lens design or capable of reducing the size of the lens resin portion 82 including the carrier portion 92 that is provided in the lens-attached substrate 41.

In the laminated lens structure 11 in FIG. 69, light propagates in a downwardly spreading state as it goes toward a lower side from the diaphragm. Accordingly, among a plurality of sheets of the lens-attached substrates 41 which constitute the laminated lens structure 11, the size of the lens resin portion 82, which is provided in several sheets of the lens-attached substrates 41 disposed on a lower side, is great. In the large lens resin portion 82, when using the through-hole 83 having the downwardly spreading shape, the operation capable of reducing the size of the lens resin portion 82 is significantly exhibited.

Therefore, in the laminated lens structure 11 in FIG. 69, among the plurality of sheets of lens-attached substrates 41 which constitute the laminated lens structure 11, particularly, in a plurality of sheets on a lower side, the lens-attached substrate 41, in which the cross-sectional shape of the through-hole 83 has a so-called downwardly spreading shape in which the opening width increases as it goes toward a lower side, is used.

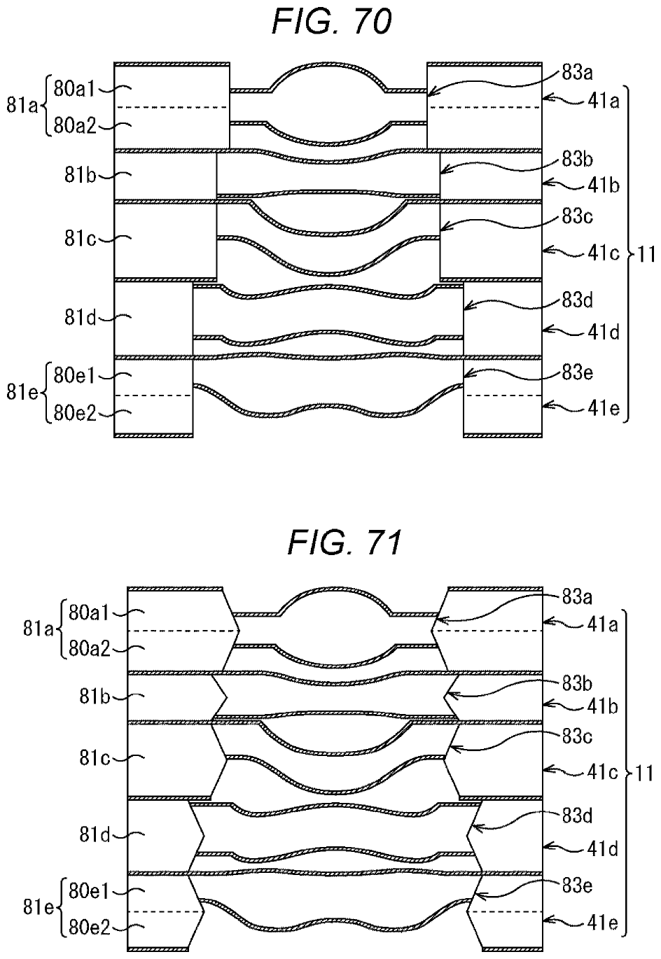

FIG. 70 is a cross-sectional view illustrating a third modification example of the laminated lens structure 11.

Even in the third modification example of the laminated lens structure 11 in FIG. 70, the cross-sectional shape of the through-hole 83 of the respective lens-attached substrates 41 which constitute the laminated lens structure 11, and a shape of a connection portion between the lens resin portion 82 and the through-hole 83 are different from the first configuration example in FIG. 2.

In the laminated lens structure 11 in FIG. 70, the cross-sectional shape of the through-hole 83 of the respective lens-attached substrate 41 is set to a vertical shape that is vertical from a light emission side to a light incidence side.

FIG. 71 is a cross-sectional view illustrating a fourth modification example of the laminated lens structure 11.

Even in the fourth modification example of the laminated lens structure 11 in FIG. 71, the cross-sectional shape of the through-hole 83 of the respective lens-attached substrates 41 which constitute the laminated lens structure 11, and a shape of a connection portion between the lens resin portion 82 and the through-hole 83 are different from the first configuration example in FIG. 2.

In the laminated lens structure 11 in FIG. 71, the lateral wall of the through-hole 83 of the respective lens-attached substrates 41 is formed in a double-tapered shape to expand from the central portion of the through-hole 83 toward both of the light emission side and the light incidence side. When the shape of the lateral wall of the through-hole 83 is set to the double-tapered shape, it is easier to form the light-shielding film 121 (FIG. 10). In addition, in this case, the contact portion of the lateral wall of the through-hole 83 with the lens resin portion 82 is set to a protruding shape, and thus it is possible to improve maintenance stability of the lens resin portion 82. In addition, in this case, the through-hole 83 is formed by performing etching from both surfaces of the carrier substrate 81, and thus it is possible to further shorten a processing time in etching of the lateral wall of the through-hole 83 in comparison to the case of a different shape.

Furthermore, in lens-attached laminated substrates 41a and 41e which use the laminated carrier substrate 81 in FIG. 71, a bonding surface of the carrier configuration substrate 80, which is indicated by a broken line, matches a shape-switching portion of the lateral wall of the through-hole 83, but it is not necessary for the bonding surface to match the shape-switching portion.

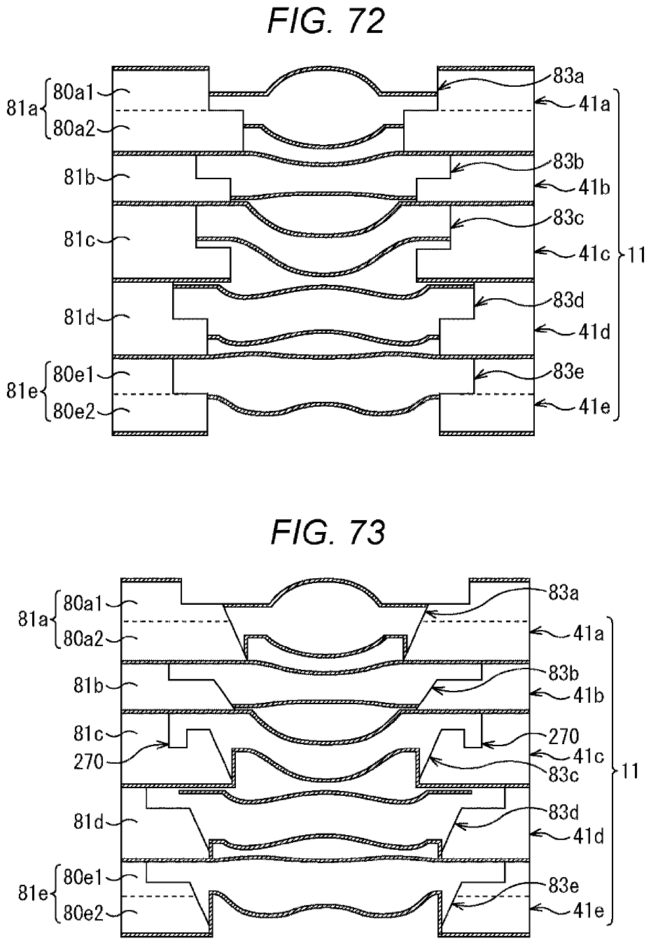

FIG. 72 is a cross-sectional view illustrating a fifth modification example of the laminated lens structure 11.

Even in the fifth modification example of the laminated lens structure 11 in FIG. 72, the cross-sectional shape of the through-hole 83 of the respective lens-attached substrates 41 which constitute the laminated lens structure 11, and a shape of a connection portion between the lens resin portion 82 and the through-hole 83 are different from the first configuration example in FIG. 2.

In the laminated lens structure 11 in FIG. 72, the lateral wall of the through-hole 83 of the respective lens-attached substrates 41 is formed in a stepped shape in which a step difference is formed partway through the through-hole 83. In addition, the cross-sectional shape of the through-hole 83 of the respective lens-attached substrates 41 is set to a vertical shape that is vertical from the light emission side to the light incidence side.

Furthermore, in lens-attached laminated substrates 41a and 41e which use the laminated carrier substrate 81 in FIG. 72, a bonding surface of the carrier configuration substrate 80, which is indicated by a broken line, matches a stepped portion of the lateral wall of the through-hole 83, but it is not necessary for the bonding surface to match the stepped portion.

FIG. 73 is a cross-sectional view illustrating a sixth modification example of the laminated lens structure 11.

Even in the sixth modification example of the laminated lens structure 11 in FIG. 73, the cross-sectional shape of the through-hole 83 of the respective lens-attached substrates 41 which constitute the laminated lens structure 11, and a shape of a connection portion between the lens resin portion 82 and the through-hole 83 are different from the first configuration example in FIG. 2.

In the laminated lens structure 11 in FIG. 73, the lateral wall of the through-hole 83 of the respective lens-attached substrates 41 is formed in a stepped shape in which a step difference is formed partway through the through-hole 83. In addition, in the through-hole 83, a cross-sectional shape on an upper side, in which an opening width of the stepped lateral wall is large, is set to a vertical shape.

In lens-attached laminated substrates 41a and 41e which use the laminated carrier substrate 81 in FIG. 73, a bonding surface of the carrier configuration substrate 80, which is indicated by a broken line, does not match the stepped portion of the lateral wall of the through-hole 83, and is set to a predetermined position of the lateral wall having a downwardly narrowing shape in which an opening width is small.

In addition, in the lens-attached laminated substrate 41a, a flat surface of the upper surface of the lens resin portion 82a matches the stepped portion of the lateral wall of the through-hole 83a. In contrast, in the lens-attached laminated substrate 41b, a flat surface of the lens resin portion 82b matches an upper surface of the carrier substrate 81b. With this arrangement, in the lens-attached laminated substrate 41b, the lens resin portion 82b is formed on the stepped portion of the through-hole 83a.

In addition, in the lens-attached laminated substrate 41c, the lateral wall of the through-hole 83c is formed in a stepped shape, and a groove 270 that is vertically recessed is formed in an upper end portion of the stepped shape. The groove 270 can attain a similar operational effect as in the groove 85 described in FIG. 59 and the like. That is, the energy-curable resin 191 is added dropwise, the groove 270 serves as a space that is a retreating site of an excessive energy-curable resin 191, and improves retention strength of the lens resin portion 82c with respect to the lateral wall of the through-hole 83c of the carrier substrate 81c.

As the shape of the lateral wall of the through-hole 83, an arbitrary shape other than the shapes described with reference to FIG. 68 to FIG. 73 can be employed.

The second to thirteenth configuration examples of the laminated lens structure 11 and modification examples thereof described above can be arbitrarily substituted with the first configuration example of the laminated lens structure 11 embedded in the camera module 1 in FIG. 1.

<30. Modification Example of Diaphragm Plate 51>

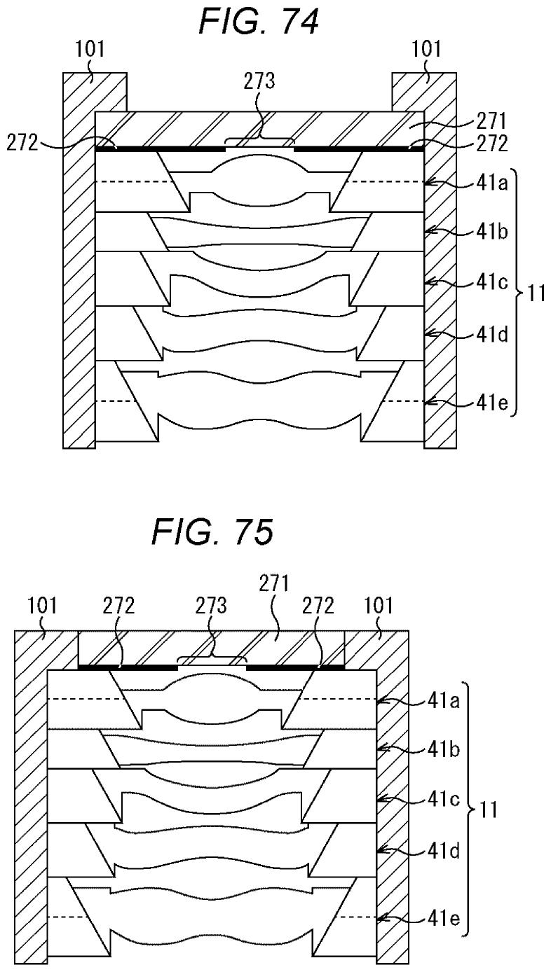

Next, a modification example of the diaphragm plate 51 will be described with reference to FIG. 74 to FIG. 76.

Cover glass may be provided on an upper portion of the laminated lens structure 11 to protect a surface of the lens resin portion 82 of the laminated lens structure 11. In this case, the cover glass can have an optical diaphragm function as in the diaphragm plate 51.

FIG. 74 is a view illustrating a first configuration example in which the cover glass has the optical diaphragm function.

In the first configuration example in which the cover glass has the optical diaphragm function as illustrated in FIG. 74, cover glass 271 is also laminated on an upper portion of the laminated lens structure 11. In addition, a lens barrel 101 is disposed on an outer side of the laminated lens structure 11 and the cover glass 271.

A light-shielding film 272 is formed on a surface of the cover glass 271 on the lens-attached substrate 41a side (in the drawing, a lower surface of the cover glass 271). Here, in the respective lens-attached substrates 41a to 41e, the light-shielding film 272 is not formed in a predetermined range from the lens center (optical center) and the predetermined range is formed as an opening 273. The opening 273 functions as an optical diaphragm. With this arrangement, for example, the diaphragm plate 51, which is provided in the camera module 1a in FIG. 1, is omitted.

According to the first configuration example of the optical diaphragm function that uses the cover glass illustrated in FIG. 74, the optical diaphragm is formed through application, and the light-shielding film 272 can be formed in a film thickness as small as approximately 1 μm, and thus it is possible to suppress optical performance deterioration (light reduction at a peripheral portion) caused by shielding-off of incident light when the diaphragm mechanism has a predetermined thickness.

A surface of the light-shielding film 272 may be rough. In this case, it is possible to reduce surface reflection from the surface of the cover glass 271 provided with the light-shielding film 272, and it is possible to increase a surface area of the light-shielding film 272. Accordingly, it is possible to improve joining strength between the cover glass 271 and the lens-attached substrate 41.

Examples of a method of forming the surface of the light-shielding film 272 as a rough surface include a method in which a light absorbing material that becomes the light-shielding film 272 is applied and the light absorbing material that is applied is processed into a rough surface through etching and the like, a method in which cover glass 271 before application of the light absorbing material is formed in a rough surface and then the light absorbing material is applied, a method in which unevenness is caused to occur on a surface due to aggregating light absorbing material after film formation, a method in which unevenness is caused to occur on a surface due to a light absorbing material containing a solid content after film formation, and the like.

In addition, an antireflection film may be formed between the light-shielding film 272 and the cover glass 271.

When the cover glass 271 also serves as a diaphragm support substrate, it is possible to reduce the size of the camera module 1.

FIG. 75 is a view illustrating a second configuration example in which the cover glass has the optical diaphragm function.

In the second configuration example in which the cover glass has the optical diaphragm function as illustrated in FIG. 75, the cover glass 271 is disposed at a position of an opening of the lens barrel 101. The other configurations are the same as in the first configuration example illustrated in FIG. 74.

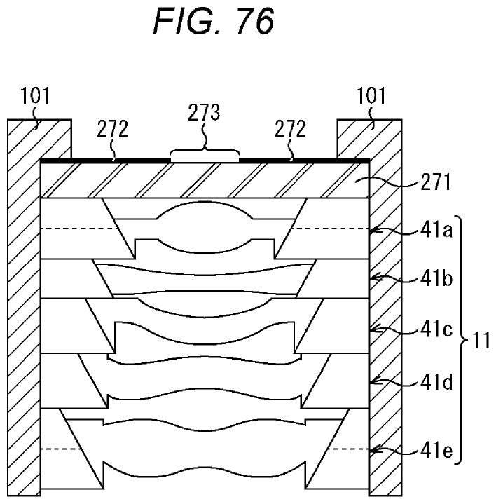

FIG. 76 is a view illustrating a third configuration example in which the cover glass has the optical diaphragm function.

In the third configuration example in which the cover glass has the optical diaphragm function as illustrated in FIG. 76, the light-shielding film 272 is formed on an upper surface of the cover glass 271, that is, on a side opposite to the lens-attached substrate 41a. The other configurations are the same as in the first configuration example as illustrated in FIG. 74.

Furthermore, even in the configuration in which the cover glass 271 is disposed in an opening of the lens barrel 101 as illustrated in FIG. 75, the light-shielding film 272 may be formed on the upper surface of the cover glass 271.

<31. Second Embodiment of Camera Module 1>

The camera module 1 includes a mechanism that adjusts a focal length of incident light that is condensed by the laminated lens structure 11. However, as the focal length adjusting mechanism, a configuration other than the configuration illustrated in FIG. 1 can be employed.

Here, hereinafter, description will be given of other embodiments of the camera module 1 employing another focal length adjusting mechanism.

First, a second embodiment of the camera module will be described.

In addition, even in the following respective embodiments from the second embodiment of the camera module 1, basically, description will be made by using a configuration example in combination with the first configuration example illustrated in FIG. 2 as the laminated lens structure 11, but a combination with the laminated lens structure 11 relating to the second to thirteenth configuration examples, and the respective modification examples is also possible.

In other words, the camera module 1 in the present disclosure can employ an arbitrary structure in which the configuration examples of the laminated lens structure 11, a focal length adjusting mechanism mounted in a camera module including the laminated lens structure 11, the optical diaphragm function, a monocular structure, a binocular structure, and the like are combined in an arbitrary combination.

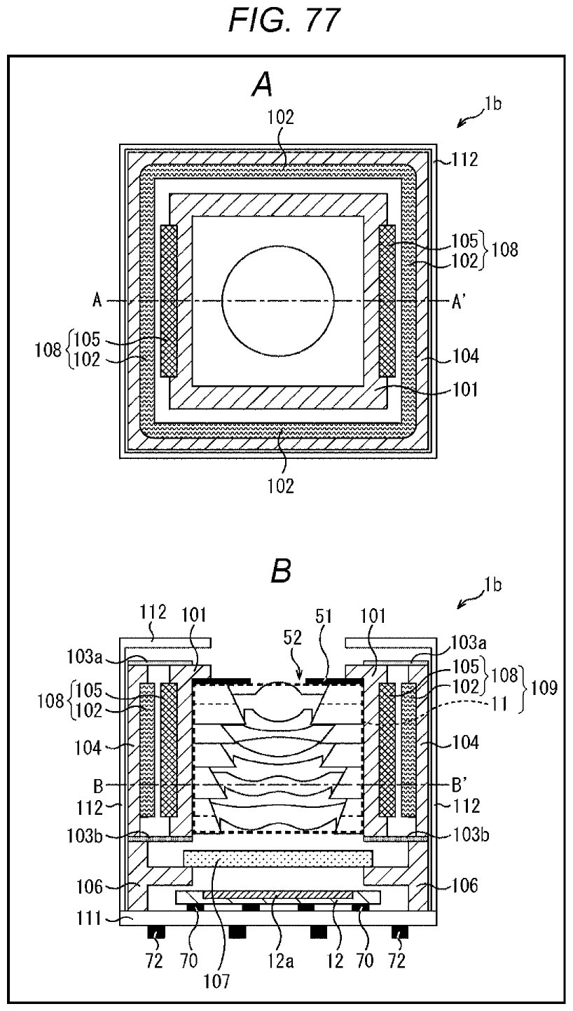

FIG. 77A and FIG. 77B are views illustrating the second embodiment of the camera module to which the present technology is applied.

FIG. 77A is a plan view of a camera module 1b as the second embodiment of the camera module 1, and FIG. 77B is a cross-section view of the camera module 1b.

FIG. 77A is a plan view taken along line B-B′ in the cross-sectional view in FIG. 77B, and FIG. 77B is a cross-sectional view taken along line A-A′ in the plan view in FIG. 77A.

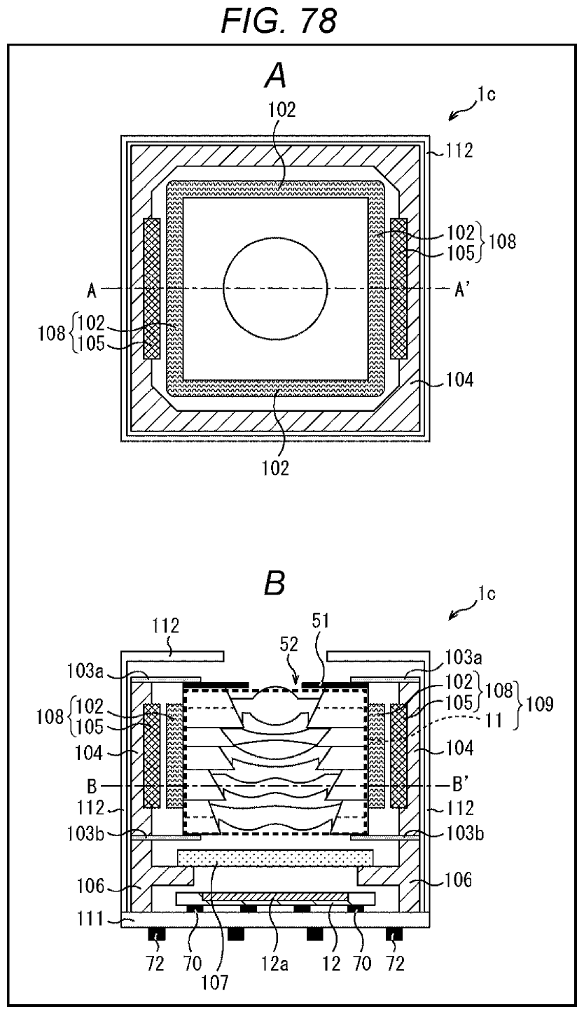

In FIG. 77A and FIG. 77B, the same reference numeral will be given to a portion corresponding to the camera module 1a illustrated in FIG. 1, and description thereof will be appropriately omitted. Description will be made with focus given to other portions. Even in other embodiments to be described in FIG. 78A and FIG. 78B and thereafter, description of portions described already will be appropriately omitted.

The camera module 1b illustrated in FIG. 77A and FIG. 77B includes the coil 102 for AF and the magnet 105 for AF which constitute the AF drive unit 108 as in the camera module 1a illustrated in FIG. 1. The camera module 1b includes a focal length adjusting mechanism that adjusts a distance between the laminated lens structure 11 and the imaging unit 12.

The camera module 1b in FIG. 77A and FIG. 77B is different from the camera module 1a in FIG. 1 in that a mounting position of the coil 102 for AF and the magnet 105 for AF, which constitute the AF drive unit 108, is opposite to the camera module 1a.

That is, in the camera module 1a illustrated in FIG. 1, the coil 102 for AF is bonded and fixed to the outer periphery side of the lens barrel 101, and the magnet 105 for AF is bonded and fixed to the inner periphery side of the first fixing and supporting portion 104. In contrast, in the camera module 1b in FIG. 77A and FIG. 77B, the magnet 105 for AF is bonded and fixed to the outer periphery side of the lens barrel 101, and the coil 102 for AF is bonded and fixed to the inner periphery side of the first fixing and supporting portion 104.

The first fixing and supporting portion 104 includes an overhang portion that overhangs toward an inner periphery side on an upper surface that is farthest from the imaging unit 12, and has an approximately L-shaped cross-sectional shape. When the coil 102 for AF is bonded and fixed to the first fixing and supporting portion 104, the coil 102 for AF is positioned to come into contact with the overhang portion on the inner periphery side and is bonded and fixed to the first fixing and supporting portion 104.

In addition, the camera module 1b and the camera module 1a are different in the number of the magnet 105 for AF that is mounted.

That is, in the camera module 1a illustrated in FIG. 1, the magnet 105 for AF is mounted on four inner peripheral surfaces of a quadrangular cylindrical shape, and thus the camera module 1a includes a total of four magnets 105 for AF. In contrast, in the camera module 1b in FIG. 77A and FIG. 77B, the magnet 105 for AF is mounted on two outer peripheral surfaces, which are opposite to each other, among the four outer peripheral surfaces of the lens barrel 101, and thus the camera module 1b includes a total of two magnets 105 for AF.

Furthermore, the number of the magnet 105 for AF that is mounted may be either two or four. That is, the camera module 1a in FIG. 1 may be provided with two magnets 105 for AF at positions opposite to each other, or the camera module 1b in FIG. 77A and FIG. 77B may be provided with four magnets 105 for AF.

The camera module 1b having the above-described configuration exhibits similar operation or effect as in the camera module 1a in FIG. 1.

That is, the camera module 1b exhibits the following operation or effect. When the imaging unit 12 captures an image, a distance between the laminated lens structure 11 and the imaging unit 12 can be changed by the AF drive unit 108, and an auto focus operation can be performed.

In addition, in a case where the laminated lens structure 11 is not employed as a configuration of a laminated lens in which a plurality of sheets of lenses are laminated in the optical axis direction, a process of loading lens-attached substrates into the lens barrel sheet by sheet is necessary in a number corresponding to the number of lenses which are provided in the camera module.

In contrast, in the case of employing the laminated lens structure 11 as the configuration of the laminated lens in which a plurality of sheets of lenses are laminated in the optical axis direction, only after loading the laminated lens structure 11, in which a plurality of sheets of lens-attached substrates 41 are integrated in the optical axis direction, into the lens barrel 101 once, assembly of the laminated lens and the lens barrel is terminated.

Accordingly, the camera module 1b exhibits an operational effect in which module assembly is easier and a variation in a central position of the respective lens resin portions 82, which is caused by a variation in a loading process, does not occur in comparison to the case of loading the lens-attached substrates 41 sheet by sheet.

In addition, in the assembly of the laminated lens structure 11 to the lens barrel 101, positioning is only performed in order for the laminated lens structure 11 to come into contact with the overhang portion that overhangs in the inner periphery side direction perpendicular to the optical axis direction. In assembly of the coil 102 for AF to the first fixing and supporting portion 104, positioning is only performed in order for the coil 102 for AF to come into contact with the overhang portion that overhangs in the inner periphery side direction perpendicular to the optical axis direction. With this arrangement, alignment of the laminated lens structure 11 and the AF drive unit 108 becomes easy and module assembly becomes easy.

Furthermore, in FIG. 77A and FIG. 77B, the overhang portion is provided on the upper surface side of the first fixing and supporting portion 104, and the coil 102 for AF is brought into upward contact with the overhang portion in the drawing. However, the overhang portion may be provided on the lower surface side of the first fixing and supporting portion 104, and the coil 102 for AF may be brought into downward contact with the overhang portion in the drawing.

The laminated lens structure 11 of the camera module 1 relating to the second embodiment can be combined with the laminated lens structure 11 relating to any one of the first to thirteenth configuration examples and the modification examples.

<32. Third Embodiment of Camera Module 1>

FIG. 78A and FIG. 78B are views illustrating a third embodiment of the camera module to which the present technology is applied.

FIG. 78A is a plan view of a camera module 1c as the third embodiment of the camera module 1, and FIG. 78B is a cross-section view of the camera module 1c.

FIG. 78A is a plan view taken along line B-B′ in the cross-sectional view in FIG. 78B, and FIG. 78B is a cross-sectional view taken along line A-A′ in the plan view in FIG. 78A.

The camera module 1c in FIG. 78A and FIG. 78B is different from the camera module 1a in FIG. 1 in that the lens barrel 101 accommodating the laminated lens structure 11 is omitted.

That is, in the camera module 1c in FIG. 78A and FIG. 78B, the lens barrel 101 is omitted, and the coil 102 for AF, the suspensions 103a and 103b are directly bonded and fixed to a part of lens-attached substrates 41 which constitute the laminated lens structure 11, and the diaphragm plate 51. The coil 102 for AF is spirally wound around an outer periphery of a part of the lens-attached substrates 41 which constitute the laminated lens structure 11.

When the lens barrel 101 is omitted, it is possible to exhibit an operation or an effect capable of further reducing the size of the camera module 1c in comparison to the camera module 1a and the camera module 1b which use the lens barrel 101. In addition, when the lens barrel 101 is omitted, it is possible to exhibit an operation or an effect capable of further suppressing the manufacturing cost of the camera module 1c in comparison to the camera module 1a and the camera module 1b.

The camera module 1c exhibits an operation or an effect capable of performing the auto focus operation as in the camera module 1a in FIG. 1. In addition, since the laminated lens structure 11, in which a plurality of sheets of the lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

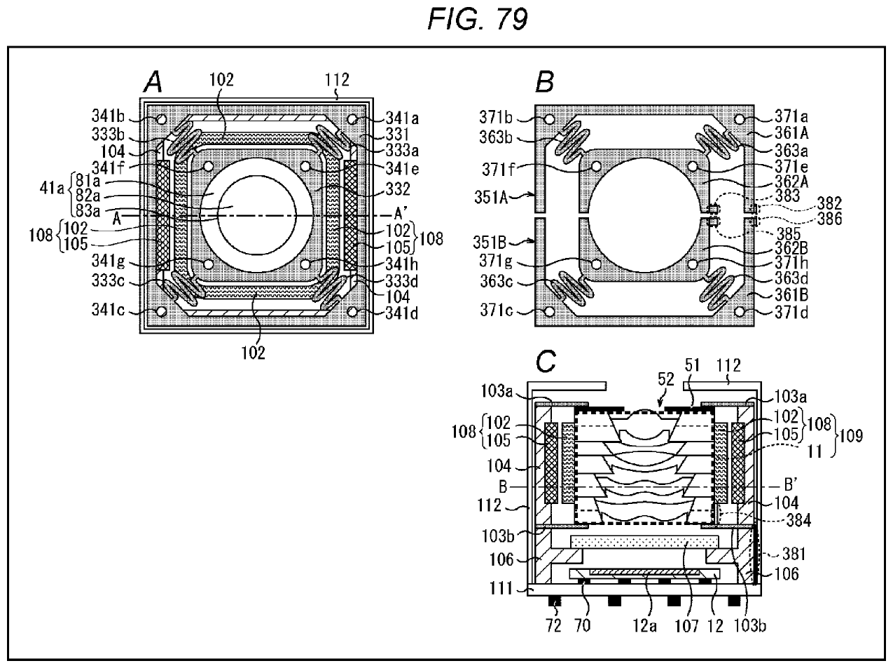

Description will be given of a planar shape of the suspensions 103a and 103b with reference to the camera module 1c relating to the third embodiment as an example with reference to FIG. 79A to FIG. 79C.

FIG. 79A is a plan view when the camera module 1c in FIG. 78A and FIG. 78B is seen from the suspension 103a in a direction (downward direction) of the imaging unit 12, and FIG. 79B is a plan view of the suspension 103b alone.

FIG. 79C is a cross-sectional view of the camera module 1c for illustrating a path of a current that flows through the coil 102 for AF.

As illustrated in FIG. 79A, the suspension 103a includes a first fixing plate 331 that is bonded and fixed to the first fixing and supporting portion 104, a second fixing plate 332 that is bonded and fixed to the diaphragm plate 51 on an upper side of the laminated lens structure 11, and connection springs 333a to 333d which connect the first fixing plate 331 and the second fixing plate 332 at four corners.

Positioning holes 341a to 341d, which are used for positioning when being bonded and fixed to the first fixing and supporting portion 104, are formed in the first fixing plate 331.

Positioning holes 341e to 341h, which are used for positioning when being bonded and fixed to the diaphragm plate 51 on an upper side of the laminated lens structure 11, are formed in the second fixing plate 332.

On the other hand, as illustrated in FIG. 79B, the suspension 103b includes two sheets of divided fixing plates 351A and 351B which are evenly divided into two pieces by a line segment that passes through the center of the optical axis and connects the two magnets 105 for AF. Furthermore, a division direction of the two sheets of divided fixing plates 351A and 351B may be a direction perpendicular to the line segment that connects the two magnets 105 for AF.

The divided fixing plate 351A includes a first fixing plate 361A that is bonded and fixed to the first fixing and supporting portion 104, a second fixing plate 362A that is bonded and fixed to the lens-attached substrate 41e in the lowermost layer of the laminated lens structure 11, and connection springs 363a and 363b which connect the first fixing plate 361A and the second fixing plate 362A to each other.

Positioning holes 371a and 371b, which are used for positioning when being bonded and fixed to the first fixing and supporting portion 104, are formed in the first fixing plate 361A.

Positioning holes 371e and 371f, which are used for positioning when being bonded and fixed to the lens-attached substrate 41e in the lowermost layer of the laminated lens structure 11, are formed in the second fixing plate 362A.

On the other hand, the divided fixing plate 351B includes a first fixing plate 361B that is bonded and fixed to the first fixing and supporting portion 104, a second fixing plate 362B that is bonded and fixed to the lens-attached substrate 41e in the lowermost layer of the laminated lens structure 11, and connection springs 363c and 363d which connect the first fixing plate 361B and the second fixing plate 362B to each other.

Positioning holes 371c and 371d, which are used for positioning when being bonded and fixed to the first fixing and supporting portion 104, are formed in the first fixing plate 361B.

Positioning holes 371g and 371h, which are used for positioning when being bonded and fixed to the lens-attached substrate 41e in the lowermost layer of the laminated lens structure 11, are formed in the second fixing plate 362B.

The suspensions 103a and 103b are manufactured, for example, through press forming of a metal plate such as Cu and Al, and have a function as an electric wire through which a current flows.

For example, a current that flows through the coil 102 for AF flows through an outer peripheral portion 381 of the second fixing and supporting portion 106 illustrated in FIG. 79C, and reaches a connection point 382 of the first fixing plate 361A illustrated in FIG. 79B. In addition, the current flows from the connection point 382 of the first fixing plate 361A to the connection spring 363a and the second fixing plate 362A, and reaches the coil 102 for AF through an outer peripheral portion 384 of the laminated lens structure 11 illustrated in FIG. 79C from a connection point 383.

Then, the current, which flows through the coil 102 for AF, reaches a connection point 385 of the second fixing plate 362B through the outer peripheral portion 384 of the laminated lens structure 11 illustrated in FIG. 79C. In addition, the current flows from the connection point 385 of the second fixing plate 362B to the connection spring 363d and the first fixing plate 361B, and reaches the module substrate 111 through the outer peripheral portion 381 of the second fixing and supporting portion 106 illustrated in FIG. 79C from a connection point 386.

The laminated lens structure 11 of the camera module 1 relating to the third embodiment can be combined with the laminated lens structure 11 relating to any one of the first to thirteenth configuration examples and the modification examples.

<33. Modification Example of Third Embodiment of Camera Module 1>

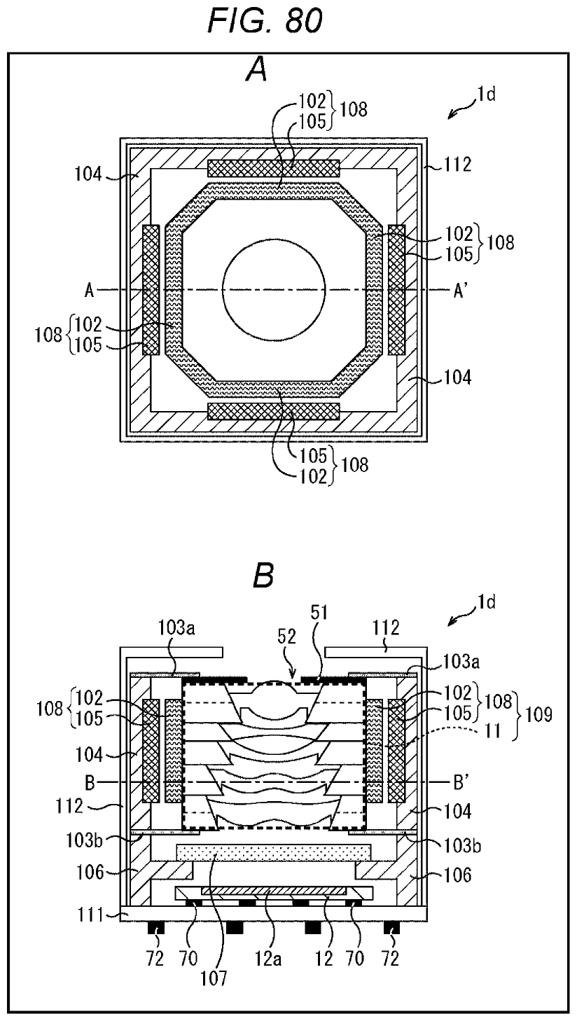

FIG. 80A and FIG. 80B are views illustrating a first modification example of the third embodiment of the camera module to which the present technology is applied.

FIG. 80A is a plan view of a camera module 1d relating to the first modification example of the third embodiment, and FIG. 80B is a cross-sectional view of the camera module 1d relating to the first modification example of the third embodiment.

FIG. 80A is a plan view taken along line B-B′ in the cross-sectional view in FIG. 80B, and FIG. 80B is a cross-sectional view taken along line A-A′ in the plan view in FIG. 80A.

The camera module 1d relating to the first modification example of the third embodiment as illustrated in FIG. 80A and FIG. 80B is different from the camera module 1c of the third embodiment illustrated in FIG. 78A and FIG. 78B in that corner portions of four corners of each of the lens-attached substrates 41, which constitute the laminated lens structure 11, are linearly removed, and a planar shape of the lens-attached substrate 41 is set to an approximately octagon as can be clearly understood from comparison between the plan view in FIG. 80A and the plan view in FIG. 78A.

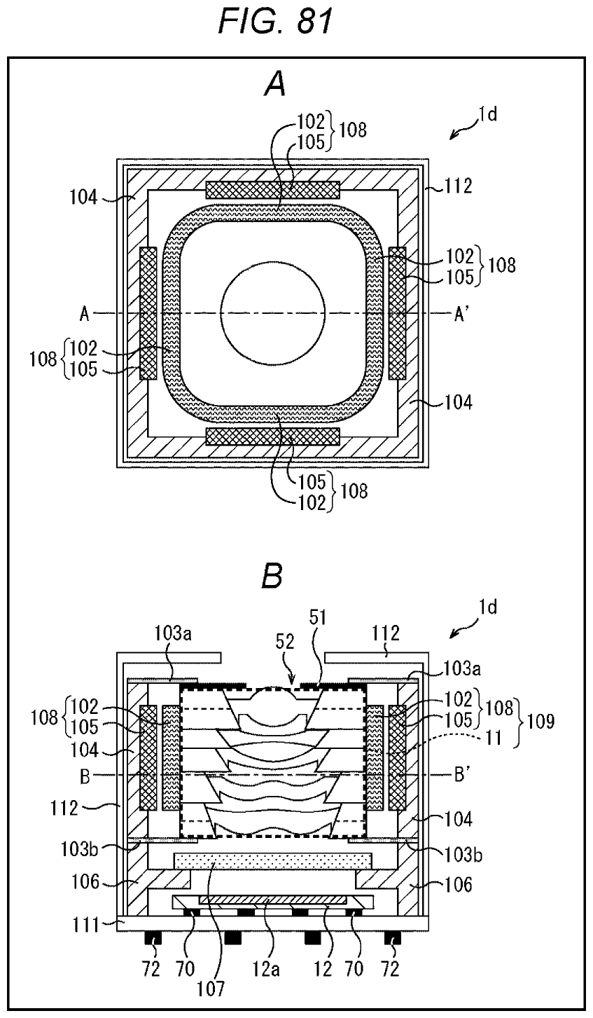

FIG. 81A and FIG. 81B are views illustrating a second modification example of the third embodiment of the camera module to which the present technology is applied.

FIG. 81A is a plan view of a camera module 1d relating to the second modification example of the third embodiment, and FIG. 81B is a cross-sectional view of the camera module 1d relating to the second modification example of the third embodiment.

FIG. 81A is a plan view taken along line B-B′ in the cross-sectional view in FIG. 81B, and FIG. 81B is a cross-sectional view taken along line A-A′ in the plan view in FIG. 81A.

The camera module 1d relating to the second modification example of the third embodiment as illustrated in FIG. 81A and FIG. 81B is different from the camera module 1c of the third embodiment illustrated in FIG. 78A and FIG. 78B in that corner portions of four corners of each of the lens-attached substrates 41, which constitute the laminated lens structure 11, are removed in conformity to a curved line, and a planar shape of the lens-attached substrate 41 is set to a rounded quadrangle as can be clearly understood from comparison between the plan view in FIG. 81A and the plan view in FIG. 78A.

The laminated lens structure 11 of the camera module 1 relating to the modification examples of the third embodiment can be combined with the laminated lens structure 11 relating to any one of the first to thirteenth configuration examples and the modification examples.

<34. Fourth Embodiment of Camera Module 1>

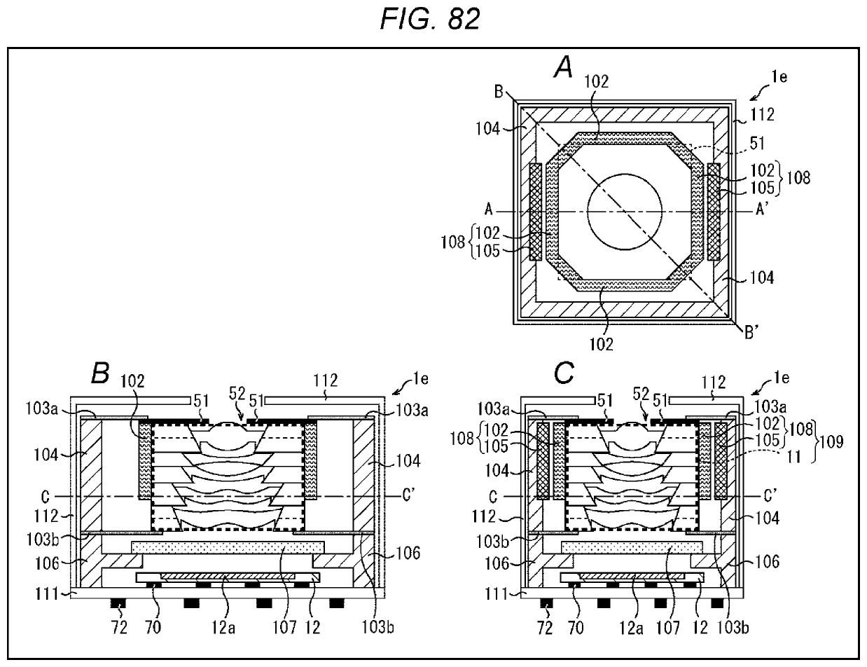

FIG. 82A to FIG. 82C are views illustrating a fourth embodiment of the camera module to which the present technology is applied.

FIG. 82A is a plan view of a camera module 1e as the fourth embodiment of the camera module 1, and FIG. 82B and FIG. 82C are cross-sectional views of the camera module 1e.

FIG. 82A is a plan view taken along line C-C′ in the cross-sectional views in FIG. 82B and FIG. 82C, FIG. 82B is a cross-sectional view taken along line B-B′ in the plan view in FIG. 82A, and FIG. 82C is a cross-sectional view taken along line A-A′ in the plan view in FIG. 82A.

The camera module 1e in FIG. 82A to FIG. 82C is different from the camera module 1a in FIG. 1 in that the lens barrel 101 accommodating the laminated lens structure 11 is omitted.

In addition, the camera module 1e in FIG. 82A to FIG. 82C is different from the camera module 1a in FIG. 1 also in that corner portions of four corners of each of the lens-attached substrates 41 which constitute the laminated lens structure 11 are linearly removed, and a planar shape of the lens-attached substrate 41 is set to an approximately octagon as in the camera module 1d relating to the first modification example of the third embodiment as described in FIG. 80A and FIG. 80B.

Here, the planar shape of the lens-attached substrate 41 is set to an approximately octagon. In contrast, as indicated by a broken line in FIG. 82A, a planar shape of the diaphragm plate 51 is set to a quadrangular shape in which corner portions of four corners are not removed, and thus the diaphragm plate 51 has a shape that further protrudes toward an outer periphery side in comparison to the lens-attached substrate 41 at the corner portions of four corners.

When bonding and fixing the coil 102 for AF to the laminated lens structure 11, the coil 102 for AF is positioned to come into contact with the diaphragm plate 51 that protrudes at the corner portions of four corners, and is bonded and fixed to the laminated lens structure 11.

The camera module 1e having the above-described configuration exhibits an operation or an effect capable of performing an auto focus operation as in the camera module 1a in FIG. 1. In addition, since the laminated lens structure 11, in which a plurality of sheets of the lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

Since the corner portions of four corners of the lens-attached substrate 41 of the laminated lens structure 11 around which the coil 102 for AF is wound have a gentle angle rather than the right angle, the following operation or effect can be exhibited. Specifically, when mounting a coil, it is possible to prevent damage from occurring in the coil and being a cause for a failure.

In addition, since the corner portions are removed before the lens-attached substrate 41W in a substrate state is divided into individual pieces, it is possible to exhibit an operation or an effect capable of preventing chipping of the lens-attached substrate 41 (carrier substrate 81) during division into individual pieces by dicing or after division into individual pieces.

In addition, in the assembly of the coil 102 for AF, since positioning is only performed in order for the coil 102 for AF to come into contact with the diaphragm plate 51 having an shape that further protrudes toward the outer periphery side in comparison to the lens-attached substrate 41 in the corner portions of four corners, it is possible to exhibit an operational effect in which alignment of the coil 102 for AF becomes easy and module assembly becomes easy.

Furthermore, the cover glass 271 and the light-shielding film 272, which are employed in FIG. 74, may be employed instead of the diaphragm plate 51 of the camera module 1e illustrated in FIG. 82A to FIG. 82C. In addition, in a case where an optical narrowing function is not necessary, only the cover glass 271 may be provided as a target object with which the coil 102 for AF comes into contact.

The laminated lens structure 11 of the camera module 1 relating to the fourth embodiment can be combined with the laminated lens structure 11 relating to any one of the first to thirteenth configuration examples and the modification examples.

<35. Fifth Embodiment of Camera Module 1>

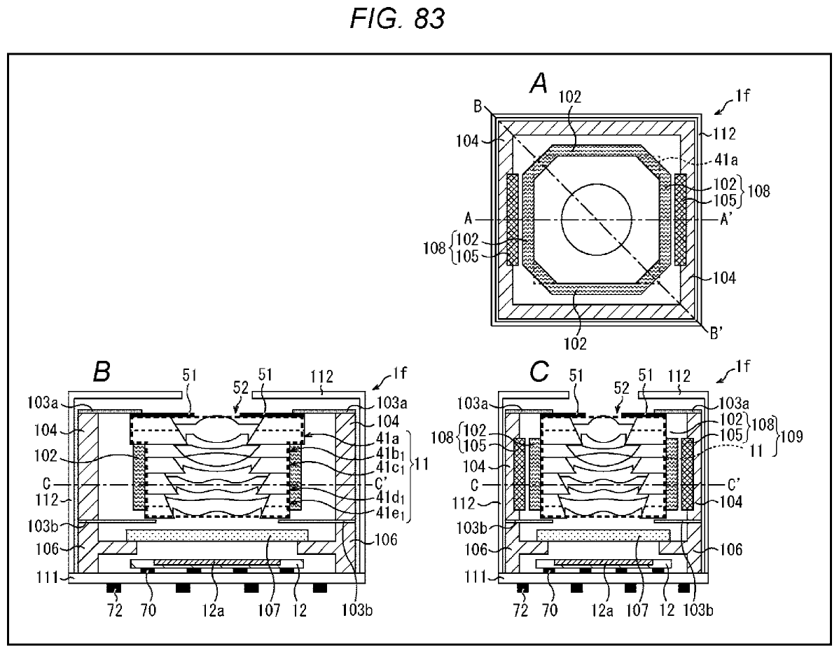

FIG. 83A to FIG. 83C are views illustrating a fifth embodiment of the camera module to which the present technology is applied.

FIG. 83A is a plan view of a camera module 1f as the fifth embodiment of the camera module 1, and FIG. 83B and FIG. 83C are cross-sectional views of the camera module 1f.

FIG. 83A is a plan view taken along line C-C′ in the cross-sectional views in FIG. 83B and FIG. 83C, FIG. 83B is a cross-sectional view taken along line B-B′ in the plan view in FIG. 83A, and FIG. 83C is a cross-sectional view taken along line A-A′ in the plan view in FIG. 83A.

When comparing the camera module 1f in FIG. 83A to FIG. 83C and the camera module 1e relating to the fourth embodiment illustrated in FIG. 82A to FIG. 82C, the lens-attached substrates 41b to 41e other than the lens-attached substrate 41a in the uppermost layer are substituted with lens-attached substrates 41b₁ to 41e₁.

That is, the laminated lens structure 11 of the camera module 1f relating to the fifth embodiment in FIG. 83A to FIG. 83C includes the lens-attached substrate 41a in the uppermost layer, and the lens-attached substrates 41b₁ to 41e₁. As indicated by a broken line in FIG. 83A, a planar shape of the lens-attached substrate 41a in the uppermost layer is set to a quadrangle in which corner portions of four corners are not removed. In contrast, a planar shape of the lens-attached substrates 41b₁ to 41e₁ is set to an octagon in which corner portions of four corners are removed. As a result, at the corner portions of four corners, the lens-attached substrate 41a in the uppermost layer further protrudes toward the outer peripheral side in comparison to the lens-attached substrates 41b₁ to 41e₁.

When bonding and fixing the coil 102 for AF to the laminated lens structure 11, the coil 102 for AF is positioned to come into contact with the lens-attached substrate 41a in the uppermost layer that protrudes at the corner portions of four corners, and is bonded and fixed to the laminated lens structure 11.

The camera module 1f having the above-described configuration exhibits an operation or an effect capable of performing an auto focus operation as in the camera module 1a in FIG. 1. In addition, since the laminated lens structure 11, in which a plurality of sheets of the lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

Since the corner portions of four corners of the lens-attached substrates 41b₁ to 41e₁ of the laminated lens structure 11 around which the coil 102 for AF is wound have a gentle angle rather than the right angle, the following operation or effect can be exhibited. Specifically, when mounting a coil, it is possible to prevent damage from occurring in the coil and being a cause for a failure.

In addition, since the corner portions are removed before the lens-attached substrate 41W in a substrate state is divided into individual pieces, it is possible to exhibit an operation or an effect capable of preventing chipping of the lens-attached substrates 41b₁ to 41e₁ (carrier substrates 81b₁ to 81e₁) during division into individual pieces by dicing or after division into individual pieces.

In addition, in the assembly of the coil 102 for AF, since positioning is only performed in order for the coil 102 for AF to come into contact with the lens-attached substrate 41a having a shape that further protrudes toward the outer periphery side at corner portions of four corners in comparison to the lens-attached substrates 41b₁ to 41e₁, it is possible to exhibit an operational effect in which alignment of the coil 102 for AF becomes easy and module assembly becomes easy.

The laminated lens structure 11 of the camera module 1 relating to the fifth embodiment can be combined with the laminated lens structure 11 relating to any one of the first to thirteenth configuration examples and the modification examples.

<36. Sixth Embodiment of Camera Module 1>

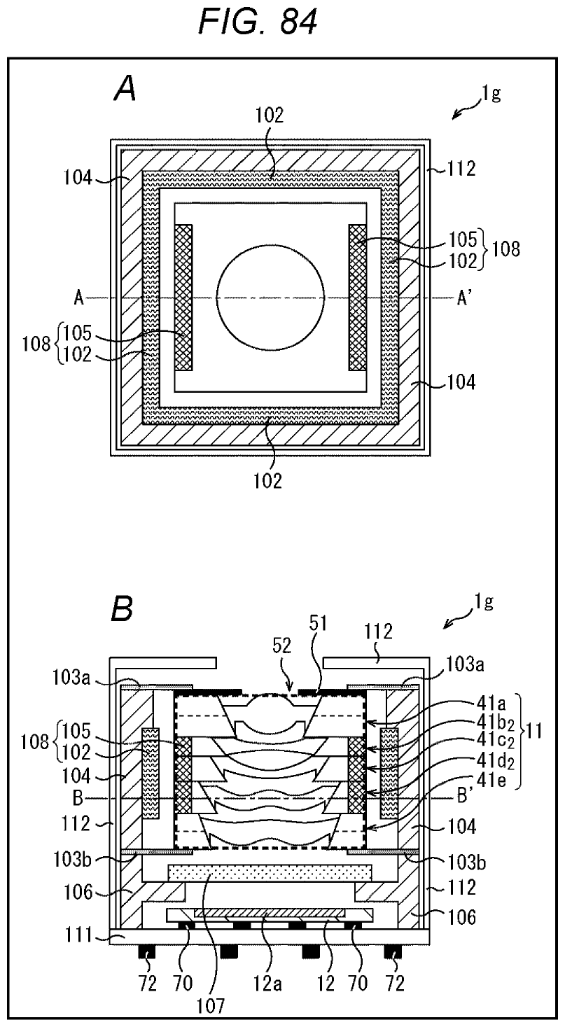

FIG. 84A and FIG. 84B are views illustrating a sixth embodiment of the camera module to which the present technology is applied.

FIG. 84A is a plan view of a camera module 1g as the sixth embodiment of the camera module 1, and FIG. 84B is a cross-sectional view of the camera module 1g.

FIG. 84A is a plan view taken along line B-B′ in the cross-sectional view in FIG. 84B, and FIG. 84B is a cross-sectional view taken along line A-A′ in the plan view in FIG. 84A.

The camera module 1g illustrated in FIG. 84A and FIG. 84B has a structure in which the lens barrel 101 accommodating the laminated lens structure 11 is omitted. The magnet 105 for AF is bonded and fixed to the outer periphery side of the laminated lens structure 11, and the coil 102 for AF is bonded and fixed to the inner periphery side of the first fixing and supporting portion 104.

In other words, in the camera module 1g in FIG. 84A and FIG. 84B, a mounting position of the coil 102 for AF and the magnet 105 for AF, which constitute the AF drive unit 108, is opposite to the camera module 1a in FIG. 1 as in the camera module 1b relating to the second embodiment illustrated in FIG. 77A and FIG. 77B.

In addition, the laminated lens structure 11 of the camera module 1g includes lens-attached substrates 41a, 41b₂ to 41d₂, and 41e, and a planar shape of the lens-attached substrates 41b₂ to 41d₂ in intermediate layers is set to a shape in which a mounting portion of the magnet 105 for AF is further recessed in comparison to the lens-attached substrates 41a and 41e in the uppermost layer and in the lowermost layer. With this arrangement, the magnet 105 for AF is embedded in a plurality of sheets of the lens-attached substrates 41 which constitute the laminated lens structure 11.

The camera module 1g having the above-described configuration exhibits an operation or an effect capable of performing an auto focus operation as in the camera module 1b in FIG. 77A and FIG. 77B. In addition, since the laminated lens structure 11, in which the plurality of sheets of lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

In addition, in the assembly of the magnet 105 for AF, positioning is only performed in order for the magnet 105 for AF to come into contact with a recessed portion that occurs due to a difference in a planar shape between the lens-attached substrates 41a and 41e in the uppermost layer and in the lowermost layer, and the lens-attached substrates 41b₂ to 41d₂ in the intermediate layers. On the other hand, in assembly of the coil 102 for AF to the first fixing and supporting portion 104, positioning is only performed in order for the coil 102 for AF to come into contact with the overhang portion that overhangs in the inner periphery side direction perpendicular to the optical axis direction. With this arrangement, alignment of the coil 102 for AF and the magnet 105 for AF becomes easy and module assembly becomes easy.

In addition, in the camera module 1g, since the magnet 105 for AF enters a state of being embedded in the plurality of sheets of lens-attached substrates 41 which constitute the laminated lens structure 11, it contributes to a reduction in size and weight of the camera module.

Furthermore, in the camera module 1g in FIG. 84A and FIG. 84B, the entirety of the magnet 105 for AF in a thickness direction is embedded in the lens-attached substrates 41, but a part of the magnet 105 for AF may be embedded.

The laminated lens structure 11 of the camera module 1 relating to the sixth embodiment can be combined with the laminated lens structure 11 relating to any one of the first to thirteenth configuration examples and the modification examples.

<37. Seventh Embodiment of Camera Module 1>

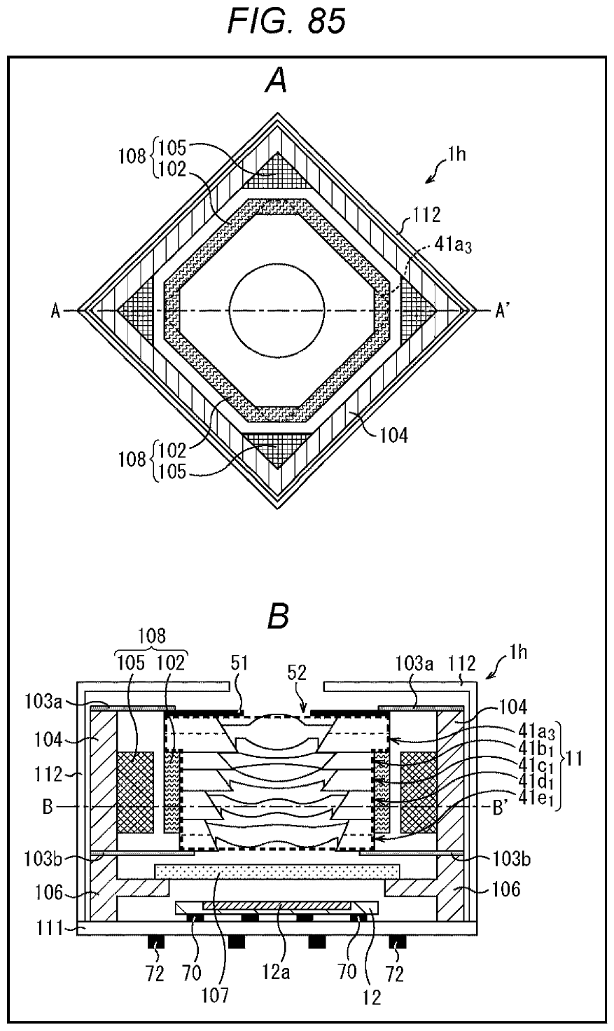

FIG. 85A and FIG. 85B are views illustrating a seventh embodiment of the camera module to which the present technology is applied.

FIG. 85A is a plan view of a camera module 1h as the seventh embodiment of the camera module 1, and FIG. 85B is a cross-sectional view of the camera module 1h.

FIG. 85A is a plan view taken along line B-B′ in the cross-sectional view in FIG. 85B, and FIG. 85B is a cross-sectional view taken along line A-A′ in the plan view in FIG. 85A.

When being compared with the camera module 1f relating to the fifth embodiment illustrated in FIG. 83A to FIG. 83C, the camera module 1h illustrated in FIG. 85A and FIG. 85B has a structure in which a mounting position of the magnet 105 for AF is changed.

Specifically, in the camera module 1f illustrated in FIG. 83A to FIG. 83C, the magnet 105 for AF is disposed at planar portions of the first fixing and supporting portion 104 having a quadrangular shape in the plan view. In contrast, in the camera module 1h in FIG. 85A and FIG. 85B, the magnet 105 for AF is disposed at corner portions of four corners of the first fixing and supporting portion 104 having a quadrangular shape. In other words, the magnet 105 for AF is disposed at positions which respectively face the four corners of the lens-attached substrate 41 having an approximately quadrangular shape.

Furthermore, as indicated by a broken line in FIG. 85A, corner portions of four corners of a lens-attached substrates 41a₃ in the uppermost layer is also slightly removed to dispose the magnet 105 for AF at the corner portions of four corners of the first fixing and supporting portion 104 differently from the lens-attached substrate 41a of the camera module 1f in FIG. 83A to FIG. 83C. The lens-attached substrates 41b₁ to 41e₁ are similar as in the camera module 1f in FIG. 83A to FIG. 83C.

In addition, with regard to the number of the magnets 105 for AF which are mounted to the first fixing and supporting portion 104, in the camera module 1f illustrated in FIG. 83A to FIG. 83C, the magnet 105 for AF is mounted on two opposing surfaces among four surfaces of the first fixing and supporting portion 104 having a quadrangular shape, and thus the number is set to two. In contrast, in the camera module 1h in FIG. 85A and FIG. 85B, the magnet 105 for AF is mounted on corner portions of four corners of the first fixing and supporting portion 104, and thus the number is set to four.

The other configurations of the camera module 1h in FIG. 85A and FIG. 85B are similar as in the camera module 1f illustrated in FIG. 83A to FIG. 83C.

The camera module 1h having the above-described configuration exhibits an operation or an effect capable of performing an auto focus operation as in the camera module 1f in FIG. 83A to FIG. 83C. In addition, since the laminated lens structure 11, in which the plurality of sheets of lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

Since the corner portions of four corners of the lens-attached substrates 41b₁ to 41e₁ of the laminated lens structure 11 around which the coil 102 for AF is wound have a gentle angle rather than the right angle, the following operation or effect can be exhibited. Specifically, when mounting a coil, it is possible to prevent damage from occurring in the coil and being a cause for a failure.

In addition, since the corner portions are removed before the lens-attached substrate 41W in a substrate state is divided into individual pieces, it is possible to exhibit an operation or an effect capable of preventing chipping of the lens-attached substrate 41 (carrier substrate 81) during division into individual pieces by dicing or after division into individual pieces.

In addition, in the assembly of the coil 102 for AF, since positioning is only performed in order for the coil 102 for AF to come into contact with the lens-attached substrate 41a₃ having a shape that further protrudes toward the outer periphery side at corner portions of four corners in comparison to the lens-attached substrates 41b₁ to 41e₁, it is possible to exhibit an operational effect in which alignment of the coil 102 for AF becomes easy and module assembly becomes easy.

The laminated lens structure 11 of the camera module 1 relating to the seventh embodiment can be combined with the laminated lens structure 11 relating to any one of the first to thirteenth configuration examples and the modification examples.

<38. Eighth Embodiment of Camera Module 1>

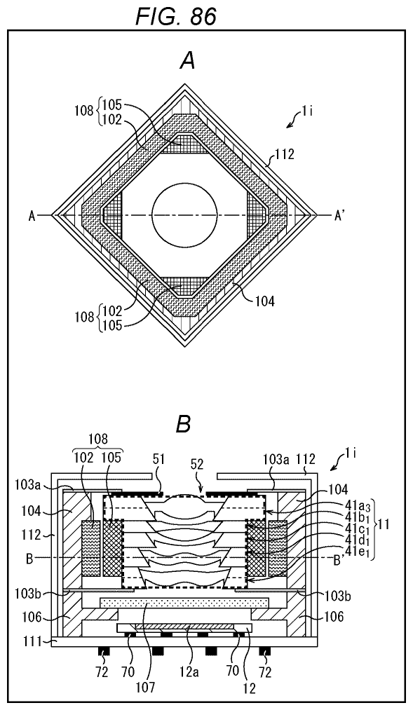

FIG. 86A and FIG. 86B are views illustrating an eighth embodiment of the camera module to which the present technology is applied.

FIG. 86A is a plan view of a camera module 1i as the eighth embodiment of the camera module 1, and FIG. 86B is a cross-sectional view of the camera module 1i.

FIG. 86A is a plan view taken along line B-B′ in the cross-sectional view in FIG. 86B, and FIG. 86B is a cross-sectional view taken along line A-A′ in the plan view in FIG. 86A.

When being compared with the camera module 1h relating to the seventh embodiment illustrated in FIG. 85A and FIG. 85B, in the camera module 1i illustrated in FIG. 86A and FIG. 86B, a mounting position of the coil 102 for AF and the magnet 105 for AF, which constitute the AF drive unit 108, is opposite.

That is, in the camera module 1h illustrated in FIG. 85A and FIG. 85B, the coil 102 for AF is bonded and fixed to the outer periphery side of the laminated lens structure 11, and the magnet 105 for AF is bonded and fixed to the inner periphery side of the first fixing and supporting portion 104. In contrast, in the camera module 1i in FIG. 86A and FIG. 86B, the magnet 105 for AF is bonded and fixed to the outer periphery side of the laminated lens structure 11, and the coil 102 for AF is bonded and fixed to the inner periphery side of the first fixing and supporting portion 104.

The first fixing and supporting portion 104 includes an overhang portion that overhangs toward the inner periphery side on the upper surface that is farthest from the imaging unit 12, and has a cross-sectional shape in an approximately L-shape. When the coil 102 for AF is bonded and fixed to the first fixing and supporting portion 104, the coil 102 for AF is positioned to come into contact with the overhang portion on the inner periphery side, and is bonded and fixed to the first fixing and supporting portion 104.

The magnet 105 for AF is disposed at corner portions of four corners of four sheets of lens-attached substrates 41b₁ to 41e₁ which constitute the laminated lens structure 11. The magnet 105 for AF is positioned to come into contact with the lens-attached substrate 41a₃ in the uppermost layer that protrudes at the corner portions of four corners, and is bonded and fixed to the laminated lens structure 11.

The other configurations of the camera module 1i in FIG. 86A and FIG. 86B are similar to the camera module 1h illustrated in FIG. 85A and FIG. 85B.

The camera module 1i having the above-described configuration exhibits an operation or an effect capable of performing an auto focus operation as in the camera module 1h in FIG. 85A and FIG. 85B. In addition, since the laminated lens structure 11, in which the plurality of sheets of lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur.

Since the corner portions of four corners of the lens-attached substrates 41b₁ to 41e₁ of the laminated lens structure 11 has a gentle angle rather than the right angle, when the corner portions are removed before the lens-attached substrate 41W in a substrate state is divided into individual pieces, it is possible to exhibit an operation or an effect capable of preventing chipping of the lens-attached substrates 41b₁ to 41e₁ (carrier substrates 81b₁ to 81e₁) during division into individual pieces by dicing or after division into individual pieces.

In addition, in assembly of the coil 102 for AF to the first fixing and supporting portion 104, positioning is only performed in order for the coil 102 for AF to come into contact with the overhang portion that overhangs in the inner periphery side direction perpendicular to the optical axis direction. With this arrangement, it is possible to exhibit an operational effect in which alignment of the coil 102 for AF becomes easy and module assembly becomes easy.

In addition, in the camera module 1i, since at least a part of the magnet 105 for AF enters a state of being embedded in the lens-attached substrates 41b₁ to 41e₁ which constitute the laminated lens structure 11, it contributes to a reduction in size and weight of the camera module.

The laminated lens structure 11 of the camera module 1 relating to the eighth embodiment can be combined with the laminated lens structure 11 relating to any one of the first to thirteenth configuration examples and the modification examples.

<39. Ninth Embodiment of Camera Module 1>

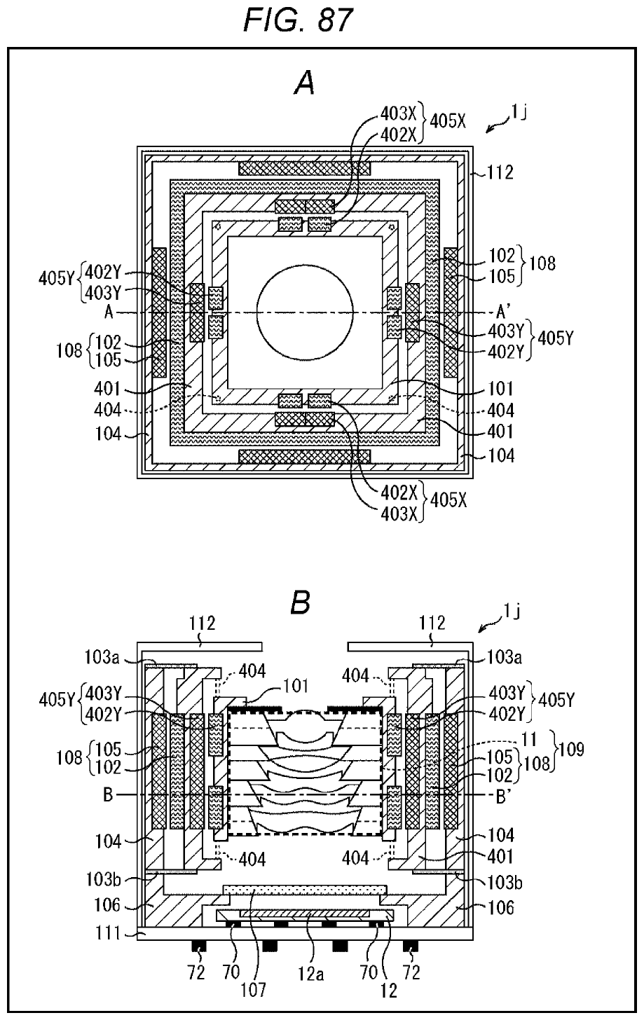

FIG. 87A and FIG. 87B are views illustrating a ninth embodiment of the camera module to which the present technology is applied.

FIG. 87A is a plan view of a camera module 1j as the ninth embodiment of the camera module 1, and FIG. 87B is a cross-sectional view of the camera module 1j.

FIG. 87A is a plan view taken along line B-B′ in the cross-sectional view in FIG. 87B, and FIG. 87B is a cross-sectional view taken along line A-A′ in the plan view in FIG. 87A.

The camera module 1j illustrated in FIG. 87A and FIG. 87B has a structure in which an optical image stabilizer (OIS) mechanism is added to the camera module 1a illustrated in FIG. 1.

When being compared with the camera module 1a illustrated in FIG. 1, in the camera module 1j in FIG. 87A and FIG. 87B, the coil 102 for AF is bonded and fixed to an outer periphery side of a movable supporting portion 401 that is additionally provided instead of the lens barrel 101. A magnet 403 for OIS that is a permanent magnet for OIS is bonded and fixed to an inner periphery side of the movable supporting portion 401.

The movable supporting portion 401 has a quadrangular cylindrical shape to surround the lens barrel 101 in which the laminated lens structure 11 is accommodated, an upper surface is fixed to the first fixing and supporting portion 104 through the suspension 103a, and a lower surface is fixed to the first fixing and supporting portion 104 through the suspension 103b.

In addition, the movable supporting portion 401 is connected to the lens barrel 101 through an OIS suspension 404 that includes a columnar metal elastic body at four corners of the lens barrel 101 having a quadrangular shape when seen from an upper surface. A coil 402 for OIS is bonded and fixed to an outer peripheral surface of the lens barrel 101 at a position that faces the magnet 403 for OIS.

A coil 402X for OIS that is bonded and fixed to predetermined two opposite sides among four sides at the outer periphery of the quadrangular lens barrel 101 when seen from an upper surface, and a magnet 403X for OIS that faces the coil 402X for OIS constitute an X-axis OIS drive unit 405X, and when a current flows through the coil 402X for OIS, the laminated lens structure 11 is moved in an X-axis direction. A coil 402Y for OIS that is bonded and fixed to other two opposite sides, and a magnet 403Y for OIS that faces the coil 402Y for OIS constitute a Y-axis OIS drive unit 405Y, and when a current flows through the coil 402Y of OIS, the laminated lens structure 11 is moved in a Y-axis direction.

Driving of the laminated lens structure 11 in the optical axis direction is similar as in the camera module 1a illustrated in FIG. 1. That is, when a current flows through the coil 102 for AF, the AF drive unit 108 including the coil 102 for AF and the magnet 105 for AF adjusts a distance between the laminated lens structure 11 and the imaging unit 12.

In the camera module 1j having the above-described configuration, in addition to the operation or effect which can be exhibited by the camera module 1a illustrated in FIG. 1, an operation or an effect capable of performing an image stabilization operation is exhibited because the optical image stabilizer mechanism is provided.

Furthermore, in the camera module 1j in FIG. 87A and FIG. 87B, the coil 402Y for OIS is bonded and fixed to the outer peripheral surface of the lens barrel 101, and the magnet 403X for OIS is bonded and fixed to the inner periphery side of the movable supporting portion 401. However, as in the positional relation between the coil 102 for AF and the magnet 105 for AF, the position of the coil 402Y for OIS and the position of the magnet 403X for OIS may be substituted with each other.

The laminated lens structure 11 of the camera module 1 relating to the ninth embodiment can be combined with the laminated lens structure 11 relating to any one of the first to thirteenth configuration examples and the modification examples.

<40. Tenth Embodiment of Camera Module 1>

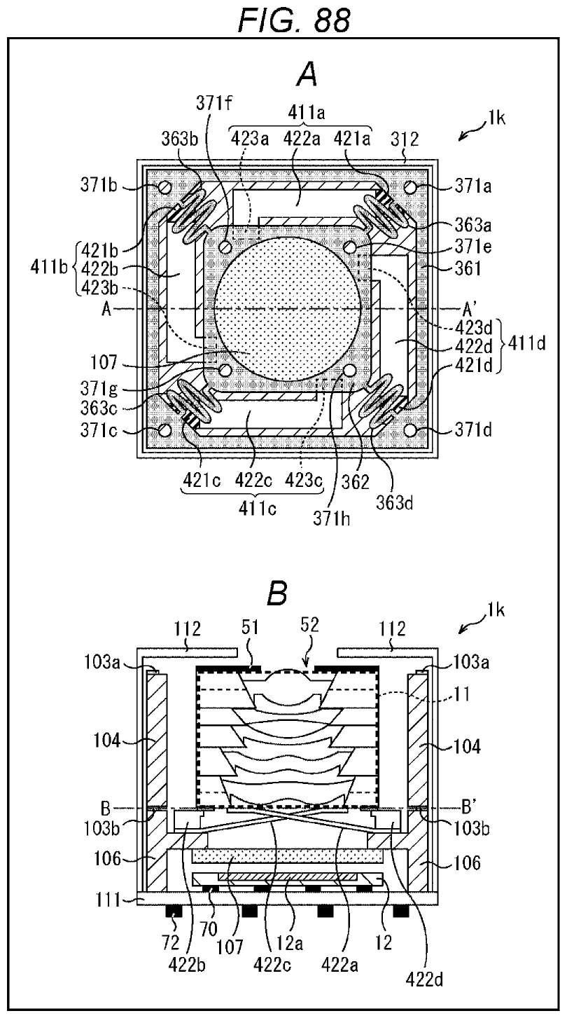

FIG. 88A and FIG. 88B are views illustrating a tenth embodiment of the camera module to which the present technology is applied.

FIG. 88A is a plan view of a camera module 1k as the tenth embodiment of the camera module 1, and FIG. 88B is a cross-sectional view of the camera module 1k.

FIG. 88A is a plan view when the camera module 1k illustrated in FIG. 88A and FIG. 88B is seen in a direction (lower direction) of the imaging unit 12 from the suspension 103b on a lower surface, and FIG. 88B is a cross-sectional view taken along line A-A′ in the plan view in FIG. 88A.

The camera module 1k illustrated in FIG. 88A and FIG. 88B has a structure in which the electromagnetic type AF drive unit 108, which performs the AF operation of the camera module 1c that is not provided with the lens barrel 101 illustrated in FIG. 78A and FIG. 78B, is changed to an actuator that uses a piezoelectric material.

More specifically, in the camera module 1k in FIG. 88A and FIG. 88B, the coil 102 for AF and the magnet 105 for AF, which constitute the electromagnetic type AF drive unit 108 in the camera module 1c in FIG. 78A and FIG. 78B are omitted, and four piezoelectric drive units 411a to 411d which use a piezoelectric element are provided instead of the coil 102 for AF and the magnet 105 for AF.

The camera module 1k does not include the coil 102 for AF, and thus it is not necessary for a current to flow therethrough. Accordingly, the suspension 103b on a lower surface is constituted by one sheet of plate as in the suspension 103a on an upper surface. Specifically, as illustrated in FIG. 88A, the suspension 103b includes a first fixing plate 361 that is bonded and fixed to the first fixing and supporting portion 104, a second fixing plate 362 that is bonded and fixed to the lens-attached substrate 41e in the lowermost layer of the laminated lens structure 11, and connection springs 363a to 363d which connect the first fixing plate 361 and the second fixing plate 362 to each other at four corners.

The piezoelectric drive units 411a to 411d are connected to respective sides of the second fixing plate 362 having an approximately quadrangular planar shape in one to one relation.

The piezoelectric drive unit 411a includes a piezoelectric fixed portion 421a that is fixed to the second fixing and supporting portion 106, a piezoelectric movable portion 422a of which a shape varies due to voltage application, and a piezoelectric fixed portion 423a that is fixed to the second fixing plate 362.

The piezoelectric movable portion 422a has a sandwich structure in which a piezoelectric material is interposed between two sheets of electrodes (opposing electrodes), and when a predetermined voltage is applied to the two sheets of electrodes, the piezoelectric movable portion 422a having a plate shape is vertically bent. Accordingly, the laminated lens structure 11 is moved in the optical axis direction.

Similarly, the piezoelectric drive unit 411b includes a piezoelectric fixed portion 421b, a piezoelectric movable portion 422b, and a piezoelectric fixed portion 423b. This is also true of the piezoelectric drive units 411c and 411d.

As illustrated in FIG. 88A and FIG. 88B, when the four piezoelectric drive units 411a to 411d are symmetrically disposed, it is possible to enlarge a driving force, and it is possible to reduce a force in a direction other than the optical axis direction.

The camera module 1k having the above-described configuration exhibits an operation or an effect capable of performing an auto focus operation as in the camera module 1a in FIG. 1. In addition, since the laminated lens structure 11, in which the plurality of sheets of lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur. In addition, the lens barrel 101 is not necessary, and thus it is possible to realize a reduction in size and weight of the camera module.

Furthermore, in the piezoelectric drive units 411a to 411d, for example, it is possible to employ an arbitrary structure such as a bimetal, a shape memory alloy, and a polymer actuator disclosed in JP 2013-200366A in which a shape of a plate-shaped piezoelectric material varies due to voltage application, and a target object is moved.

The laminated lens structure 11 of the camera module 1 relating to the tenth embodiment can be combined with the laminated lens structure 11 relating to any one of the first to thirteenth configuration examples and the modification examples.

<41. Eleventh Embodiment of Camera Module 1>

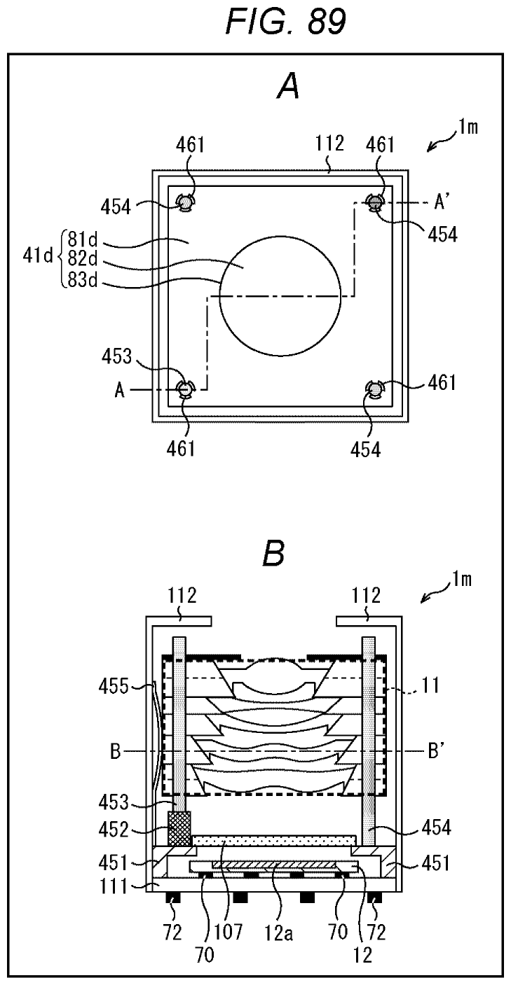

FIG. 89A and FIG. 89B are views illustrating an eleventh embodiment of the camera module to which the present technology is applied.

FIG. 89A is a plan view of a camera module 1m as the eleventh embodiment of the camera module 1, and FIG. 89B is a cross-sectional view of the camera module 1m.

FIG. 89A is a plan view taken along line B-B′ in the cross-sectional view in FIG. 89B, and FIG. 89B is a cross-sectional view taken along line A-A′ in the plan view in FIG. 89A.

The camera module 1m illustrated in FIG. 89A and FIG. 89B has a structure in which the electromagnetic type AF drive unit 108, which performs the AF operation of the camera module 1c relating to the third embodiment illustrated in FIG. 78A and FIG. 78B, is changed to a linear actuator that uses ultrasonic drive.

More specifically, in the camera module 1m in FIG. 89A and FIG. 89B, the coil 102 for AF and the magnet 105 for AF, which constitute the electromagnetic type AF drive unit 108 in the camera module 1c in FIG. 78A and FIG. 78B are omitted, and a piezoelectric element 452 to which a driving body 453 is connected, and three guide bodies 454 are provided instead of the coil 102 for AF and the magnet 105 for AF. The piezoelectric element 452 and the three guide bodies 454 are fixed to a fixing and supporting portion 451.

The driving body 453 and the three guide bodies 454 are inserted into (are inserted into and pass through) holes 461 which are formed in the vicinity of four corners of the plurality of sheets of lens-attached substrates 41 (carrier substrates 81 thereof) which constitute the laminated lens structure 11. For example, the driving body 453 and the three guide bodies 454 include a metal or a resin and have a columnar shape.

When a predetermined voltage is applied, the piezoelectric element 452 periodically extends and contracts the driving body 453 in a state in which an extension speed and a contraction speed are set to be different from each other. A shape of an inner wall of the holes 461 formed in the vicinity of the four corners of the lens-attached substrate 41 (carrier substrate 81 thereof), and a shape of an outer wall of the driving body 453 or the guide bodies 454 are designed to obtain an optimal frictional force. That is, in a case where driving performance of the piezoelectric element 452 is high, the shapes are designed to a large frictional force, and in a case where the driving performance of the piezoelectric element 452 is low, the shapes are designed to obtain a small frictional force.

For example, in an example in FIG. 89A and FIG. 89B, as illustrated in FIG. 89A, the following shape is employed. Specifically, a groove is formed on three sides of the inner wall of the holes 461, and a part of the inner wall of the holes 461 comes into contact with the driving body 453 or each of the guide bodies 454 to generate a desired frictional force. The holes 461 can be formed simultaneously with the through-hole 83 by using wet etching and the like. With this arrangement, a hole shape and a positional relation of the respective holes 461 can be set with accuracy, and thus it is possible to exhibit an operation or an effect capable of improving driving accuracy of the laminated lens structure 11.

In a case where a driving speed of the piezoelectric element 452 is slow, the laminated lens structure 11 conforms to movement of the driving body 453 due to a static frictional force. In a case where the driving speed of the piezoelectric element 452 is fast, the sum of inertia of the laminated lens structure 11, a static frictional force, and the like is greater than a driving force that is given to the driving body 453 from the piezoelectric element 452, and thus the laminated lens structure 11 does not move. When slow extension drive and fast contraction drive are alternately repeated, the laminated lens structure 11 moves an upward or downward optical axis direction.

The three guide bodies 454 are directly fixed to the fixing and supporting portion 451 and guide a movement direction of the laminated lens structure 11 that conforms to movement of the driving body 453. A pushing spring 455 presses the laminated lens structure 11 and generates an appropriate frictional force to the driving body 453 so as to efficiently transfer driving.

The camera module 1m having the above-described configuration exhibits an operation or an effect capable of performing an auto focus operation as in the camera module 1a in FIG. 1. In addition, since the laminated lens structure 11, in which the plurality of sheets of lens-attached substrates 41 are integrated in the optical axis direction, is used, it is possible to exhibit an operational effect in which module assembly becomes easy, and a variation in the central position of each of the lens resin portions 82 of the plurality of sheets of lens-attached substrates 41 does not occur. In addition, the lens barrel 101 is not necessary, and thus it is possible to realize a reduction in size and weight of the camera module.

The linear actuator that uses the ultrasonic driving that is employed in the eleventh embodiment can exhibits an operation or an effect capable of further reducing the whole size of the camera module 1 in comparison to a case where another ultrasonic driving actuator is externally attached to the laminated lens structure 11.

The laminated lens structure 11 of the camera module 1 relating to the eleventh embodiment can be combined with the laminated lens structure 11 relating to any one of the first to thirteenth configuration examples and the modification examples.

<42. Twelfth Embodiment of Camera Module 1>

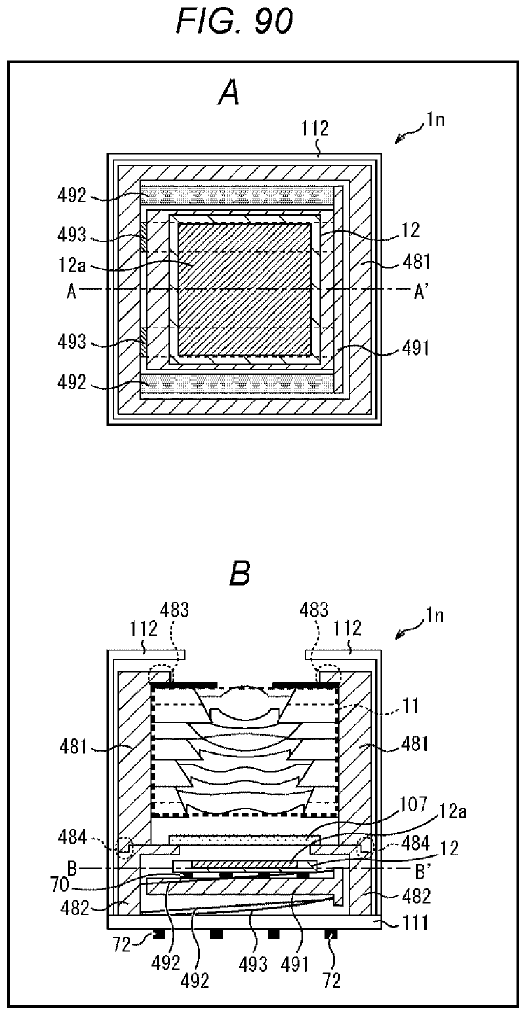

FIG. 90A and FIG. 90B are views illustrating a twelfth embodiment of the camera module to which the present technology is applied.

FIG. 90A is a plan view of a camera module 1n as the twelfth embodiment of the camera module 1, and FIG. 90B is a cross-sectional view of the camera module 1n.

FIG. 90A is a plan view taken along line B-B′ in the cross-sectional view in FIG. 90B seen in a direction (downward direction) of the imaging unit 12, and FIG. 90B is a cross-sectional view taken along line A-A′ in the plan view in FIG. 90A.

The camera modules 1a to 1m which are related to the first embodiment to the eleventh embodiment employs a mode in which the laminated lens structure 11 is moved in the optical axis direction. In contrast, the camera module 1n illustrated in FIG. 90A and FIG. 90B employs a mode in which the laminated lens structure 11 is fixed, and the imaging unit 12 is moved in the optical axis direction.

The laminated lens structure 11 is accommodated in a lens barrel 481, and the lens barrel 481 is directly coupled to the second fixing and supporting portion 482. Accordingly, the laminated lens structure 11 is set to a fixed position with respect to the module substrate 111.

The imaging unit 12 is placed on a light-receiving element holder 491, and the light-receiving element holder 491 is coupled to the second fixing and supporting portion 482 with a plurality of parallel links 492. Accordingly, the imaging unit 12 can move in approximately parallel to the optical axis direction.

The piezoelectric actuator 493 has a sandwich structure in which a piezoelectric material is interposed between two sheets of electrodes (opposing electrodes), and when a predetermined voltage is applied to the two sheets of electrodes, the piezoelectric actuator 493 having a plate shape is vertically bent. Accordingly, the imaging unit 12 that is placed on the light-receiving element holder 491 is moved in the optical axis direction. With this arrangement, a distance between the laminated lens structure 11 and the imaging unit 12 can be adjusted.

In the piezoelectric actuator 493, for example, it is possible to employ an arbitrary structure such as a bimetal, a shape memory alloy, and a polymer actuator disclosed in JP 2013-200366A in which a shape of a plate-shaped piezoelectric material varies due to voltage application, and a target object is moved.

Furthermore, as a focus adjustment mechanism (auto focus mechanism), the camera module 1 can use means other than the piezoelectric actuator as long as the imaging unit 12 is moved in the optical axis direction of the laminated lens structure 11 by the means. For example, the linear actuator that uses ultrasonic driving described in FIG. 89A and FIG. 89B may be mounted to the imaging unit 12, and the imaging unit 12 may be moved in the optical axis direction of the laminated lens structure 11. In addition, as another example, the electromagnetic type AF drive unit 108 described in FIG. 1 may be mounted to the imaging unit 12, and the imaging unit 12 may be moved in the optical axis direction of the laminated lens structure 11. In addition, as still another example, a support body may be mounted to the imaging unit 12, and the support body may be moved by using an electromagnetic type drive mechanism using a coil and a magnet to move the imaging unit 12 in the optical axis direction of the laminated lens structure 11.

As illustrated in FIG. 90B, the lens barrel 481 includes an overhang portion 483 that overhangs toward an inner periphery side on an upper surface that is farthest from the imaging unit 12, and has an approximately L-shaped cross-sectional shape. When bonding and fixing the laminated lens structure 11 to the lens barrel 481, the laminated lens structure 11 is positioned to come into contact with the overhang portion 483 and is bonded and fixed to the lens barrel 481. With this arrangement, it is possible to assemble the laminated lens structure 11 and the lens barrel 481 with an accurate positional relation.

In addition, in the lens barrel 481, as illustrated in FIG. 90B, when a coupling portion 484, in which a predetermined concave-convex shape is formed in a connection surface with the second fixing and supporting portion 482, is provided, fixing can be performed after positioning with accuracy.

The camera module 1n having the above-described configuration exhibits an operation or an effect capable of performing an auto focus operation as in the camera module 1a in FIG. 1. In addition, since the laminated lens structure 11, in which the plurality of sheets of lens-attached substrates 41 are integrated in the optical axis direction, is used, and positioning is only performed in order for the laminated lens structure 11 to come into contact with the overhang portion 483 of the lens barrel 481, it is possible to exhibit an operational effect in which module assembly becomes easy, and a variation in the central position of each of the lens resin portions 82 of the plurality of sheets of lens-attached substrates 41 does not occur. In addition, the lens barrel 101 is not necessary, and thus it is possible to realize a reduction in size and weight of the camera module.

The laminated lens structure 11 of the camera module 1 relating to the twelfth embodiment can be combined with the laminated lens structure 11 relating to any one of the first to thirteenth configuration examples and the modification examples.

<43. Thirteenth Embodiment of Camera Module 1>

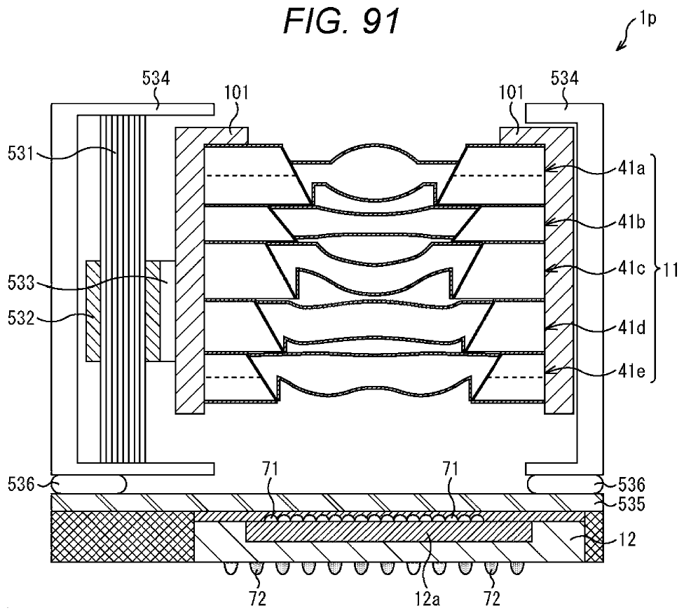

FIG. 91 is a view illustrating a thirteenth embodiment of the camera module to which the present technology is applied.

In a camera module 1p as the thirteenth embodiment of the camera module 1 as illustrated in FIG. 91, the laminated lens structure 11 is accommodated in a lens barrel 101. The lens barrel 101 is fixed to a moving member 532 that moves along a shaft 531 by a fixing member 533. When the lens barrel 101 is moved in an axial direction of the shaft 531 by a driving motor (not illustrated in the drawing), a distance from the laminated lens structure 11 to the imaging surface of the imaging unit 12 is adjusted.

The lens barrel 101, the shaft 531, the moving member 532, and the fixing member 533 are accommodated in a housing 534. A protective substrate 535 is disposed on an upper side of the imaging unit 12, and the protective substrate 535 and the housing 534 are connected to each other with an adhesive 536.

The mechanism that moves the laminated lens structure 11 exhibits an operation or an effect capable of performing an auto focus operation when a camera using the camera module 1p captures an image.

The laminated lens structure 11 of the camera module 1 relating to the thirteenth embodiment can be combined with the laminated lens structure 11 relating to any one of the first to thirteenth configuration examples and the modification examples.

<44. Fourteenth Embodiment of Camera Module 1>

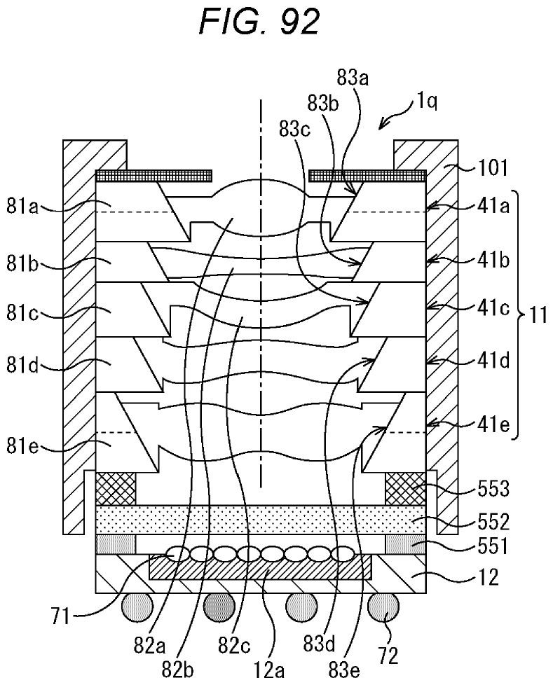

FIG. 92 is a view illustrating a fourteenth embodiment of the camera module to which the present technology is applied.

A camera module 1q as the thirteenth embodiment of the camera module 1 as illustrated in FIG. 92 is a camera module that is additionally provided with a focus adjustment mechanism by a piezoelectric element.

That is, in the camera module 1q, a structure material 551 is disposed on an upper side of the imaging unit 12 at a part thereof. The imaging unit 12 and a light-transmissive substrate 552 are fixed through the structure material 551. For example, the structure material 551 is an epoxy-based resin.

A piezoelectric element 553 is disposed on an upper side of the light-transmissive substrate 552. The light-transmissive substrate 552 and the laminated lens structure 11 are fixed through the piezoelectric element 553.

In the camera module 1q, a voltage is applied to the piezoelectric element 553 disposed on a lower side of the laminated lens structure 11 or the voltage is shut off to move the laminated lens structure 11 in an upper and lower direction. As means for moving the laminated lens structure 11, another device of which a shape varies due to application and shutting-off a voltage can be used without limitation to the piezoelectric element 553. For example, a MEMS device can be used.

The mechanism that moves the laminated lens structure 11 exhibits an operation or an effect capable of performing an auto focus operation when a camera using the camera module 1q captures an image.

The laminated lens structure 11 of the camera module 1 relating to the fourteenth embodiment can be combined with the laminated lens structure 11 relating to any one of the first to thirteenth configuration examples and the modification examples.

<45. Fifteenth Embodiment of Camera Module 1>

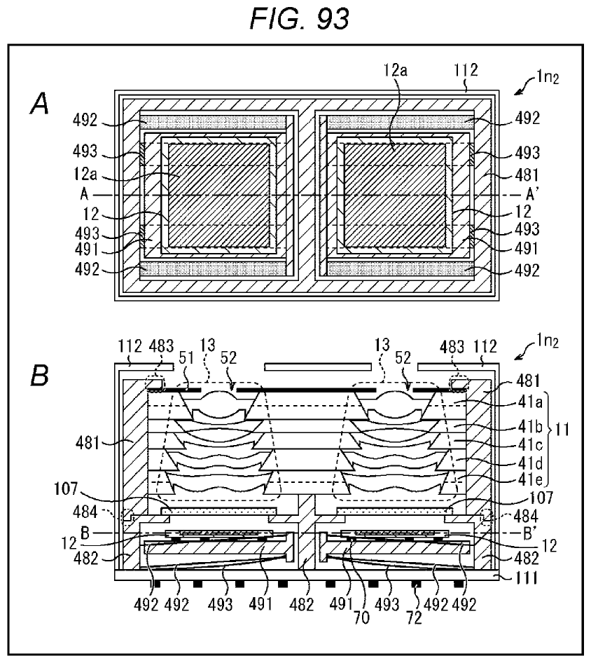

FIG. 93A and FIG. 93B are views illustrating a fifteenth embodiment of the camera module to which the present technology is applied.

The camera modules 1a to 1q as the first embodiment to the fourteenth embodiment of the camera module 1 is also applicable to a laminated lens structure 11 having a binocular structure.

A structure example of a binocular camera module is illustrated in FIG. 93A and FIG. 93B with reference to the camera module 1n illustrated in FIG. 90A and FIG. 90B as an example.

FIG. 93A is a plan view taken along line B-B′ in the cross-sectional view in FIG. 93B, and FIG. 93B is a cross-sectional view taken along line A-A′ in the plan view in FIG. 93A.

A camera module 1n₂ illustrated in FIG. 93A and FIG. 93B includes a laminated lens structure 11 in which two optical units 13 are connected with a carrier substrate 81. Each of the optical units 13 includes a lens group including a plurality of lens resin portions 82 which are laminated in the optical axis direction and a diaphragm plate 51. In addition, the camera module 1n₂ includes an IR cutter filter 107 and an imaging unit 12 which are respectively disposed on lower sides of the two optical units 13. Each of the two imaging units 12 is placed on a light-receiving element holder 491, and the light-receiving element holder 491 is coupled to the second fixing and supporting portion 482 with a plurality of parallel links 492, and can independently move in approximately parallel to the optical axis direction.

In a case where the laminated lens structure 11 includes two or more optical units 13, a plurality of the optical units 13, which constitute the laminated lens structure 11, are divided into individual pieces in a state of being coupled to each other with the carrier substrate 81. Accordingly, it is possible to set a positional relation in an XY direction perpendicular to the optical axis with accuracy in a wafer process.

In addition, when bonding and fixing the laminated lens structure 11 to the lens barrel 481, the laminated lens structure 11 is positioned to come into contact with an overhang portion 483 that overhangs toward an inner periphery side on an upper surface side of the lens barrel 481, and is bonded and fixed to the lens barrel 481. With this arrangement, it is possible to exhibit an operation or an effect which is capable of setting a positional relation of the optical axis direction with accuracy, and is capable of omitting special optical axis matching.

In addition, the imaging units 12 are independently disposed to be individually driven in the optical axis direction. Accordingly, even in a combination of optical units 13 which are different in back focus, it is possible to exhibit an operation or an effect capable of realizing accurate focus matching.

Furthermore, description has been given of a configuration in which the camera module 1n illustrated in FIG. 90A and FIG. 90B is set as a binocular camera module with reference to FIG. 93A and FIG. 93B, it is needless to say that the binocular camera module configuration can be employed for all of the camera modules 1a to 1q relating to the first to fourteenth embodiments.

<46. Sixteenth Embodiment of Camera Module 1>

The focus adjustment mechanism (auto focus mechanism) may be realized by setting the lens resin portion 82 of the lens-attached substrate 41 of the laminated lens structure 11 as a shape variable lens 82V in which a lens shape can be deformed in addition to the electromagnetic type AF drive unit 108 including the coil 102 for AF and the magnet 105 for AF, and the piezoelectric actuator 493.

Hereinafter, description will be given of a configuration of the camera module 1 in which the lens resin portion 82 of at least one lens-attached substrate 41 among a plurality of sheets of the laminated lens-attached substrates 41 of the laminated lens structure 11 is set as the shape variable lens 82V.

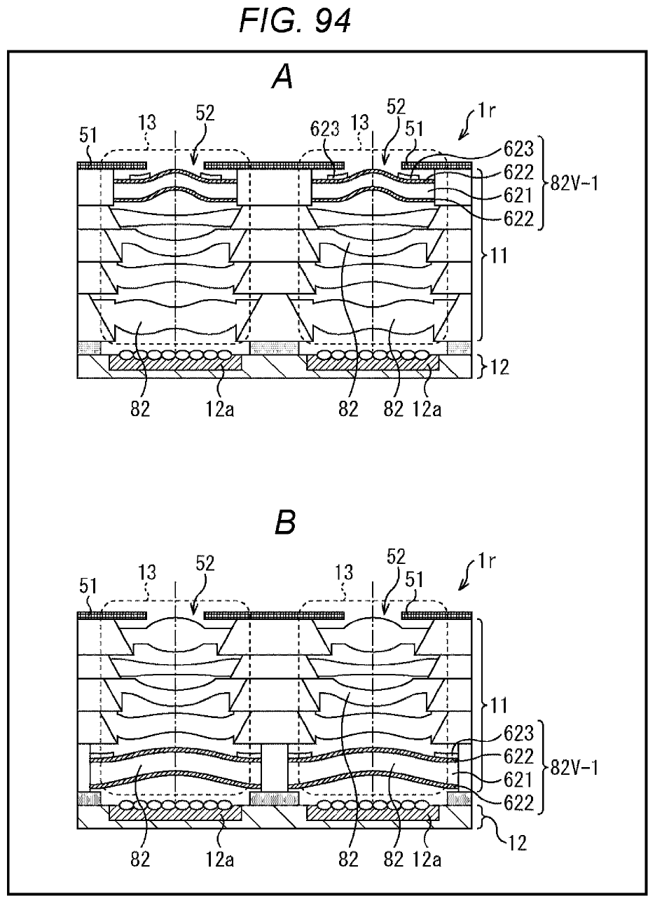

FIG. 94A to FIG. 97B are schematic cross-sectional views illustrating a camera module 1r as a sixteenth embodiment of the camera module 1 to which the present technology is applied.

Furthermore, in FIG. 94A to FIG. 97B, description is made with focus given to the lens resin portion 82 of the lens-attached substrate 41, and the lens-attached substrate 41 is illustrated in the drawing as a lens-attached single-layer substrate 41 that uses a single-layer-structure carrier substrate 81. However, it is needless to say that the lens-attached laminated substrate 41 that uses a lamination-structure carrier substrate 81 can also be employed. In addition, in FIG. 94A to FIG. 97B, description will be given of an example of the binocular structure as illustrated in FIG. 93A and FIG. 93B, but application to a monocular structure is also possible.

<Example of First Shape Variable Lens>

FIG. 94A illustrates a configuration example in which the lens resin portion 82 of the lens-attached substrate 41 in the uppermost layer among a plurality of sheets of the lens-attached substrates 41 which are laminated is substituted with a first shape variable lens 82V-1.

FIG. 94B illustrates a configuration example in which the lens resin portion 82 of the lens-attached substrate 41 in the lowermost layer among the plurality of sheets of lens-attached substrates 41 which are laminated is substituted with the first shape variable lens 82V-1.

The first shape variable lens 82V-1 includes a lens material 621 that uses a reversibly shape variable material, cover materials 622 disposed on an upper surface and a lower surface in order for the lens material 621 to be interposed therebetween, and a piezoelectric material 623 that is disposed to be in contact with the cover material 622 on the upper surface.

For example, the lens material 621 is constituted by a soft polymer (US 2011/149409A), a flexible polymer (US 2011/158617A), a movable fluid (JP 2000-081504A) such as a silicon oil, a fluid (JP 2002-243918A) such as a silicon oil, an elastic rubber, jelly, water, and the like.

For example, the cover material 622 is constituted by cover glass including a flexible material (US 2011/149409A), a bendable transparent cover (US 2011/158617A), an elastic film including a silica glass (JP 2000-081504A), a soft substrate using a synthetic resin or an organic material (JP 2002-243918A), and the like.

In the first shape variable lens 82V-1, when a voltage is applied to the piezoelectric material 623, it is possible to deform a shape of the lens material 621. Accordingly, it is possible to make a focus variable.

FIG. 94A and FIG. 94B illustrate an example in which one sheet of the lens-attached substrate 41 that uses the first shape variable lens 82V-1 is disposed in the uppermost layer or in the lowermost layer of a plurality of sheets of the lens-attached substrates 41 which constitute the laminated lens structure 11, but the lens-attached substrate 41 may be disposed in an intermediate layer between the uppermost layer and the lowermost layer. In addition, the number of sheets of the lens-attached substrate 41 that uses the first shape variable lens 82V-1 may be set to a plurality of sheets instead of one sheet.

<Example of Second Shape Variable Lens>

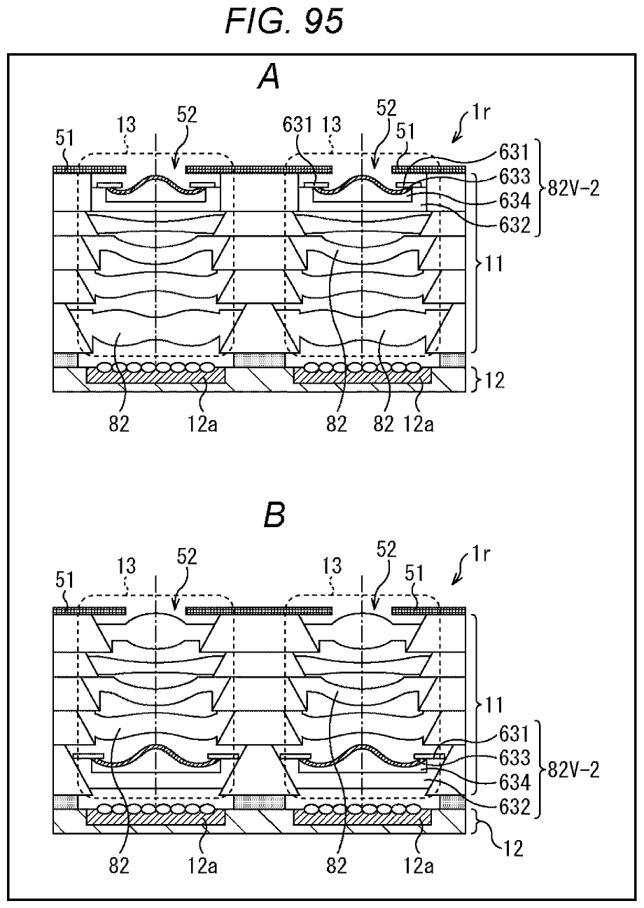

FIG. 95A illustrates a configuration example in which the lens resin portion 82 of the lens-attached substrate 41 in the uppermost layer among a plurality of sheets of the lens-attached substrates 41 which are laminated is substituted with a second shape variable lens 82V-2.

FIG. 95B illustrates a configuration example in which the lens resin portion 82 of the lens-attached substrate 41 in the lowermost layer among the plurality of sheets of lens-attached substrates 41 which are laminated is substituted with the second shape variable lens 82V-2.

The second shape variable lens 82V-2 includes a pressure application portion 631, a light-transmissive base material 632 including a concave portion, a light-transmissive film 633 that is disposed on an upper side of the concave portion of the base material 632, and a fluid 634 that is enclosed between the film 633 and the concave portion of the base material 632.

For example, the film 633 is constituted by polydimethylsiloxane, polymethyl methacrylate, polyterephthalate ethylene, polycarbonate, parylene, an epoxy resin, a photosensitive polymer, silicon, silicon oxide, silicon nitride, silicon carbide, polycrystalline silicon, titanium nitride, diamond carbon, indium tin oxide, aluminum, copper, nickel, piezoelectric material, and the like.

For example, the fluid 634 is constituted by propylene carbonate, water, a refractive liquid, an optical oil, an ionic liquid, a gas such as air, nitrogen, and helium, and the like.

In the second shape variable lens 82V-2, when the pressure application portion 631 presses the vicinity of an outer periphery of the film 633, the central portion of the film 633 becomes thick. It is possible to deform a shape of the fluid 634 at the thick portion by controlling the magnitude of pressing by the pressure application portion 631, and thus it is possible to make a focus variable.

A structure of the second shape variable lens 82V-2 is disclosed, for example, in US 2012/170920A and the like.

FIG. 95A and FIG. 95B illustrate an example in which one sheet of the lens-attached substrate 41 that uses the second shape variable lens 82V-2 is disposed in the uppermost layer or in the lowermost layer of a plurality of sheets of the lens-attached substrates 41 which constitute the laminated lens structure 11, but the lens-attached substrate 41 may be disposed in an intermediate layer between the uppermost layer and the lowermost layer. In addition, the number of sheets of the lens-attached substrate 41 that uses the second shape variable lens 82V-2 may be set to a plurality of sheets instead of one sheet.

<Example of Third Shape Variable Lens>

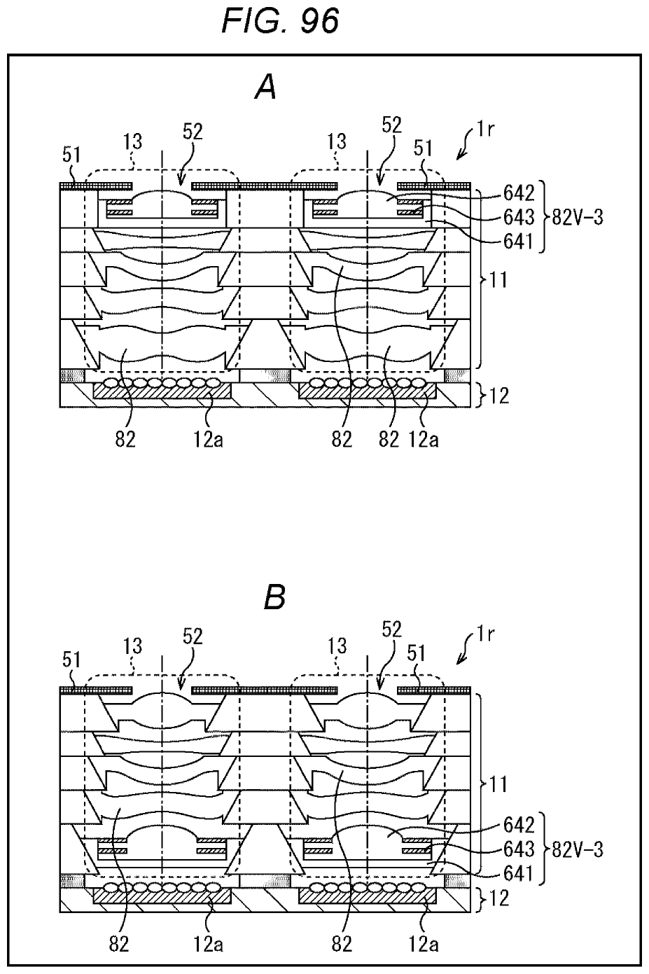

FIG. 96A illustrates a configuration example in which the lens resin portion 82 of the lens-attached substrate 41 in the uppermost layer among a plurality of sheets of the lens-attached substrates 41 which are laminated is substituted with a third shape variable lens 82V-3.

FIG. 96B illustrates a configuration example in which the lens resin portion 82 of the lens-attached substrate 41 in the lowermost layer among the plurality of sheets of lens-attached substrates 41 which are laminated is substituted with the third shape variable lens 82V-3.

The third shape variable lens 82V-3 includes a light-transmissive base material 641 including a concave portion, a light-transmissive electrical active material 642 that is disposed on an upper side of the concave portion of the base material 641, and an electrode 643.

In the third shape variable lens 82V-3, when a voltage is applied to the electrical active material 642 from the electrode 643, the central portion of the electrical active material 642 becomes thick. It is possible to deform a shape of the central portion of the electrical active material 642 by controlling the magnitude of an application voltage, and thus it is possible to make a focus variable.

A structure of the third shape variable lens 82V-3 is disclosed, for example, in JP 2011-530715A, and the like.

FIG. 96A and FIG. 96B illustrate an example in which one sheet of the lens-attached substrate 41 that uses the third shape variable lens 82V-3 is disposed in the uppermost layer or in the lowermost layer of a plurality of sheets of the lens-attached substrates 41 which constitute the laminated lens structure 11, but the lens-attached substrate 41 may be disposed in an intermediate layer between the uppermost layer and the lowermost layer. In addition, the number of sheets of the lens-attached substrate 41 that uses the third shape variable lens 82V-3 may be set to a plurality of sheets instead of one sheet.

<Example of Fourth Shape Variable Lens>

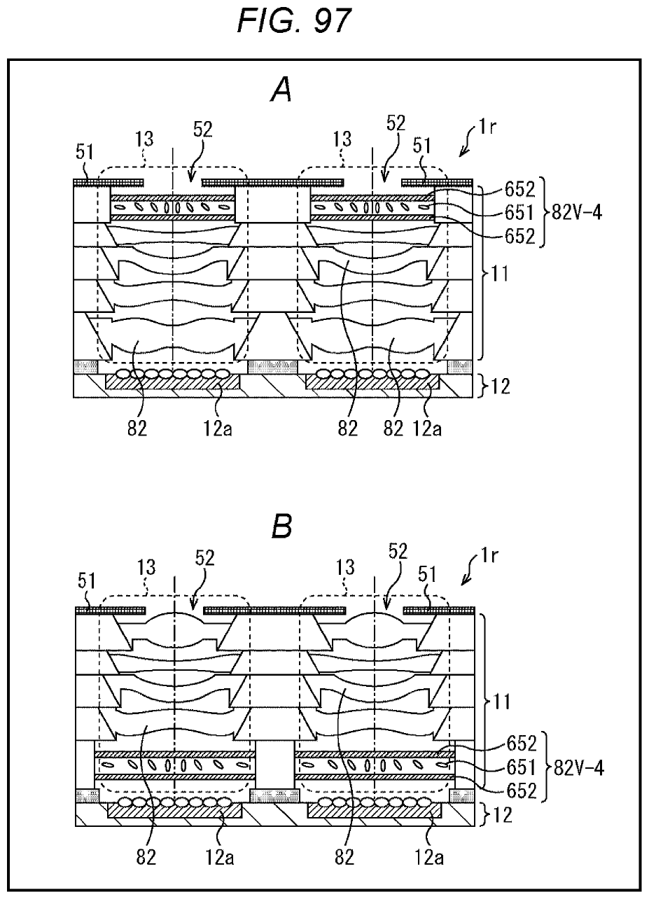

FIG. 97A illustrates a configuration example in which the lens resin portion 82 of the lens-attached substrate 41 in the uppermost layer among a plurality of sheets of the lens-attached substrates 41 which are laminated is substituted with a fourth shape variable lens 82V-4.

FIG. 97B illustrates a configuration example in which the lens resin portion 82 of the lens-attached substrate 41 in the lowermost layer among the plurality of sheets of lens-attached substrates 41 which are laminated is substituted with the fourth shape variable lens 82V-4.

The fourth shape variable lens 82V-4 includes a liquid crystal material 651, and two sheets of electrodes 652 which sandwich the liquid crystal material 651 from an upper side and a lower side.

In the fourth shape variable lens 82V-4, when a predetermined voltage is applied to the liquid crystal material 651 from the two sheets of electrodes 652, an orientation of the liquid crystal material 651 varies, and thus a refractive index of light that is transmitted through the liquid crystal material 651 varies. It is possible to make a focus variable by controlling the magnitude of a voltage applied to the liquid crystal material 651 to change the refractive index of light.

A structure of the fourth shape variable lens 82V-4 is disclosed, for example, in US 2014/0036183A, and the like.

FIG. 97A and FIG. 97B illustrate an example in which one sheet of the lens-attached substrate 41 that uses the fourth shape variable lens 82V-4 is disposed in the uppermost layer or in the lowermost layer of a plurality of sheets of the lens-attached substrates 41 which constitute the laminated lens structure 11, but the lens-attached substrate 41 may be disposed in an intermediate layer between the uppermost layer and the lowermost layer. In addition, the number of sheets of the lens-attached substrate 41 that uses the fourth shape variable lens 82V-4 may be set to a plurality of sheets instead of one sheet.

The first shape variable lens 82V-1 to the fourth shape variable lens 82V-4 can be substituted with an arbitrary lens-attached substrate 41 of the laminated lens structure 11 relating to the first to thirteenth configuration examples and the modification examples.

<47. Seventeenth Embodiment of Camera Module 1>

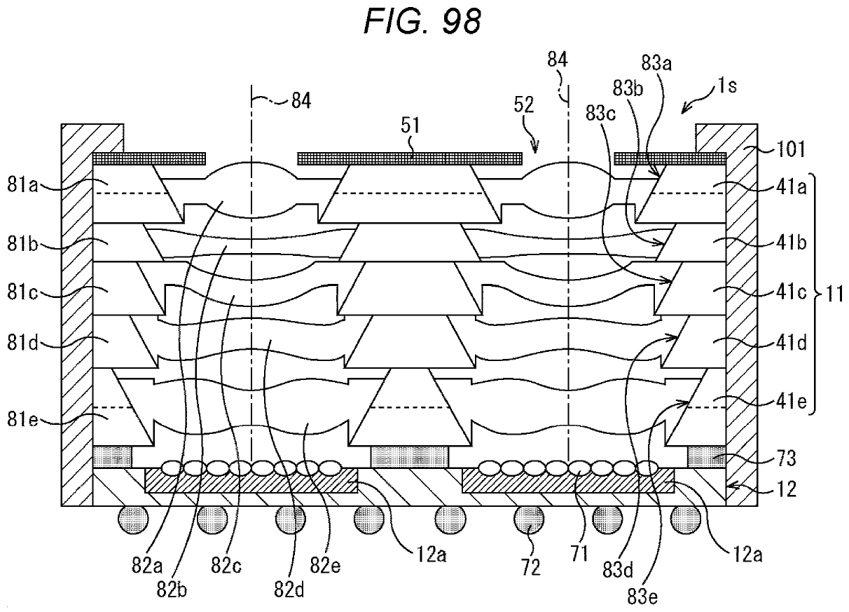

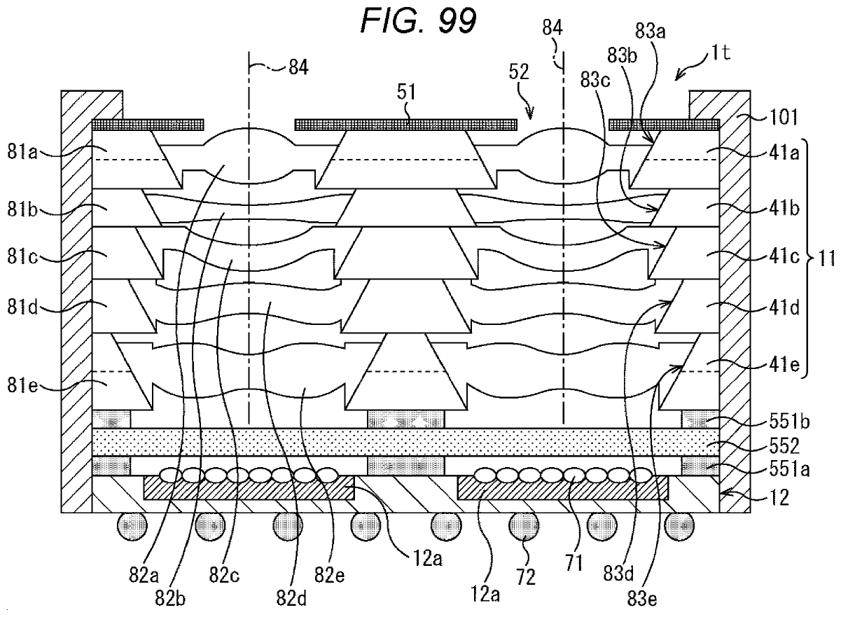

Next, a description will be given of an embodiment of a fixed focus type camera module with reference to FIG. 98 to FIG. 101.

Furthermore, in FIG. 98 to FIG. 101, the same reference numerals will be given to portions which are described already in the camera module 1 relating to the above-described embodiments, and description thereof will be omitted. In FIG. 98 to FIG. 101, description will be given of an example of a binocular structure as in FIG. 93A and FIG. 93B, but application to a monocular structure is also possible.

FIG. 98 is a schematic cross-sectional view illustrating a camera module is as a seventeenth embodiment of the camera module 1 to which the present technology is applied.

A structure material 73 is disposed on an upper side of the imaging unit 12. The laminated lens structure 11 and the imaging unit 12 are fixed through the structure material 73. For example, the structure material 73 is an epoxy-based resin.

An on-chip lens 71 is formed in an upper surface of the imaging unit 12 on the laminated lens structure 11 side, and an external terminal 72 through which a signal is input or output is formed on a lower surface of the imaging unit 12.

The laminated lens structure 11 of the camera module 1 relating to the seventeenth embodiment can be combined with the laminated lens structure 11 relating to any one of the first to thirteenth configuration examples and the modification examples.

<48. Eighteenth Embodiment of Camera Module 1>

FIG. 99 is a schematic cross-sectional view illustrating a camera module 1t as an eighteenth embodiment of the camera module 1 to which the present technology is applied.

In the camera module 1t in FIG. 99, a portion of the structure material 73 in the camera module is in FIG. 98 is substituted with another structure.

In the camera module 1t in FIG. 99, a portion of the structure material 73 in the camera module is in FIG. 98 is substituted with structure materials 551a and 551b, and a light-transmissive substrate 552.

Specifically, the structure material 551a is disposed at a part on an upper side of the imaging unit 12. The imaging unit 12 and the light-transmissive substrate 552 are fixed through the structure material 551a. For example, the structure material 551a is an epoxy-based resin.

The structure material 551b is disposed on an upper side of the light-transmissive substrate 552. The light-transmissive substrate 552 and the laminated lens structure 11 are fixed through the structure material 551b. For example, the structure material 551b is an epoxy-based resin.

The laminated lens structure 11 of the camera module 1 relating to the eighteenth embodiment can be combined with the laminated lens structure 11 relating to any one of the first to thirteenth configuration examples and the modification examples.

<49. Nineteenth Embodiment of Camera Module 1>

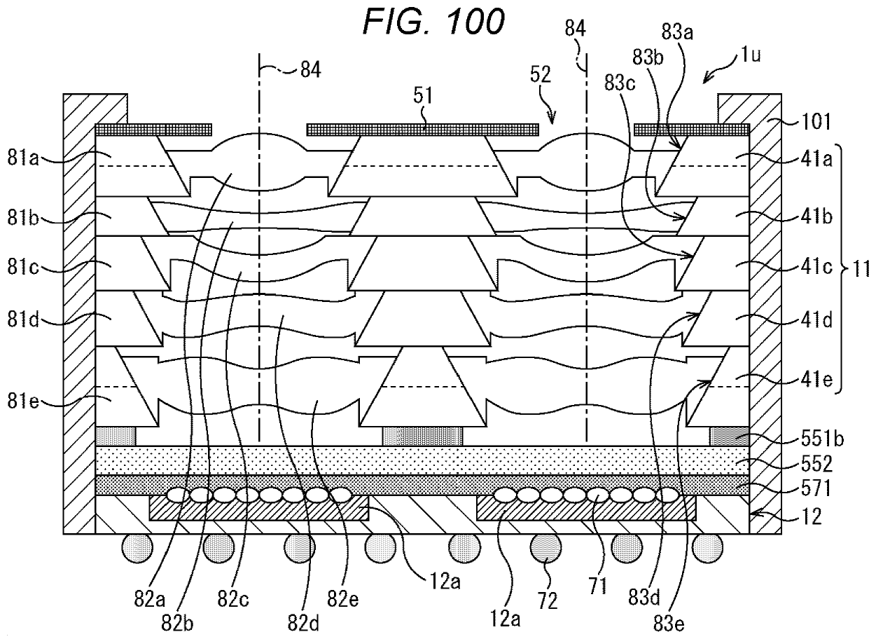

FIG. 100 is a schematic cross-sectional view illustrating a camera module 1u as a nineteenth embodiment of the camera module 1 to which the present technology is applied.

In the camera module 1u in FIG. 100, a portion of the structure material 551a in the camera module 1t illustrated in FIG. 99 is substituted with another structure.

Specifically, in the camera module 1u in FIG. 100, a portion of the structure material 551a of the camera module 1t illustrated in FIG. 99 is substituted with a light-transmissive resin layer 571.

The resin layer 571 is disposed on the entirety of an upper surface of the imaging unit 12. The imaging unit 12 and the light-transmissive substrate 552 are fixed through the resin layer 571. The resin layer 571 exhibits the following operation or an effect. Specifically, in a case where a stress from an upward side of the light-transmissive substrate 552 to the light-transmissive substrate 552 increases, the resin layer 571, which is disposed on the entirety of the upper surface of the imaging unit 12, prevents the stress from being applied to a partial region of the imaging unit 12 in a concentrated manner, and receives the stress in a state in which the stress is dispersed to the entirety of the surface of the imaging unit 12.

The structure material 551b is disposed on an upper side of the light-transmissive substrate 552. The light-transmissive substrate 552 and the laminated lens structure 11 are fixed through the structure material 551b.

The camera module 1t in FIG. 99 and the camera module 1u in FIG. 100 include the light-transmissive substrate 552 on an upper side of the imaging unit 12. The light-transmissive substrate 552 exhibits an operation or an effect capable of suppressing damage from being transferred to the imaging unit 12, for example, in the middle of manufacturing the camera module 1t or 1u.

The laminated lens structure 11 of the camera module 1 relating to the nineteenth embodiment can be combined with the laminated lens structure 11 relating to any one of the first to thirteenth configuration examples and the modification examples.

<50. Twentieth Embodiment of Camera Module 1>

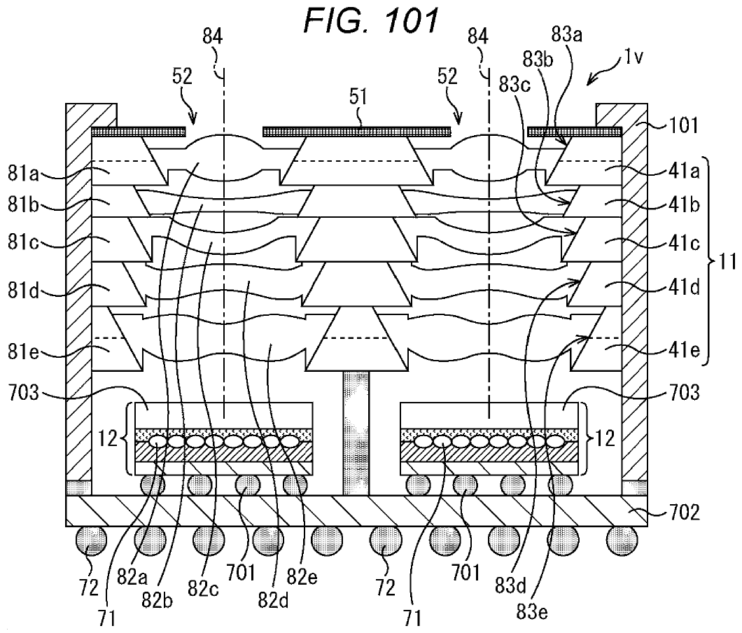

FIG. 101 is a schematic cross-sectional view illustrating a camera module 1v as a twentieth embodiment of the camera module 1 to which the present technology is applied.

The camera module 1v in FIG. 101 has a configuration in which the two light-receiving regions 12a of the imaging unit 12 in the camera module is illustrated in FIG. 98 are divided into an individual imaging unit 12 for each light-receiving region 12a.

A pixel signal generated by the imaging unit 12 is output from an external terminal 72 through a relay terminal 701 and a relay substrate 702. An IR cutter filter 703 is formed on the uppermost surface of each of the imaging units 12.

The laminated lens structure 11 of the camera module 1 relating to the twentieth embodiment can be combined with the laminated lens structure 11 relating to any one of the first to thirteenth configuration examples and the modification examples.

<51. Twenty-First Embodiment of Camera Module 1>

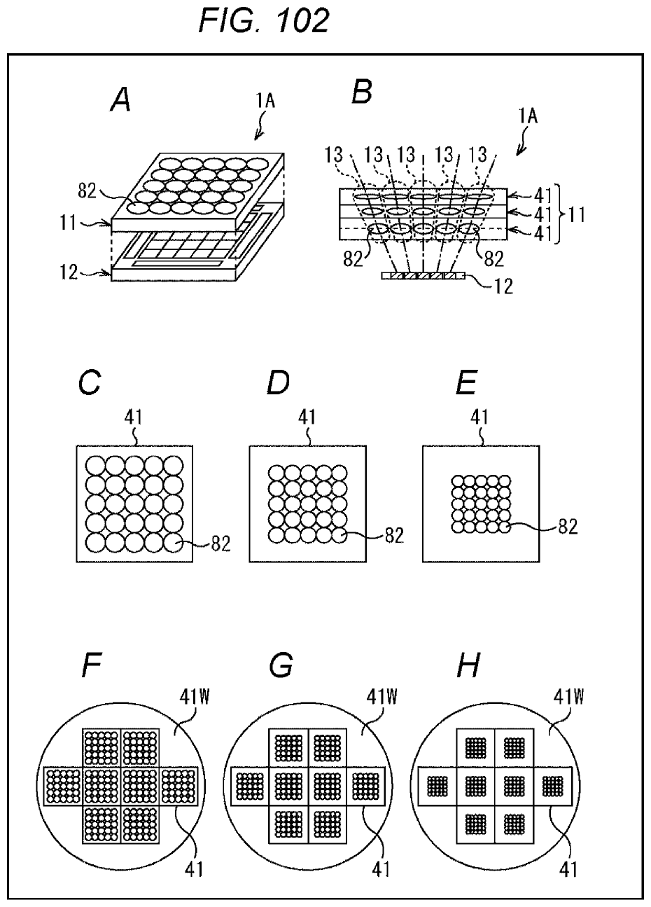

Next, other embodiments of the camera module having a binocular structure will be described with reference to FIG. 102A to FIG. 131.

FIG. 102A to FIG. 102H are views illustrating a twenty-first embodiment of the camera module to which the present technology is applied.

FIG. 102A is an exploded perspective view illustrating a configuration of a camera module 1A as the twenty-first embodiment of the camera module 1, and FIG. 102B is a cross-sectional view of the camera module 1A.

As illustrated in FIG. 102B, the camera module 1A is a binocular camera module including a plurality of optical units 13, and each of the optical units 13 includes a plurality of the lens resin portions 82 in the optical axis direction. The laminated lens structure 11 includes a total of twenty five optical unit 13 in five-by-five in a vertical direction and a horizontal direction. The laminated lens structure 11 is constituted by laminating three sheets of the lens-attached substrates 41, and a lens-attached substrate 41 in the lowermost layer among the lens-attached substrates 41 is set as the lens-attached laminated substrate 41.

In the camera module 1A, an optical axis of the plurality of optical units 13 is disposed to be expanded toward an outer side of the module. With this arrangement, wide-angle image capturing becomes possible. In FIG. 102B, the laminated lens structure 11 in which only three layers of the lens-attached substrates 41 are laminated for simplicity, but it is needless to say that a larger number of lens-attached substrates 41 may be laminated.

FIG. 102C to FIG. 102E are views illustrating a planar shape of the three layers of lens-attached substrates 41 which constitute the laminated lens structure 11.

FIG. 102C is a plan view of a lens-attached substrate 41 in an uppermost layer among the three layers, FIG. 102D is a plan view of a lens-attached substrate 41 in an intermediate layer, and FIG. 102E is a plan view of a lens-attached substrate 41 in a lowermost layer. The camera module 1A is a binocular wide-angle camera module. Accordingly, as it goes toward an upper layer, a diameter of the lens resin portion 82 further increases, and a pitch between lenses becomes wider.

FIG. 102F to FIG. 102H are plan views of the lens-attached substrate 41W in a substrate state to obtain the lens-attached substrate 41 illustrated in FIG. 102C to FIG. 102E.

A lens-attached substrate 41W illustrated in FIG. 102F represents a substrate state corresponding to the lens-attached substrate 41 in FIG. 102C, a lens-attached substrate 41W illustrated in FIG. 102G represents a substrate state corresponding to the lens-attached substrate 41 in FIG. 102D, and a lens-attached substrate 41W illustrated in FIG. 102H represents a substrate state corresponding to the lens-attached substrate 41 in FIG. 102E.

The lens-attached substrates 41W in a substrate state as illustrated in FIG. 102F to FIG. 102H are set to have a configuration in which eight pieces of the camera modules 1A illustrated in FIG. 102A are obtained for one sheet of substrate.

It can be seen that in the lens-attached substrates 41W in FIG. 102F to FIG. 102H, a pitch between lenses in the lens-attached substrate 41 in a module unit is different between a lens-attached substrate 41W in an upper layer and a lens-attached substrate 41W in a lower layer, and in the lens-attached substrates 41W, a pitch for disposing the lens-attached substrate 41 in a module unit becomes constant from the lens-attached substrate 41W in the upper layer to the lens-attached substrate 41W in the lower layer.

<52. Twenty-Second Embodiment of Camera Module 1>

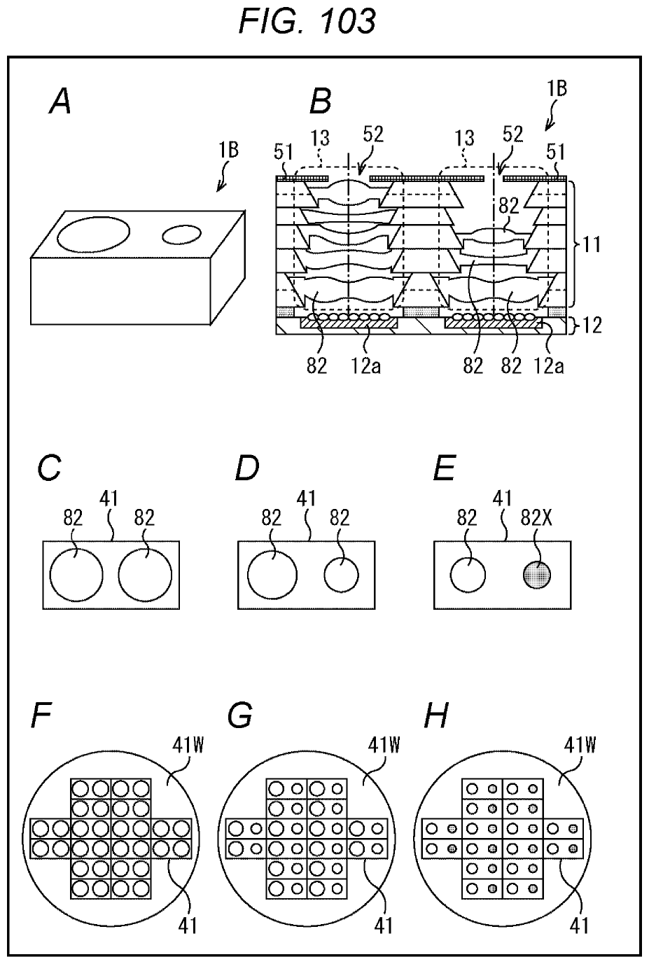

FIG. 103A to FIG. 103F are views illustrating a twenty-second embodiment of the camera module to which the present technology is applied.

FIG. 103A is a schematic view illustrating an external appearance of a camera module 1B as the twenty-second embodiment of the camera module 1, and FIG. 103B is a schematic cross-sectional view of the camera module 1B.

The camera module 1B includes two optical units 13. The two optical units 13 include the diaphragm plate 51 in the uppermost layer of the laminated lens structure 11. An opening 52 is provided in the diaphragm plate 51.

The camera module 1B includes the two optical units 13, but optical parameters of the two optical units 13 are different from each other. That is, the camera module 1B includes two kinds of optical units 13 which are different in optical performance. For example, the two kinds of optical units 13 can be set as an optical unit 13 in which a focal length is short for photographing a short-distance view, and an optical unit 13 in which a focal length is long for photographing a long-distance view.

In the camera module 1B, the optical parameters of the two optical units 13 are different from each other. Accordingly, for example, the number of sheets of lenses is different between the two optical units 13 in the method illustrated in FIG. 103B. In addition, any one of a diameter, a thickness, a surface shape, a volume, and a distance between adjacent lenses can be set to be different between lens resin portions 82 in the same layer of the laminated lens structure 11 that is provided in the two optical units 13. Accordingly, with regard to a planar shape of the lens resin portion 82 in the camera module 1B, for example, the two optical units 13 may include lens resin portions 82 having the same diameter as illustrated in FIG. 103C, or lens resin portions 82 having different shapes as illustrated in FIG. 103D. In addition, one of the two optical units 13 has a structure in which the lens resin portion 82 is not provided and is set as a cavity 82X as illustrated in FIG. 103E.

FIG. 103F to FIG. 103H are plan views of lens-attached substrates 41W in a substrate state for obtaining the lens-attached substrates 41 illustrated in FIG. 103C to FIG. 103E.

A lens-attached substrate 41W illustrated in FIG. 103F represents a substrate state corresponding to the lens-attached substrate 41 in FIG. 103C, a lens-attached substrate 41W illustrated in FIG. 103G represents a substrate state corresponding to the lens-attached substrate 41 in FIG. 103D, and a lens-attached substrate 41W illustrated in FIG. 103H represents a substrate state corresponding to the lens-attached substrate 41 in FIG. 103E.

The lens-attached substrates 41W in a substrate state as illustrated in FIG. 103F to FIG. 103H are set to have a configuration in which sixteen pieces of the camera modules 1B illustrated in FIG. 103A are obtained for one sheet of substrate.

As illustrated in FIG. 103F to FIG. 103H, to form the camera module 1B, over the entirety of the surface of the lens-attached substrate 41W in a substrate state, lenses having the same shape are formed, lenses having shapes different from each other are formed, or a lens is formed at a part and a lens is not formed at a part.

<53. Twenty-Third Embodiment of Camera Module 1>

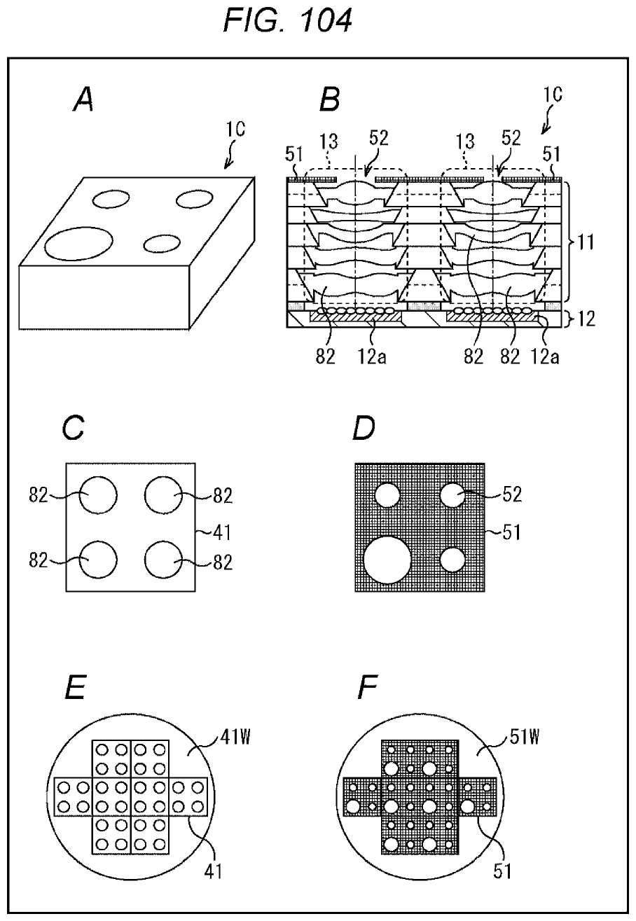

FIG. 104A to FIG. 104F are views illustrating a twenty-third embodiment of the camera module to which the present technology is applied.

FIG. 104A is a schematic view illustrating an external appearance of a camera module 1C as the twenty-third embodiment of the camera module 1, and FIG. 104B is a schematic cross-sectional view of the camera module 1C.

The camera module 1C includes a total of four optical units 13 on light incident surface in two-by-two in a vertical direction and a horizontal direction. In the four optical units 13, the shape of the lens resin portion 82 is the same in each case.

The four optical units 13 includes the diaphragm plate 51 in the uppermost layer of the laminated lens structure 11, but the four optical units 13 are different from each other in the size of the opening 52 of the diaphragm plate 51. With this arrangement, for example, the camera module 1C can realize the following camera module 1C. Specifically, for example, with regard to a security monitoring camera, in a camera module 1C using the imaging unit 12 that includes a light-receiving pixel that includes three kinds of RGB color filters and receives three kinds of RGB light beams for color image monitoring in the daytime, and a light-receiving pixel that does not include color filters for RGB for monochrome image monitoring in the nighttime, it is possible to enlarge the size of a diaphragm opening only at a pixel for capturing the monochrome image in the nighttime with low illuminance. Accordingly, a planar shape of the lens resin portion 82 in one piece of the camera module 1C, for example, as illustrated in FIG. 104C, a diameter of the lens resin portion 82 provided in the four optical unit 13 is the same in each case, and as illustrated in FIG. 104D, the size of the opening 52 of the diaphragm plate 51 is different depending on the optical units 13.

FIG. 104E is a plan view of a lens-attached substrate 41W for obtaining the lens-attached substrate 41 in a substrate state illustrated in FIG. 104C. FIG. 104F is a plan view of a diaphragm plate 51W in a substrate state for obtaining the diaphragm plate 51 illustrated in FIG. 104D.

The lens-attached substrate 41W in a substrate state in FIG. 104E, and the diaphragm plate 51W in a substrate state in FIG. 104F are set to have a configuration in which eight pieces of the camera modules 1C illustrated in FIG. 104A are obtained for one sheet of substrate.

As illustrated in FIG. 104F, in the diaphragm plate 51W in a substrates state as illustrated in FIG. 104F, to form the camera module 1C, a different size of the opening 52 may be set for every optical unit 13 that is provided in the camera module 1C.

<54. Twenty-Fourth Embodiment of Camera Module 1>

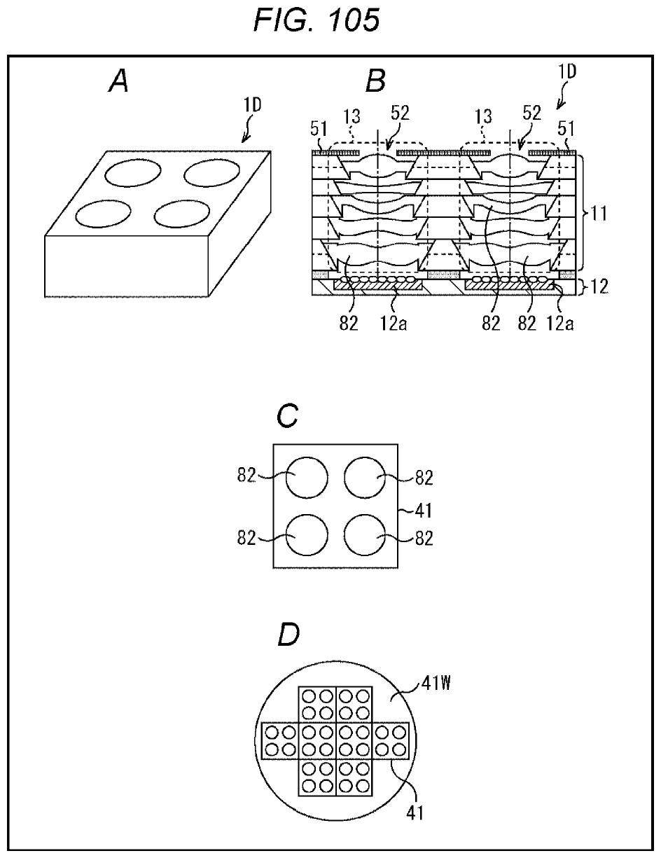

FIG. 105A to FIG. 105D are views illustrating a twenty-fourth embodiment of the camera module to which the present technology is applied.

FIG. 105A is a schematic view illustrating an external appearance of a camera module 1D as the twenty-fourth embodiment of the camera module 1, and FIG. 105B is a schematic cross-sectional view of the camera module 1D.

As in the camera module 1C, the camera module 1D includes a total of four optical units 13 on a light incident surface in two-by-two in a vertical direction and a horizontal direction. In the four optical units 13, the shape of the lens resin portion 82 and the size of the opening 52 of the diaphragm plate 51 are the same in each case.

In the camera module 1D, optical axes of the optical units 13, which are disposed in two-by-two in a vertical direction and a horizontal direction of the light incident surface, extend in the same direction. A one-dot chain line illustrated in FIG. 105B represents an optical axis of each of the optical units 13. The camera module 1D having the above-described structure is more suitable for capturing of a high-resolution image by using super-resolution technique in comparison to image capturing by one piece of the optical unit 13.

In the camera module 1D, an image is captured with a plurality of the imaging units 12 which are disposed at different positions in a vertical direction and in a horizontal direction and of which optical axes are oriented in the same direction, or an image is captured with light-receiving pixels in different regions in one piece of the imaging unit 12. Accordingly, it is possible to obtain a plurality of sheets of images which are not necessarily the same as each other while the optical axes are oriented in the same direction. An image with high resolution can be obtained by matching image data for every location in the plurality of sheets of images which are not the same as each other. Accordingly, it is preferable that a planar shape of the lens resin portion 82 in one piece of the camera module 1D is the same in each of the four optical units 13 as illustrated in FIG. 105C.

FIG. 105D is a plan view of a lens-attached substrate 41W in a substrate state for obtaining the lens-attached substrate 41 illustrated in FIG. 105C. The lens-attached substrate 41W in a substrate state has a configuration in which eight pieces of the camera modules 1D illustrated in FIG. 105A are obtained for one sheet of substrate.

As illustrated in FIG. 105D, in the lens-attached substrate 41W in a substrate state, to form the camera module 1D, the camera module 1D includes a plurality of the lens resin portions 82, and a plurality of lens groups, each being set for one piece of module, are disposed on a substrate at a constant pitch.

<55. Description of Pixel Arrangement of Imaging Unit 12, and Structure and Usage of Diaphragm Plate>

Next, description will be given of a pixel arrangement of the imaging unit 12 and a configuration of the diaphragm plate 51, the imaging unit 12 and the diaphragm plate 51 being provided in the camera modules 1 illustrated in FIG. 104A to FIG. 104F and FIG. 105A to FIG. 105D.

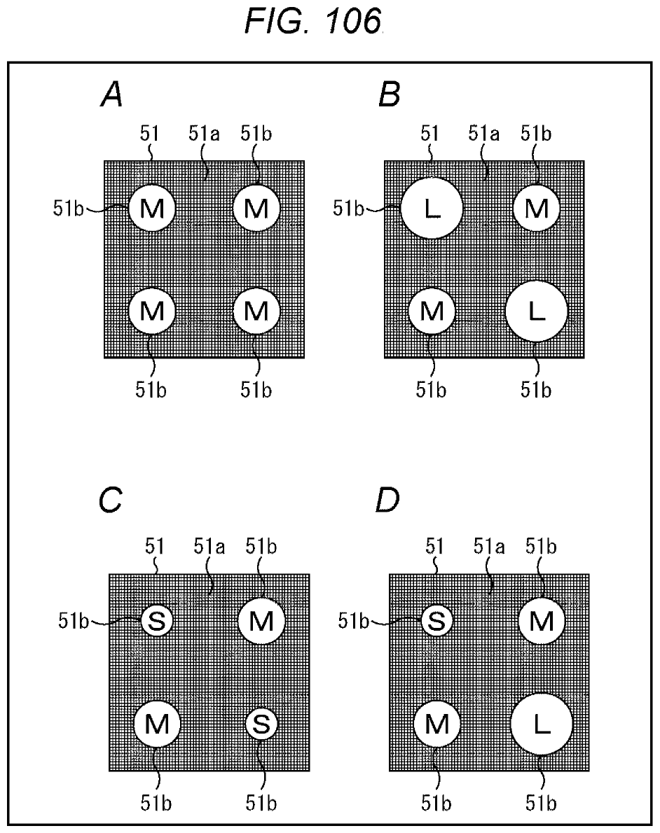

FIG. 106A to FIG. 106D are views illustrating an example of a planar shape of the diaphragm plate 51 that is provided in the camera modules 1 illustrated in FIG. 104 and FIG. 105A to FIG. 105D.

The diaphragm plate 51 includes a shield region 51a that prevents incidence of light by absorbing or reflecting light, and an opening region 51b through which light is transmitted.

In the four optical units 13 which are provided in the camera modules 1 illustrated in FIG. 104A to FIG. 104F and FIG. 105A to FIG. 105D, opening diameters of four opening regions 51b of the diaphragm plate 51 may be the same as each other or different from each other as illustrated in FIG. 106A to FIG. 106D. “L”, “M”, or “S” in FIG. 106A to FIG. 106D represents that the opening diameter of the opening region 51b is “large”, “middle”, or “small”.

In a diaphragm plate 51 described in FIG. 106A, the opening diameter of four opening regions 51b is the same in each case.

In a diaphragm plate 51 described in FIG. 106B, the size of the opening diameter of two opening regions 51b is “middle”, that is, a standard diaphragm opening. In this configuration, for example, as illustrated in FIG. 1, the diaphragm plate 51 may slightly overlap the lens resin portion 82 of the lens-attached substrate 41. In other words, the opening region 51b of the diaphragm plate 51 may be slightly smaller than the diameter of the lens resin portion 82. In addition, in the remaining two opening regions 51b of the diaphragm plate 51 described in FIG. 106B, the size of the opening diameter is “large”, that is, the opening diameter is greater than the opening diameter of “middle”. For example, in a case where illuminance of a subject is low, the large opening region 51b exhibits an operation of allowing a large number of light beams to be incident to the imaging unit 12 that is provided in the camera module 1.

A diaphragm plate 51 described in FIG. 106C, the size of the opening diameter of two opening regions 51b is “middle”, that is, a standard diaphragm opening. In addition, in the remaining two opening regions 51b of the diaphragm plate 51 described in FIG. 106C, the opening diameter is “small”, that is, the opening diameter is smaller than the opening diameter of “middle”. For example, in a case where illuminance of a subject is high, and in a case where light is transmitted through the opening region 51b in which the size of the opening diameter is “middle” and is incident to the imaging unit 12 provided in the camera module 1, charges, which occur in a photoelectric conversion unit provided in the imaging unit 12, may exceed a saturation charge amount of the photoelectric conversion unit, the small opening regions 51b exhibit an operation of reducing a light amount incident to the imaging unit 12.

In a diaphragm plate 51 described in FIG. 106D, the size of the opening diameter of two opening regions 51b is “middle”, that is, a standard diaphragm opening. In addition, in the remaining two opening regions 51b of the diaphragm plate 51 described in FIG. 106D, the size of one opening diameter is “large”, and the size of one opening diameter is “small”. The opening regions 51b exhibit a similar operation as in the opening regions 51b, in which the size of the opening diameter is “large” or “small”, as described in FIG. 106B and FIG. 106C.

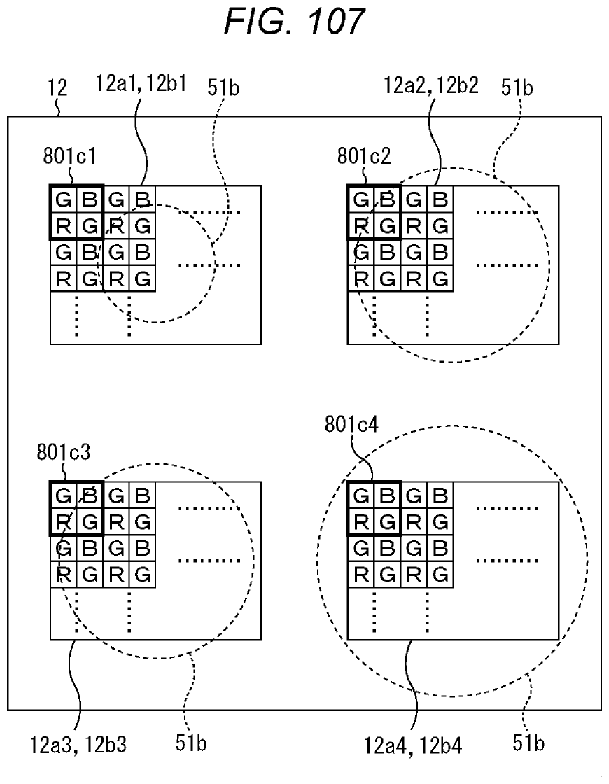

FIG. 107 illustrates a configuration of the imaging unit 12 of the camera modules 1 illustrated in FIG. 104A to FIG. 104F and FIG. 105A to FIG. 105D.

As illustrated in FIG. 107, the camera modules 1 include four optical units 13 (not illustrated in the drawing). In addition, light beams, which are incident to the four optical units 13, are received by light-receiving units corresponding to the optical units 13. Accordingly, in the camera modules 1 illustrated in FIG. 104A to FIG. 104F and FIG. 105A to FIG. 105D, the imaging unit 12 includes four light-receiving regions 12a1 to 12a4.

Furthermore, as additional embodiment relating to the light-receiving units, the following configuration may be employed. Specifically, the imaging unit 12 includes one piece of light-receiving region 12a that receives a light beam incident to one optical unit 13 provided in the camera module 1, and the camera module 1 includes the imaging unit 12 in a number corresponding to the number of the optical units 13 provided in the camera module 1, for example, four in the case of the camera modules 1 described in FIG. 104A to FIG. 104F and FIG. 105A to FIG. 105D.

The light-receiving regions 12a1 to 12a4 respectively include pixel arrays 12b1 to 12b4 in which pixels receiving light are arranged in an array.

Furthermore, in FIG. 107, a circuit that drives pixels in the pixel arrays or a circuit that reads out the pixels is omitted for simplification, and the light-receiving regions 12a1 to 12a4, and the pixel arrays 12b1 to 12b4 are illustrated in the same size.

The pixel arrays 12b1 to 12b4, which are respectively provided in the light-receiving regions 12a1 to 12a4, include pixel repetition units 801c1 to 801c4, each including a plurality of pixels. A plurality of the repetition units 801c1, a plurality of the repetition units 801c2, a plurality of the repetition units 801c3, and a plurality of the repetition units 801c4 are arranged in an array shape both in a vertical direction and in a horizontal direction to constitute the pixel arrays 12b1 to 12b4.

The optical unit 13 is disposed on each of the four light-receiving regions 12a1 to 12a4 provided in the imaging unit 12. The four optical units 13 include the diaphragm plate 51 as a part thereof. In FIG. 107, as an example of an opening diameter of the four opening regions 51b of the diaphragm plate 51, the opening regions 51b of the diaphragm plate 51 illustrated in FIG. 106D are indicated by a broken line.

In an image signal processing field, as a technology of obtaining an image with high resolution through adaption to an original image, super-resolution technique is known. An example thereof is disclosed, for example, in JP 2015-102794A.

The camera modules 1 described in FIG. 104A to FIG. 104F and FIG. 105A to FIG. 105D can take a structure described in FIG. 98 to FIG. 101, and the like as a cross-sectional structure.

In the camera modules 1, optical axes of the optical units 13, which are disposed in two-by-two in a vertical direction and a horizontal direction of a surface of the camera modules 1 as a light incident surface, extend in the same direction. With this arrangement, it is possible to obtain a plurality of sheets of images which are not necessarily the same as each other by using different light-receiving regions while the optical axes are oriented in the same direction.

The camera modules 1 having the above-described structure are suitable to obtain an image with resolution higher than resolution of one sheet of image obtained from one piece of optical unit 13 by using the super-resolution technique on the basis of a plurality of sheets of original images which are obtained.

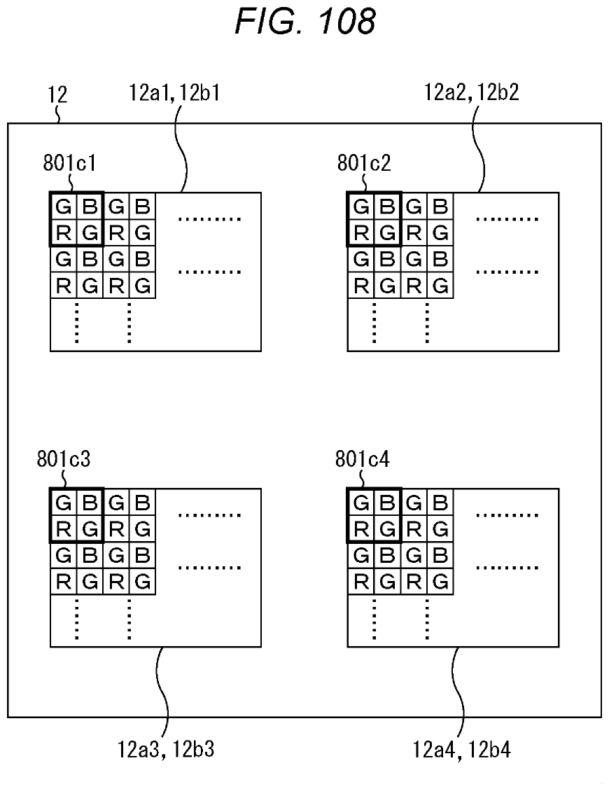

FIG. 108 to FIG. 111 illustrate a configuration example of pixels in the light-receiving region 12a of the camera modules 1 illustrated in FIG. 104A to FIG. 104F and FIG. 105A to FIG. 105D.

Furthermore, in FIG. 108 to FIG. 111, a pixel of G represents a pixel that receives light of a green wavelength, a pixel of R represents a pixel that receives light of a red wavelength, and pixel of B represents a pixel that receives light of a blue wavelength. A pixel of C represents a pixel that receives light in entire wavelength regions of visible light.

FIG. 108 illustrates a first example of a pixel arrangement of the four pixel arrays 12b1 to 12b4 which are provided in the imaging unit 12 of the camera module 1.

In the four pixel arrays 12b1 to 12b4, the repetition units 801c1 to 801c4 are repetitively arranged in a column direction and a row direction. Each of the repetition units 801c1 to 801c4 in FIG. 108 includes pixels of R, G, B, and G.

The pixel arrangement in FIG. 108 exhibits an operation suitable for spectrally separating incident light from a subject irradiated with visible light into red (R), green (G), and blue (B) to obtain an image including three colors of RGB.

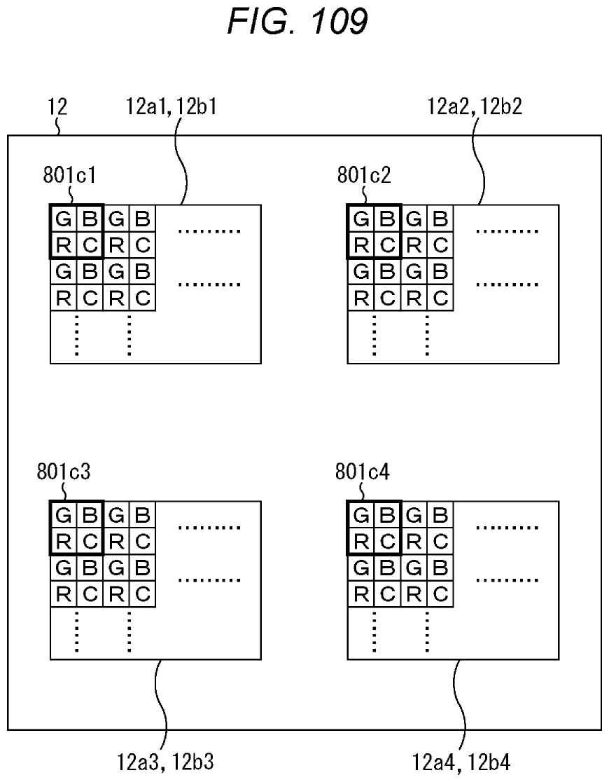

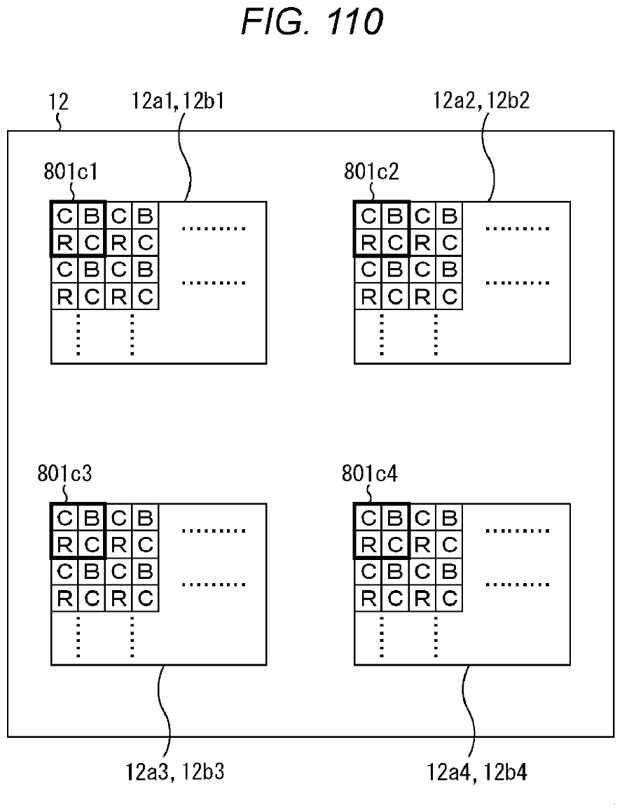

FIG. 109 illustrates a second example of a pixel arrangement of the four pixel arrays 12b1 to 12b4 which are provided in the imaging unit 12 of the camera module 1.

The pixel arrangement in FIG. 109 is different from the pixel arrangement in FIG. 108 in a combination of wavelengths (colors) of light received by respective pixels which constitute the repetition units 801c1 to 801c4. In FIG. 109, each of the repetition units 801c1 to 801c4 is constituted by pixels of R, G, B, and C.

The pixel arrangement in FIG. 109 includes a pixel of C that receives light in entire wavelength regions of visible light without spectrally separating the light as described above. The pixel of C receives a large amount of light in comparison to pixels of R, G, and B which receive parts of light that is spectrally separated. Accordingly, for example, even in a case where illuminance of a subject is low, the above-described configuration exhibits an operation capable of obtaining an image with higher luminosity or an image with higher gradation relating to luminance by using information obtained from the pixel of C in which a light reception amount is great, for example, luminance information of the subject.

FIG. 110 illustrates a third example of a pixel arrangement of the four pixel arrays 12b1 to 12b4 which are provided in the imaging unit 12 of the camera module 1.

In FIG. 110, each of the repetition units 801c1 to 801c4 includes pixels of R, C, B, and C.

The pixel repetition units 801c1 to 801c4 described in FIG. 110 do not include a pixel of G. Information corresponding to the pixel of G is obtained through operation processing of information obtained from pixels of C, R, and B. For example, the information corresponding to the pixel of G is obtained by subtracting output values of the pixel of R and the pixel of B from an output value of the pixel of C.

The pixel repetition units 801c1 to 801c4 described in FIG. 110 include two pixels of C which receives light of entire wavelength regions, which are two times the number the pixel of C in the repetition units 801c1 to 801c4 described in FIG. 109. In addition, in the pixel repetition units 801c1 to 801c4 described in FIG. 110, the two pixels of C are repetitively disposed in a diagonal direction of a contour line of the unit 801c so that a pitch of the pixel of C in the pixel array 12b provided in FIG. 110 becomes two times a pitch of the pixel C in the pixel array 12b provided in FIG. 109 both in the vertical direction and in the horizontal direction of the pixel array 12b.

Accordingly, for example in a case where illuminance of a subject is low, the configuration described in FIG. 110 exhibits an operation capable of obtaining information that is obtained from the pixel of C in which the light reception amount is great, for example, luminance information with resolution that is two times resolution in the configuration described in FIG. 109, thereby obtaining an clear image with resolution enhanced by two times.

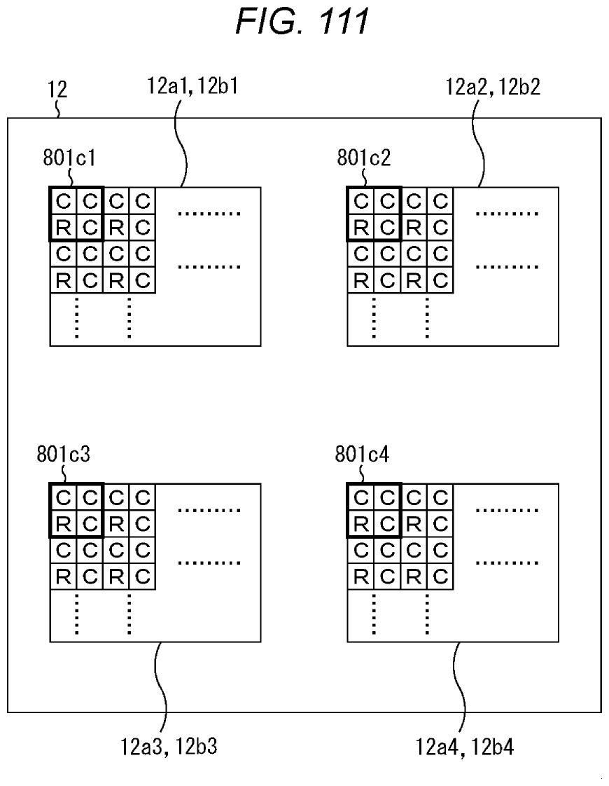

FIG. 111 illustrates a fourth example of a pixel arrangement of the four pixel arrays 12b1 to 12b4 which are provided in the imaging unit 12 of the camera module 1.

In FIG. 111, each of the repetition units 801c1 to 801c4 includes pixels of R, C, C, and C.

For example, in a use of a camera that is mounted on a vehicle and photographs a forward side, a color image may not necessary in many cases. In many cases, it is necessary to recognize a red brake lamp of a vehicle that travels on a forward side and a red signal of a traffic signal provided on a road, and to recognize a shape of other subjects.

Accordingly, the configuration described in FIG. 111 exhibits the following operation. Specifically, since the pixel of R is provided, the red brake lamp of a vehicle and the red signal of the traffic signal provided on a load are recognized. In addition, the pixel of C in which a light reception amount is great is provided in a number greater in comparison to the pixel repetition unit 801c described in FIG. 110. Accordingly, for example, even in a case where illuminance of a subject is low, it is possible to obtain a clear image with higher resolution.

Furthermore, the camera module 1 that includes any one of the imaging units 12 illustrated in FIG. 108 to FIG. 111 may use a shape described in any of FIG. 106A to FIG. 106D as a shape of the diaphragm plate 51.

In the camera modules 1 described in FIG. 104A to FIG. 104F and FIG. 105A to FIG. 105D, which include any one of the imaging units 12 illustrated in FIG. 108 to FIG. 111, and the diaphragm plate 51 described in any one of FIG. 106A to FIG. 106D, optical axes of the optical units 13, which are disposed in two-by-two in a vertical direction and a horizontal direction of a surface of the camera modules 1 as a light incident surface, extend in the same direction.

The camera modules 1 having the above-described structure exhibit an operation capable of obtaining an image with high resolution by adapting the super-resolution technique to a plurality of sheet of original images which are obtained.

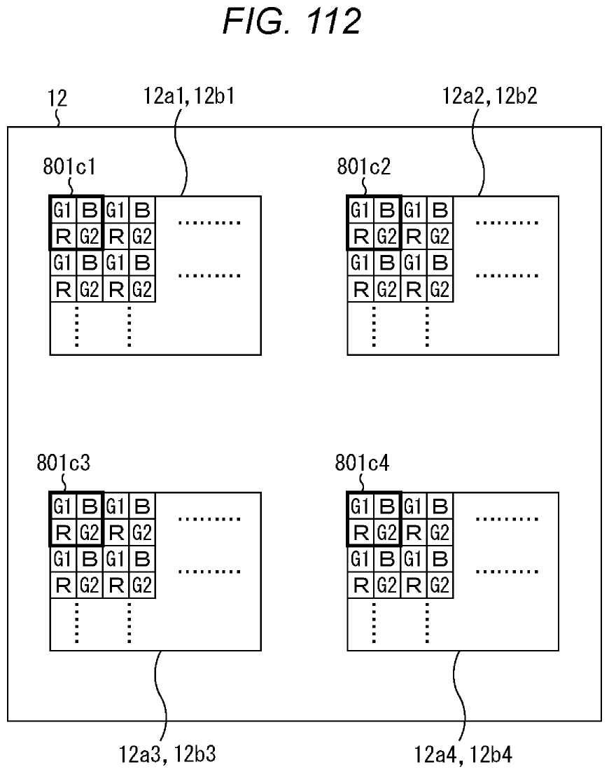

FIG. 112 illustrates a modification example of the pixel arrangement illustrated in FIG. 108.

The repetition units 801c1 to 801c4 in FIG. 108 include pixels of R, G, B, and G, and have the same structure between two pixels of G having the same color. In contrast, in FIG. 112, repetition units 801c1 to 801c4 include pixels of R, G1, B, and G2. In addition, a pixel structure is different between two pixels of G having the same color, that is, the pixel of G1 and the pixel of G2.

The pixel of G1 and the pixel of G2 respectively include signal generation units (for example, photodiodes). An appropriate operation limit is higher (for example, a saturation charge amount is greater) in the signal generation unit provided in the pixel of G2 in comparison to the signal generation unit provided in the pixel of G1. In addition, the magnitude of generated signal conversion means (for example, a charge voltage conversion capacity) provided in a pixel is also greater on the pixel of G2 side in comparison to the pixel of G1 side.

According to the configurations, in the pixel of G2, an output signal in a case of generating a signal (for example, a charge) in a constant amount per unit time can be suppressed to be smaller in comparison to the pixel of G1, and a saturation charge amount is greater. Accordingly, for example, even in a case where illuminance of a subject is high, it is possible to exhibit an operation in which a pixel does not reach the operation limit, an image with higher gradation is obtained.

On the other hand, in the pixel of G1, in a case of generating a signal (for example, a charge) in a constant amount per unit time, an output signal that is larger in comparison to the pixel of G2 is obtained. Accordingly, for example, even in a case where illuminance of a subject is low, it is possible to exhibit an operation in which an image with high gradation is obtained.

The imaging unit 12 described in FIG. 112 includes the pixel of G1 and the pixel of G2. Accordingly, it is possible to exhibit an operation capable of obtaining an image with high gradation in a wide illuminance range, that is, a so-called wide dynamic range image is obtained.

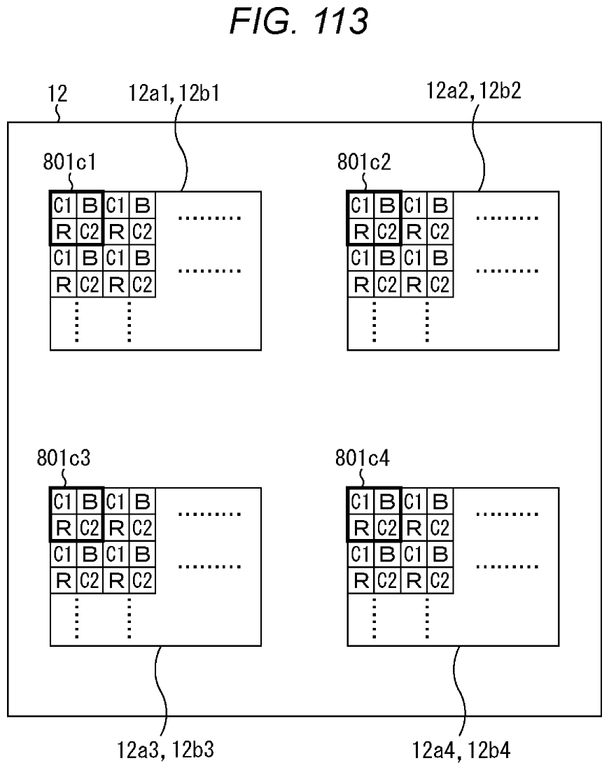

FIG. 113 illustrates a modification example of the pixel arrangement in FIG. 110.

The repetition units 801c1 to 801c4 in FIG. 110 include pixels of R, C, B, and C, and have the same structure between two pixels of C having the same color. In contrast, in FIG. 113, repetition units 801c1 to 801c4 include pixels of R, C1, B, and C2. In addition, a pixel structure is different between two pixels of C having the same color, that is, the pixel of C1 and the pixel of C2.

The pixel of C1 and the pixel of C2 respectively include signal generation units (for example, photodiodes) provided in the pixels. An operation limit is higher (for example, a saturation charge amount is greater) in the signal generation unit provided in the pixel of C2 in comparison to the signal generation unit provided in the pixel of C1. In addition, the magnitude of generated signal conversion means (for example, a charge voltage conversion capacity) provided in a pixel is also greater on the pixel of C2 side in comparison to the pixel of C1 side.

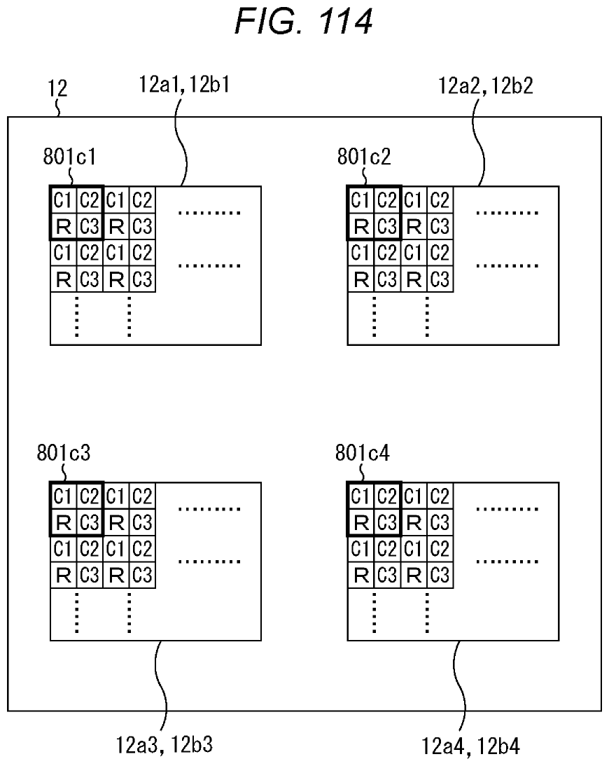

FIG. 114 illustrates a modification example of the pixel arrangement illustrated in FIG. 111.

The repetition units 801c1 to 801c4 in FIG. 111 include pixels of R, C, C, and C, and have the same structure between three pixels of C having the same color. In contrast, in FIG. 114, repetition units 801c1 to 801c4 include pixels of R, C1, C2, and C3. In addition, a pixel structure is different between three pixels of C having the same color, that is, the pixels of C1 to C3.

For example, the pixels of C1 to C3 respectively include signal generation units (for example, photodiodes) which are provided in the pixels. An operation limit is higher (for example, a saturation charge amount is greater) in the signal generation unit provided in the pixel of C2 in comparison to the signal generation unit provided in the pixels of C1. In addition, the operation limit is higher in the signal generation unit provided in the pixels of C3 in comparison to the signal generation unit provided in the pixel of C2. In addition, the magnitude of generated signal conversion means (for example, a charge voltage conversion capacity) provided in pixels of C2 is also greater than the magnitude of the generated signal conversion means in pixels of C1, and the magnitude of the generated signal conversion means in the pixels of C3 is greater than the magnitude of the generated signal conversion means in the pixels of C2.

Since the imaging units 12 described in FIG. 113 and FIG. 114 have the above-described configurations. Accordingly, it is possible to exhibit an operation capable of obtaining an image with high gradation in a wide illuminance range, that is, a so-called wide dynamic range image as in the imaging unit 12 described in FIG. 112.

As a configuration of the diaphragm plate 51 of the camera modules 1 which include the imaging units 12 described in FIG. 112 to FIG. 114, it is possible to employ configurations of various diaphragm plates 51 which are illustrated in FIG. 106A to FIG. 106D, or modification examples thereof.

In the camera modules 1 described in FIG. 104A to FIG. 104F and FIG. 105A to FIG. 105D, which include any one of the imaging units 12 illustrated in FIG. 112 to FIG. 114, and the diaphragm plate 51 described in any one of FIG. 106A to FIG. 106D, optical axes of the optical units 13, which are disposed in two-by-two in a vertical direction and a horizontal direction of a surface of the camera modules 1 as a light incident surface, extend in the same direction.

The camera modules 1 having the above-described structure exhibit an operation capable of obtaining an image with high resolution by adapting the super-resolution technique to a plurality of sheet of original images which are obtained.

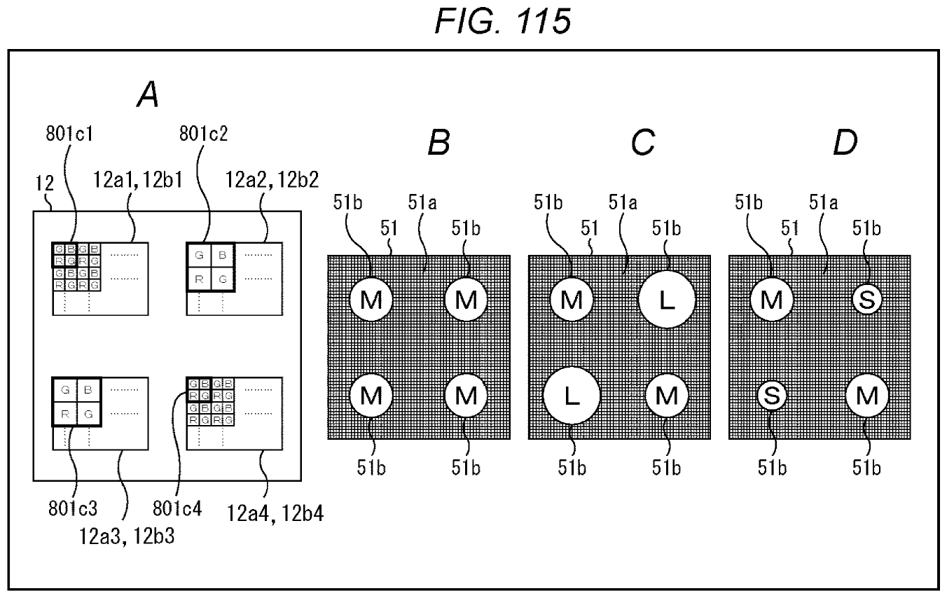

FIG. 115A illustrates a fifth example of the pixel arrangement of the four pixel arrays 12b1 to 12b4 which are provided in the imaging unit 12 of the camera module 1.

The four pixel arrays 12b1 to 12b4, which are provided in the imaging unit 12, may have structures different from each other as illustrated in FIG. 115A instead of the same structure as described above.

In the imaging unit 12 illustrated in FIG. 115A, the pixel array 12b1 and the pixel array 12b4 have the same structure. Accordingly, repetition units 801c1 and 801c4 which constitute the pixel array 12b1 and the pixel array 12b4 also have the same structure.

In contrast, a structure of the pixel array 12b2 and the pixel array 12b3 is different from a structure of the pixel array 12b1 and the pixel array 12b4. Specifically, a pixel size in the repetition units 801c2 and 801c3 of the pixel array 12b2 and the pixel array 12b3 is larger than a pixel size in the repetition units 801c1 and 801c4 of the pixel array 12b1 and the pixel array 12b4. In other words, the size of the photoelectric conversion unit included in a pixel is greater on the larger pixel size side. Since the pixel size is larger, a region size of the repetition units 801c2 and 801c3 is also greater than a region size of the repetition units 801c1 and 801c4. Accordingly, although having the same area, the number of pixels in the pixel array 12b2 and the pixel array 12b3 is smaller than the number of pixels in the pixel array 12b1 and the pixel array 12b4.

As a configuration of the diaphragm plate 51 of the camera module 1 that includes the imaging unit 12 described in FIG. 115A, it is possible to employ configurations of various diaphragm plates 51 illustrated in FIG. 106A to FIG. 106C, configurations of the diaphragm plates 51 illustrated in FIG. 115B to FIG. 115D, or modification examples thereof.

Typically, a light-receiving element that uses a large pixel exhibits an operation of obtaining an image with a satisfactory signal to noise ratio (S/N ratio) in comparison to a light-receiving element that uses a small pixel.

For example, the magnitude of noise in a signal reading-out circuit or a circuit that amplifies a read-out signal is approximately the same between a light-receiving element that uses a large pixel and a light-receiving element that uses a small pixel. In contrast, the larger a pixel is, the greater the magnitude of a signal generated in a signal generation unit provided in a pixel becomes.

Accordingly, the light-receiving element that uses a large pixel exhibits an operation of obtaining an image with a further satisfactory signal to noise ratio (S/N ratio) in comparison to a light-receiving element that uses a small pixel.

On the other hand, when pixel arrays have the same size, the light-receiving element that uses a small pixel has higher resolution in comparison to the light-receiving element that uses a large pixel.

Accordingly, the light-receiving element that uses a small pixel exhibits an operation of obtaining an image with higher resolution in comparison to the light-receiving element that uses a large pixel.

The configuration that is provided in the imaging unit 12 described in FIG. 115A exhibits the following operation. For example, in a case where illuminance of a subject is high and thus a large signal is obtained in the imaging unit 12, it is possible to obtain images with high resolution by using the light-receiving regions 12a1 and 12a4 in which a pixel size is small and resolution is high. In addition, images with higher resolution are obtained by adapting the super-resolution technique to two sheets of the images.

In addition, the following operation is also exhibited. In a case where illuminance of a subject is low and a large signal is not obtained in the imaging unit 12, and thus there is a concern that the S/N ratio of an image deteriorates, it is possible to obtain images with a high S/N ratio by using the light-receiving regions 12a2 and 12a3 in which images with a high S/N ratio are obtained. In addition, images with higher resolution are obtained by adapting the super-resolution technique to two sheets of the images.

In this case, as the shape of the diaphragm plate 51, the camera module 1 including the imaging unit 12 illustrated in FIG. 115A may use, for example, a shape of the diaphragm plate described in FIG. 115B among three sheets relating to the shape of the diaphragm plates 51 described in FIG. 115B to FIG. 115D.

Among the three sheets relating to the shape of the diaphragm plates 51 described in FIG. 115B to FIG. 115D, for example, the opening region 51b of the diaphragm plate 51 in FIG. 115C, which is used in combination with the light-receiving regions 12a2 and the light-receiving region 12a3 which use a large pixel, is larger than the opening region 51b of the diaphragm plate 51 that is used in combination with other light-receiving regions.

Accordingly, in a camera module 1 that uses the diaphragm plate 51 in FIG. 115C among the three sheets relating to the shape of the diaphragm plates 51 described in FIG. 115B to FIG. 115D in combination with the imaging unit 12 illustrated in FIG. 115A, for example, in a case where illuminance of a subject is low and thus a large signal is not obtained in the imaging unit 12, it is possible to exhibit an operation capable of obtaining an image with a higher S/N ratio in the light-receiving region 12a2 and the light-receiving region 12a3 in comparison to a camera module 1 that uses the diaphragm plate 51 in FIG. 115B in combination with the imaging unit 12 illustrated in FIG. 115A.

Among the three sheets relating to the shape of the diaphragm plates 51 described in FIG. 115B to FIG. 115D, for example, the opening region 51b of the diaphragm plate 51 in FIG. 115D, which is used in combination with the light-receiving regions 12a2 and the light-receiving region 12a3 which use a large pixel, is smaller than the opening region 51b of the diaphragm plate 51 that is used in combination with other light-receiving regions.

Accordingly, in a camera module 1 that uses the diaphragm plate 51 in FIG. 115D among the three sheets relating to the shape of the diaphragm plates 51 described in FIG. 115B to FIG. 115D in combination with the imaging unit 12 illustrated in FIG. 115A, for example, in a case where illuminance of a subject is high and thus a large signal is obtained in the imaging unit 12, it is possible to exhibit an operation of further suppressing the amount of light incident to the light-receiving region 12a2 and the light-receiving region 12a3 in comparison to a camera module 1 that uses the diaphragm plate 51 in FIG. 115B among the three sheets relating to the shape of the diaphragm plate 51 described in FIG. 115B to FIG. 115D in combination with the imaging unit 12 illustrated in FIG. 115A.

According to this, it is possible to exhibit an operation of suppressing occurrence of a situation in which excessive light is incident to pixels provided in the light-receiving region 12a2 and the light-receiving region 12a3, and thus it exceeds an appropriate operation limit (for example, it exceeds a saturation charge amount) of pixels provided in the light-receiving region 12a2 and the light-receiving region 12a3.

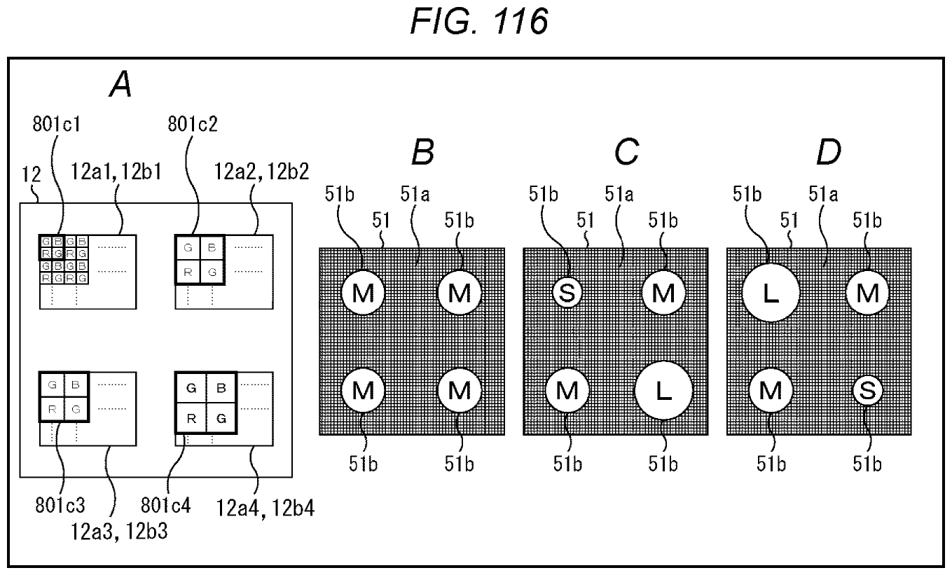

FIG. 116A illustrates a sixth example of the pixel arrangement of the four pixel arrays 12b1 to 12b4 which are provided in the imaging unit 12 of the camera module 1.

In the imaging unit 12 illustrated in FIG. 116A, a region size of the repetition unit 801c1 of the pixel array 12b1 is smaller than a region size of the repetition units 801c2 and 801c3 of the pixel arrays 12b2 and 12b3. A region size of a repetition unit 801c4 of the pixel array 12b4 is larger than a region size of repetition units 801c2 and 801c3 of the pixel arrays 12b2 and 12b3.

That is, the region sizes of the repetition units 801c1 to 801c4 have a relationship, that is, the repetition unit 801c1<(the repetition unit 801c2=the repetition unit 801c3)<the repetition unit 801c4.

Further larger the region size of the repetition units 801c1 to 801c4 is, the larger the pixel size is, and the larger the size of the photoelectric conversion unit is.

As a configuration of the diaphragm plate 51 of the camera module 1 that includes the imaging unit 12 described in FIG. 116A, it is possible to employ configurations of various diaphragm plates 51 illustrated in FIG. 106A to FIG. 106C, configurations of the diaphragm plates 51 illustrated in FIG. 116B to FIG. 116D, or modification examples thereof.

The configuration that is provided in the imaging unit 12 described in FIG. 116A exhibits the following operation. For example, in a case where illuminance of a subject is high and thus a large signal is obtained in the imaging unit 12, it is possible to obtain an image with high resolution by using the light-receiving regions 12a1 in which a pixel size is small and resolution is high.

In addition, the following operation is also exhibited. In a case where illuminance of a subject is low and a large signal is not obtained in the imaging unit 12, and thus there is a concern that the S/N ratio of an image deteriorates, it is possible to obtain images with a high S/N ratio by using the light-receiving regions 12a2 and 12a3 in which images with a high S/N ratio are obtained. In addition, images with higher resolution are obtained by adapting the super-resolution technique to two sheets of the images.

In addition, the following operation is exhibited. In a case where illuminance of a subject is lower and thus there is a concern that the S/N ratio of an image in the imaging unit 12 further deteriorates, it is possible to obtain an image with a high S/N ratio by using the light-receiving region 12a4 in which an image with a higher S/N ratio is obtained.

In this case, as the shape of the diaphragm plate 51, the camera module 1 including the imaging unit 12 illustrated in FIG. 116A may use, for example, a shape of the diaphragm plate 51 described in FIG. 116B among three sheets relating to the shape of the diaphragm plates 51 described in FIG. 116B to FIG. 116D.

Among the three sheets relating to the shape of the diaphragm plates 51 described in FIG. 116B to FIG. 116D, for example, the opening region 51b of the diaphragm plate 51 in FIG. 116C, which is used in combination with the light-receiving regions 12a2 and the light-receiving region 12a3 which use a large pixel, is larger than the opening region 51b of the diaphragm plate 51 that is used in combination with light-receiving regions 12a1 that uses a small pixel. In addition, the opening region 51b of the diaphragm plate 51 that is used in combination with the light-receiving region 12a4 that uses a large pixel is further larger.

Accordingly, in a camera module 1 that uses the diaphragm plate 51 in FIG. 116C among three sheets relating to the shape of the diaphragm plates 51 described in FIG. 116B to FIG. 116D in combination with the imaging unit 12 illustrated in FIG. 116A, for example, in a case where illuminance of a subject is low and thus a large signal is not obtained in the imaging unit 12, it is possible to exhibit an operation capable of obtaining an image with a higher S/N ratio in the light-receiving region 12a2 and the light-receiving region 12a3 in comparison to a camera module 1 that uses the diaphragm plate 51 in FIG. 116B among the three sheets relating to the shape of the diaphragm plate 51 described in FIG. 116B to FIG. 116D in combination with the imaging unit 12 illustrated in FIG. 116A. In addition, in a case where illuminance of the subject is further lower, it is possible to exhibit an operation capable of obtaining an image with a high S/N ratio in the light-receiving region 12a4.

Among the three sheets relating to the shape of the diaphragm plates 51 described in FIG. 116B to FIG. 116D, for example, the opening region 51b of the diaphragm plate 51 in FIG. 116D, which is used in combination with the light-receiving regions 12a2 and the light-receiving region 12a3 which use a large pixel, is smaller than the opening region 51b of the diaphragm plate 51 that is used in combination with light-receiving regions 12a1 that uses a small pixel. In addition, the opening region 51b of the diaphragm plate 51 that is used in combination with the light-receiving region 12a4 that uses a large pixel is further smaller.

Accordingly, in a camera module 1 that uses the diaphragm plate 51 in FIG. 116D among three sheets relating to the shape of the diaphragm plates 51 described in FIG. 116B to FIG. 116D in combination with the imaging unit 12 illustrated in FIG. 116A, for example, in a case where illuminance of a subject is high and thus a large signal is obtained in the imaging unit 12, it is possible to exhibit an operation of further suppressing the amount of light incident to the light-receiving region 12a2 and the light-receiving region 12a3 in comparison to a camera module 1 that uses the diaphragm plate 51 in FIG. 116B among the three sheets relating to the shape of the diaphragm plate 51 described in FIG. 116B to FIG. 116D in combination with the imaging unit 12 illustrated in FIG. 116A.

According to this, it is possible to exhibit an operation of suppressing occurrence of a situation in which excessive light is incident to pixels provided in the light-receiving region 12a2 and the light-receiving region 12a3, and thus it exceeds an appropriate operation limit (for example, it exceeds a saturation charge amount) of pixels provided in the light-receiving region 12a2 and the light-receiving region 12a3.

In addition, it is possible to exhibit an operation of further suppressing the amount of light incident to the light-receiving region 12a4, thereby suppressing occurrence of a situation in which excessive light is incident to the pixels provided in the light-receiving region 12a4, and it exceeds an appropriate operation limit (for example, it exceeds a saturation charge amount) of a pixel provided in the light-receiving region 12a4.

Furthermore, as another embodiment, for example, a diaphragm plate 51 in which the opening region 51b is variable may be provided in a camera module by using a similar structure as in a diaphragm in which a plurality of plates are combined and a positional relation thereof is changed to change the size of an opening as can be used in a typical camera, and the size of the opening of the diaphragm may be changed in correspondence with illuminance of a subject.

For example, in the case of using the imaging units 12 described in FIG. 115A and FIG. 116A, the following structure may be used. Specifically, in a case where illuminance of a subject is low, among three sheets relating to the shape of the diaphragm plates 51 described in FIG. 115B to FIG. 115D and FIG. 116B to FIG. 116D, shapes in FIG. 115C and FIG. 116C are used. In addition, in a case where illuminance of the subject is higher, shapes in FIG. 115B and in FIG. 116B are used. In addition, in a case where illuminance of the subject is further higher, shapes in FIG. 115D and FIG. 116D are used.

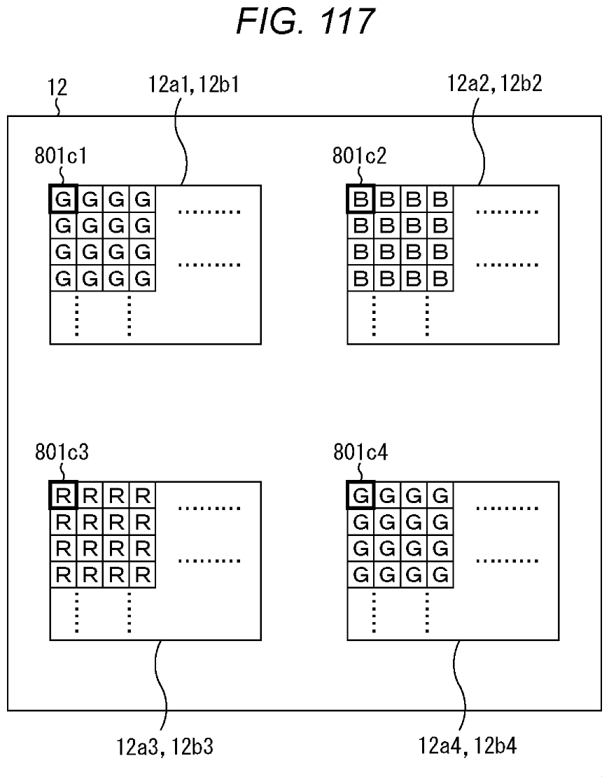

FIG. 117 illustrates a seventh example of the pixel arrangement of the four pixel arrays 12b1 to 12b4 which are provided in the imaging unit 12 of the camera module 1.

In the imaging unit 12 illustrated in FIG. 117, the entirety of pixels of the pixel array 12b1 are pixels which receive light of a green wavelength. The entirety of pixels of the pixel array 12b2 are pixels which receive light of a blue wavelength. The entirety of pixels of the pixel array 12b3 are pixels which receive light of a red wavelength. The entirety of pixels of the pixel array 12b4 are pixels which receive light of a green wavelength.

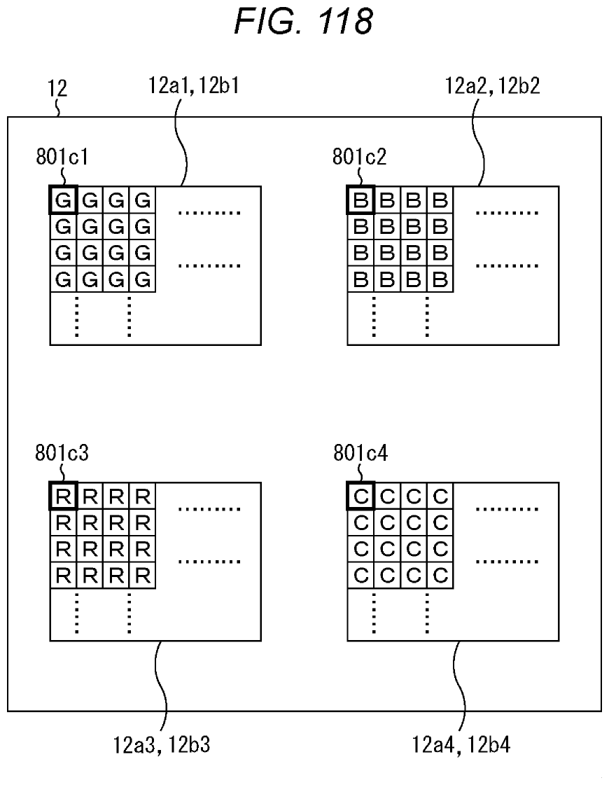

FIG. 118 illustrates an eighth example of the pixel arrangement of the four pixel arrays 12b1 to 12b4 which are provided in the imaging unit 12 of the camera module 1.

In the imaging unit 12 illustrated in FIG. 118, the entirety of pixels of the pixel array 12b1 are pixels which receive light of a green wavelength. The entirety of pixels of the pixel array 12b2 are pixels which receive light of a blue wavelength. The entirety of pixels of the pixel array 12b3 are pixels which receive light of a red wavelength. The entirety of pixels of the pixel array 12b4 are pixels which receive light in entire wavelength regions of visible light.

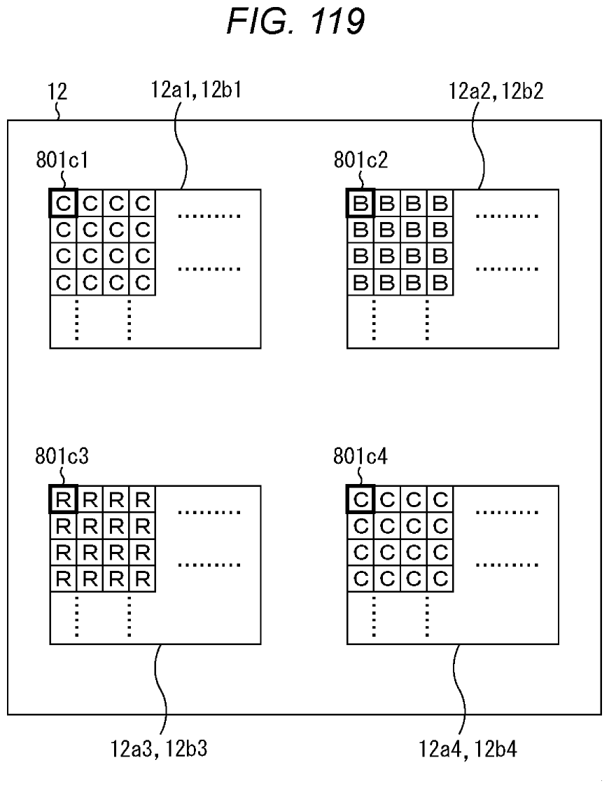

FIG. 119 illustrates a ninth example of the pixel arrangement of the four pixel arrays 12b1 to 12b4 which are provided in the imaging unit 12 of the camera module 1.

In the imaging unit 12 illustrated in FIG. 119, the entirety of pixels of the pixel array 12b1 are pixels which receive light in entire wavelength regions of visible light. The entirety of pixels of the pixel array 12b2 are pixels which receive light of a blue wavelength. The entirety of pixels of the pixel array 12b3 are pixels which receive light of a red wavelength. The entirety of pixels of the pixel array 12b4 are pixels which receive light in entire wavelength regions of visible light.

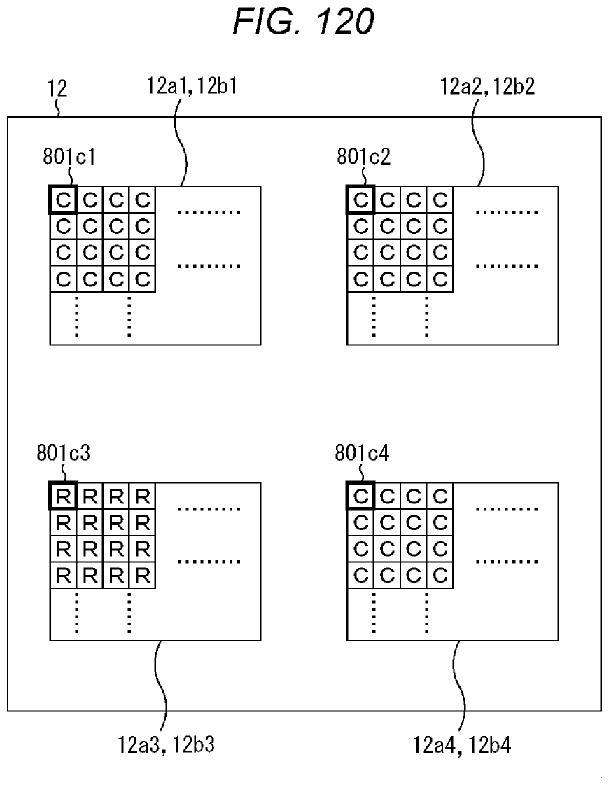

FIG. 120 illustrates a tenth example of the pixel arrangement of the four pixel arrays 12b1 to 12b4 which are provided in the imaging unit 12 of the camera module 1.

In the imaging unit 12 illustrated in FIG. 120, the entirety of pixels of the pixel array 12b1 are pixels which receive light in entire wavelength regions of visible light. The entirety of pixels of the pixel array 12b2 are pixels which receive light in entire wavelength regions of visible light. The entirety of pixels of the pixel array 12b3 are pixels which receive light of a red wavelength. The entirety of pixels of the pixel array 12b4 are pixels which receive light in entire wavelength regions of visible light.

As illustrated in FIG. 117 to FIG. 120, the pixel arrays 12b1 to 12b4 of the imaging unit 12 may be configured to receive light of a wavelength in the same band in pixel array unit.

A solid-state imaging element in an RGB three-plate type in the related art includes three light-receiving elements, and the light-receiving elements respectively capture only an R image, only a G image, and only a B image. The solid-state imaging element in the RGB three-plate type in the related art spectrally separates light incident to one optical unit in three directions by using a prism, and receives the light by using three light-receiving elements. Accordingly, a position of a subject image that is incident to the three light-receiving elements is the same in each case. Accordingly, it is difficult to obtain a highly sensitive image by applying the super-resolution technique to the three images.

In contrast, in the camera modules 1 which use any one of the imaging units 12 described in FIG. 117 to FIG. 120 and are illustrated in FIG. 104A to FIG. 104F and FIG. 105A to FIG. 105D, the optical units 13 are disposed in a plane two-by-two in a vertical direction and a horizontal direction of a surface of the camera module 1 as a light incident surface, and optical axes of the four optical units 13 extend in parallel to each other in the same direction. With this arrangement, it is possible to obtain a plurality of sheets of images which are not necessarily the same as each other by using different four light-receiving regions 12a1 to 12a4 which are provided in the imaging unit 12 while the optical axes are oriented in the same direction.

The camera modules 1 having the above-described structure exhibit an operation capable of obtaining an image with resolution higher than resolution of one sheet of image that is obtained from one piece of optical unit 13 by using the super-resolution technique on the basis of a plurality of sheets of images which are obtained from the four optical units 13 which are arranged as described above.

Furthermore, the configuration of obtaining four sheets of images of G, R, G, and B by the imaging unit 12 described in FIG. 117 exhibits an operation similar to the operation exhibited by the configuration in which four pixels of G, R, G, and B are set as a repetition unit in the imaging unit 12 described in FIG. 108.

In the imaging unit 12 described in FIG. 118, the configuration of obtaining four sheets of images of R, G, B, and C exhibits an operation similar to the operation that is exhibited by the configuration in which four pixels of R, G, B, and C are set as a repetition unit in the imaging unit 12 described in FIG. 109.

In the imaging unit 12 described in FIG. 119, the configuration of obtaining four sheets of images of R, C, B, and C exhibits an operation similar to the operation that is exhibited by the configuration in which four pixels of R, C, B, and C are set as a repetition unit in the imaging unit 12 described in FIG. 110.

In the imaging unit 12 described in FIG. 120, the configuration of obtaining four sheets of images of R, C, C, and C exhibits an operation similar to the operation that is exhibited by the configuration in which four pixels of R, C, C, and C are set as a repetition unit in the imaging unit 12 described in FIG. 111.

As a configuration of the diaphragm plate 51 of the camera modules 1 which include any of the imaging units 12 described in FIG. 117 to FIG. 120, it is possible to employ configurations of various diaphragm plates 51 which are illustrated in FIG. 106A to FIG. 106D, or modification examples thereof.

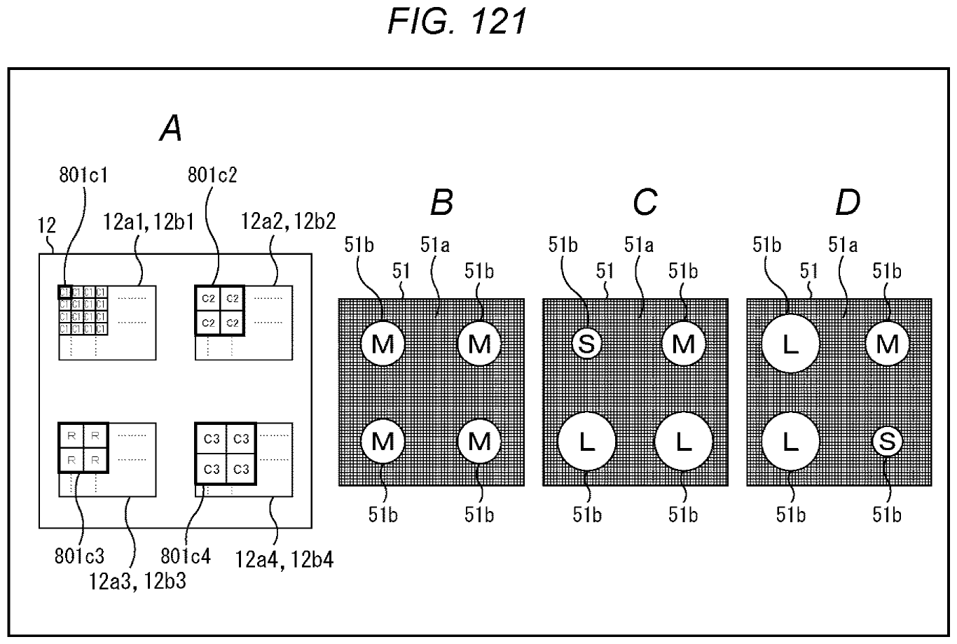

FIG. 121A illustrates an eleventh example of the pixel arrangement of the four pixel arrays 12b1 to 12b4 which are provided in the imaging unit 12 of the camera module 1.

In the imaging unit 12 illustrated in FIG. 121A, the pixel arrays 12b1 to 12b4 are different from each other in a pixel size of one pixel or a wavelength of light received by each pixel.

With regard to a pixel size, the pixel size of the pixel array 12b1 is the smallest. The pixel arrays 12b2 and 12b3 have the same pixel size, and the pixel size thereof is larger than the pixel size of the pixel array 12b1. The pixel size of the pixel array 12b4 is larger than the pixel size of the pixel arrays 12b2 and 12b3. The magnitude of the pixel size is proportional to the size of the photoelectric conversion unit that is provided in each pixel.

With regard to a wavelength of light that is received by each pixel, the pixel arrays 12b1, 12b2, and 12b4 include pixels which receive light in entire wavelength regions of visible light, and the pixel array 12b3 includes pixels which receive light of a red wavelength.

The configuration that is provided in the imaging unit 12 described in FIG. 121A exhibits the following operation. For example, in a case where illuminance of a subject is high, and thus a large signal is obtained in the imaging unit 12, it is possible to obtain an image with high resolution by using the light-receiving region 12a1 in which the pixel size is small and resolution is high.

In addition, the following operation is also exhibited. In a case where illuminance of a subject is low and a large signal is not obtained in the imaging unit 12, and thus there is a concern that the S/N ratio of an image deteriorates, it is possible to obtain an image with a high S/N ratio by using the light-receiving region 12a2 in which an image with a high S/N ratio is obtained.

In addition, the following operation is exhibited. In a case where illuminance of a subject is lower and thus there is a concern that the S/N ratio of an image in the imaging unit 12 further deteriorates, it is possible to obtain an image with a higher S/N ratio by using the light-receiving region 12a4 in which an image with a higher S/N ratio is obtained.

Furthermore, a configuration in which the imaging unit 12 described in FIG. 121A is used in combination with the diaphragm plate 51 in FIG. 121B among three sheets relating to the shape of the diaphragm plates 51 described in FIG. 121B to FIG. 121D exhibits an operation similar to the operation that is exhibited by the configuration in which the imaging unit 12 described in FIG. 116A is used in combination with the diaphragm plate 51 in FIG. 116B among three sheets relating to the shape of the diaphragm plates 51 described in FIG. 116B to FIG. 116D.

In addition, a configuration in which the imaging unit 12 described in FIG. 121A is used in combination with the diaphragm plate 51 in FIG. 121C among the three sheets relating to the shape of the diaphragm plates 51 described in FIG. 121B to FIG. 121D exhibits an operation similar to the operation that is exhibited by the configuration in which the imaging unit 12 described in FIG. 116A is used in combination with the diaphragm plate 51 in FIG. 116C among the three sheets relating to the shape of the diaphragm plates 51 described in FIG. 116B to FIG. 116D.

In addition, a configuration in which the imaging unit 12 described in FIG. 121A is used in combination with the diaphragm plate 51 in FIG. 121D among the three sheets relating to the shape of the diaphragm plates 51 described in FIG. 121B to FIG. 121D exhibits an operation similar to the operation that is exhibited by the configuration in which the imaging unit 12 described in FIG. 116A is used in combination with the diaphragm plate 51 in FIG. 116D among the three sheets relating to the shape of the diaphragm plates 51 described in FIG. 116B to FIG. 116D.

In the camera module 1 that includes the imaging unit 12 described in FIG. 121A, it is possible to employ a configuration of the diaphragm plate 51 illustrated in FIG. 106A or FIG. 106D, configurations of the diaphragm plates 51 illustrated in FIG. 121B to FIG. 121D, or modification examples thereof.

<56. Twenty-Fifth Embodiment of Camera Module 1>

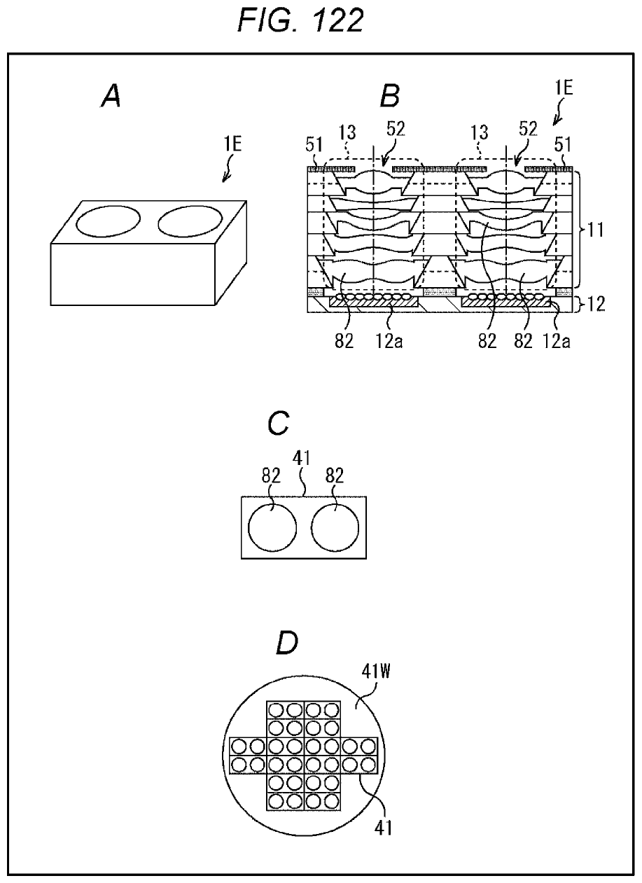

FIG. 122A to FIG. 122D are views illustrating a twenty-fifth embodiment of the camera module to which the present technology is applied.

FIG. 122A is a schematic view illustrating an external appearance of a camera module 1E as the twenty-fifth embodiment of the camera module 1, and FIG. 122B is a schematic cross-sectional view of the camera module 1E.

As in the camera module 1B relating to the twenty-second embodiment illustrated in FIG. 103A to FIG. 103H, the camera module 1E includes two optical units 13. The camera module 1E and the camera module 1B in FIG. 103A to FIG. 103H are different from each other as follows. The camera module 1B relating to the twenty-second embodiment has a configuration in which optical parameters of the two optical units 13 are different from each other. In contrast, the camera module 1E relating to the twenty-fifth embodiment, optical parameters of the two optical units 13 are the same as each other. That is, in the two optical units 13 which are provided in the camera module 1E, the number of the lens resin portions 82, a diameter, a thickness, a surface shape, a material, a distance between two sheets of lens resin portions 82 which are adjacent in a vertical direction, and the like are the same.

FIG. 122C is a view illustrating a planar shape of a predetermined one sheet of lens-attached substrate 41 that constitute the laminated lens structure 11 of the camera module 1E.

FIG. 122D is a plan view of a lens-attached substrate 41W in a substrate state for obtaining the lens-attached substrate 41 illustrated in FIG. 122C.

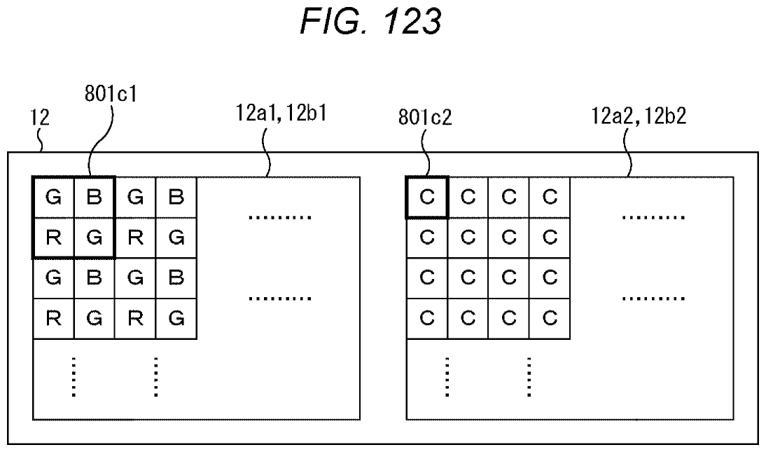

FIG. 123 is a view illustrating a structure of the imaging unit 12 of the camera module 1E illustrated in FIG. 122A to FIG. 122D.

The imaging unit 12 of the camera module 1E includes two light-receiving regions 12a1 and 12a2. The light-receiving region 12a1 and the light-receiving region 12a2 respectively include pixel arrays 12b1 and 12b2 in which pixels receiving light are arranged in an array.

The pixel arrays 12b1 and 12b2 respectively include repetition units 801c1 and 801c2 which include a plurality of pixels or single pixel. More specifically, the pixel array 12b1 has a configuration in which a plurality of the repetition units 801c1 are arranged in an array both in a vertical direction and in a horizontal direction. The pixel array 12b2 has a configuration in which a plurality of the repetition units 801c2 are arranged in an array both in a vertical direction and in a horizontal direction. Each of the repetition units 801c1 is constituted by four pixels including respective pixels of R, G, B, and G, and each of the repetition units 801c2 is constituted by one pixel of C.

Accordingly, the camera module 1E includes a set of sensor unit that outputs a color image signal, that is, a set of the pixel array 12b1 including respective pixels of R, G, and B, and the optical unit 13, and a set of sensor unit that outputs a monochrome image signal, that is, the pixel array 12b2 including a pixel of C, and the optical unit 13.

As can be seen from the following Expression (1) relating to a luminance signal Y of the standard ITU-R BT. 601-7 which is defined by international telecommunication union (ITU) and converts pixel signals of R, G, and B into a luminance signal and a chrominance signal, among pixel signals of R, G, and B, sensitivity relating to luminance is highest in the signal of G, and the sensitivity relating to luminance is lowest in the signal of B.

Y=0.299R+0.587G+0.114B Expression (1)

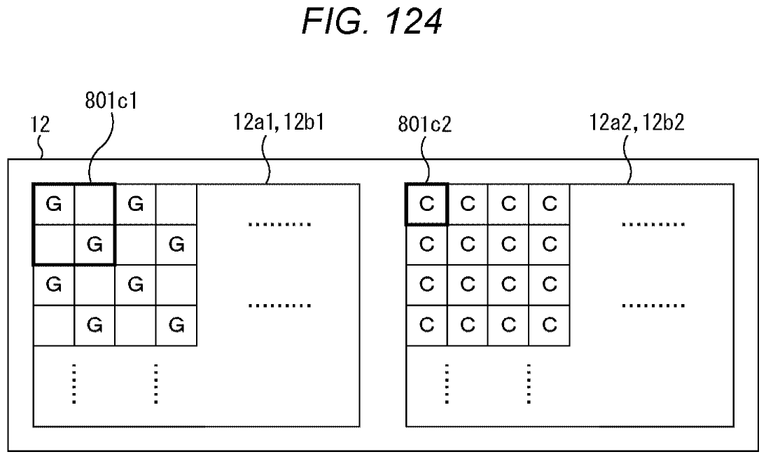

Here, when showing a location at which a pixel in which luminance information is obtained with high sensitivity on the assumption that a pixel in which luminance information is obtained with high sensitivity is only the pixel of G in the light-receiving region 12a1 described in FIG. 123 for simplification, the location is shown as in FIG. 124.

FIG. 124 is a view illustrating a location at which the pixel, in which luminance information is obtained with high sensitivity, is disposed in the imaging unit 12 illustrated in FIG. 123.

A pixel in which luminance information is obtained with high sensitivity is only the pixel of G in the light-receiving region 12a1 on the basis of the above-described assumption relating to the luminance information. In contrast, in the light-receiving region 12a2, all pixels which constitute the pixel array 12b2 are constituted by a pixel of C that receives light in entire wavelength regions of visible light, and thus luminance information is obtained with higher sensitivity.

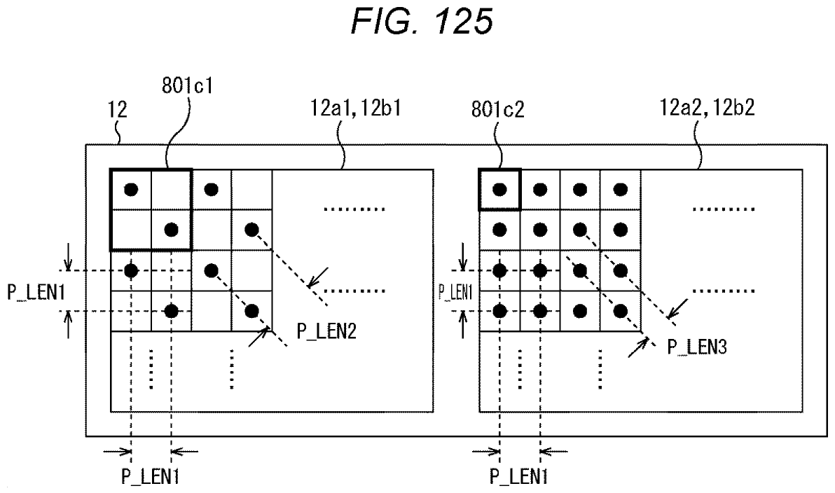

FIG. 125 is a view illustrating an arrangement pitch of a pixel (hereinafter, also referred to as “high-luminance pixel”) in which luminance information is obtained with high sensitivity in the imaging unit 12 illustrated in FIG. 124 in a state in which an output point of an image signal of respective pixels is set as the pixel center.

When comparing arrangement pitches of high-luminance pixels in the light-receiving region 12a1 and the light-receiving region 12a2, a common arrangement pitch P_LEN1 is set in a row direction and a column direction.

However, with regard to an oblique direction of 45° with respect to the row direction and the column direction, the arrangement pitch P_LEN2 of the light-receiving region 12a1 and the arrangement pitch P_LEN3 of the light-receiving region 12a2 are different from each other. Specifically, the arrangement pitch P_LEN3 of the light-receiving region 12a2 is set to ½ times the width of the arrangement pitch P_LEN2 of the light-receiving region 12a1. In other words, in the oblique direction of 45° with respect to the row direction and the column direction, in the light-receiving region 12a2, it is possible to obtain an image having resolution that is two times resolution in the light-receiving region 12a1.

The binocular camera module 1E described with reference to FIG. 122A to FIG. 125 includes the light-receiving region 12a2 in which all pixels which constitute the pixel array 12b2 are the pixels of C in addition to the light-receiving region 12a1, which includes the pixel arrays of R, G, B, and G as the repetition unit 801c1, in a so-called Bayer array.

The structure of the camera module 1E exhibits an operation capable of obtaining a clearer image in comparison to an image that is obtained from only the light-receiving region 12a1. For example, information of a luminance variation for every pixel is obtained from the light-receiving region 12a2. When complementing luminance information obtained from the light-receiving region 12a1 on the basis of the above-described luminance variation information, it is possible to exhibit an operation capable of obtaining an image with higher resolution in comparison to an image that is obtained only from the light-receiving region 12a1. As described above, the resolution in the oblique direction becomes two times the resolution in a case where the pixel information is obtained only from the light-receiving region 12a1. Accordingly, it is possible to realize a two times lossless zoom (enlarged image without image quality deterioration) by combining pixel information of the light-receiving region 12a1 and pixel information of light-receiving region 12a2. There is a method of realizing the lossless zoom by using lenses which are different in an image capturing range. However, in this case, the height of a camera module becomes different. According to the camera module 1E, it is possible to realize the lossless zoom without changing the height of the module.

In addition, a luminance signal, which is obtained from the light-receiving region 12a2 that is not provided with three kinds of RGB color filters, has a signal level that is approximately 1.7 times a signal level of a luminance signal obtained from the light-receiving region 12a1 that is provided with the color filters. Accordingly, for example, it is possible to generate and output a pixel signal of which a signal to noise ratio (SN ratio) is improved with a combination of the pixel information of the light-receiving region 12a1 and the pixel information of the light-receiving region 12a2 such as substitution of the luminance signal of G that is obtained in the light-receiving region 12a1 with the luminance signal of a corresponding pixel which is obtained in the light-receiving region 12a2. For example, there is a technology in which a plurality of sheets of images are captured by using a monocular color imaging sensor, and image signals thereof are combined to improve the SN ratio. However, in the method, time taken until a plurality of sheets of images are acquired is lengthened, and thus the method is not suitable for a moving object or a moving image. The camera module 1E can capture an image in the light-receiving region 12a1 and the light-receiving region 12a2 in synchronization with each other. Accordingly, the camera module 1E can generate an image with a high SN ratio in a short time, and is also suitable for capturing of the moving image or image capturing of the moving body.

In addition, when pixel information of the light-receiving region 12a1 and pixel information of the light-receiving region 12a2 are combined so that a pixel signal of each pixel of the light-receiving region 12a2 is located at a position corresponding to an intermediate position between pixels of the light-receiving region 12a1, it is possible to obtain super-resolution image having resolution two times resolution of an image that is obtained only from the light-receiving region 12a1. For example, a monocular color imaging sensor in which the number of pixels is 20 megapixels and which captures a moving image of 8 megapixels of 4K×2K is known. In the case of using the binocular camera module 1E having the same number of pixels as in the color imaging sensor, as described above, when complementing pixel information by deviating a pixel position of the light-receiving region 12a2 with respect to the light-receiving region 12a1 by ½ pixels in a horizontal direction and a vertical direction, it is possible to obtain super-resolution moving image corresponding to 32 megapixels of 8K×4K.

As described above, according to the binocular camera module 1E, it is possible to generate images for various uses such as an enlarged image without image quality deterioration, an image having an improved SN ratio, and a super-resolution image by using pixel information that is obtained by the two light-receiving regions 12a1 and 12a2. For example, when generating an image, a use thereof is selected and determined by setting of an operation mode of an imaging apparatus provided with the camera module 1E.

<57. Twenty-Sixth Embodiment of Camera Module 1>

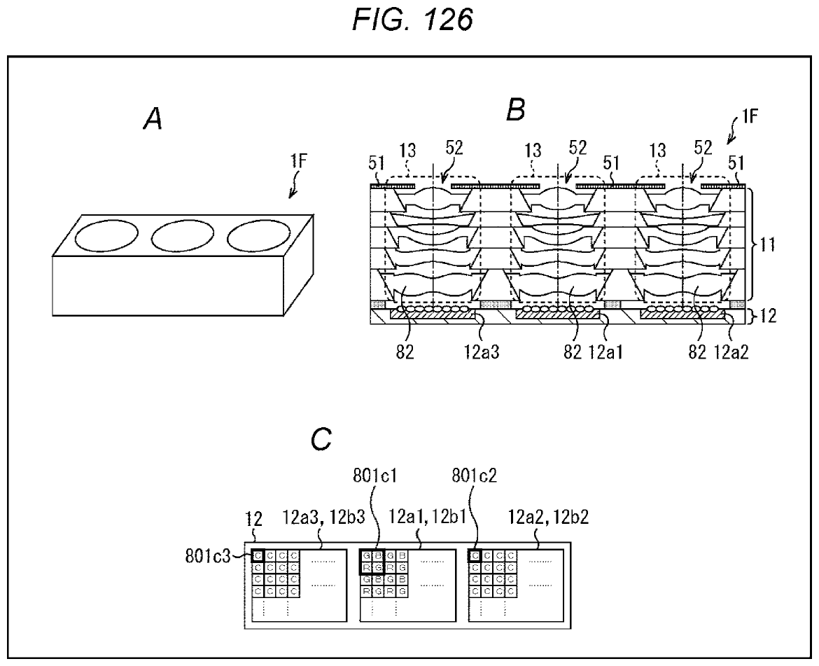

FIG. 126A to FIG. 126C are views illustrating a twenty-sixth embodiment of the camera module to which the present technology is applied.

FIG. 126A is a schematic view illustrating an external appearance of a camera module 1F as the twenty-sixth embodiment of the camera module 1, and FIG. 126B is a schematic cross-sectional view of the camera module 1F.

As illustrated in FIG. 126B, the camera module 1F includes three optical units 13 having the same optical parameters.

FIG. 126C is a view illustrating a structure of the imaging unit 12 of the camera module 1F.

The imaging unit 12 of the camera module 1F includes three light-receiving regions 12a1 to 12a3 at positions corresponding to three optical units 13 which are disposed on an upper side of the imaging unit 12. The light-receiving regions 12a1 to 12a3 respectively include pixel arrays 12b1 to 12b3 in which pixels are arranged in an array.

The pixel arrays 12b1 to 12b3 respectively include repetition units 801c1 to 801c3 which include a plurality of pixels or single pixel. More specifically, the pixel array 12b1 has a configuration in which a plurality of the repetition units 801c1 are arranged in an array both in a vertical direction and in a horizontal direction. The pixel array 12b2 has a configuration in which a plurality of the repetition units 801c2 are arranged in an array both in a vertical direction and in a horizontal direction. The pixel array 12b3 has a configuration in which a plurality of the repetition units 801c3 are arranged in an array both in a vertical direction and in a horizontal direction. Each of the repetition units 801c1 is constituted by four pixels including respective pixels of R, G, B, and G, and the repetition units 801c2 and 801c3 are constituted by one pixel of C.

Accordingly, the camera module 1F includes a set of sensor unit that outputs a color image signal, that is, a set of the pixel array 12b1 including respective pixels of R, G, and B, and the optical unit 13, two sets of sensor unit that outputs a monochrome image signal, that is, a set of the pixel array 12b2 including a pixel of C and the optical unit 13, and a set of the pixel array 12b3 including a pixel of C and the optical unit 13.

As in the binocular camera module 1E, the structure of the camera module 1F exhibits an operation capable of obtaining a clearer image in comparison to an image that is obtained from only the light-receiving region 12a1. That is, when complementing luminance information obtained from the Bayer array light-receiving region 12a1 including a pixel arrangement of R, G, B, and G as a repetition unit 801c1 by using pixel information from the light-receiving region 12a2 including the pixel array 12b2 constituted by pixels of C, and the light-receiving region 12a3 including the pixel array 12b3 constituted by pixels of C, for example, luminance variation information for each pixel, it is possible to exhibit an operation capable of obtaining an image with higher resolution in comparison to an image obtained only from the light-receiving region 12a1. As described above, the resolution in the oblique direction becomes two times the resolution in a monocular color imaging sensor. Accordingly, it is possible to realize a two times lossless zoom (enlarged image without image quality deterioration) by combining a plurality of pieces of pixel information of the light-receiving regions 12a1 to 12a3. There is a method of realizing the lossless zoom by using lenses which are different in an image capturing range. However, in this case, the height of a camera module becomes different. According to the camera module 1F, it is possible to realize the lossless zoom without changing the height of the camera module.

As in the binocular camera module 1E, the three-eye camera module 1F also captures an image in the light-receiving regions 12a1 to 12a3 in synchronization with each other. Accordingly, the camera module 1F can capture a moving image and an image of a moving object with a high SN ratio. In addition, when complementing pixel information by deviating a pixel position of the light-receiving region 12a2 and the light-receiving region 12a3 with respect to the light-receiving region 12a1 by ½ pixels in a horizontal direction and in a vertical direction, it is possible to obtain a super-resolution image having double resolution.

In addition, for example, as in a distance measuring apparatus disclosed in JP 2008-286527A or WO 2011/058876A, the structure of the camera module 1F exhibits an operation capable of obtaining distance information as a binocular distance measuring apparatus by using image information from the light-receiving region 12a2 constituted by pixels of C and image information from the light-receiving region 12a3 constituted by pixels of C.

In the light-receiving region 12a2 and the light-receiving region 12a3 which are constituted by pixels of C, a luminance signal in a signal level that is approximately 1.7 times a signal level in a color imaging sensor is obtained. Accordingly, when obtaining distance information by using the light-receiving region 12a2 and the light-receiving region 12a3, even in an image capturing environment in which illuminance of a subject is low and thus luminance of the subject is low, it is possible to exhibit an operation capable of obtaining distance information at a high speed and in an accurate manner. When using the distance information, for example, in an imaging apparatus using the camera module 1F, it is possible to exhibit an operation capable of performing an auto focus operation at a high speed and in an accurate manner.

As an auto focus mechanism, typically, in a single-lens reflex camera, an auto focus dedicated sensor can be used. In a compact digital camera and the like, a combination of an image surface phase difference method in which a phase difference pixel is disposed at a part of an image sensor, and a contrast AF method can be used. With regard to the phase difference pixel, for example, a light-receiving region is constituted by pixels which are approximately the half of typical pixels, and thus there is a disadvantage that the image surface phase difference method is weak for low illuminance. In addition, the contrast AF method has a disadvantage that a focus time is slow, and the auto focus dedicated sensor has a disadvantage that an apparatus size increases.

In the camera module 1F, all pixels of the two light-receiving regions 12a2 and 12a3 which acquire distance information are constituted by typical pixels in which a light-receiving region is not reduced. In addition, image capturing in the light-receiving regions 12a2 and 12a3 for obtaining distance information can be performed in synchronization with image capturing in the light-receiving region 12a1 capable of acquiring a color image. Accordingly, the camera module 1F is compact and is strong against low illuminance. Accordingly, it is possible to perform auto focus at a high speed.

In addition, for example, as in a distance image disclosed in JP 2006-318060A and JP 2012-15642A, the structure of the camera module 1F exhibits an operation capable of outputting a distance image that expresses a distance by the degree of light and shade by using distance information.

As described above, according to the three-eye camera module 1F, it is possible to generate images for various uses such as an enlarged image without image quality deterioration, an image having an improved SN ratio, and a super-resolution image by using pixel information that is obtained by the three light-receiving regions 12a1 to 12a3. In addition, it is also possible to generate distance information based on a parallax of the light-receiving regions 12a2 and 12a3. For example, when using the pixel information obtained from the three light-receiving regions 12a1 to 12a3, a use thereof is selected and determined by setting of an operation mode of an imaging apparatus provided with the camera module 1F.

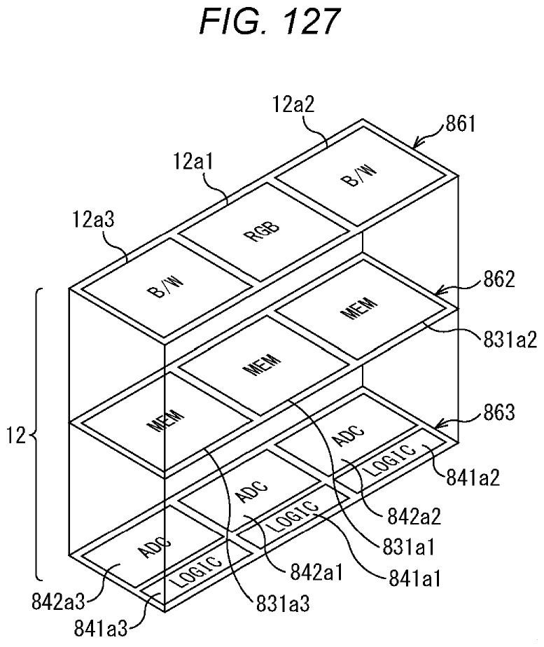

FIG. 127 illustrates a substrate configuration example of the imaging unit 12 used in the three-eye camera module 1F.

As illustrated in FIG. 127, the imaging unit 12 used in the three-eye camera module 1F can be formed in a three-layer structure in which three sheets of semiconductor substrates 861 to 863 are laminated.

Among the three sheets of semiconductor substrates 861 to 863, in a first semiconductor substrate 861 on a light incident side, three light-receiving regions 12a1 to 12a3 corresponding to three optical units 13 are formed.

In a second semiconductor substrate 862 on an intermediate side, three memory regions 831a1 to 831a3 corresponding to the three light-receiving regions 12a1 to 12a3 are formed. For example, the memory regions 831a1 to 831a3 retain a pixel signal, which is supplied through control regions 842a1 to 842a3 of a third semiconductor substrate 863, for a predetermined time.

In the third semiconductor substrate 863 in a lower layer of the second semiconductor substrate 862, logic regions 841a1 to 841a3 and control regions 842a1 to 842a3 which correspond to the three light-receiving regions 12a1 to 12a3 are formed. The control regions 842a1 to 842a3 perform a reading-out control of reading out a pixel signal from the light-receiving regions 12a1 to 12a3, an AD conversion processing of converting an analog pixel signal into a digital signal, outputting of a pixel signal to the memory regions 831a1 to 831a3, and the like. For example, the logic regions 841a1 to 841a3 perform predetermined signal processing such as gradation correction processing of AD-converted image data.

For example, the three sheets of semiconductor substrates 861 to 863 are electrically connected to each other by a through-via or a metal bond of Cu—Cu.

As described above, the imaging unit 12 can be constituted by a three-layer structure in which the memory regions 831a1 to 831a3, the logic regions 841a1 to 841a3, and the control regions 842a1 to 842a3 are disposed in the three sheets of semiconductor substrates 861 to 863 in correspondence with the three light-receiving regions 12a1 to 12a3.

Typically, when capturing an image at a high speed frame rate by using a monocular color imaging sensor, an exposure time of one frame is short, and thus an SN ratio deteriorates. In contrast, the camera module 1F performs imaging operation in a state in which an imaging initiation timing is deviated by ½ exposure time in the two light-receiving regions 12a2 and 12a3, and thus it is possible to secure a double exposure time at the same frame rate as in the monocular color imaging sensor. In addition, it is possible to output an image with a high SN ratio even at a high speed frame rate by alternately substituting luminance information obtained from a color image signal of the light-receiving region 12a1 with monochrome image signals (luminance information) of the two light-receiving regions 12a2 and 12a3 which are obtained by setting the double exposure time.

In addition, in the case of capturing an image by any one of the three light-receiving regions 12a1 to 12a3, it is possible to use the three memory regions 831a1 to 831a3 with respect to one light-receiving region 12a, and thus memory capacity becomes three times memory capacity in a typical case. According to this, in a super-slow moving image that is captured by setting the exposure time to be short, and the like, it is possible to lengthen an imaging time to three times. In addition, even in the AD conversion processing, each analog/digital converter (ADC) of the three control regions 842a1 to 842a3 can be used, and thus a high-speed drive nearly three times becomes possible.

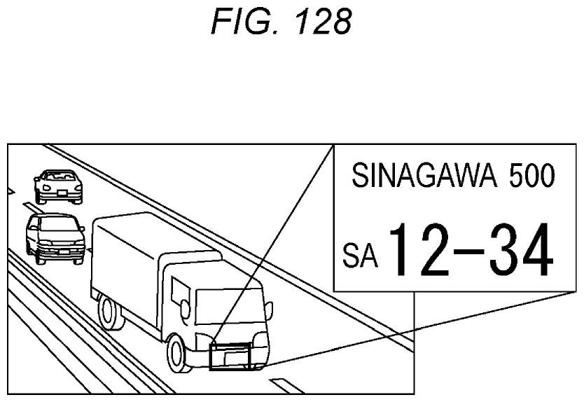

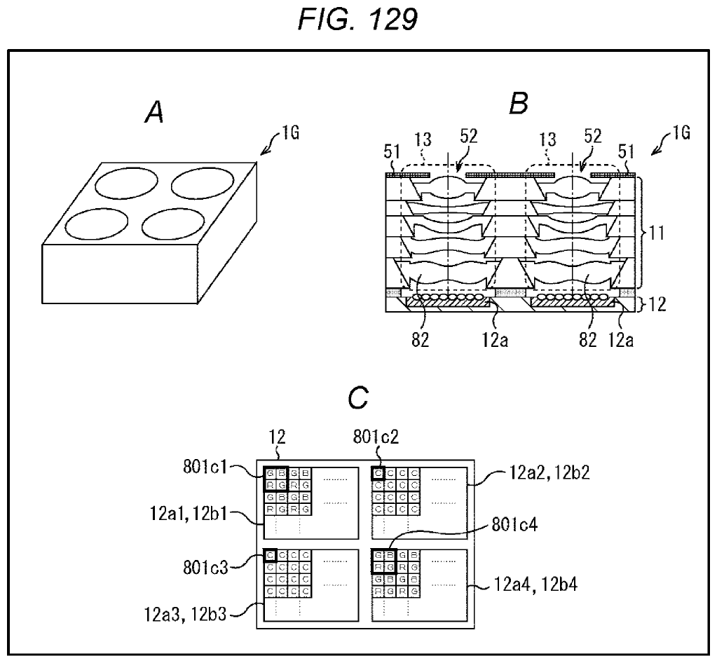

In addition, the imaging unit 12 includes the memory regions 831a1 to 831a3 in correspondence with the three light-receiving regions 12a1 to 12a3. Accordingly, for example, as illustrated in FIG. 128, it is possible to realize processing such as outputting of only an image signal in a number plate region among the entirety of captured images to a rear stage. With this arrangement, a data amount that is transmitted can be compressed, and thus it is possible to exhibit an effect such as a reduction in data transmission load, an improvement in a transmission speed, and a reduction in power consumption.

As described above, the imaging unit 12 of the camera module 1F is constructed in the three-layer structure in which the three sheets of semiconductor substrates 861 to 863 are laminated, a use of an image obtained from the imaging unit 12 is also expanded.

<58. Twenty-Seventh Embodiment of Camera Module 1>

FIG. 129A to FIG. 129C are views illustrating a twenty-seventh embodiment of the camera module to which the present technology is applied.

FIG. 129A is a schematic view illustrating an external appearance of a camera module 1G as the twenty-seventh embodiment of the camera module 1, and FIG. 129B is a schematic cross-sectional view of the camera module 1G.

The camera module 1G includes four optical units 13 having the same optical parameters.

FIG. 129C is a view illustrating a structure of the imaging unit 12 of the camera module 1G.

The imaging unit 12 of the camera module 1G includes four light-receiving regions 12a1 to 12a4 at positions corresponding to four optical units 13 which are disposed on an upper side of the imaging unit 12. The light-receiving regions 12a1 to 12a4 include respectively include pixel arrays 12b1 to 12b4 in which pixels receiving light are arranged in an array.

The pixel arrays 12b1 to 12b4 respectively include repetition units 801c1 to 801c4 which include a plurality of pixels or single pixel. More specifically, the pixel array 12b1 has a configuration in which a plurality of the repetition units 801c1 are arranged in an array both in a vertical direction and in a horizontal direction. The pixel array 12b2 has a configuration in which a plurality of the repetition units 801c2 are arranged in an array both in a vertical direction and in a horizontal direction. In addition, the pixel array 12b3 has a configuration in which a plurality of the repetition units 801c3 are arranged in an array both in a vertical direction and in a horizontal direction. The pixel array 12b4 has a configuration in which a plurality of the repetition units 801c4 are arranged in an array both in a vertical direction and in a horizontal direction. Each of the repetition units 801c1 and 801c4 is constituted by four pixels including respective pixels of R, G, B, and G, and each of the repetition units 801c2 and 801c3 is constituted by one pixel of C.

Accordingly, the camera module 1G includes two sets of sensor units which output a color image signal, that is, a set of the pixel array 12b1 including respective pixels of R, G, and B, and the optical unit 13, and a set of the pixel array 12b4 including respective pixels of R, G, and B, and the optical unit 13, and two sets of sensor units which output a monochrome image signal, that is, a set of the pixel array 12b2 including a pixel of C, and the optical unit 13, and a set of the pixel array 12b3 including a pixel of C and the optical unit 13.

As in the binocular camera module 1E, the structure of the camera module 1G exhibits an operation capable of obtaining a clearer image in comparison to an image that is obtained from only the light-receiving region 12a1. That is, when complementing luminance information obtained from the Bayer array light-receiving region 12a1 or 12a4 that includes a pixel arrangement of R, G, B, and G as a repetition unit 801c1 by using pixel information from the light-receiving region 12a2 including the pixel array 12b2 constituted by pixels of C, and the light-receiving region 12a3 including the pixel array 12b3 constituted by pixels of C, for example, luminance variation information for each pixel, it is possible to exhibit an operation capable of obtaining an image with higher resolution in comparison to an image obtained only from the light-receiving region 12a1 or 12a4. In addition, as described above, the resolution in the oblique direction becomes two times the resolution in a monocular or binocular color imaging sensor. Accordingly, it is possible to realize a two times lossless zoom (enlarged image without image quality deterioration) by combining a plurality of pieces of pixel information of the light-receiving regions 12a1 to 12a4. There is a method of realizing the lossless zoom by using lenses which are different in an image capturing range. However, in this case, the height of a camera module becomes different. According to the camera module 1G, it is possible to realize the lossless zoom without changing the height of the module.

In an area in which image capturing ranges overlap each other between two light-receiving regions 12a1 and 12a4 which capture a color image, a signal amount becomes two times, and noise becomes 1.4 times, and thus it is possible to improve an SN ratio of a pixel signal. With regard to two light-receiving regions 12a2 and 12a3 which capture a monochrome image, in an overlapping area, a signal level of a luminance signal is approximately 1.7 times a signal level of the light-receiving regions 12a1 and 12a4 which capture a color image, and thus the SN ratio is also improved. In a case of combining a plurality of pieces of pixel information of the four light-receiving regions 12a1 to 12a4, the SN ratio is improved to approximately 2.7 times in comparison to a monocular color imaging sensor. The camera module 1G can capture an image in the light-receiving regions 12a1 and the light-receiving region 12a2 in synchronization with each other, and thus it is possible to generate an image with a high SN ratio in a short time. Accordingly, the camera module 1G is also appropriate for capturing of a moving image and an image of a moving object.

In addition, for example, as in a distance measuring apparatus disclosed in JP 2008-286527A or WO 2011/058876A, the structure of the camera module 1G exhibits an operation capable of obtaining distance information as a binocular distance measuring apparatus by using image information from the light-receiving region 12a2 constituted by pixels of C and image information from the light-receiving region 12a3 constituted by pixels of C.

In addition, when obtaining distance information by using the light-receiving region 12a2 and the light-receiving region 12a3 which include pixels of C with a high luminance signal level, even in an image capturing environment in which illuminance of a subject is low and thus luminance of the subject is low, it is possible to exhibit an operation capable of obtaining distance information at a high speed and in an accurate manner. When using the distance information, for example, in an imaging apparatus using the camera module 1G, it is possible to exhibit an operation capable of performing an auto focus operation at a high speed and in an accurate manner.

In the camera module 1G, all pixels of the two light-receiving regions 12a2 and 12a3 which acquire distance information are constituted by typical pixels instead of phase difference pixels in which a light-receiving region is reduced. In addition, image capturing in the light-receiving regions 12a2 and 12a3 for obtaining distance information can be performed in synchronization with image capturing in the light-receiving regions 12a1 and 12a4 capable of acquiring a color image. Accordingly, the camera module 1G is compact and is strong against low illuminance. Accordingly, it is possible to perform auto focus at a high speed.

In addition, for example, as in a distance image disclosed in JP 2006-318060A and JP 2012-15642A, the structure of the camera module 1G exhibits an operation capable of outputting a distance image that expresses a distance by the degree of light and shade by using distance information.

In addition, the camera module 1G can obtain an image (high dynamic range image) in which a dynamic range is wide by changing a pixel driving method.

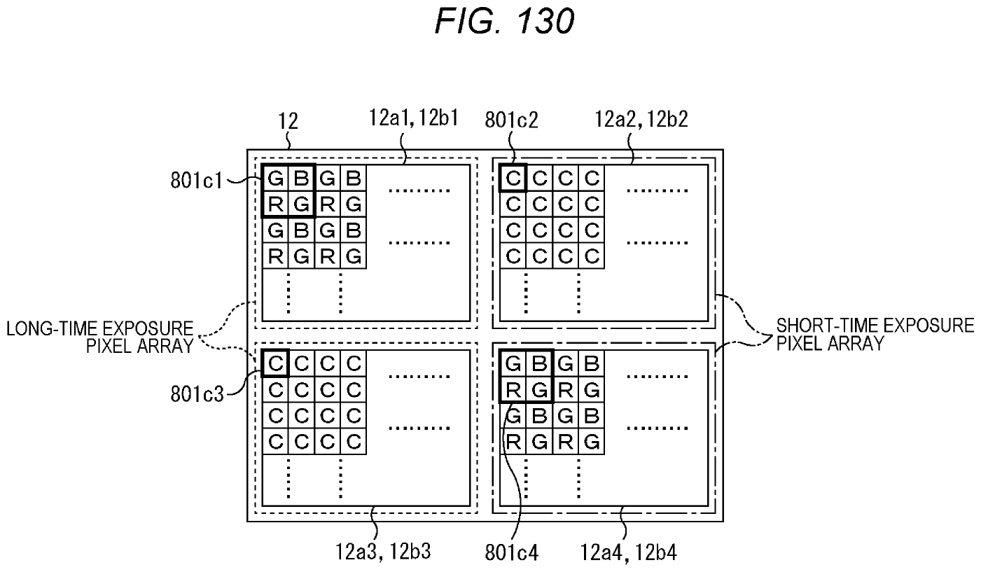

FIG. 130 is a view illustrating a pixel driving method for obtaining the high dynamic range image.

In the camera module 1G, in a case where illuminance of a subject is lower than specific illuminance, the light-receiving region 12a1 including the pixel array 12b1 that is constituted by pixels of R, G, B, and G, and the light-receiving region 12a3 including the pixel array 12b3 that is constituted by pixels of C capture an image for a predetermined exposure time (hereinafter, referred to as “first exposure time”).

On the other hand, in a case where the subject is lower than the specific illuminance, the light-receiving region 12a2 including the pixel array 12b2 that is constituted by pixels C and the light-receiving region 12a4 including the pixel array 12b4 that is constituted by pixels of R, G, B, and G capture an image for an exposure time (hereinafter, referred to as “second exposure time”) that is shorter than the first exposure time. Furthermore, in the following description, the first exposure time is also referred to as “long-second exposure time”, and the second exposure time is also referred to as “short-second exposure time”.

For example, in a case where illuminance of a subject is high, when capturing an image for the long-second exposure time, a pixel that captures an image of a part of the subject, in which luminance is high, enters a state in which an image capturing operation is performed in a state of exceeding an appropriate operation limit (for example, a saturation charge amount) of the pixel, and thus image data obtained as a result of the image capturing may be in a so-called overexposed white state in which gradation is lost. Even in this case, in the camera module 1G, an image captured from the light-receiving region 12a2 and the light-receiving region 12a4 for a short-second exposure time, in other words, an image captured in a state in which the pixel is in an appropriate operation range (for example, equal to or less than a saturation charge amount) can be obtained.

The camera module 1G exhibits an operation capable of obtaining a high dynamic range image by combining the image captured for the long-second exposure time and the image captured for the short-second exposure time in a similar manner as in a pixel signal combining method for enlargement of the dynamic range as disclosed in, for example, JP 11-75118A or JP 11-27583A.

Typically, examples of the method of generating the high dynamic range image includes a method in which an image captured for the long-second exposure time and an image captured for the short-second exposure time are acquired with a time difference by using the monocular color imaging sensor and the like, and are combined, a method in which images are captured in a state in which a pixel array is divided into a long-second exposure pixel and a short-second exposure pixel, and the like. The method of combining two sheets of images including the image captured for the long-second exposure time and the image captured for the short-second exposure time is not suitable for a moving object or a moving image. In the method in which the pixel array is divided into the long-second exposure pixel and the short-second exposure pixel, deterioration of resolution occurs. According to the method of generating the high dynamic range image by using the four-eye camera module 1G, resolution does not deteriorate, and a decrease in frame rate does not occur, and thus the camera module 1G is suitable for a moving object or a moving image.

As described above, according to the four-eye camera module 1G, it is possible to generate images for various uses such as an enlarged image without image quality deterioration, an image having an improved SN ratio, a super-resolution image, a distance image, and a high dynamic range image by using a plurality of pieces of pixel information obtained by the four light-receiving regions 12a1 to 12a4. In addition, it is possible to generate distance information based on a parallax of the light-receiving regions 12a2 and 12a3. For example, when using the pixel information obtained from the four light-receiving regions 12a1 to 12a4, a use thereof is selected and determined by setting of an operation mode of an imaging apparatus provided with the camera module 1G.

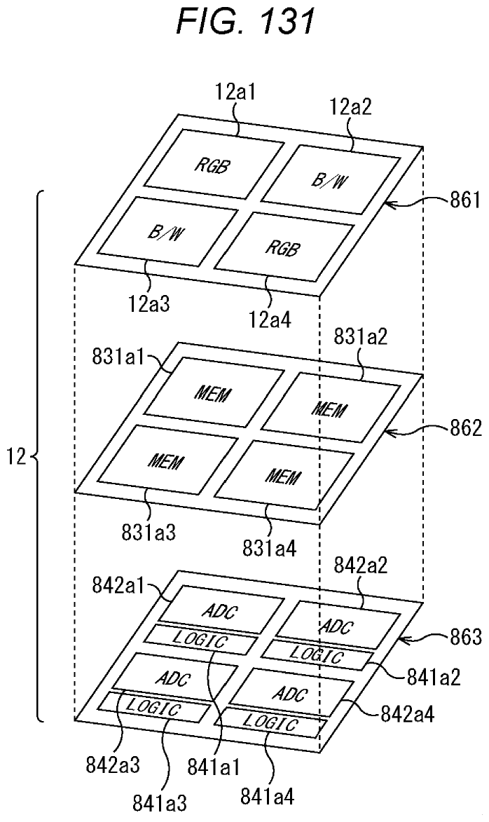

FIG. 131 illustrates a substrate configuration example of the imaging unit 12 used in the four-eye camera module 1G.

As illustrated in FIG. 131, the imaging unit 12 that used in the four-eye camera module 1G can be formed in a three-layer structure in which three sheets of semiconductor substrates 861 to 863 are laminated.

Among the three sheets of semiconductor substrates 861 to 863, in a first semiconductor substrate 861 on a light incident side, four light-receiving regions 12a1 to 12a4 corresponding to four optical units 13 are formed.

In a second semiconductor substrate 862 on an intermediate side, four memory regions 831a1 to 831a4 corresponding to the four light-receiving regions 12a1 to 12a4 are formed. In a third semiconductor substrate 863, logic regions 841a1 to 841a4 and control regions 842a1 to 842a4 which correspond to the four light-receiving regions 12a1 to 12a4 are formed.

Typically, when capturing an image at a high speed frame rate by using a monocular color imaging sensor, an exposure time of one frame is short, and thus an SN ratio deteriorates. In contrast, the camera module 1G performs imaging operation in a state in which an imaging initiation timing is deviated by ¼ exposure time by using the four light-receiving regions 12a1 to 12a4, and thus it is possible to secure a quadruple exposure time at the same frame rate as in the monocular color imaging sensor. In addition, it is possible to output an image with a high SN ratio even at a high speed frame rate by alternately substituting luminance information obtained from a color image signal of the light-receiving region 12a1 or 12a4 with a plurality of pieces of luminance information of the four light-receiving regions 12a1 to 12a4 which are obtained by setting the quadruple exposure time.

In addition, in the case of capturing an image by any one of the four light-receiving regions 12a1 to 12a4, it is possible to use the four memory regions 831a1 to 831a4 with respect to one light-receiving region 12a, and thus memory capacity becomes four times memory capacity in a typical case. According to this, in a super-slow moving image that is captured by setting the exposure time to be short, and the like, it is possible to lengthen an imaging time to four times. In addition, even in the AD conversion processing, an ADC of each of the four control regions 842a1 to 842a4 can be used, and thus a high-speed drive nearly four times becomes possible.

In addition, the imaging unit 12 includes the memory regions 831a1 to 831a4 in correspondence with the four light-receiving regions 12a1 to 12a4. Accordingly, as described with reference to FIG. 128, it is possible to realize processing such as outputting of only an image signal in a desired region to a rear stage, and the like. With this arrangement, a data amount that is transmitted can be compressed, and thus it is possible to exhibit an effect such as a reduction in data transmission load, an improvement in a transmission speed, and a reduction in power consumption.

As described above, when the imaging unit 12 of the camera module 1G is constructed in the three-layer structure in which the three sheets of semiconductor substrates 861 to 863 are laminated, a use of an image obtained from the imaging unit 12 is also expanded.

<59. First Modification Example of Imaging Unit 12>

As described above, in the first to twenty-seventh embodiments to which the present technology is applied, the camera module 1 includes the imaging unit 12, the light-receiving region 12a provided in the imaging unit 12 includes the pixel array 12b in which pixels are two-dimensionally arranged in a matrix shape, and respective pixels in the pixel array 12b include a photoelectric conversion element such as a photodiode, and a plurality of pixel transistors.

Here, the respective pixel in the pixel array 12b may have a configuration in which one photoelectric conversion element is provided in a direction in which light is incident to the pixels, in other words, a pixel depth direction, or a configuration in which a plurality of the photoelectric conversion elements are provided in the direction.

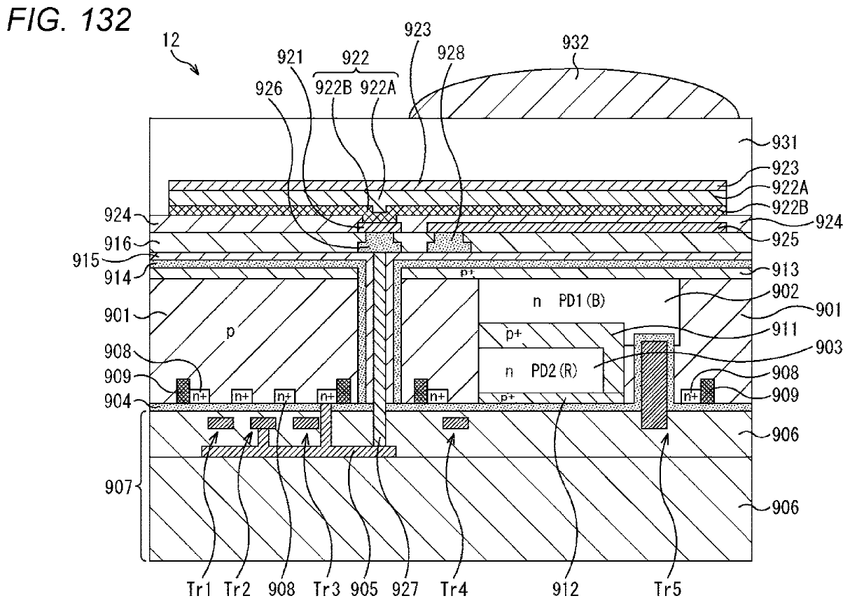

Description will be given of an example of a lamination-structure pixel in which a plurality of photoelectric conversion elements are provided in one pixel of the pixel array 12b as a first modification example of the imaging unit 12 with reference to FIG. 132.

FIG. 132 is a cross-sectional view illustrating a configuration example of a lamination-structure pixel including a plurality of photoelectric conversion elements in a pixel depth direction.

For example, in the imaging unit 12 in FIG. 132, for example, n-type (second conductive) semiconductor regions 902 and 903 are formed in a p-type (first conductive) semiconductor substrate (semiconductor region) 901 by laminating the semiconductor regions 902 and 903 in a depth direction in pixel unit. Accordingly, photodiodes PD1 and PD2 due to PN junction are formed in the depth direction. The photodiode PD1 in which the semiconductor region 902 is set as a charge accumulation region is a photoelectric conversion element that receives blue light and photoelectrically converts the blue light. The photodiode PD2 in which the semiconductor region 903 is set as a charge accumulation region is a photoelectric conversion element that receives red light and photoelectrically converts the red light.

On a surface side of the semiconductor substrate 901, which is a lower side in FIG. 132, an oxide film 904 is formed, and a plurality of pixel transistors Tr1 to Tr5 configured to perform such as reading-out of charges accumulated in the photoelectric conversion elements including the photodiodes PD1 and PD2, and a multi-layer interconnection layer 907 including a plurality of interconnection layers 905 and an interlayer insulating film 906 are formed. Furthermore, only one layer of the interconnection layer 905 is illustrated in FIG. 132 for simplification.

In FIG. 132, for example, the pixel transistor Tr1 is a selection transistor, the pixel transistor Tr2 is a amplification transistor, the pixel transistor Tr3 is a reset transistor, the pixel transistor Tr4 is a transfer transistor that transfers charges accumulated in the photodiode PD2, and the pixel transistor Tr5 is a transfer transistor that transfers charges accumulated in the photodiode PD1.

An n⁺-type semiconductor region 908 that becomes a source region or a drain region of the plurality of pixel transistors Tr1 to Tr5, and an element isolation region 909, and the like are formed on a surface side of the semiconductor substrate 901. Furthermore, the n⁺-type and a p⁺-type represent that a concentration of impurities is higher in comparison to the n-type and the p-type.

A p⁺-type semiconductor region 911 is formed between the n-type semiconductor regions 902 and 903, and a p⁺-type semiconductor region 912 configured to suppress a dark current is formed on an interface of the n-type semiconductor region 903 on a surface side interface.

A p⁺-type semiconductor region 913 configured to suppress the dark current is formed on a rear surface side of the semiconductor substrate 901, and a fixed charge film 914 having a negative fixed charge, and a transparent insulating film 915 are formed on the p⁺-type semiconductor region 913. For example, the transparent insulating film 915 is formed in a single layer or a plurality of layers by using a material such as silicon oxide (Sift), silicon nitride (SiN), silicon oxynitride (SiON), and hafnium oxide (HfO₂).

A photoelectric conversion element, in which a first electrode 921, a photoelectric conversion layer 922, and a second electrode 923 are laminated, is formed on an upper side of the transparent insulating film 915 through an insulating layer 916. The photoelectric conversion element receives green light and photoelectrically converts the green light. For example, the photoelectric conversion layer 922 that is interposed between the first electrode 921 and the second electrode 923 has a lamination structure including an upper photoelectric conversion layer 922A that includes a rhodamine-based dye, a melacyanine-based dye, a quinacridone derivative, a subphthalocyanine-based dye (subphthalocyanine derivative), and the like, and a lower semiconductor layer 922B that includes IGZO as an example. The photoelectric conversion element includes a charge accumulation electrode 925 that is disposed to be spaced away from the first electrode 921, and is disposed to face the photoelectric conversion layer 922 through an insulating layer 924. The charge accumulation electrode 925 is connected to a drive circuit through a metal interconnection 928, and a predetermined voltage is applied to the charge accumulation electrode 925 during charge accumulation.

A protective layer 931 formed on an upper surface of the second electrode 923, and an on-chip microlens 932 is formed on the protective layer 931.

The first electrode 921 is connected to a metal interconnection 926 that penetrates through the insulating layer 916, and the metal interconnection 926 is connected to a conductive plug 927 that penetrates through the semiconductor substrate 901. For example, the metal interconnection 926 includes a material such as tungsten (W), aluminum (Al), and copper (Cu).

The conductive plug 927 is connected a charge accumulation portion that includes the n⁺-type semiconductor region 908 in the vicinity of a surface side interface of the semiconductor substrate 901. The outer periphery of the conductive plug 927, which penetrates through the semiconductor substrate 901, is insulated with the transparent insulating film 915.

The lamination-structure pixel of the imaging unit 12 which has a configuration as illustrated in FIG. 132 has a lamination structure in which (1) a first photoelectric conversion element that is disposed on a lower side of the on-chip microlens 932 and on an outer side of the semiconductor substrate 901, includes the first electrode 921, the charge accumulation electrode 925, the upper photoelectric conversion layer 922A, the lower semiconductor layer 922B, and the second electrode 923, and photoelectrically converts green light, (2) a second photoelectric conversion element that is disposed on a lower side of the first photoelectric conversion element and on an inner side of the semiconductor substrate 901, includes the n-type semiconductor region 902, and photoelectrically converts blue light, (3) a third photoelectric conversion element that is disposed on a lower side of the second photoelectric conversion element and on an inner side of the semiconductor substrate 901, includes the n-type semiconductor region 903, and photoelectrically converts red light are laminated.

The lamination-structure pixel described in FIG. 132 has the above-described configuration. Accordingly, at one pixel, it is possible to independently photoelectrically convert green light, blue light, and red light from light incident to the pixel, and it is possible to independently output the resultant information. In addition, with this arrangement, it is not necessary to limit light incident to each pixel as a photoelectric conversion target to only greed light, only blue light, or only red light, and thus it is not necessary for the lamination-structure pixel to include color filters which limit light incident to the pixel to light of a specific wavelength and prevent light of other wavelengths from being incident to the pixel.

In the first to twenty-seventh embodiments to which the present technology is applied, the pixel array 12b in which the lamination-structure pixels are two-dimensionally disposed can be provided in the light-receiving region 12a of the imaging unit 12 provided in the camera module 1. In the lamination-structure pixel, as described above, at one pixel, it is possible to independently photoelectrically convert green light, blue light, and red light which are incident to the pixel, and it is possible to output the resultant information. Accordingly, in the first to twenty-seventh embodiments to which the present technology is applied, in a case where the pixel array 12b in which the lamination-structure pixels in FIG. 132 are two-dimensionally disposed is provided in the light-receiving region 12a of the imaging unit 12 provided in the camera module 1, each pixels of the pixel array 12b can independently photoelectrically convert green light, blue light, and red light which are incident to the pixel, and can output the resultant information.

For example, in a case where each of the pixels formed in the imaging unit 12 has a configuration in which only green light, only blue light, or only red light is photoelectrically converted and the resultant information is output, typically, on an outer side of the imaging unit 12, operation processing of interpolating an output between respective pixels for every color is performed, and the respective pixels have a plurality of pieces of pixel data of respective colors of green, blue, and red, and thus a final output image is generated. In contrast, in the case of using pixels of the lamination-structure pixel in FIG. 132, respective pixels can independently and photoelectrically convert green light, blue light, and red light, and can output the resultant information. Accordingly, the operation processing of interpolating an output between respective pixels for every color is not necessary, and thus it is possible to capture an image with higher resolution in comparison to the imaging unit 12 that performs the operation processing.

Furthermore, in the first to twenty-seventh embodiments to which the present technology is applied, in a case where the light-receiving region 12a of the imaging unit 12 provided in the camera module 1 includes the pixel (the above-described pixel of C) that receives light in entire wavelength regions of visible light, it is possible to employ a configuration in which photoelectric conversion results in the first to third photoelectric conversion elements included in the lamination-structure pixel are output after being added in the lamination-structure pixel. In addition, it is possible to employ a configuration in which the photoelectric conversion results of the first to third photoelectric conversion elements provided in the lamination-structure pixel are independently output, the photoelectric conversion results are added on an outer side of the pixel array 12b, and the resultant value is output.

<60. Second Modification Example of Imaging Unit 12>

As described above, in the first to twenty-seventh embodiment to which the present technology is applied, the camera module 1 includes the imaging unit 12, and the light-receiving region 12a of the imaging unit 12 includes the pixel array 12b in which pixels are two-dimensionally arranged in a matrix shape. Here, it is possible to employ a configuration in which a part of the pixels in the pixel array 12b or all of the pixels are provided with a polarization element.

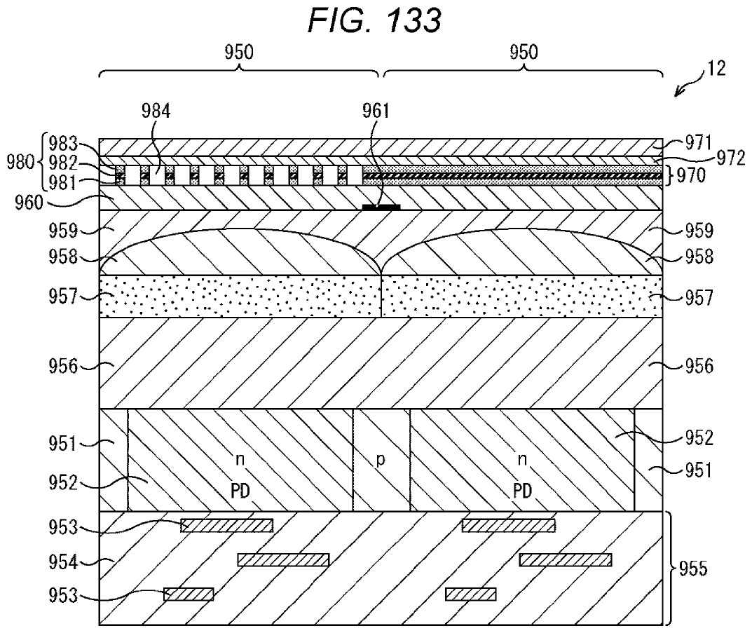

Description will be given of an example of the imaging unit 12 in which at least a part of the pixels in the pixel array 12b is provided with the polarization element as a second modification example of the imaging unit 12 with reference to FIG. 133.

FIG. 133 is a cross-sectional view of a pixel including the polarization element in the imaging unit 12.

In the imaging unit 12, an n-type semiconductor region 952 is formed in a p-type semiconductor substrate (semiconductor region) 951 for every pixel 950, and thus a photodiode PD that is a photoelectric conversion element is formed in pixel unit.

A plurality of pixel transistors Tr (not illustrated in the drawing) which perform reading-out of charges accumulated in the photodiode PD, and the like, and a multi-layer interconnection layer 955 including a plurality of interconnection layers 953 and an interlayer insulating film 954 are formed on a surface side of the semiconductor substrate 951 (on a lower side in the drawing).

A first planarization film 956, a color filter layer 957, an on-chip lens 958 are laminated in this order on a rear surface side of the semiconductor substrate 951 (on an upper side in the drawing), and a second planarization film 959 is formed on the on-chip lens 958. The first planarization film 956 includes, for example, SiO₂, and the second planarization film 959 includes, for example, an acrylic resin.

A base insulating layer 960 using, for example, SiO₂ is formed on an upper side of the second planarization film 959, and a light-shielding film 961 including tungsten (W) and the like is provided at a pixel boundary of the base insulating layer 960. For example, the light-shielding film 961 is grounded.

In addition, a wire grid polarization element 970 is formed on an upper surface of the base insulating layer 960 in a lamination structure, and a first protective layer 971 and a second protective layer 972 are formed on an upper surface of the wire grid polarization element 970. A refractive index of a material that constitutes the first protective layer 971 is set as n1, and a refractive index of a material that constitutes the second protective layer 972 is set as n2, the refractive indexes of the first protective layer 971 and the second protective layer 972 satisfy a relation of n1>n2. For example, the first protective layer 971 includes SiN (n1=2.0), and for example, the second protective layer 972 includes SiO₂ (n2=1.46). The drawing illustrates a state in which a bottom surface of the second protective layer 972 (surface that is in contact with the wire grid polarization element 970) is planarized, but the shape of the bottom surface of the second protective layer 972 may be a convex shape, a concave shape, or a state recessed in a wedge shape.

In the wire grid polarization element 970, a plurality of line portions 980 including a light reflective layer 981, an insulating layer 982, and a light absorbing layer 983 are regularly arranged at a predetermined interval maintained by the space portion 984. Among three layers of the line portions 980, the light reflective layer 981 on a side closest to the photodiode PD includes, for example, a conductive material such as aluminum, the insulating layer 982 on an intermediate side includes, for example, SiO₂, and the light absorbing layer 983 on a side closest to the second protective layer 972 includes a conductive material such as tungsten.

In a planar region of the pixel 950, the respective line portions 980 is curved in a predetermined direction such as a vertical direction, a horizontal direction, and an inclination direction and extend in a line shape, and a space portion 984 is disposed between the line portions 980 adjacent to each other. A width (horizontal width) in a direction that is perpendicular to an extension direction of the line portions 980 is constant. In an example in FIG. 133, an extension direction of the line portions 980 of a right pixel 950 between two pixels which are arranged in a horizontal direction is a horizontal direction in FIG. 133, and an extension direction of the line portions 980 of a left pixel 950 is a direction perpendicular to a paper surface. The space portion 984 is a space of which a part or the entirety is filled with air. For example, the entirety of the space portion 984 is filled with air.

As described above, the wire grid polarization element 970 includes a plurality of strip-shaped line portions 980, and the space portion 984 therebetween, and the line portions 980 include the light reflective layer 981, the insulating layer 982, and the light absorbing layer 983 from a side close to the photodiode PD. The insulating layer 982 is formed on the entirety of the upper surface of the light reflective layer 981, and the light absorbing layer 983 is formed on the entirety of the upper surface of the insulating layer 982. Specifically, the light reflective layer 981 is constituted by aluminum (Al) having a thickness of 150 nm, the insulating layer 982 is constituted by SiO₂ having a thickness of 25 nm or 50 nm, and the light absorbing layer 983 is constituted by tungsten (W) having a thickness of 25 nm. A direction (first direction) in which the strip-shaped light reflective layer 981 extends matches a polarization direction in which light is to be extinguished, and a repetition direction (second direction perpendicular to the first direction) of the strip-shaped light reflective layer 981 matches a polarization direction in which the light is transmitted. That is, the light reflective layer 981 has a function as a polarizer. The light reflective layer 981 attenuates a polarized wave having an electric field component in a direction parallel to the direction (first direction) in which the light reflective layer 981 extends in light that is incident to the wire grid polarization element 970, and allows a polarized wave, which has an electric field component in a direction (second direction) perpendicular to the direction in which the light reflective layer 981 extends, to be transmitted therethrough. The first direction is a light absorption axis of the wire grid polarization element 970, and the second direction is a light transmission axis of the wire grid polarization element 970.

A length of the line portion 980 in the first direction is the same as a length of the photodiode PD along the first direction. In addition, in the example illustrated in the drawing, an example of a pixel, in which an angle between the direction (first direction) in which the strip-shaped light reflective layer 981 of the pixel 950 extends and a vertical direction of the pixel array 12b is set to, for example, an angle of 0° and an angle of 90°, is illustrated. However, it is possible to dispose a pixel in which an angle between the direction in which the strip-shaped light reflective layer 981 of the pixel 950 extends and a vertical direction of the pixel array 12b is set to 45°, and a pixel in which the angle is set to 135°.

The pixel 950 of the imaging unit 12 which has a configuration illustrated in FIG. 133 has a structure including (1) the wire grid polarization element 970 including the plurality of line portions 980 in which the light reflective layer 981, the insulating layer 982, and the light absorbing layer 983 are laminated, and the space portion 984 that is located between the line portions 980, and (2) the photodiode PD that is a photoelectric conversion element in a superimposition manner.

Furthermore, in FIG. 133, the wire grid polarization element 970 is formed on an upper side of the on-chip lens 958, but may be formed on a lower side of the on-chip lens 958 and on an upper side of the photodiode PD.

In the first to twenty-seventh embodiments to which the present technology is applied, the light-receiving region 12a of the imaging unit 12 provided in the camera module 1 may include the pixel array 12b in which pixels are two-dimensionally arranged, and a part or all of the pixels in the pixel array 12b may include the above-described wire grid polarization element 970 as a polarization element.

As the pixel including the polarization element, it is possible to employ two kinds of pixels, that is, a pixel in which an angle between the extension direction of the line portions 980 of the wire grid polarization element 970 and a row direction of two-dimensionally arranged pixels of the pixel array 12b is set to 0° and a pixel in which the angle is set to 90°. In other words, it is possible to employ two kinds of pixels, that is, a pixel in which a polarization direction of light transmitted through a polarization element is set to 0° and a pixel in which the polarization direction is set to 90°.

In addition, as the pixel including the polarization element, it is possible to employ four kinds of pixels, that is, a pixel in which an angle between the extension direction of the line portions 980 of the wire grid polarization element 970 and a row direction of two-dimensionally arranged pixels of the pixel array 12b is set to 0°, a pixel in which the angle is set to 45°, a pixel in which the angle is set to 90°, and a pixel in which the angle is set to 135°. In other words, it is possible to employ four kinds of pixels, that is, a pixel in which a polarization direction of light transmitted through a polarization element is set to 0°, a pixel in which the polarization direction is set to 45°, a pixel in which the polarization direction is set to 90°, and a pixel in which the polarization direction is set to 135°.

In the first to twenty-seventh embodiments to which the present technology is applied, when the pixels of the imaging unit 12 provided in the camera module 1 include the polarization element, for example, in the case of capturing an image of a subject that is close to a water surface, or a subject on a road on which water remains due to rainfall, it is possible to capture only light reflected from the original subject surface of which an image is desired to be captured after removing light reflected from the water surface or the load surface on which water remains. In addition, it is possible to understand a shape of a subject surface by detecting only a light beam in a specific polarization direction in light that is reflected from the subject surface and is incident to the camera module 1.

<61. Application Example to Electronic Apparatus>

The above-described camera module 1 can be used in electronic apparatuses such as an imaging apparatus including a digital still camera, a video camera, and the like, a portable terminal device having an image capturing function, a copier that uses a solid-state imaging element in an image reading unit in combination with the electronic apparatuses in which a solid-state imaging element is used in an image reading-in unit (photoelectric conversion unit).

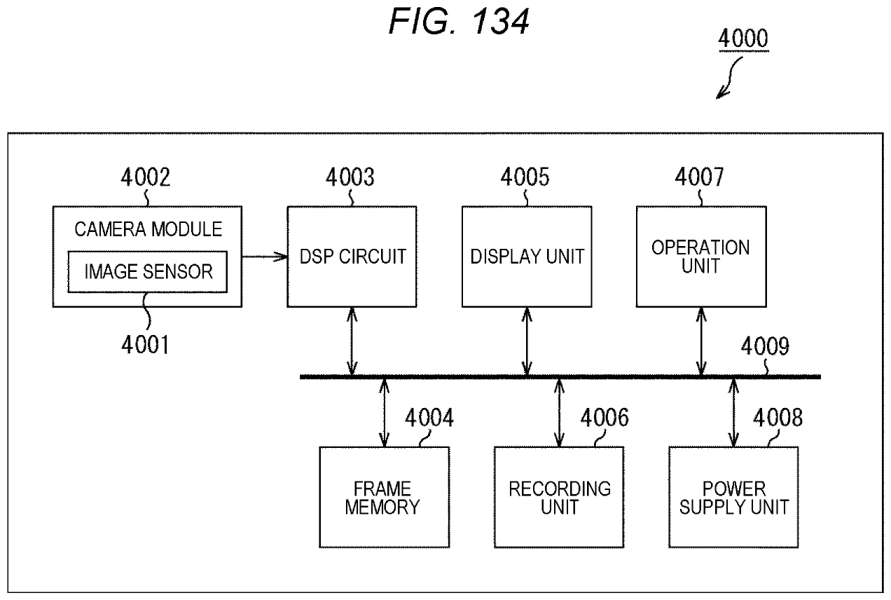

FIG. 134 is a block diagram illustrating a configuration example of an imaging apparatus as an electronic apparatus to which the present technology is applied.

An imaging apparatus 4000 in FIG. 134 includes a camera module 4002, and a digital signal processing (DSP) circuit 4003 that is a camera signal processing circuit. In addition, the imaging apparatus 4000 also includes a frame memory 4004, a display unit 4005, a recording unit 4006, an operation unit 4007, and a power supply unit 4008. The DSP circuit 4003, the frame memory 4004, the display unit 4005, the recording unit 4006, the operation unit 4007, and the power supply unit 4008 are connected to each other through a bus line 4009.

The image sensor 4001 in the camera module 4002 receives incident light (image light) from a subject, converts a light amount of incident light imaged on an imaging surface into an electric signal in pixel unit, and outputs the electric signal as a pixel signal. As the camera module 4002, the above-described camera module 1 is employed, and the image sensor 4001 corresponds to the imaging unit 12. The DSP circuit 4003 processes the signal output from the camera module 4002, and supplies a processing result to the frame memory 4004 and the display unit 4005.

For example, the display unit 4005 is configured as a panel type display device such as a liquid crystal panel and an organic electroluminescence (EL) panel, and displays a moving image or a still image which is captured by the image sensor 4001. The recording unit 4006 records the moving image or the still image which is captured by the image sensor 4001 in a recording medium such as a hard disk and a semiconductor memory.

The operation unit 4007 issues an operation command with respect to various functions provided in the imaging apparatus 4000 under an operation by a user. The power supply unit 4008 appropriately supplies various kinds of power to the DSP circuit 4003, the frame memory 4004, the display unit 4005, the recording unit 4006, and the operation unit 4007 as operation power of the supply targets.

As described above, when using the camera module 1 relating to the first to twenty-seventh embodiments on which the laminated lens structure 11, which includes the lens-attached laminated substrate 41 using at least one sheet of the lamination-structure carrier substrate 81, and the lens-attached single-layer substrate 41 using at least one sheet of the single-layer-structure carrier substrate 81, is mounted as the camera module 4002, it is possible to realize high image quality and a reduction in size. Accordingly, even in the imaging apparatus 4000 using, for example, a camera module for mobile apparatuses such as a video camera, a digital still camera, and a portable telephone, it is possible to realize compatibility between a reduction in size of a semiconductor package and high image quality of a captured image.

<Use Example of Camera Module>

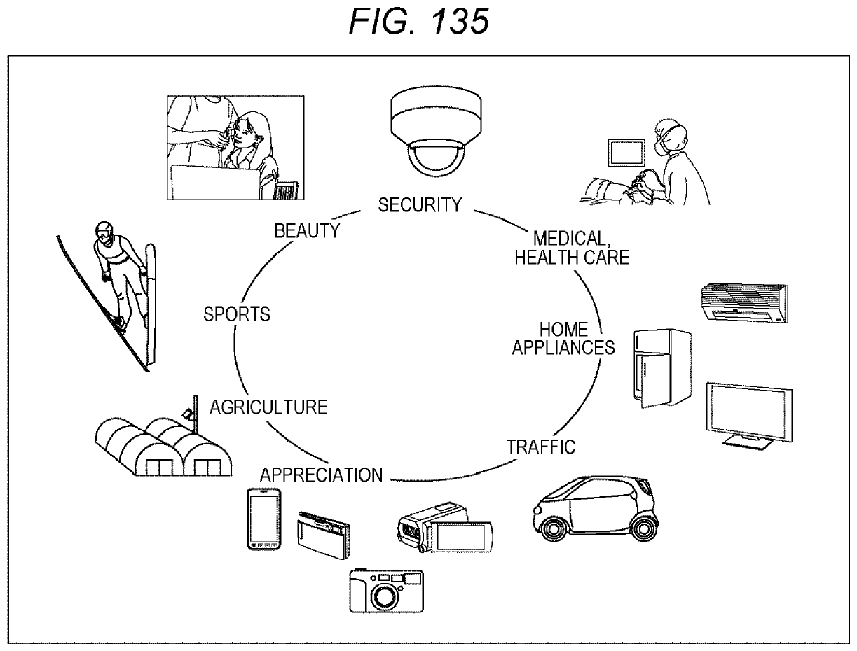

FIG. 135 is a view illustrating a use example of the above-described camera module 1.

For example, the above-described camera module 1 can be used for various cases of sensing light such as visible light, infrared light, ultraviolet light, and X-rays.
Apparatuses such as a digital still camera and a portable device with a camera function which capture an image that is supplied for appreciation
Apparatuses for traffic such as an in-vehicle sensor that captures images of a forward side, a backward side, the periphery, a vehicle interior, and the like of the vehicle for safe travelling such as automatic stopping, recognition of a driver state, and the like, a monitoring camera that monitors a travelling vehicle or a road, and a distance measuring sensor that measures a distance between vehicles, and the like
Apparatuses for home appliances such as a TV, a refrigerator, and an air-conditioner to photograph a gesture of a user and to perform an apparatus operation in accordance with the gesture
Apparatuses for medical or health care such as an endoscope and an apparatus that performs angiography through reception of infrared light
Apparatuses for security such as a security monitoring camera and a personal authentication camera
Apparatus for beauty such as a skin measuring device and a microscope that photographs a scalp
Apparatuses for sports such as an action camera and a wearable camera for sports or the like
Apparatuses for agriculture such as a camera for monitoring a state of a farm and a crop plant

<62. Application Example of In-Vivo Information Acquisition System>

The technology (present technology) relating to the present disclosure is applicable to various products. For example, the present technology may be applied to an in-vivo information acquisition system of patients by using a capsule type endoscope.

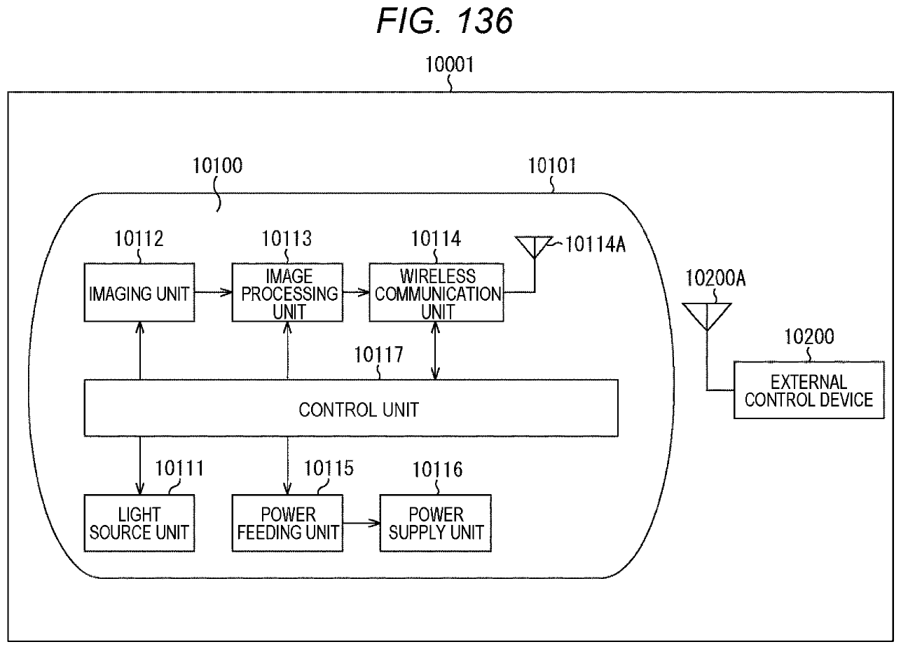

FIG. 136 is a block diagram illustrating an example of a schematic configuration of an in-vivo information acquisition system of patients by using a capsule type endoscope to which the technology (present technology) relating the present disclosure is applicable.

An in-vivo information acquisition system 10001 includes a capsule type endoscope 10100 and an external control device 10200.

The capsule type endoscope 10100 is swallowed by a patient in inspection. The capsule type endoscope 10100 has an image capturing function and a wireless communication function, sequentially captures images (hereinafter, also referred to as an in-vivo image) inside organs such as the stomach and the intestines at a predetermined interval while moving at the inside thereof through peristalsis or the like until being naturally ejected from the patient, and sequentially wirelessly transmits information relating to the in-vivo image to the external control device 10200 on an external side of the body.

The external control device 10200 collectively controls operations of the in-vivo information acquisition system 10001. In addition, the external control device 10200 receives in-vivo image related information transmitted from the capsule type endoscope 10100, and generates image data for displaying the in-vivo image on a display device (not illustrated) on the basis of the in-vivo image related information that is received.

In this manner, in the in-vivo information acquisition system 10001, it is possible to obtain the in-vivo image obtained by capturing an in-vivo state of the patient from the swallowing of the capsule type endoscope 10100 to the natural ejection at any time.

The configuration and the function of the capsule type endoscope 10100 and the external control device 10200 will be described in more detail.

The capsule type endoscope 10100 includes a capsule type casing 10101, and a light source unit 10111, an imaging unit 10112, an image processing unit 10113, a wireless communication unit 10114, a power feeding unit 10115, a power supply unit 10116, and a control unit 10117 are accommodated in the casing 10101.

For example, the light source unit 10111 is constituted by a light source such as a light emitting diode (LED), and irradiates an imaging visual field of the imaging unit 10112 with light.

The imaging unit 10112 is constituted by an optical system including an imaging element and a plurality of lenses provided at a front end of the imaging element. Reflected light (hereinafter, referred to as “observation light”) of light, which is emitted to a body tissue as an observation target, is condensed to the optical system, and is incident to the imaging element. In the imaging unit 10112, light incident to the imaging element is photoelectrically converted in the imaging unit, and an image signal corresponding to the observation light is generated. The image signal generated by the imaging unit 10112 is supplied to the image processing unit 10113.

The image processing unit 10113 is constituted by a processor such as a central processing unit (CPU) and a graphics processing unit (GPU), and performs various kinds of signal processing with respect to the image signal that is generated by the imaging unit 10112. The image processing unit 10113 supplies the image signal, which is subjected to the signal processing, to the wireless communication unit 10114 as RAW data.

The wireless communication unit 10114 performs predetermined processing such as modulation processing with respect to the image signal that is subjected to the signal processing by the image processing unit 10113, and transmits the image signal to the external control device 10200 through an antenna 10114A. In addition, the wireless communication unit 10114 receives a control signal relating to a drive control of the capsule type endoscope 10100 from the external control device 10200 through the antenna 10114A. The wireless communication unit 10114 supplies the control signal received from the external control device 10200 to the control unit 10117.

The power feeding unit 10115 includes an antenna coil for power reception, a power reproducing circuit that reproduces power from a current generated in the antenna coil, a booster circuit, and the like. In the power feeding unit 10115, power is generated by using a so-called non-contact charging principle.

The power supply unit 10116 is constituted by a secondary battery, and stores power generated by the power feeding unit 10115. In FIG. 136, to avoid complication of the drawing, an arrow indicating a power supply destination from the power supply unit 10116, and the like are not illustrated, but power stored in the power supply unit 10116 is supplied to the light source unit 10111, the imaging unit 10112, the image processing unit 10113, the wireless communication unit 10114, and the control unit 10117, and can be used to drive the units.

The control unit 10117 is constituted by a processor such as a CPU, and appropriately controls drive of the light source unit 10111, the imaging unit 10112, the image processing unit 10113, the wireless communication unit 10114, and the power feeding unit 10115 in accordance with a control signal that is transmitted from the external control device 10200.

The external control device 10200 includes a processor such as a CPU and a GPU, a microcomputer in which a processor and a storage element such as a memory are mixed in, a control substrate, and the like. The external control device 10200 transmits a control signal to the control unit 10117 of the capsule type endoscope 10100 through the antenna 10200A to control an operation of the capsule type endoscope 10100. In the capsule type endoscope 10100, for example, irradiation conditions of light as an observation target in the light source unit 10111 can be changed in accordance with the control signal from the external control device 10200. In addition, imaging conditions (for example, a frame rate, an exposure value, and the like in the imaging unit 10112) can be changed in accordance with the control signal from the external control device 10200. In addition, processing contents in the image processing unit 10113 and image signal transmitting conditions (for example, a transmission interval, the number of transmission images, and the like) from the wireless communication unit 10114 may be changed in accordance with the control signal from the external control device 10200.

In addition, the external control device 10200 performs various kinds of signal processing with respect to the image signal transmitted from the capsule type endoscope 10100, and generates image data for displaying the captured in-vivo image on a display device. As the imaging processing, for example, various kinds of processing such as development processing (demosaic processing), high image quality processing (such as band emphasizing processing, super image processing, noise reduction (NR) processing and/or image stabilization processing), and/or enlargement processing (electronic zoom processing) can be performed. The external control device 10200 controls drive of the display device and displays the captured in-vivo image on the basis of the generated image data. In addition, the external control device 10200 records the generated image data on a recording device (not illustrated) or may output the image data to a printing apparatus (not illustrated) for printing.

Hereinbefore, description has been given of an example of the in-vivo information acquisition system to which the technology relating to the present disclosure is applicable. The technology relating to the present disclosure is applicable to the imaging unit 10112 among the above-described configurations. Specifically, as the imaging unit 10112, the camera modules 1 according to the first to twenty-seventh embodiments are applicable. When the technology relating to the present disclosure is applied to the imaging unit 10112, the capsule type endoscope 10100 can be made to be smaller, and thus it is possible to reduce load on the patient. In addition, a clearer operation site image can be obtained while miniaturizing the capsule type endoscope 10100, and thus inspection accuracy is improved.

<63. Application Example to Endoscopic Surgery System>

The technology (present technology) relating to the present disclosure can be applied to various products. For example, the technology relating to the present disclosure may be applied to an endoscopic surgery system.

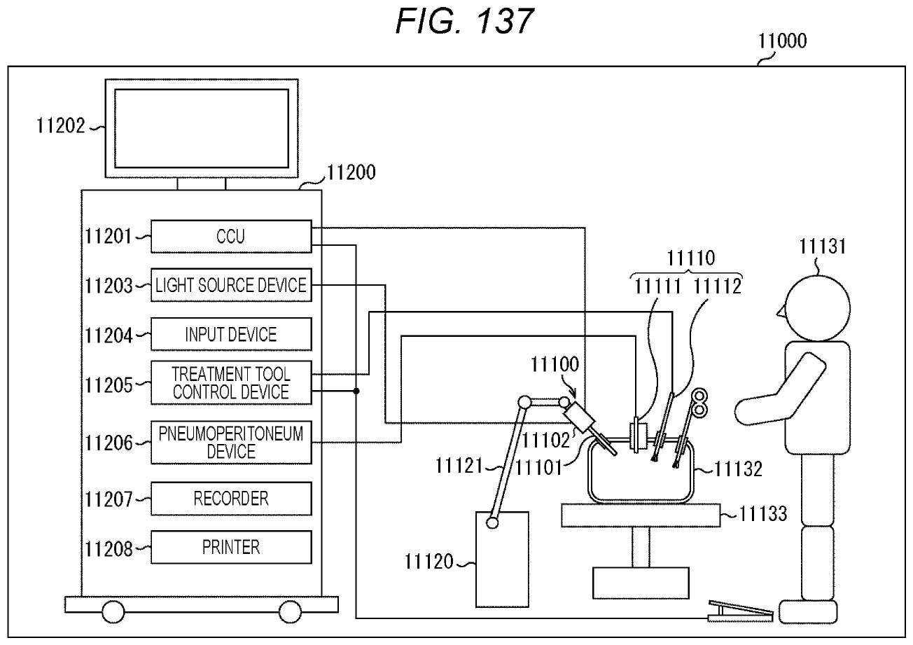

FIG. 137 is a view illustrating an example of a schematic configuration of the endoscope surgery system to which the technology (present technology) relating to the present disclosure is applicable.

FIG. 137 illustrates a state in which an operator (doctor) 11131 performs an operation with respect to a patient 11132 on a patient bed 11133 by using an endoscopic surgery system 11000. As illustrated in the drawing, the endoscopic surgery system 11000 includes an endoscope 11100, an operation tool 11110 such as a pneumoperitoneum tube 11111 and an energy treatment tool 11112, a support arm device 11120 that supports the endoscope 11100, and a cart 11200 on which various devices for endoscopic surgery are mounted.

The endoscope 11100 includes a lens-barrel 11101 of which a predetermined length of region from the tip end is inserted into a body cavity of the patient 11132, and a camera head 11102 that is connected to a base end of the lens-barrel 11101. In the example illustrated in the drawing, the endoscope 11100 configured as a so-called hard mirror including the hard lens-barrel 11101 is illustrated in the drawing, but the endoscope 11100 may be configured as a so-called soft mirror including a soft lens-barrel.

An opening into which an objective lens is fitted is provided at a tip end of the lens-barrel 11101. A light source device 11203 is connected to the endoscope 11100, and light generated by the light source device 11203 is guided to the tip end of the lens-barrel by a light guide that is provided to extend into the lens-barrel 11101, and is emitted toward an observation target in the body cavity of the patient 11132 through the objective lens. Furthermore, the endoscope 11100 may be a direct-viewing mirror, a perspective-viewing mirror, or a side-viewing mirror.

An optical system and an imaging element are provided in the camera head 11102, and reflected light (observation light) from the observation target is condensed to the imaging element by the optical system. When the observation light is photoelectrically converted by the imaging element, an electric signal corresponding to the observation light, that is, an image signal corresponding to an observation image is generated. The image signal is transmitted to a camera control unit (CCU) 11201 as RAW data.

The CCU 11201 is constituted by a central processing unit (CPU), a graphics processing unit (GPU), and the like, and collectively controls operations of the endoscope 11100 and a display device 11202. In addition, the CCU 11201 receives an image signal from the camera head 11102, and performs various kinds of image processing such as development processing (demosaic processing) for displaying an image based on the image signal with respect to the image signal.

The display device 11202 displays an image based on the image signal that is subjected to the image processing by the CCU 11201 in accordance with a control from the CCU 11201.

For example, the light source device 11203 includes a light source such as a light emitting diode (LED), and supplies irradiation light when photographing an operation site and the like to the endoscope 11100.

An input device 11204 is an input interface with respect to the endoscopic surgery system 11000. A user can perform input or instruction input of various pieces of information with respect to the endoscopic surgery system 11000 through the input device 11204. For example, the user inputs an instruction indicating changing of image capturing conditions (the kind of irradiation light, a magnification, a focal length, and the like) by the endoscope 11100, and the like.

A treatment tool control device 11205 controls drive of the energy treatment tool 11112 configured to perform cauterization of a tissue, incision, sealing of a blood vessel, and the like. A pneumoperitoneum device 11206 supplies a gas into the body cavity through the pneumoperitoneum tube 11111 to swell the body cavity of the patient 11132 so as to secure a visual field by the endoscope 11100 and a working space of the doctor. A recorder 11207 is a device that can record various pieces of information relating to surgery. A printer 11208 is a device that can print various pieces of information relating to the surgery in various types such as a text, an image, and a graph.

Furthermore, for example, the light source device 11203, which supplies irradiation light when photographing an operation site with the endoscope 11100, can be constituted by an LED, a laser light source, and a white light source that is constituted by a combination of the LED and the laser light source. In a case where the white light source is constituted by a combination of RGB laser light sources, output intensity and an output timing of each color (each wavelength) can be controlled with high accuracy, and thus it is possible to perform adjustment of white balance of captured image in the light source device 11203. In addition, in this case, when laser light from the respective RGB laser light sources is emitted to an observation target in a time-division manner, and drive of the imaging element of the camera head 11102 is controlled in synchronization with the emission timing, it is also possible to capture images corresponding to RGB in a time-division manner. According to the method, even though color filters are not provided in the imaging element, it is possible to obtain a color image.

In addition, the drive of the light source device 11203 may be controlled so that the intensity of light that is emitted is changed for every predetermined time. When the drive of the imaging element of the camera head 11102 is controlled in synchronization with the light intensity changing timing to acquire images in a time-division manner, and the images are combined, it is possible to generate high dynamic range image without black defects and halation.

In addition, the light source device 11203 may be configured to supply light in a predetermined wavelength band corresponding special light observation. In the special light observation, for example, light in a band narrower than that of irradiation light (that is, white light) in a typical observation is emitted by using wavelength dependency of light absorption in a body tissue to perform a so-called narrow band light observation (narrow band imaging), which photographs a predetermined tissue such as a blood vessel in a mucous membrane surface layer. In addition, in the special light observation, a fluorescent observation may be performed to obtain an image by fluorescence that occurs due to irradiation of excited light. In the fluorescent observation, for example, the body tissue may be irradiated with excited light to observe fluorescence from the body tissue (self-fluorescence observation), a reagent such as indocyanine green (ICG) may be locally injected into the body tissue and the body tissue may be irradiated with excited light corresponding to a fluorescent wavelength of the reagent to obtain a fluorescent image. The light source device 11203 may be configured to supply narrow band light and/or excited light corresponding to the special light observation.

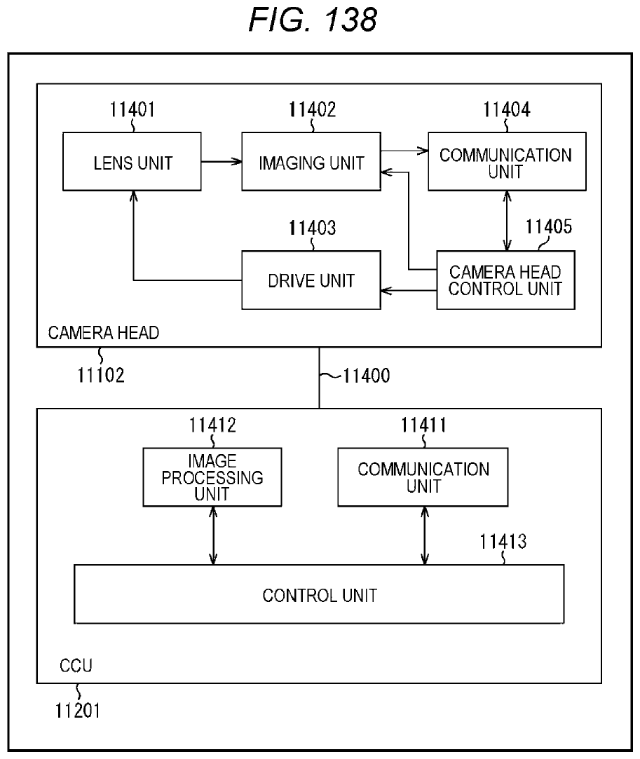

FIG. 138 is a block diagram illustrating an example of a functional configuration of the camera head 11102 and the CCU 11201 which are illustrated in FIG. 137.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected to each other through a transmission cable 11400 in a communication-possible manner.

The lens unit 11401 is an optical system that is provided in a connection portion with the lens-barrel 11101. Observation light that is received from the tip end of the lens-barrel 11101 is guided to the camera head 11102, and is incident to the lens unit 11401. The lens unit 11401 is constituted in combination of a plurality of lenses including a zoom lens and a focus lens.

The imaging unit 11402 includes an imaging element. The number of the imaging element that constitutes the imaging unit 11402 may be one piece (a so-called single plate type) or a plurality of pieces (a so-called multi-plate type). In a case where the imaging unit 11402 is configured in the multi-plate type, for example, image signals corresponding to RGB may be generated by respective imaging elements, and may be combined with each other to obtain a color image. In addition, the imaging unit 11402 may include one piece of imaging element that acquires an image signal for a right eye and an image signal for a left eye which correspond to 3D (dimensional) display. When the 3D display is realized, the operator 11131 can understand a depth length of a biological tissue at an operation site with more accuracy. Furthermore, in a case where the imaging unit 11402 is configured as the multi-plate type, a plurality of the lens units 11401 may be provided in correspondence with respective imaging element.

In addition, it is not necessary for the imaging unit 11402 to be provided in the camera head 11102. For example, the imaging unit 11402 may be provided immediately after an objective lens at the inside of the lens-barrel 11101.

The drive unit 11403 includes an actuator and moves the zoom lens and the focus lens of the lens unit 11401 by a control from the camera head control unit 11405 by a predetermined length along an optical axis. With this arrangement, it is possible to appropriately adjust a magnification and a focus of an image captured by the imaging unit 11402.

The communication unit 11404 is constituted by a communication device that transmits and receives various pieces of information to and from the CCU 11201. The communication unit 11404 transmits the image signal obtained from the imaging unit 11402 to the CCU 11201 as RAW data through the transmission cable 11400.

In addition, the communication unit 11404 receives a control signal for controlling the drive of the camera head 11102 from the CCU 11201, and supplies the control signal to the camera head control unit 11405. For example, the control signal includes information relating to image capturing conditions such as information indicating designation of a frame rate of a captured image, information indicating designation of an exposure value during image capturing, and/or information indicating designation of a magnification and a focus of the captured image.

Furthermore, image capturing conditions such as the frame rate, the exposure value, the magnification, and the focus may be appropriately designated by a user, or may be automatically set by the control unit 11413 of the CCU 11201 on the basis of an image signal that is acquired. In the latter case, an auto exposure (AE) function, an auto focus (AF) function, and an auto white balance (AWB) function are provided in the endoscope 11100.

The camera head control unit 11405 controls the drive of the camera head 11102 on the basis of the control signal from the CCU 11201 which is received through the communication unit 11404.

The communication unit 11411 is constituted by a communication device that transmits and receives various pieces information to and from the camera head 11102. The communication unit 11411 receives an image signal that is transmitted from the camera head 11102 through the transmission cable 11400.

In addition, the communication unit 11411 transmits a control signal for controlling the drive of the camera head 11102 to the camera head 11102. The image signal and the control signal can be transmitted through electric communication, optical communication, and the like.

The image processing unit 11412 performs various kinds of image processing with respect to the image signal that is RAW data transmitted from the camera head 11102.

The control unit 11413 performs various controls relating to capturing an image of the operation site and the like by the endoscope 11100, and display of a captured image obtained by capturing the image of the operation site and the like. For example, the control unit 11413 generates a control signal for controlling the drive of the camera head 11102.

In addition, the control unit 11413 displays the captured image, on which the operation site and the like reflect, on the display device 11202 on the basis of the image signal that is subjected to the image processing by the image processing unit 11412. At this time, the control unit 11413 may recognize various objects in the captured image by using various image recognition technologies. For example, the control unit 11413 can recognize operation tools such as a forceps, a specific biological portion, bleeding, mist when using the energy treatment tool 11112, and the like by detecting an edge shape, a color, and the like of an object included in the captured image. When allowing the display device 11202 to display the captured image, the control unit 11413 may overlap various pieces of operation assisting information on the image of the operation site by using the recognition result. The operation assisting information is displayed in an overlapping manner and is provided to the operator 11131, it is possible to reduce load on the operator 11131, or the operator 11131 can reliably progress the operation.

The transmission cable 11400 that connects the camera head 11102 and the CCU 11201 is an electric signal cable corresponding to communication of an electric signal, optical fiber corresponding to optical communication, or a composite cable thereof.

Here, in the example illustrated in the drawing, communication is performed in a wired manner by using the transmission cable 11400, but communication between the camera head 11102 and the CCU 11201 may be performed in a wireless manner.

Hereinbefore, description has been given of an example of the endoscopic surgery system to which the technology relating to the present disclosure is applicable. The technology relating to the present disclosure is applicable to the lens unit 11401 of the camera head 11102 and the imaging unit 11402 among the above-described configurations. Specifically, as the lens unit 11401 and the imaging unit 11402, the camera modules 1 relating to the first to twenty-seventh embodiments are applicable. When the technology relating to the present disclosure is applied to the lens unit 11401 and the imaging unit 11402, it is possible to obtain a clearer image of an operation site while reducing a size of the camera head 11102.

Furthermore, here, description has been given of the endoscopic surgery system as an example, but the technology relating to the present disclosure may be applied to a microscope surgery system, for example.

<64. Application Example to Moving Object>

The technology (present technology) relating to the present disclosure can be applied to various products. For example, the technology relating to the present disclosure may be realized as a device that is mounted on any one kind of moving object among an automobile, an electric vehicle, a hybrid electric vehicle, a motorcycle, a bicycle, a personal mobility, an airplane, a drone, a ship, a robot, and the like.

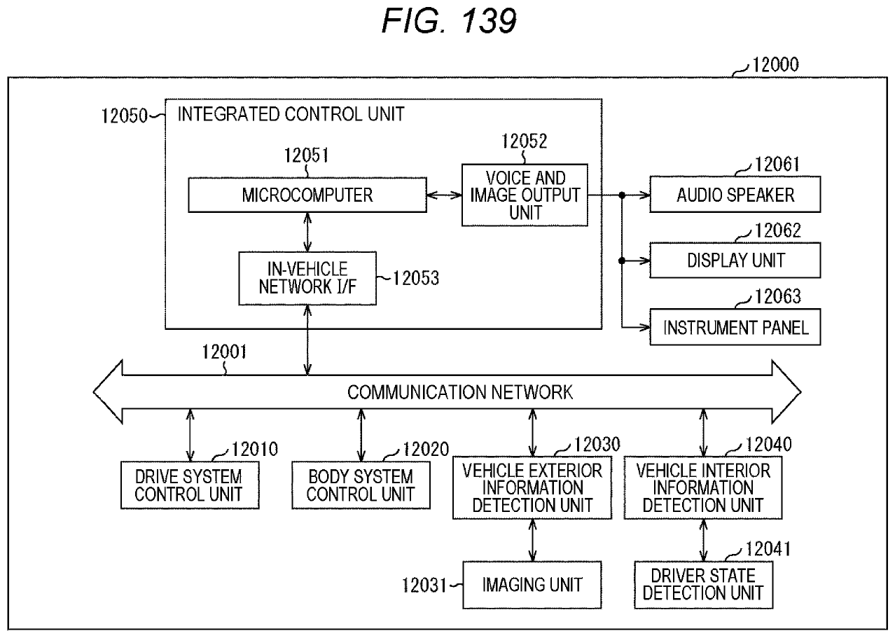

FIG. 139 is a block diagram illustrating a schematic configuration example of a vehicle control system that is an example of a moving object control system to which the technology relating to the present disclosure is applicable.

A vehicle control system 12000 includes a plurality of electronic control units which are connected to each other through a communication network 12001. In the example illustrated in FIG. 139, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a voice and image output unit 12052, and a vehicle-mounted network interface (IF) 12053 are illustrated in the drawing.

The drive system control unit 12010 controls an operation of devices relating to a drive system of a vehicle in accordance with various programs. For example, the drive system control unit 12010 functions as a control device of a drive force generating device such as an internal combustion engine and a drive motor which generates a driving force of the vehicle, a drive force transmitting mechanism that transmits the drive force to wheels, a steering mechanism that adjusts a rudder angle of the vehicle, a brake device that generates a braking force of the vehicle, and the like.

The body system control unit 12020 controls an operation of various devices mounted on a vehicle body in accordance with various programs. For example, the body system control unit 12020 functions as a control device of various lamps such as a keyless entry system, a smart key system, a power window device, a head lamp, a back lamp, a brake lamp, a winker, and a fog lamp. In this case, an electric wave transmitted from a portable device that substitutes for a key, or signals of various switches can be input to the body system control unit 12020. The body system control unit 12020 receives input of the electric wave or the signals, and controls a door lock device, a power window device, and lamps, and the like of the vehicle.

The vehicle exterior information detection unit 12030 detects information of the outside of the vehicle on which the vehicle control system 12000 is mounted. For example, the imaging unit 12031 is connected to the vehicle exterior information detection unit 12030. The vehicle exterior information detection unit 12030 allows the imaging unit 12031 to capture a vehicle exterior image and receives the captured image. The vehicle exterior information detection unit 12030 may perform object detection processing with respect to a person, a vehicle, an obstacle, a mark, a character on a road surface, or the like, or distance detection processing on the basis of the image that is received.

The imaging unit 12031 is an optical sensor that receives light, and outputs an electric signal corresponding to a light reception amount of the light. The imaging unit 12031 can output the electric signal as an image, or as distance measurement information. In addition, light that is received by the imaging unit 12031 may be visible light, or non-visible light such as infrared rays.

The vehicle interior information detection unit 12040 detects vehicle interior information. For example, a driver state detection unit 12041 that detects a driver state is connected to the vehicle interior information detection unit 12040. For example, the driver state detection unit 12041 includes a camera that captures an image of a driver, and the vehicle interior information detection unit 12040 may calculate the degree of fatigue or the degree of concentration of the driver on the basis of detection information that is input from the driver state detection unit 12041, or may determine whether or not the driver dozes off.

The microcomputer 12051 can calculate a control target value of the drive force generating device, the steering mechanism, or the brake device on the basis of the vehicle interior information or the vehicle exterior information which are acquired by the vehicle exterior information detection unit 12030 or the vehicle interior information detection unit 12040, and can output a control command to the drive system control unit 12010. For example, the microcomputer 12051 can perform a cooperative control to realize a function of an advanced driver assistance system (ADAS) which includes collision avoidance or shock mitigation of a vehicle, following travel based on a distance between vehicles, vehicle velocity retention travel, vehicle collision alarm, vehicle lane deviation alarm, and the like.

In addition, the microcomputer 12051 can perform a cooperative control for automatic driving in which the vehicle autonomously travels, and the like without depending on an operation by a driver by controlling the drive force generating device, the steering mechanism, the brake device, and the like on the basis of vehicle peripheral information that is acquired by the vehicle exterior information detection unit 12030 or the vehicle interior information detection unit 12040.

In addition, microcomputer 12051 can output a control command to the body system control unit 12020 on the basis of the vehicle exterior information that is acquired by the vehicle exterior information detection unit 12030. For example, the microcomputer 12051 can perform a cooperative control to realize glare protection by controlling a head lamp in correspondence with a position of a preceding vehicle or an oncoming vehicle which is detected by the vehicle exterior information detection unit 12030 to switch a high beam to a low beam.

The voice and image output unit 12052 transmits an output signal of at least one of a voice and an image to an output device that can visually or auditorily notify a vehicle passenger or a vehicle exterior side of information. In the example of FIG. 139, as the output device, an audio speaker 12061, a display unit 12062, and an instrument panel 12063 are exemplified. For example, the display unit 12062 may include at least one of an on-board display and a head-up display.

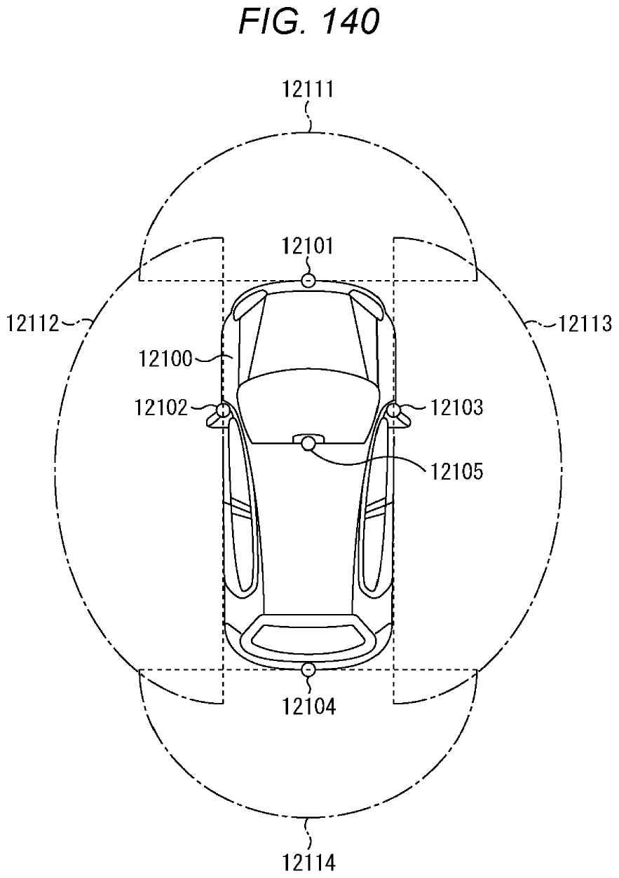

FIG. 140 is a view illustrating an example of an installation position of the imaging unit 12031.

In FIG. 140, a vehicle 12100 includes imaging units 12101, 12102, 12103, 12104, and 12105 as the imaging unit 12031.

For example, the imaging units 12101, 12102, 12103, 12104, and 12105 are installed at positions such as a front nose, a side-view mirror, a rear bumper, a back door, an upper side of a vehicle front glass in a vehicle room, and the like of the vehicle 12100. The imaging unit 12101 provided at the front nose, and the imaging unit 12105 that is provided on an upper side of the vehicle front glass in a vehicle room mainly acquire images on a forward side of the vehicle 12100. The imaging units 12102 and 12103 which are provided in the side-view mirror mainly acquire images on a lateral side of the vehicle 12100. The imaging unit 12104 that is provided in the rear bumper or the back door mainly acquires images on a backward side of the vehicle 12100. The images on the forward side, which are acquired by the imaging units 12101 and 12105, can be mainly used to detect a preceding vehicle, a pedestrian, an obstacle, a traffic signal, a traffic sign, a vehicle lane, and the like.

Furthermore, FIG. 140 illustrates an example of a photographing range of the imaging units 12101 to 12104. An image capturing range 12111 represents an image capturing range of the imaging unit 12101 that is provided in the front nose, image capturing ranges 12112 and 12113 respectively represent image capturing ranges of the imaging units 12102 and 12103 which are provided in the side-view mirrors, an image capturing range 12114 represents an image capturing range of the imaging unit 12104 that is provided in the rear bumper or the back door. For example, the imaging units 12101 to 12104 can superimpose a plurality of pieces of image data captured by the imaging unit 12101 to 12104 on each other, thereby obtaining an overlooking image when the vehicle 12100 is seen from an upper side.

At least one of the imaging units 12101 to 12104 may have a function of acquiring distance information. For example, at least one of the imaging units 12101 to 12104 may be a stereo camera including a plurality of imaging elements, or may be an imaging element that includes pixels for phase difference detection.

For example, the microcomputer 12051 can extract a three-dimensional object, which is a closest three-dimensional object, particularly, on a proceeding path of the vehicle 12100 and travels in approximately the same direction as that of the vehicle 12100 that travels at a predetermined velocity (for example, 0 km/h or greater), as a preceding vehicle by obtaining distances to respective three-dimensional objects in the image capturing ranges 12111 to 12114 and a variation of the distances with the passage of time (relative velocity to the vehicle 12100) on the basis of the distance information obtained from the imaging units 12101 to 12104. In addition, the microcomputer 12051 can set a distance between vehicles to be secured in advance in front of the preceding vehicle to perform automatic brake control (also including a following stop control), an automatic acceleration control (also including a following acceleration control), and the like. As described above, it is possible to perform a cooperative control for automatic driving in which a vehicle autonomously travels without depending on an operation by a driver, and the like.

For example, the microcomputer 12051 can extract three-dimensional object data by classifying a plurality of pieces of the three-dimensional object data into data of a two-wheel vehicle, data of typical vehicle, data of a large-sized vehicle, data of pedestrian, and data of other three-dimensional objects such as an electric pole on the basis of the distance information obtained from the imaging units 12101 to 12104, and can use the three-dimensional object data for automatic obstacle avoidance. For example, the microcomputer 12051 discriminates obstacles at the periphery of the vehicle 12100 into an obstacle that is visually recognized by a driver of the vehicle 12100 and an obstacle that is difficult to be visually recognized by the driver. In addition, the microcomputer 12051 determines collision risk indicating the degree of danger of collision with each of the obstacles. In a situation in which the collision risk is equal to or greater than a set value, and collision may occur, the microcomputer 12051 can assist driving for collision avoidance by outputting an alarm to the drive through the audio speaker 12061 or the display unit 12062, or by performing compulsory deceleration or avoidance steering through the drive system control unit 12010.

At least one of the imaging units 12101 to 12104 may be an infrared camera that detects infrared rays. For example, the microcomputer 12051 can recognize a pedestrian by determining whether or not the pedestrian exists during image capturing by the imaging units 12101 to 12104. For example, the pedestrian recognition is performed by a procedure of extracting a specific point in images captured by the imaging units 12101 to 12104 as an infrared camera, and a procedure of performing pattern matching processing for a series of specific points indicating a contour line of an object to determine whether or not the object is a pedestrian. The microcomputer 12051 determines that a pedestrian exists on the images captured by the imaging units 12101 to 12104, and recognizes the pedestrian, the voice and image output unit 12052 controls the display unit 12062 to overlap and display a quadrangular contour line for emphasis on the pedestrian who is recognized. In addition, the voice and image output unit 12052 may control the display unit 12062 to display an icon and the like indicating the pedestrian at a desired position.

Hereinbefore, description has been given of an example of the vehicle control system to which the present technology relating to the present disclosure is applicable. The technology relating to the present disclosure is applicable to the imaging unit 12031 among the above-described configurations. Specifically, it is possible to apply the camera modules 1 relating to the first to twenty-seventh embodiments as the imaging unit 12031. When applying the technology relating to the present disclosure to the imaging unit 12031, it is possible to obtain a captured image that is easier to view, or it is possible to acquire distance information while realizing a reduction in size. In addition, it is possible to reduce fatigue of a driver or it is possible to enhance stability of a driver or a vehicle by using the captured image or the distance information which is obtained.

The present technology is applicable to a camera module that captures a distribution of an incident amount of infrared rays, X-rays, particles, and the like as an image, and the entirety of camera modules (physical amount distribution detection devices) such as a finger print detection sensor that detects other physical amount distributions such as a pressure and electrostatic capacitance and captures the distribution as an image in the broad sense without limitation to application to a camera module that detects a distribution of an incident light amount of visible light and captures the distribution as an image.

An embodiment of the present technology is not limited to the above-described embodiments, and various modifications can be made in a range not departing from the gist of the present technology.

For example, it is possible to employ an aspect in which the entirety of the plurality of embodiments described above or parts thereof are arbitrarily combined.

For example, all embodiments and examples pertaining to the laminated lens structure may be combined in any way with each other, e.g. by combining, from different embodiments/(modification) examples, laminated lens structures, lens-attached substrates, lenses, sheets, shapes, lens resin portions, manufacturing methods, camera modules, imaging units, diaphragm plates, etc. with each other.

Furthermore, the effects described in this specification are illustrative only and are not limited thereto, and effects other than the effects described in this specification may exist.

Furthermore, the present technology can have the following configurations.

(1) A laminated lens structure including:

at least one or more sheets of first lens-attached substrates and at least one or more sheets of second lens-attached substrates as a lens-attached substrate including a lens resin portion that forms a lens, and a carrier substrate that carries the lens resin portion,

in which the carrier substrate of the first lens-attached substrates is constituted by laminating a plurality of sheets of carrier configuration substrates in a thickness direction, and

the carrier substrate of the second lens-attached substrates is constituted by one sheet of carrier configuration substrate.

(2) The laminated lens structure according to (1),

in which the thickness of the carrier substrate of each of the one or more sheets of first lens-attached substrates is larger than the thickness of the carrier substrate of each of the one or more sheets of second lens-attached substrates.

(3) The laminated lens structure according to (1) or (2),

in which among a plurality of sheets of the lens-attached substrates, a lens-attached substrate that is disposed on a side closest to a light incident surface is constituted by the first lens-attached substrate.

(4) The laminated lens structure according to (1) or (2),

in which among a plurality of sheets of the lens-attached substrates, a lens-attached substrate that is disposed on a side closest to an imaging unit is constituted by the first lens-attached substrate.

(5) The laminated lens structure according to (1) or (2),

in which among a plurality of sheets of the lens-attached substrates, both a lens-attached substrate that is disposed on a side closest to a light incident surface, and a lens-attached substrate that is disposed on a side closest to an imaging unit are constituted by the first lens-attached substrate.

(6) The laminated lens structure according to any one of (1) to (5),

in which the thickness of the carrier substrate of the first lens-attached substrate is 775 μm to 1550 μm.

(7) The laminated lens structure according to any one of (1) to (5),

in which the thickness of the carrier substrate of the first lens-attached substrate is 775 μm to 2325 μm.

(8) The laminated lens structure according to any one of (1) to (7),

in which the thickness of the carrier substrate of the second lens-attached substrate is equal to or greater than 50 μm and less than 775 μm.

(9) The laminated lens structure according to any one of (1) to (7),

in which the thickness of the carrier substrate of the second lens-attached substrate is equal to or greater than 100 μm and less than 775 μm.

(10) The laminated lens structure according to any one of (1) to (7),

in which the thickness of the carrier substrate of the second lens-attached substrate is equal to or greater than 200 μm and less than 775 μm.

(11) The laminated lens structure according to any one of (1) to (10),

in which the thickness of each of the plurality of sheets of carrier configuration substrates which constitute the carrier substrate of the predetermined first lens-attached substrate among the one or more sheets of first lens-attached substrate is larger than the thickness of the carrier substrate of the one or more sheets of second lens-attached substrates.

(12) The laminated lens structure according to any one of (1) to (10),

in which the thickness of each of the plurality of sheets of carrier configuration substrates which constitute the carrier substrate of the predetermined first lens-attached substrate among the one or more sheets of first lens-attached substrate is smaller than the thickness of the carrier substrate of the one or more sheets of second lens-attached substrates.

(13) The laminated lens structure according to any one of (1) to (12),

in which the thickness of the lens resin portion in a region, in which the lens resin portion and the carrier substrate of each of the one or more sheets of first lens-attached substrate are in contact with each other, in a direction that is perpendicular to the first lens-attached substrate is larger than the thickness of the lens resin portion in a region, in which the lens resin portion and the carrier substrate of each of the one or more sheets of second lens-attached substrates are in contact with each other, in a direction that is perpendicular to the second lens-attached substrate.

(14) The laminated lens structure according to (13),

in which the thickness of the lens resin in a region, in which the lens resin portion and the carrier substrate are in contact with each other, of the carrier substrate of the first lens-attached substrate is 775 μm to 1550 μm.

(15) The laminated lens structure according to (13),

in which the thickness of the lens resin in a region, in which the lens resin portion and the carrier substrate are in contact with each other, of the carrier substrate of the first lens-attached substrate is 775 μm to 2325 μm.

(16) The laminated lens structure according to any one of (13) to (15),

in which the thickness of the lens resin in a region, in which the lens resin portion and the carrier substrate are in contact with each other, of the carrier substrate of the second lens-attached substrate is equal to or greater than 50 μm and less than 775 μm.

(17) The laminated lens structure according to any one of (13) to (15),

in which the thickness of the lens resin in a region, in which the lens resin portion and the carrier substrate are in contact with each other, of the carrier substrate of the second lens-attached substrate is equal to or greater than 100 μm and less than 775 μm.

(18) The laminated lens structure according to any one of (13) to (15),

in which the thickness of the lens resin in a region, in which the lens resin portion and the carrier substrate are in contact with each other, of the carrier substrate of the second lens-attached substrate is equal to or greater than 200 μm and less than 775 μm.

(19) The laminated lens structure according to any one of (1) to (18),

in which the thickness of a central portion of the lens resin portion of each of the one or more sheets of first lens-attached substrates is larger than the thickness of the central portion of the lens resin portion of each of the one or more sheets of second lens-attached substrates.

(20) The laminated lens structure according to (19),

in which the thickness of the central portion of the lens resin portion of the first lens-attached substrate is 775 μm to 1550 μm.

(21) The laminated lens structure according to (19),

in which the thickness of the central portion of the lens resin portion of the first lens-attached substrate is 775 μm to 2325 μm.

(22) The laminated lens structure according to any one of (19) to (21),

in which the thickness of the central portion of the lens resin portion of the second lens-attached substrate is equal to or greater than 50 μm and less than 775 μm.

(23) The laminated lens structure according to any one of (19) to (21),

in which the thickness of the central portion of the lens resin portion of the second lens-attached substrate is equal to or greater than 100 μm and less than 775 μm.

(24) The laminated lens structure according to any one of (19) to (21),

in which the thickness of the central portion of the lens resin portion of the second lens-attached substrate is equal to or greater than 200 μm and less than 775 μm.

(25) The laminated lens structure according to any one of (1) to (24),

in which the thickness of the lens of each of the one or more sheets of first lens-attached substrates is larger than the thickness of the lens of each of the one or more sheets of second lens-attached substrates.

(26) The laminated lens structure according to (25),

in which the thickness of the lens of the first lens-attached substrate is 775 μm to 1550 μm.

(27) The laminated lens structure according to (25),

in which the thickness of the lens of the first lens-attached substrate is 775 μm to 2325 μm.

(28) The laminated lens structure according to any one of (25) to (27),

in which the thickness of the lens of the second lens-attached substrate is equal to or greater than 50 μm and less than 775 μm.

(29) The laminated lens structure according to any one of (25) to (27),

in which the thickness of the lens of the second lens-attached substrate is equal to or greater than 100 μm and less than 775 μm.

(30) The laminated lens structure according to any one of (25) to (27),

in which the thickness of the lens of the second lens-attached substrate is equal to or greater than 200 μm and less than 775 μm.

(31) The laminated lens structure according to any one of (1) to (30),

in which at least one sheet of the second lens-attached substrates includes,

an extension structure in which a lower surface of the lens resin portion provided in the lens-attached substrate further extends to a lower side in comparison to a lower surface of the carrier substrate that carries the lens resin portion,

an upper surface of the lens resin portion provided in the lens-attached substrate further extends to an upper side in comparison to an upper surface of the carrier substrate that carries the lens resin portion, or

the lens resin portion provided in the lens-attached substrate further extends in upper and lower directions in comparison to the thickness of the carrier substrate.

(32) The laminated lens structure according to (31),

in which the second lens-attached substrates include a third lens-attached substrate that includes the extension structure, and a fourth lens-attached substrate that does not include the extension structure, and

among a plurality of the fourth lens-attached substrates which do not include the extension structure, when a fourth lens-attached substrate in which the thickness of the carrier substrate is equal to or less than the carrier substrate of the third lens-attached substrate is set as a fifth lens-attached substrate,

the thickness of the lens of the third lens-attached substrate is larger than the thickness of the lens of any of the fifth lens-attached substrates.

(33) The laminated lens structure according to (31) or (32),

in which the second lens-attached substrates include a third lens-attached substrate that includes the extension structure, and a sixth lens-attached substrate which is adjacent to the third lens-attached substrate, and in which a part of the lens resin portion of the third lens-attached substrate is disposed, and

the sum of the thickness of the lens resin portion that exists in a through-hole of the sixth lens-attached substrate is larger than the thickness of the lens resin portion of any of the second lens-attached substrates in which the thickness of the carrier substrate is equal to or less than the thickness of the carrier substrate of the sixth lens-attached substrate.

(34) The laminated lens structure according to any one of (31) to (33),

in which the second lens-attached substrates include a third lens-attached substrate that includes the extension structure, and a fourth lens-attached substrate that does not include the extension structure,

a part of the lens resin portion of the third lens-attached substrate is disposed in a through-hole of the first lens-attached substrate that is adjacent to the third lens-attached substrate, and

the thickness of the lens of the third lens-attached substrate is larger than the thickness of the lens of the fourth lens-attached substrate.

(35) A solid-state imaging element, including:

a laminated lens structure including at least one or more sheets of first lens-attached substrates and at least one or more sheets of second lens-attached substrates as a lens-attached substrate including a lens resin portion that forms a lens, and a carrier substrate that carries the lens resin portion, the carrier substrate of the first lens-attached substrates being constituted by laminating a plurality of sheets of carrier configuration substrates in a thickness direction, and the carrier substrate of the second lens-attached substrates being constituted by one sheet of carrier configuration substrate; and

an imaging unit that photoelectrically converts incident light that is condensed by the lens.

(36) An electronic apparatus, including:

a laminated lens structure including at least one or more sheets of first lens-attached substrates and at least one or more sheets of second lens-attached substrates as a lens-attached substrate including a lens resin portion that forms a lens, and a carrier substrate that carries the lens resin portion, the carrier substrate of the first lens-attached substrates being constituted by laminating a plurality of sheets of carrier configuration substrates in a thickness direction, and the carrier substrate of the second lens-attached substrates being constituted by one sheet of carrier configuration substrate;

an imaging unit that photoelectrically converts incident light that is condensed by the lens; and

a signal processing circuit that processes a signal that is output from the imaging unit.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 Camera module
11 Laminated lens structure
12 Imaging unit
12a Light-receiving region
13 Optical unit
41 Lens-attached substrate
42 Spacer substrate
51 Diaphragm plate
52 Opening
80 Carrier configuration substrate
81 Carrier substrate
82 Lens resin portion
83 Through-hole
85 Groove
91 Lens portion
92 Carrier portion
111 Module substrate
121 Light-shielding film
261 Concave portion
265 Diffusion region
4000 Imaging apparatus
4001 Image sensor
4002 Camera module
4003 DSP circuit

What is claimed is:

1. A laminated lens structure comprising:
at least one sheet of a first type of lens-attached substrate and at least one sheet of a second type of lens-attached substrate, wherein each of the first type and the second type lens-attached substrate includes a lens resin portion that forms a lens, and a carrier substrate that carries the lens resin portion,
wherein the carrier substrate of the first type of lens-attached substrate is constituted by a plurality of sheets of carrier configuration substrates which are laminated in a thickness direction of the carrier substrate, and
the carrier substrate of the second type of lens-attached substrate is constituted by one sheet of carrier configuration substrate.

2. The laminated lens structure according to claim 1,
wherein the thickness of the carrier substrate of the first type of lens-attached substrate is larger than the thickness of the carrier substrate of the second type of lens-attached substrate.

3. The laminated lens structure according to claim 1,
wherein a sheet of the first type of lens-attached substrate is disposed on a side closest to a light incident surface.

4. The laminated lens structure according to claim 1,
wherein a sheet of the first type of lens-attached substrate is disposed on a side closest to an imaging unit.

5. The laminated lens structure according to claim 1,
wherein a sheet of the first type of lens-attached substrate is disposed on a side closest to a light incident surface and another sheet of the first type of lens-attached substrate is disposed on a side closest to an imaging unit.

6. The laminated lens structure according to claim 1, the laminated lens structure comprising at least two sheets of the first type of lens-attached substrate,
wherein the thickness of each of the plurality of sheets of carrier configuration substrates which constitute the carrier substrate of a predetermined sheet of the at least two sheets of the first type of lens-attached substrates is larger than the thickness of the carrier substrate of the at least one sheet of the second type of lens-attached substrate.

7. The laminated lens structure according to claim 1, the laminated lens structure comprising at least two sheets of the first type of lens-attached substrate,
wherein the thickness of each of the plurality of sheets of carrier configuration substrates which constitute the carrier substrate of a predetermined sheet of the at least two sheets of the first type of lens-attached substrates is smaller than the thickness of the carrier substrate of the at least one sheet of the second type of lens-attached substrate.

8. The laminated lens structure according to claim 1,
wherein the thickness of the lens resin portion in a region, in which the lens resin portion and the carrier substrate of each of the at least one sheet of the first type of lens-attached substrate are in contact with each other, in a direction that is perpendicular to the at least one sheet of the first type of lens-attached substrate is larger than the thickness of the lens resin portion in a region, in which the lens resin portion and the carrier substrate of each of the at least one sheet of the second type of lens-attached substrate are in contact with each other, in a direction that is perpendicular to the at least one sheet of the second type of lens-attached substrate.

9. The laminated lens structure according to claim 1,
wherein the thickness of a central portion of the lens resin portion of each of the at least one sheet of the first type of lens-attached substrate is larger than the thickness of the central portion of the lens resin portion of each of the at least one sheet of the second type of lens-attached substrates.

10. The laminated lens structure according to claim 1,
wherein the thickness of the lens of each of the at least one sheet of the first type of lens-attached substrate is larger than the thickness of the lens of each of the at least one sheet of the second type of lens-attached substrate.

11. The laminated lens structure according to claim 1,
wherein the at least one sheet of the second type of lens-attached substrate includes:
an extension structure in which a lower surface of the lens resin portion provided in the lens-attached substrate further extends to a lower side in comparison to a lower surface of the carrier substrate that carries the lens resin portion, and/or
an upper surface of the lens resin portion provided in the lens-attached substrate further extending to an upper side in comparison to an upper surface of the carrier substrate that carries the lens resin portion, and/or
the lens resin portion provided in the lens-attached substrate further extending in upper and lower directions in comparison to the thickness of the carrier substrate.

12. The laminated lens structure according to claim 11,
further comprising at least one sheet of a third type of lens-attached substrate including one sheet of the second type of lens-attached substrate including the extension structure,
wherein the thickness of the lens of the at least one sheet of the third type of lens-attached substrate is larger than the thickness of the lens of any of the at least one sheet of the second type of lens-attached substrate having a thickness of the carrier substrate being equal to or larger than the thickness of the carrier substrate of the third type of lens-attached substrate.

13. The laminated lens structure according to claim 11,
further comprising at least one sheet of a third type of lens-attached substrate including one sheet of the second type of lens-attached substrate including the extension structure, and a further sheet of the second type of lens-attached substrate which is adjacent to the sheet of the third type of lens-attached substrate, and in which a part of the lens resin portion of the sheet of the third type of lens-attached substrate is disposed, and wherein
the sum of the thickness of the lens resin portion that exists in a through-hole of the further sheet of the second type of lens-attached substrate is larger than the thickness of the lens resin portion of any of the other sheets of the second type of lens-attached substrates in which the thickness of the carrier substrate is equal to or less than the thickness of the carrier substrate of the further sheet of the second type of lens-attached substrate.

14. The laminated lens structure according to claim 11,
further comprising a sheet of a third type of lens-attached substrate including one sheet of the second type of lens-attached substrate including the extension structure, wherein
a part of the lens resin portion of the sheet of the third type of lens-attached substrate is disposed in a through-hole of a sheet of the first type of lens-attached substrate that is adjacent to the sheet of the third lens-attached substrate, and
the thickness of the lens of the sheet of the third type of lens-attached substrate is larger than the thickness of the lens of the sheet of the second type of lens-attached substrate.

15. A solid-state imaging element, comprising a laminated lens structure according to claim 1; and
an imaging unit that photoelectrically converts incident light that is condensed by the lens.

16. An electronic apparatus, comprising:
a laminated lens structure according to claim 1;
an imaging unit that photoelectrically converts incident light that is condensed by the lens; and
a signal processing circuit that processes a signal that is output from the imaging unit.
